(19) United States
(12) Patent Application Publication
(10) Pub. No.: US 2025/0031513 A1
(43) Pub. Date: Jan. 23, 2025

(54) ORGANIC LIGHT EMITTING DEVICE

(71) Applicant: LT MATERIALS CO., LTD., Yongin-City (KR)

(72) Inventors: Yu-Jin HEO, Yongin-City (KR); Jun-Tae MO, Yongin-City (KR); Hyo-Kyun HAM, Yongin-City (KR); Dong-Jun KIM, Yongin-City (KR); Dae-Hyuk CHOI, Yongin-City (KR)

(73) Assignee: LT MATERIALS CO., LTD., Yongin-City (KR)

(21) Appl. No.: 18/666,931

(22) Filed: May 17, 2024

(30) Foreign Application Priority Data
Jun. 23, 2023 (KR) 10-2023-0081246

(51) Int. Cl. H10K 50/11; H10K 50/15; H10K 85/60

(52) U.S. Cl. CPC H10K 50/11; H10K 50/15; H10K 85/636; H10K 85/654; H10K 85/6572; H10K 85/6574

(57) ABSTRACT

Disclosed is an organic light emitting device which includes a heterocyclic compound of Chemical Formula 1 in a light emitting device and a compound of Chemical Formula 2 in a hole transport layer.

### CROSS-REFERENCE TO RELATED APPLICATIONS

This application claims priority to and the benefit of Korean Patent Application No. 10-2023-0081246 filed in the Korean Intellectual Property Office on Jun. 23, 2023, the entire contents of which are incorporated herein by reference.

### TECHNICAL FIELD

The present specification relates to an organic light emitting device.

### BACKGROUND ART

An organic light emitting device is a kind of self-emitting type display device, and has an advantage in that the viewing angle is wide, the contrast is excellent, and the response speed is fast.

An organic light emitting device has a structure in which an organic thin film is disposed between two electrodes. When a voltage is applied to an organic light emitting device having the structure, electrons and holes injected from the two electrodes combine with each other in an organic thin film to make a pair, and then, emit light while being extinguished. The organic thin film may be composed of a single layer or multiple layers, if necessary.

A material for the organic thin film may have a light emitting function, if necessary. For example, as the material for the organic thin film, it is also possible to use a compound, which may itself constitute a light emitting layer alone, or it is also possible to use a compound, which may serve as a host or a dopant of a host-dopant-based light emitting layer. In addition, as a material for the organic thin film, it is also possible to use a compound, which may play a role such as a hole injection, hole transport, electron blocking, hole blocking, electron transport or electron injection.

In order to improve the performance, service life, or efficiency of the organic light emitting device, there is a continuous need for developing a material for an organic thin film.

### RELATED ART DOCUMENT

### Patent Document

(Patent Document 1) U.S. Pat. No. 4,356,429

### SUMMARY OF THE INVENTION

The present specification has been made in an effort to provide an organic light emitting device.

An exemplary embodiment of the present invention provides an organic light emitting device including: a first electrode; a second electrode provided to face the first electrode; and an organic material layer having one or more layers provided between the first electrode and the second electrode, in which the organic material layer includes a light emitting layer and a hole transport layer, the light emitting layer includes a heterocyclic compound represented by the following Chemical Formula 1, and the hole transport layer includes a compound represented by the following Chemical Formula 2.

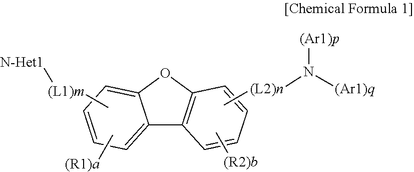

In Chemical Formula 1,
R1 and R2 are the same as or different from each other, and are each independently selected from the group consisting of hydrogen; deuterium; a halogen; —CN; a substituted or unsubstituted C1 to C60 alkyl group; a substituted or unsubstituted C2 to C60 alkenyl group; a substituted or unsubstituted C2 to C60 alkynyl group; a substituted or unsubstituted C1 to C60 alkoxy group; a substituted or unsubstituted C3 to C60 cycloalkyl group; a substituted or unsubstituted C2 to C60 heterocycloalkyl group; a substituted or unsubstituted C6 to C60 aryl group; a substituted or unsubstituted C2 to C60 heteroaryl group; —P(═O)RR′; and —SiRR′R″,
L1 and L2 are the same as or different from each other, and are each independently a direct bond; a substituted or unsubstituted C6 to C60 arylene group; or a substituted or unsubstituted C2 to C60 heteroarylene group,
Ar1 and Ar2 are the same as or different from each other, and are each independently a substituted or unsubstituted C6 to C60 aryl group; or a substituted or unsubstituted C2 to C60 heteroaryl group, or two or more adjacent groups are bonded to each other to form a substituted or unsubstituted benzocarbazole ring,
N-Het1 is a heteroaryl group which is substituted or unsubstituted and includes one or more N's,
a and b are each an integer from 0 to 3,
m and n are each an integer from 0 to 4,
p and q are each an integer from 1 to 4,
when a, b, m, n, p and q are 2 or higher, substituents in the parenthesis are the same as or different from each other,

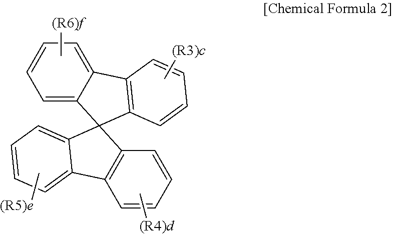

in Chemical Formula 2,
R3 to R6 are the same as or different from each other, and are each independently selected from the group consisting of hydrogen; deuterium; a halogen; —CN; a substituted or unsubstituted C1 to C60 alkyl group; a substituted or unsubstituted C2 to C60 alkenyl group; a substituted or unsubstituted C2 to C60 alkynyl group; a substituted or unsubstituted C1 to C60 alkoxy group; a substituted or unsubstituted C3 to C60 cycloalkyl group; a substituted or unsubstituted C2 to C60 heterocycloalkyl group; a substituted or unsubstituted C6 to C60 aryl group; a substituted or unsubstituted C2 to C60 heteroaryl group; —P(═O)RR′; —SiRR′R″; and the following Chemical Formula 3, and one of R3 to R6 is the following Chemical Formula 3,

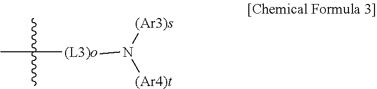

in Chemical Formula 3,

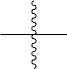

is a moiety linked to Chemical Formula 2,
L3 is a direct bond; a substituted or unsubstituted C6 to C60 arylene group; or a substituted or unsubstituted C2 to C60 heteroarylene group,
Ar3 and Ar4 are the same as or different from each other, and are each independently a substituted or unsubstituted C6 to C60 aryl group; or a substituted or unsubstituted C2 to C60 heteroaryl group,
c, d, e and f are each an integer from 0 to 4,
o is an integer of 0 to 4, and
s and t are each an integer from 1 to 4,
when c, d, e, f, o, s and t are 2 or higher, substituents in the parenthesis are the same as or different from each other, and
R, R′ and R″ are the same as or different from each other, and are each independently a substituted or unsubstituted C1 to C60 alkyl group; a substituted or unsubstituted C6 to C60 aryl group; or a substituted or unsubstituted C2 to C60 heteroaryl group.

The organic light emitting device described in the present specification can have low driving voltage, improved light emitting efficiency and long service life characteristics. Specifically, the present invention can reduce driving voltage and improve efficiency and service life by including the heterocyclic compound of Chemical Formula 1 in the light emitting layer and the compound of Chemical Formula 2 in the hole transport layer.

### BRIEF DESCRIPTION OF THE DRAWINGS

FIGS. 1 to 4 are views each exemplarily illustrating a stacking structure of an organic light emitting device according to an exemplary embodiment of the present specification.

### DETAILED DESCRIPTION

Hereinafter, the present specification will be described in more detail.

When one part “includes” one constituent element in the present specification, unless otherwise specifically described, this does not mean that another constituent element is excluded, but means that another constituent element may be further included.

In the present specification,

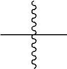

of a chemical formula means a position to which a constituent element is bonded.

The term “substitution” means that a hydrogen atom bonded to a carbon atom of a compound is changed into another substituent, and a position to be substituted is not limited as long as the position is a position at which the hydrogen atom is substituted, that is, a position at which the substituent may be substituted, and when two or more are substituted, the two or more substituents may be the same as or different from each other.

In the present specification, “substituted or unsubstituted” means being unsubstituted or substituted with one or more substituents selected from the group consisting of deuterium; a halogen group; a cyano group; a C1 to C60 alkyl group; a C2 to C60 alkenyl group; a C2 to C60 alkynyl group; a C3 to C60 cycloalkyl group; a C2 to C60 heterocycloalkyl group; a C6 to C60 aryl group; a C2 to C60 heteroaryl group; a silyl group; a phosphine oxide group; and an amine group, or with a substituent to which two or more substituents selected among the substituents are bonded.

In the present specification, “when a substituent is not indicated in the structure of a chemical formula or compound” means that a hydrogen atom is bonded to a carbon atom. However, since deuterium (²H) is an isotope of hydrogen, some hydrogen atoms may be deuterium.

In an exemplary embodiment of the present application, “when a substituent is not indicated in the structure of a chemical formula or compound” may mean that all the positions that may be reached by the substituent are hydrogen or deuterium. That is, deuterium is an isotope of hydrogen, and some hydrogen atoms may be deuterium which is an isotope, and in this case, the content of deuterium may be 0% to 100%.

In an exemplary embodiment of the present application, in “the case where a substituent is not indicated in the structure of a chemical formula or compound”, when the content of deuterium is 0%, the content of hydrogen is 100%, and all the substituents do not explicitly exclude deuterium such as hydrogen, hydrogen and deuterium may be mixed and used in the compound.

In an exemplary embodiment of the present application, deuterium is one of the isotopes of hydrogen, is an element that has a deuteron composed of one proton and one neutron as a nucleus, and may be represented by hydrogen-2, and the element symbol may also be expressed as D or ²H.

In an exemplary embodiment of the present application, the isotope means an atom with the same atomic number (Z), but different mass numbers (A), and the isotope may also be interpreted as an element which has the same number of protons, but different number of neutrons.

In an exemplary embodiment of the present application, when the total number of substituents of a basic compound is defined as T1 and the number of specific substituents among the substituents is defined as T2, the content T % of the specific substituent may be defined as T2/T1×100=T %.

That is, in an example, the deuterium content of 20% in a phenyl group represented by

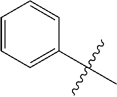 [SMILES: *c1ccccc1]

may be represented by 20% when the total number of substituents that the phenyl group can have is 5 (T1 in the formula) and the number of deuteriums among the substituents is 1 (T2 in the formula). That is, a deuterium content of 20% in the phenyl group may be represented by the following structural formula.

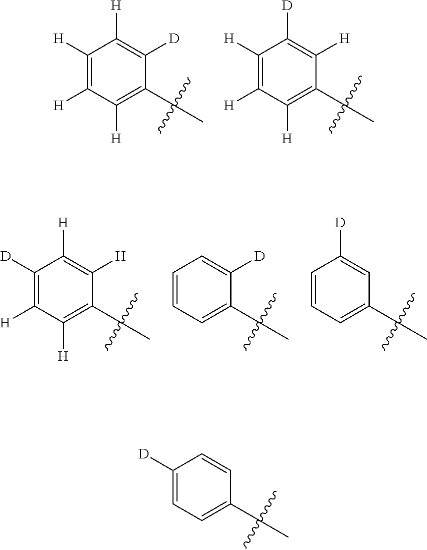 [SMILES: *c1ccccc1[2H] ; *c1cccc([2H])c1 ; *c1ccc([2H])cc1 ; *c1ccccc1[2H] ; *c1cccc([2H])c1 ; *c1ccc([2H])cc1]

Further, in an exemplary embodiment of the present application, “a phenyl group having a deuterium content of 0%” may mean a phenyl group that does not include a deuterium atom, that is, has five hydrogen atoms.

In the present specification, the halogen may be fluorine, chlorine, bromine or iodine.

In the present specification, the alkyl group includes a straight-chain or branched-chain having 1 to 60 carbon atoms, and may be additionally substituted with another substituent. The number of carbon atoms of the alkyl group may be 1 to 60, specifically 1 to 40, and more specifically 1 to 20. Specific examples thereof include a methyl group, an ethyl group, a propyl group, an n-propyl group, an isopropyl group, a butyl group, an n-butyl group, an isobutyl group, a tert-butyl group, a sec-butyl group, a 1-methyl-butyl group, a 1-ethyl-butyl group, a pentyl group, an n-pentyl group, an isopentyl group, a neopentyl group, a tert-pentyl group, a hexyl group, an n-hexyl group, a 1-methylpentyl group, a 2-methylpentyl group, a 4-methyl-2-pentyl group, a 3,3-dimethylbutyl group, a 2-ethylbutyl group, a heptyl group, an n-heptyl group, a 1-methylhexyl group, a cyclopentylmethyl group, a cyclohexylmethyl group, an octyl group, an n-octyl group, a tert-octyl group, a 1-methylheptyl group, a 2-ethylhexyl group, a 2-propylpentyl group, an n-nonyl group, a 2,2-dimethylheptyl group, a 1-ethyl-propyl group, a 1,1-dimethyl-propyl group, an isohexyl group, a 2-methylpentyl group, a 4-methylhexyl group, a 5-methylhexyl group, and the like, but are not limited thereto.

In the present specification, the alkenyl group includes a straight-chain or branched-chain having 2 to 60 carbon atoms, and may be additionally substituted with another substituent. The number of carbon atoms of the alkenyl group may be 2 to 60, specifically 2 to 40, and more specifically 2 to 20. Specific examples thereof include a vinyl group, a 1-propenyl group, an isopropenyl group, a 1-butenyl group, a 2-butenyl group, a 3-butenyl group, a 1-pentenyl group, a 2-pentenyl group, a 3-pentenyl group, a 3-methyl-1-butenyl group, a 1,3-butadienyl group, an allyl group, a 1-phenylvinyl-1-yl group, a 2-phenylvinyl-1-yl group, a 2,2-diphenylvinyl-1-yl group, a 2-phenyl-2-(naphthyl-1-yl)vinyl-1-yl group, a 2,2-bis(diphenyl-1-yl)vinyl-1-yl group, a stilbenyl group, a styrenyl group, and the like, but are not limited thereto.

In the present specification, the alkynyl group includes a straight-chain or branched-chain having 2 to 60 carbon atoms, and may be additionally substituted with another substituent. The number of carbon atoms of the alkynyl group may be 2 to 60, specifically 2 to 40, and more specifically 2 to 20.

In the present specification, an alkoxy group may be straight-chained, branched, or cyclic. The number of carbon atoms of the alkoxy group is not particularly limited, but is preferably 1 to 20. Specific examples thereof include methoxy, ethoxy, n-propoxy, isopropoxy, n-butoxy, isobutoxy, tert-butoxy, sec-butoxy, n-pentyloxy, neopentyloxy, isopentyloxy, n-hexyloxy, 3,3-dimethylbutyloxy, 2-ethylbutyloxy, n-octyloxy, n-nonyloxy, n-decyloxy, benzyloxy, p-methylbenzyloxy, and the like, but are not limited thereto.

In the present specification, the cycloalkyl group includes a monocycle or polycycle having 3 to 60 carbon atoms, and may be additionally substituted with another substituent. Here, the polycycle means a group in which a cycloalkyl group is directly linked to or fused with another cyclic group. Here, another cyclic group may also be a cycloalkyl group, but may also be another kind of cyclic group, for example, a heterocycloalkyl group, an aryl group, a heteroaryl group, and the like. The number of carbon atoms of the cycloalkyl group may be 3 to 60, specifically 3 to 40, and more specifically 5 to 20. Specific examples thereof include a cyclopropyl group, a cyclobutyl group, a cyclopentyl group, a 3-methylcyclopentyl group, a 2,3-dimethylcyclopentyl group, a cyclohexyl group, a 3-methylcyclohexyl group, a 4-methylcyclohexyl group, a 2,3-dimethylcyclohexyl group, a 3,4,5-trimethylcyclohexyl group, a 4-tert-butylcyclohexyl group, a cycloheptyl group, a cyclooctyl group, and the like, but are not limited thereto.

In the present specification, the heterocycloalkyl group includes O, S, Se, N, or Si as a heteroatom, includes a monocycle or polycycle having 2 to 60 carbon atoms, and may be additionally substituted with another substituent. Here, the polycycle means a group in which a heterocycloalkyl group is directly linked to or fused with another cyclic group. Here, another cyclic group may also be a heterocycloalkyl group, but may also be another kind of cyclic group, for example, a cycloalkyl group, an aryl group, a heteroaryl group, and the like. The number of carbon atoms of the heterocycloalkyl group may be 2 to 60, specifically 2 to 40, and more specifically 3 to 20.

In the present specification, the aryl group includes a monocycle or polycycle having 6 to 60 carbon atoms, and may be additionally substituted with another substituent. Here, the polycycle means a group in which an aryl group is directly linked to or fused with another cyclic group. Here, another cyclic group may also be an aryl group, but may also be another kind of cyclic group, for example, a cycloalkyl group, a heterocycloalkyl group, a heteroaryl group, and the like. The aryl group includes a spiro group. The number of carbon atoms of the aryl group may be 6 to 60, specifically 6 to 40, and more specifically 6 to 25. Specific examples of the aryl group include a phenyl group, a biphenyl group, a terphenyl group, a naphthyl group, an anthryl group, a chrysenyl group, a phenanthrenyl group, a perylenyl group, a fluoranthenyl group, a triphenylenyl group, a phenalenyl group, a pyrenyl group, a tetracenyl group, a pentacenyl group, a fluorenyl group, an indenyl group, an acenaphthylenyl group, a benzofluorenyl group, a spirobifluorenyl group, a 2,3-dihydro-1H-indenyl group, a fused cyclic group thereof, and the like, but are not limited thereto.

In the present specification, the terphenyl group may be selected from the following structures.

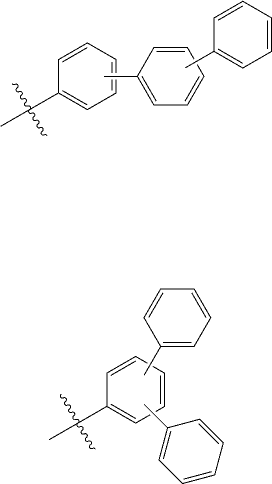

In the present specification, the fluorenyl group may be substituted, and adjacent substituents may be bonded to each other to form a ring.

When the fluorenyl group is substituted, the following structures may be exemplified, but the structure is not limited thereto.

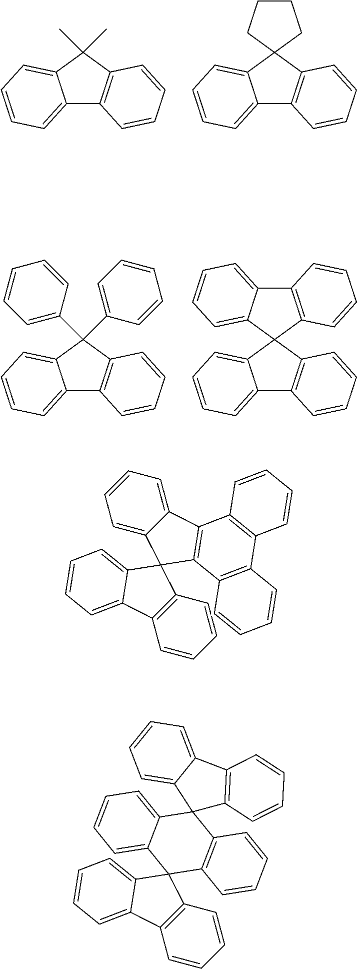

In the present specification, the heteroaryl group includes S, O, Se, N, or Si as a heteroatom, includes a monocycle or polycycle having 2 to 60 carbon atoms, and may be additionally substituted with another substituent. Here, the polycycle means a group in which a heteroaryl group is directly linked to or fused with another cyclic group. Here, another cyclic group may also be a heteroaryl group, but may also be another kind of cyclic group, for example, a cycloalkyl group, a heterocycloalkyl group, an aryl group, and the like. The number of carbon atoms of the heteroaryl group may be 2 to 60, specifically 2 to 40, and more specifically 3 to 25. Specific examples of the heteroaryl group include a pyridyl group, a pyrrolyl group, a pyrimidyl group, a pyridazinyl group, a furanyl group, a thiophene group, an imidazolyl group, a pyrazolyl group, an oxazolyl group, an isoxazolyl group, a thiazolyl group, an isothiazolyl group, a triazolyl group, a furazanyl group, an oxadiazolyl group, a thiadiazolyl group, a dithiazolyl group, a tetrazolyl group, a pyranyl group, a thiopyranyl group, a diazinyl group, an oxazinyl group, a thiazinyl group, a dioxynyl group, a triazinyl group, a tetrazinyl group, a quinolyl group, an isoquinolyl group, a quinazolinyl group, an isoquinazolinyl group, a quinozolilyl group, a naphthyridyl group, an acridinyl group, a phenanthridinyl group, an imidazopyridinyl group, a diaza naphthalenyl group, a triazaindene group, an indolyl group, an indolizinyl group, a benzothiazolyl group, a benzoxazolyl group, a benzimidazolyl group, a benzothiophene group, a benzofuran group, a dibenzothiophene group, a dibenzofuran group, a carbazolyl group, a benzocarbazolyl group, a dibenzocarbazolyl group, a phenazinyl group, a dibenzosilole group, spirobi (dibenzosilole), a dihydrophenazinyl group, a phenoxazinyl group, a phenanthridyl group, an imidazopyridinyl group, a thienyl group, an indolo[2,3-a]carbazolyl group, an indolo[2,3-b]carbazolyl group, an indolinyl group, a 10,11-dihydro-dibenzo[b,f]azepin group, a 9,10-dihydroacridinyl group, a phenanthrazinyl group, a phenothiathiazinyl group, a phthalazinyl group, a naphthylidinyl group, a phenanthrolinyl group, a benzo[c][1,2,5]thiadiazolyl group, a 2,3-dihydrobenzo[b]thiophene group, a 2,3-dihydrobenzofuran group, a 5,10-dihydrodibenzo[b,e][1,4]azasilinyl group, a pyrazolo[1,5-c]quinazolinyl group, a pyrido[1,2-b]indazolyl group, a pyrido[1,2-a]imidazo[1,2-e]indolinyl group, a 5,11-dihydroindeno[1,2-b]carbazolyl group, and the like, but are not limited thereto.

In the present specification, a silyl group includes Si and is a substituent to which the Si atom is directly linked as a radical, and is represented by —Si(R101) (R102) (R103), and R101 to R103 are the same as or different from each other, and may be each independently a substituent composed of at least one of hydrogen; deuterium; a halogen group; an alkyl group; an alkenyl group; an alkoxy group; a cycloalkyl group; a heterocycloalkyl group; an aryl group; and a heteroaryl group.

Examples of the silyl group include

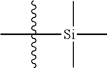 [SMILES: *[Si](C)(C)C]

(a trimethylsilyl group),

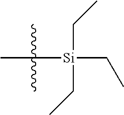 [SMILES: *[Si](CC)(CC)CC]

(a triethylsilyl group),

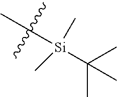 [SMILES: *[Si](C)(C)C(C)(C)C]

(a t-butyldimethylsilyl group),

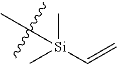 [SMILES: *[Si](C)(C)C=C]

(a vinyldimethylsilyl group),

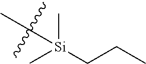 [SMILES: *[Si](C)(C)CCC]

(a propyldimethylsilyl group),

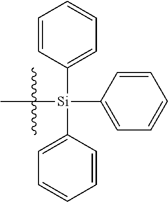 [SMILES: *[Si](c1ccccc1)(c1ccccc1)c1ccccc1]

(a triphenylsilyl group),

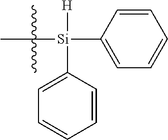 [SMILES: *[SiH](c1ccccc1)c1ccccc1]

(a diphenylsilyl group),

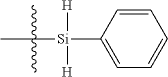 [SMILES: *[SiH2]c1ccccc1]

(a phenylsilyl group) and the like, but are not limited thereto.

In the present specification, the phosphine oxide group is represented by —P(═O) (R104) (R105), and R104 and R105 are the same as or different from each other, and may be each independently a substituent composed of at least one of hydrogen; deuterium; a halogen group; an alkyl group; an alkenyl group; an alkoxy group; a cycloalkyl group; a heterocycloalkyl group; an aryl group; and a heteroaryl group. Specifically, the phosphine oxide group may be substituted with an alkyl group or an aryl group, and the above-described example may be applied to the alkyl group and the aryl group. Examples of the phosphine oxide group include a dimethylphosphine oxide group, a diphenylphosphine oxide group, a dinaphthylphosphine oxide group, and the like, but are not limited thereto.

In the present specification, the amine group is represented by —N(R106) (R107), and R106 and R107 are the same as or different from each other, and may be each independently a substituent composed of at least one of hydrogen; deuterium; a halogen group; an alkyl group; an alkenyl group; an alkoxy group; a cycloalkyl group; a heterocycloalkyl group; an aryl group; and a heteroaryl group. The amine group may be selected from the group consisting of —NH₂; a monoalkylamine group; a monoarylamine group; a monoheteroarylamine group; a dialkylamine group; a diarylamine group; a diheteroarylamine group; an alkylarylamine group; an alkylheteroarylamine group; and an arylheteroarylamine group, and the number of carbon atoms thereof is not particularly limited, but is preferably 1 to 30. Specific examples of the amine group include a methylamine group, a dimethylamine group, an ethylamine group, a diethylamine group, a phenylamine group, a naphthylamine group, a biphenylamine group, a dibiphenylamine group, an anthracenylamine group, a 9-methyl-anthracenylamine group, a diphenylamine group, a phenylnaphthylamine group, a ditolylamine group, a phenyltolylamine group, a triphenylamine group, a biphenylnaphthylamine group, a phenylbiphenylamine group, a biphenylfluorenylamine group, a phenyltriphenylenylamine group, a biphenyltriphenylenylamine group, and the like, but are not limited thereto.

In the present specification, the above-described examples of the aryl group may be applied to an arylene group except for a divalent arylene group.

In the present specification, the above-described examples of the heteroaryl group may be applied to a heteroarylene group except for a divalent heteroarylene group.

An exemplary embodiment of the present specification provides an organic light emitting device including: a first electrode; a second electrode provided to face the first electrode; and an organic material layer having one or more layers provided between the first electrode and the second electrode, in which the organic material layer includes a light emitting layer and a hole transport layer, the light emitting layer includes a heterocyclic compound represented by the following Chemical Formula 1, and the hole transport layer includes a compound represented by the following Chemical Formula 2.

In an exemplary embodiment of the present application, Chemical Formula 1 may be represented by any one of the following Chemical Formulae 1-1 to 1-16.

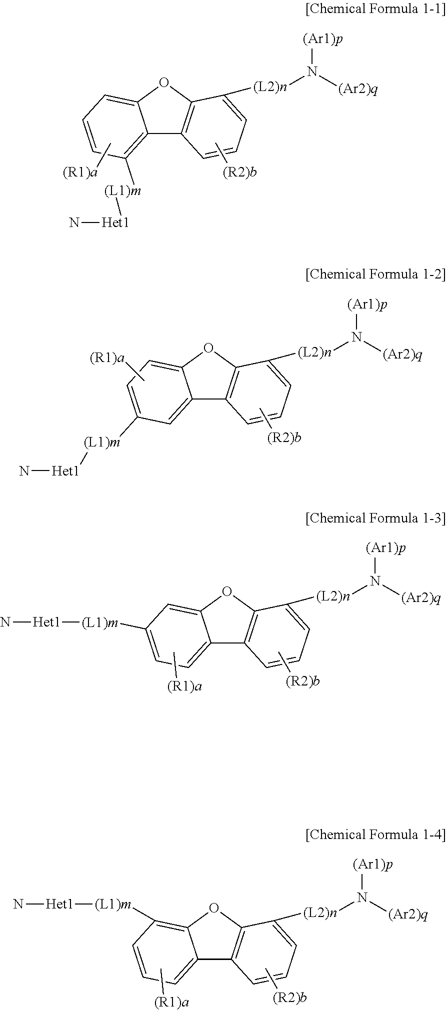

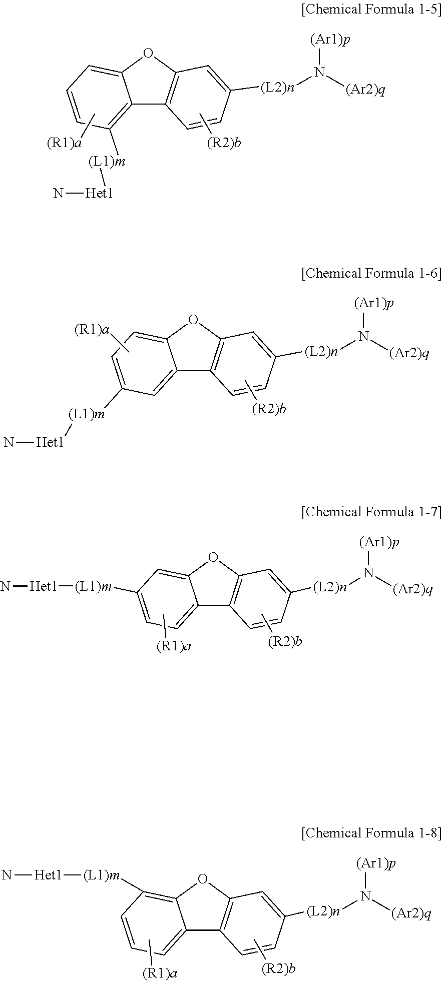

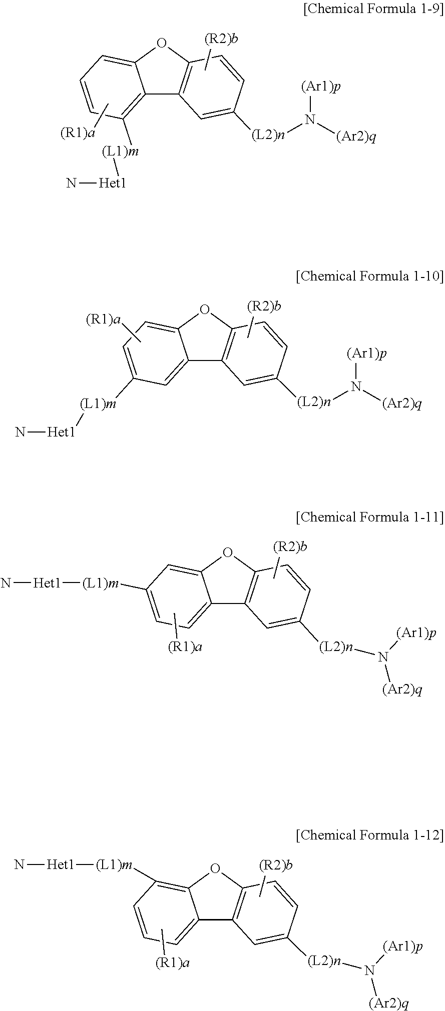

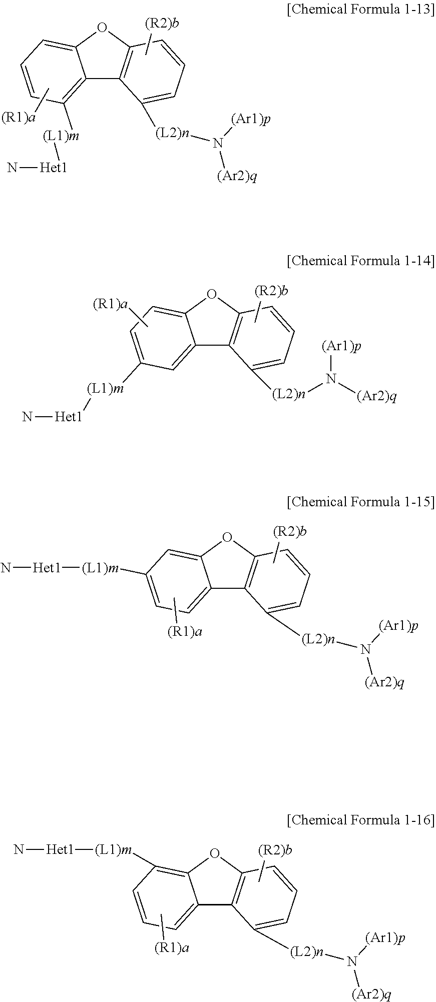

In Chemical Formulae 1-1 to 1-16, the definition of each substituent is the same as the definition in Chemical Formula 1.

In an exemplary embodiment of the present application,

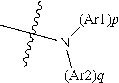

of Chemical Formula 1 may be represented by the following Structural Formula A or the following Structural Formula B.

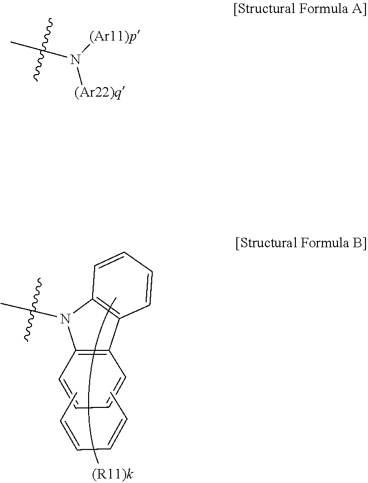

In Structural Formulae A and B,

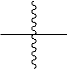

is a moiety linked to L2,
Ar11 and Ar22 are the same as or different from each other, and are each independently a substituted or unsubstituted C6 to C60 aryl group; or a substituted or unsubstituted C2 to C60 heteroaryl group,
p′ and q′ are each an integer from 1 to 4, and when each of p′ and q′ is 2 or higher, substituents in the parenthesis are the same as or different from each other,
R11 is a substituted or unsubstituted C6 to C60 aryl group; or a substituted or unsubstituted C2 to C60 heteroaryl group, and
k is an integer from 0 to 10, and when k is 2 or higher, R11's are the same as or different from each other.

In an exemplary embodiment of the present application, Chemical Formula 2 may be represented by any one of the following Chemical Formulae 2-1 to 2-4.

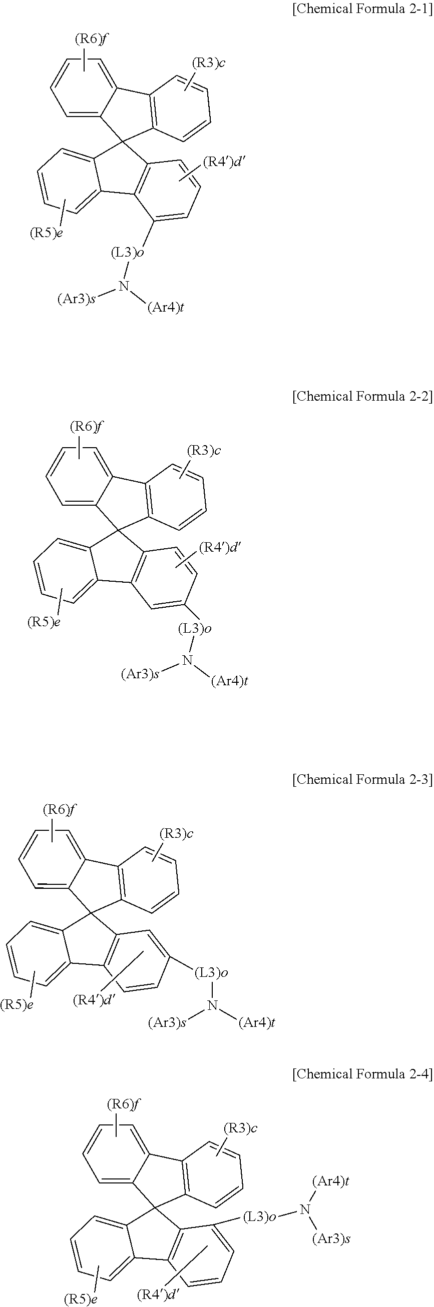

In Chemical Formulae 2-1 to 2-4,
the definitions of R3, R5, R6, L3, Ar3, Ar4, c, f, e, o, s and t are the same as those defined in Chemical Formula 2,
R4′ is selected from the group consisting of hydrogen; deuterium; a halogen; —CN; a substituted or unsubstituted C1 to C60 alkyl group; a substituted or unsubstituted C2 to C60 alkenyl group; a substituted or unsubstituted C2 to C60 alkynyl group; a substituted or unsubstituted C1 to C60 alkoxy group; a substituted or unsubstituted C3 to C60 cycloalkyl group; a substituted or unsubstituted C2 to C60 heterocycloalkyl group; a substituted or unsubstituted C6 to C60 aryl group; a substituted or unsubstituted C2 to C60 heteroaryl group; —P(═O)RR′; and —SiRR′R″,
R, R′ and R″ are the same as or different from each other, and are each independently a substituted or unsubstituted C1 to C60 alkyl group; a substituted or unsubstituted C6 to C60 aryl group; or a substituted or unsubstituted C2 to C60 heteroaryl group, and
d′ is an integer from 0 to 3, and when d′ is 2 or higher, R4's are the same as or different from each other.

In an exemplary embodiment of the present application, R1 and R2 are the same as or different from each other, and may be each independently selected from the group consisting of hydrogen; deuterium; a halogen; —CN; a substituted or unsubstituted C1 to C60 alkyl group; a substituted or unsubstituted C2 to C60 alkenyl group; a substituted or unsubstituted C2 to C60 alkynyl group; a substituted or unsubstituted C1 to C60 alkoxy group; a substituted or unsubstituted C3 to C60 cycloalkyl group; a substituted or unsubstituted C2 to C60 heterocycloalkyl group; a substituted or unsubstituted C6 to C60 aryl group; a substituted or unsubstituted C2 to C60 heteroaryl group; —P(═O)RR′; and —SiRR′R″.

In an exemplary embodiment of the present application, R1 and R2 are the same as or different from each other, and may be each independently selected from the group consisting of hydrogen; deuterium; a halogen; —CN; a substituted or unsubstituted C1 to C40 alkyl group; a substituted or unsubstituted C2 to C40 alkenyl group; a substituted or unsubstituted C2 to C40 alkynyl group; a substituted or unsubstituted C1 to C40 alkoxy group; a substituted or unsubstituted C3 to C40 cycloalkyl group; a substituted or unsubstituted C2 to C40 heterocycloalkyl group; a substituted or unsubstituted C6 to C40 aryl group; a substituted or unsubstituted C2 to C40 heteroaryl group; —P(═O)RR′; and —SiRR′R″.

In an exemplary embodiment of the present application, R1 and R2 are the same as or different from each other, and may be each independently selected from the group consisting of hydrogen; deuterium; a halogen; —CN; a substituted or unsubstituted C1 to C20 alkyl group; a substituted or unsubstituted C2 to C20 alkenyl group; a substituted or unsubstituted C2 to C20 alkynyl group; a substituted or unsubstituted C1 to C20 alkoxy group; a substituted or unsubstituted C3 to C20 cycloalkyl group; a substituted or unsubstituted C2 to C20 heterocycloalkyl group; a substituted or unsubstituted C6 to C20 aryl group; a substituted or unsubstituted C2 to C20 heteroaryl group; —P(═O)RR′; and —SiRR′R″.

In an exemplary embodiment of the present application, R1 and R2 are the same as or different from each other, and may be each independently selected from the group consisting of hydrogen; deuterium; a halogen; and —CN.

In an exemplary embodiment of the present application, R1 and R2 are the same as or different from each other, and may be each independently hydrogen; or deuterium.

In an exemplary embodiment of the present application, L1 and L2 are the same as or different from each other, and may be each independently a direct bond; a substituted or unsubstituted C6 to C60 arylene group; or a substituted or unsubstituted C2 to C60 heteroarylene group.

In an exemplary embodiment of the present application, L1 and L2 are the same as or different from each other, and may be each independently a direct bond; a substituted or unsubstituted C6 to C40 arylene group; or a substituted or unsubstituted C2 to C40 heteroarylene group.

In an exemplary embodiment of the present application, L1 and L2 are the same as or different from each other, and may be each independently a direct bond; a substituted or unsubstituted C6 to C20 arylene group; or a substituted or unsubstituted C2 to C20 heteroarylene group.

In an exemplary embodiment of the present application, L1 and L2 are the same as or different from each other, and may be each independently a direct bond; or a substituted or unsubstituted C6 to C20 arylene group.

In an exemplary embodiment of the present application, L1 and L2 are the same as or different from each other, and may be each independently a direct bond; or an unsubstituted C6 to C20 arylene group.

In an exemplary embodiment of the present application, L1 and L2 are the same as or different from each other, and may be each independently a direct bond; or an unsubstituted C6 to C12 arylene group.

In an exemplary embodiment of the present application, L1 and L2 are the same as or different from each other, and may be each independently a direct bond; a phenylene group; or a naphthylene group.

In an exemplary embodiment of the present application, Ar1 and Ar2 are the same as or different from each other, and are each independently a substituted or unsubstituted C6 to C60 aryl group; or a substituted or unsubstituted C2 to C60 heteroaryl group, or two or more adjacent groups may be bonded to each other to form a substituted or unsubstituted benzocarbazole ring.

In an exemplary embodiment of the present application, Ar1 and Ar2 are the same as or different from each other, and are each independently a substituted or unsubstituted C6 to C40 aryl group; or a substituted or unsubstituted C2 to C40 heteroaryl group, or two or more adjacent groups may be bonded to each other to form a substituted or unsubstituted benzocarbazole ring.

In an exemplary embodiment of the present application, Ar1 and Ar2 are the same as or different from each other, and are each independently a substituted or unsubstituted C6 to C20 aryl group; or a substituted or unsubstituted C2 to C20 heteroaryl group, or two or more adjacent groups may be bonded to each other to form a substituted or unsubstituted benzocarbazole ring.

In an exemplary embodiment of the present application, Ar1 and Ar2 are the same as or different from each other, and are each independently a substituted or unsubstituted phenyl group; a substituted or unsubstituted biphenyl group; a substituted or unsubstituted naphthyl group; a substituted or unsubstituted terphenyl group; a substituted or unsubstituted fluorenyl group; a substituted or unsubstituted dibenzofuran group; or a substituted or unsubstituted dibenzothiophene group, or two or more adjacent groups may be bonded to each other to form a substituted or unsubstituted benzocarbazole ring.

In an exemplary embodiment of the present application, Ar1 and Ar2 are the same as or different from each other, and are a phenyl group unsubstituted or substituted with deuterium; a biphenyl group unsubstituted or substituted with deuterium; a naphthyl group unsubstituted or substituted with deuterium; a terphenyl group unsubstituted or substituted with deuterium; a fluorenyl group unsubstituted or substituted with deuterium, an alkyl group, or an aryl group; a dibenzofuran group unsubstituted or substituted with deuterium; or a dibenzothiophene group unsubstituted or substituted with deuterium, or two or more adjacent groups may be bonded to each other to form a benzocarbazole ring unsubstituted or substituted with deuterium, a C6 to C60 aryl group, or a C2 to C60 heteroaryl group.

In an exemplary embodiment of the present application, Ar1 and Ar2 are the same as or different from each other, and are each independently a phenyl group unsubstituted or substituted with deuterium; a biphenyl group unsubstituted or substituted with deuterium; a naphthyl group unsubstituted or substituted with deuterium; a terphenyl group unsubstituted or substituted with deuterium; a fluorenyl group unsubstituted or substituted with deuterium, an alkyl group, or an aryl group; a dibenzofuran group unsubstituted or substituted with deuterium; or a dibenzothiophene group unsubstituted or substituted with deuterium, or two or more adjacent groups may be bonded to each other to form a benzocarbazole ring unsubstituted or substituted with one or more substituents of deuterium, a C6 to C40 aryl group and a C2 to C40 heteroaryl group.

In an exemplary embodiment of the present application, Ar1 and Ar2 are the same as or different from each other, and are each independently a phenyl group unsubstituted or substituted with deuterium; a biphenyl group unsubstituted or substituted with deuterium; a naphthyl group unsubstituted or substituted with deuterium; a terphenyl group unsubstituted or substituted with deuterium; a fluorenyl group unsubstituted or substituted with deuterium, an alkyl group, or an aryl group; a dibenzofuran group unsubstituted or substituted with deuterium; or a dibenzothiophene group unsubstituted or substituted with deuterium, or two or more adjacent groups may be bonded to each other to form a benzocarbazole ring unsubstituted or substituted with one or more substituents of deuterium, a C6 to C20 aryl group and a C2 to C20 heteroaryl group.

In an exemplary embodiment of the present application, Ar1 and Ar2 are the same as or different from each other, and are each independently a phenyl group unsubstituted or substituted with deuterium; a biphenyl group unsubstituted or substituted with deuterium; a naphthyl group unsubstituted or substituted with deuterium; a terphenyl group unsubstituted or substituted with deuterium; a fluorenyl group unsubstituted or substituted with deuterium, an alkyl group, or an aryl group; a dibenzofuran group unsubstituted or substituted with deuterium; or a dibenzothiophene group unsubstituted or substituted with deuterium, or two or more adjacent groups may be bonded to each other to form a benzocarbazole ring unsubstituted or substituted with one or more substituents of deuterium, a phenyl group, a biphenyl group, a naphthyl group, a dibenzofuran group, a dibenzothiophene group and a carbazole group.

In an exemplary embodiment of the present application, N-Het1 may be a heteroaryl group which is substituted or unsubstituted and includes one or more N's.

In an exemplary embodiment of the present application, N-Het1 may be a heteroaryl group which is substituted or unsubstituted and includes two or more N's.

In an exemplary embodiment of the present application, N-Het1 may be a monocyclic or polycyclic heteroaryl group which is substituted or unsubstituted and includes two or more N's.

In an exemplary embodiment of the present application, N-Het1 may be a C2 to C60 heteroaryl group which is substituted or unsubstituted and includes two or more N's.

In an exemplary embodiment of the present application, N-Het1 may be a C2 to C40 heteroaryl group which is substituted or unsubstituted and include two or more N's.

In an exemplary embodiment of the present application, N-Het1 may be a C2 to C20 heteroaryl group which is substituted or unsubstituted and includes two or more N's.

In an exemplary embodiment of the present application, N-Het1 may be a structure represented by the following Structural Formula N.

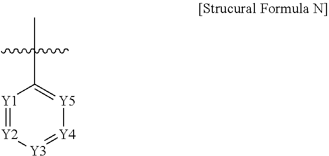

In Structural Formula N,

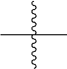

means a moiety linked to L1,
Y1 to Y5 are the same as or different from each other, and are each independently CRa or N, and at least one is N, and
Ra is a substituted or unsubstituted C6 to C60 aryl group; or a substituted or unsubstituted C2 to C60 heteroaryl group, or two or more adjacent Ra groups may be bonded to each other to form a ring.

In an exemplary embodiment of the present application, at least two of Y1 to Y5 may be N.

In an exemplary embodiment of the present application, Ra is a substituted or unsubstituted C6 to C40 aryl group; or a substituted or unsubstituted C2 to C40 heteroaryl group, or two or more adjacent Ra groups may be bonded to each other to form a substituted or unsubstituted C2 to C40 aromatic ring.

In an exemplary embodiment of the present application, Ra is a substituted or unsubstituted C6 to C20 aryl group; or a substituted or unsubstituted C2 to C20 heteroaryl group, or two or more adjacent Ra groups may be bonded to each other to form a substituted or unsubstituted C2 to C20 heteroaryl ring or C6 to C20 aryl ring.

In an exemplary embodiment of the present application, Ra is a substituted or unsubstituted phenyl group; a substituted or unsubstituted biphenyl group; a substituted or unsubstituted naphthyl group; a substituted or unsubstituted terphenyl group; a substituted or unsubstituted fluorenyl group; a substituted or unsubstituted dibenzofuran group; a substituted or unsubstituted dibenzothiophene group; or a substituted or unsubstituted carbazole group, or two or more adjacent Ra groups may be bonded to each other to form a substituted or unsubstituted benzofuran ring; a substituted or unsubstituted benzothiophene ring; or a substituted or unsubstituted phenyl ring.

In an exemplary embodiment of the present application, Ra is a phenyl group unsubstituted or substituted with deuterium; a biphenyl group unsubstituted or substituted with deuterium; a naphthyl group unsubstituted or substituted with deuterium; a terphenyl group unsubstituted or substituted with deuterium; a fluorenyl group unsubstituted or substituted with deuterium, an alkyl group or an aryl group; a dibenzofuran group unsubstituted or substituted with deuterium; a dibenzothiophene group unsubstituted or substituted with deuterium; or a carbazole group unsubstituted or substituted with deuterium, or two or more adjacent Ra groups may be bonded to each other to form a benzofuran ring unsubstituted or substituted with deuterium; a benzothiophene ring unsubstituted or substituted with deuterium; or a phenyl ring unsubstituted or substituted with deuterium.

In an exemplary embodiment of the present application, Structural Formula N may be selected from among the following structural formulae.

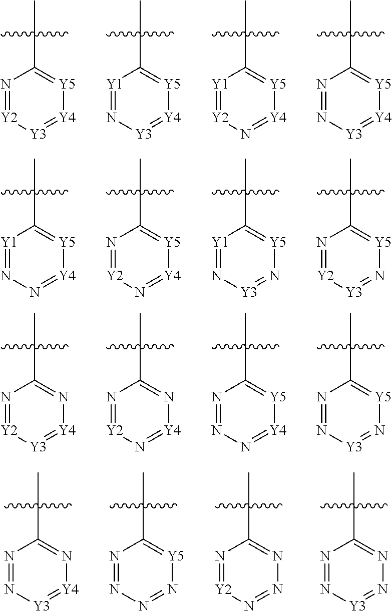

In the structural formulae, the definitions of

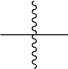

and Y1 to Y5 are the same as those defined in Structural Formula N.

In an exemplary embodiment of the present application, when the two or more adjacent Ra groups of Structural Formula N are bonded to each other to form a substituted or unsubstituted phenyl ring, Structural Formula N may be selected from among the following structural formulae.

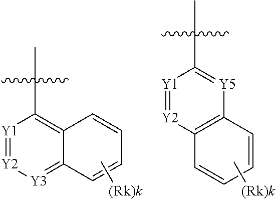

In the structural formulae, the definitions of

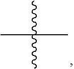

Y1 to Y3 and Y5 are the same as those defined in Structural Formula N,
Rk is selected from the group consisting of hydrogen; deuterium; a halogen; —CN; a substituted or unsubstituted C1 to C60 alkyl group; a substituted or unsubstituted C2 to C60 alkenyl group; a substituted or unsubstituted C2 to C60 alkynyl group; a substituted or unsubstituted C1 to C60 alkoxy group; a substituted or unsubstituted C3 to C60 cycloalkyl group; a substituted or unsubstituted C2 to C60 heterocycloalkyl group; a substituted or unsubstituted C6 to C60 aryl group; and a substituted or unsubstituted C2 to C60 heteroaryl group, and
k is an integer from 0 to 4, and when k is 2 or higher, Rk's are the same as or different from each other.

In an exemplary embodiment of the present application, when the two or more adjacent Ra groups of Structural Formula N are bonded to each other to form a substituted or unsubstituted benzofuran ring, Structural Formula N may be selected from among the following structural formulae.

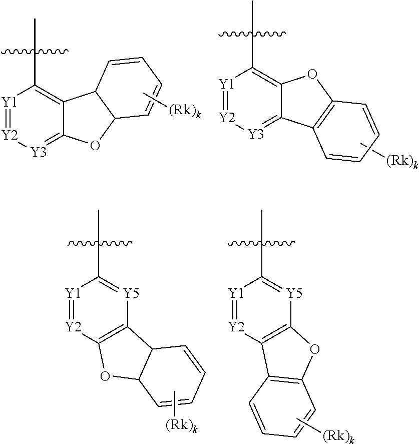

In the structural formulae,

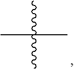

Y1 to Y3 and Y5 are the same as those defined in Structural Formula N,
Rk is selected from the group consisting of hydrogen; deuterium; a halogen; —CN; a substituted or unsubstituted C1 to C60 alkyl group; a substituted or unsubstituted C2 to C60 alkenyl group; a substituted or unsubstituted C2 to C60 alkynyl group; a substituted or unsubstituted C1 to C60 alkoxy group; a substituted or unsubstituted C3 to C60 cycloalkyl group; a substituted or unsubstituted C2 to C60 heterocycloalkyl group; a substituted or unsubstituted C6 to C60 aryl group; and a substituted or unsubstituted C2 to C60 heteroaryl group, and
k is an integer from 0 to 4, and when k is 2 or higher, Rk's are the same as or different from each other.

In an exemplary embodiment of the present application, when the two or more adjacent Ra groups of Structural Formula N are bonded to each other to form a substituted or unsubstituted benzothiophene ring, Structural Formula N may be selected from among the following structural formulae.

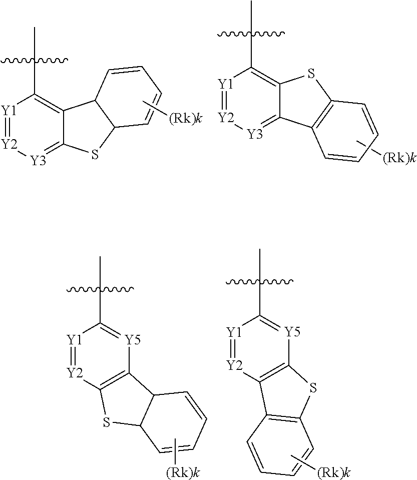

In the structural formulae, the definitions of

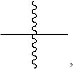

Y1 to Y3 and Y5 are the same as those defined in Structural Formula N, Rk is selected from the group consisting of hydrogen; deuterium; a halogen; —CN; a substituted or unsubstituted C1 to C60 alkyl group; a substituted or unsubstituted C2 to C60 alkenyl group; a substituted or unsubstituted C2 to C60 alkynyl group; a substituted or unsubstituted C1 to C60 alkoxy group; a substituted or unsubstituted C3 to C60 cycloalkyl group; a substituted or unsubstituted C2 to C60 heterocycloalkyl group; a substituted or unsubstituted C6 to C60 aryl group; and a substituted or unsubstituted C2 to C60 heteroaryl group, and
k is an integer from 0 to 4, and when k is 2 or higher, Rk's are the same as or different from each other.

In an exemplary embodiment of the present application, Rk may be selected from the group consisting of hydrogen; deuterium; a halogen; —CN; a substituted or unsubstituted C1 to C40 alkyl group; a substituted or unsubstituted C2 to C40 alkenyl group; a substituted or unsubstituted C2 to C40 alkynyl group; a substituted or unsubstituted C1 to C40 alkoxy group; a substituted or unsubstituted C3 to C40 cycloalkyl group; a substituted or unsubstituted C2 to C40 heterocycloalkyl group; a substituted or unsubstituted C6 to C40 aryl group; and a substituted or unsubstituted C2 to C40 heteroaryl group.

In an exemplary embodiment of the present application, Rk may be selected from the group consisting of hydrogen; deuterium; a halogen; —CN; a substituted or unsubstituted C1 to C20 alkyl group; a substituted or unsubstituted C2 to C20 alkenyl group; a substituted or unsubstituted C2 to C20 alkynyl group; a substituted or unsubstituted C1 to C20 alkoxy group; a substituted or unsubstituted C3 to C20 cycloalkyl group; a substituted or unsubstituted C2 to C20 heterocycloalkyl group; a substituted or unsubstituted C6 to C20 aryl group; and a substituted or unsubstituted C2 to C20 heteroaryl group.

In an exemplary embodiment of the present application, Rk may be selected from the group consisting of hydrogen; deuterium; a halogen; —CN; a substituted or unsubstituted C1 to C20 alkyl group; a substituted or unsubstituted C2 to C20 alkenyl group; a substituted or unsubstituted C2 to C20 alkynyl group; a substituted or unsubstituted C1 to C20 alkoxy group; a substituted or unsubstituted C3 to C20 cycloalkyl group; and a substituted or unsubstituted C2 to C20 heterocycloalkyl group.

In an exemplary embodiment of the present application, Rk may be hydrogen; or deuterium.

In an exemplary embodiment of the present application, R3 to R6 are the same as or different from each other, and are each independently selected from the group consisting of hydrogen; deuterium; a halogen; —CN; a substituted or unsubstituted C1 to C60 alkyl group; a substituted or unsubstituted C2 to C60 alkenyl group; a substituted or unsubstituted C2 to C60 alkynyl group; a substituted or unsubstituted C1 to C60 alkoxy group; a substituted or unsubstituted C3 to C60 cycloalkyl group; a substituted or unsubstituted C2 to C60 heterocycloalkyl group; a substituted or unsubstituted C6 to C60 aryl group; a substituted or unsubstituted C2 to C60 heteroaryl group; —P(═O)RR′; —SiRR′R″; and Chemical Formula 3, and one of R3 to R6 may be Chemical Formula 3.

In an exemplary embodiment of the present application, R3 to R6 are the same as or different from each other, and are each independently selected from the group consisting of hydrogen; deuterium; a halogen; —CN; a substituted or unsubstituted C1 to C40 alkyl group; a substituted or unsubstituted C2 to C40 alkenyl group; a substituted or unsubstituted C2 to C40 alkynyl group; a substituted or unsubstituted C1 to C40 alkoxy group; a substituted or unsubstituted C3 to C40 cycloalkyl group; a substituted or unsubstituted C2 to C40 heterocycloalkyl group; a substituted or unsubstituted C6 to C40 aryl group; a substituted or unsubstituted C2 to C40 heteroaryl group; —P(═O)RR′; —SiRR′R″; and Chemical Formula 3, and one of R3 to R6 may be Chemical Formula 3.

In an exemplary embodiment of the present application, R3 to R6 are the same as or different from each other, and are each independently selected from the group consisting of hydrogen; deuterium; a halogen; —CN; a substituted or unsubstituted C1 to C20 alkyl group; a substituted or unsubstituted C2 to C20 alkenyl group; a substituted or unsubstituted C2 to C20 alkynyl group; a substituted or unsubstituted C1 to C20 alkoxy group; a substituted or unsubstituted C3 to C20 cycloalkyl group; a substituted or unsubstituted C2 to C20 heterocycloalkyl group; a substituted or unsubstituted C6 to C20 aryl group; a substituted or unsubstituted C2 to C20 heteroaryl group; —P(═O)RR′; —SiRR′R″; and Chemical Formula 3, and one of R3 to R6 may be Chemical Formula 3.

In an exemplary embodiment of the present application, R3 to R6 are the same as or different from each other, and are each independently selected from the group consisting of hydrogen; deuterium; a halogen; —CN; a substituted or unsubstituted C6 to C20 aryl group and Chemical Formula 3, and one of R3 to R6 may be Chemical Formula 3.

In an exemplary embodiment of the present application, R3 to R6 are the same as or different from each other, and are each independently selected from the group consisting of hydrogen; deuterium; a substituted or unsubstituted C6 to C20 aryl group and Chemical Formula 3, and one of R3 to R6 may be Chemical Formula 3.

In an exemplary embodiment of the present application, R3 to R6 are the same as or different from each other, and are each independently selected from the group consisting of hydrogen; deuterium; phenyl; naphthyl; and Chemical Formula 3, and one of R3 to R6 may be Chemical Formula 3.

In an exemplary embodiment of the present application, L3 may be a direct bond; a substituted or unsubstituted C6 to C60 arylene group; or a substituted or unsubstituted C2 to C60 heteroarylene group.

In an exemplary embodiment of the present application, L3 may be a direct bond; a substituted or unsubstituted C6 to C40 arylene group; or a substituted or unsubstituted C2 to C40 heteroarylene group.

In an exemplary embodiment of the present application, L3 may be a direct bond; a substituted or unsubstituted C6 to C20 arylene group; or a substituted or unsubstituted C2 to C20 heteroarylene group.

In an exemplary embodiment of the present application, L3 may be a direct bond; or a substituted or unsubstituted C6 to C20 arylene group.

In an exemplary embodiment of the present application, L3 may be a direct bond; or a substituted or unsubstituted phenylene group.

In an exemplary embodiment of the present application, L3 may be a direct bond; or a phenylene group unsubstituted or substituted with deuterium.

In an exemplary embodiment of the present application, Ar3 and Ar4 are the same as or different from each other, and may be each independently a substituted or unsubstituted C6 to C60 aryl group; or a substituted or unsubstituted C2 to C60 heteroaryl group.

In an exemplary embodiment of the present application, Ar3 and Ar4 are the same as or different from each other, and may be each independently a substituted or unsubstituted C6 to C40 aryl group; or a substituted or unsubstituted C2 to C40 heteroaryl group.

In an exemplary embodiment of the present application, Ar3 and Ar4 are the same as or different from each other, and may be each independently a substituted or unsubstituted C6 to C30 aryl group; or a substituted or unsubstituted C2 to C30 heteroaryl group.

In an exemplary embodiment of the present application, Ar3 and Ar4 are the same as or different from each other, and may be each independently a substituted or unsubstituted C6 to C20 aryl group; or a substituted or unsubstituted C2 to C20 heteroaryl group.

In an exemplary embodiment of the present application, Ar3 and Ar4 are the same as or different from each other, and may be each independently a C6 to C20 aryl group unsubstituted or substituted with deuterium; or a C2 to C20 heteroaryl group unsubstituted or substituted withy deuterium.

In an exemplary embodiment of the present application, Ar3 and Ar4 are the same as or different from each other, and may be each independently a biphenyl group unsubstituted or substituted with deuterium, a dimethylfluorene group unsubstituted or substituted with deuterium, a diphenylfluorene group unsubstituted or substituted with deuterium, a terphenyl group unsubstituted or substituted with deuterium, a dibenzofuran group unsubstituted or substituted with deuterium, or a dibenzothiophene group unsubstituted or substituted with deuterium.

In an exemplary embodiment of the present application, Chemical Formula 1 may be represented by any one of the following heterocyclic compounds.

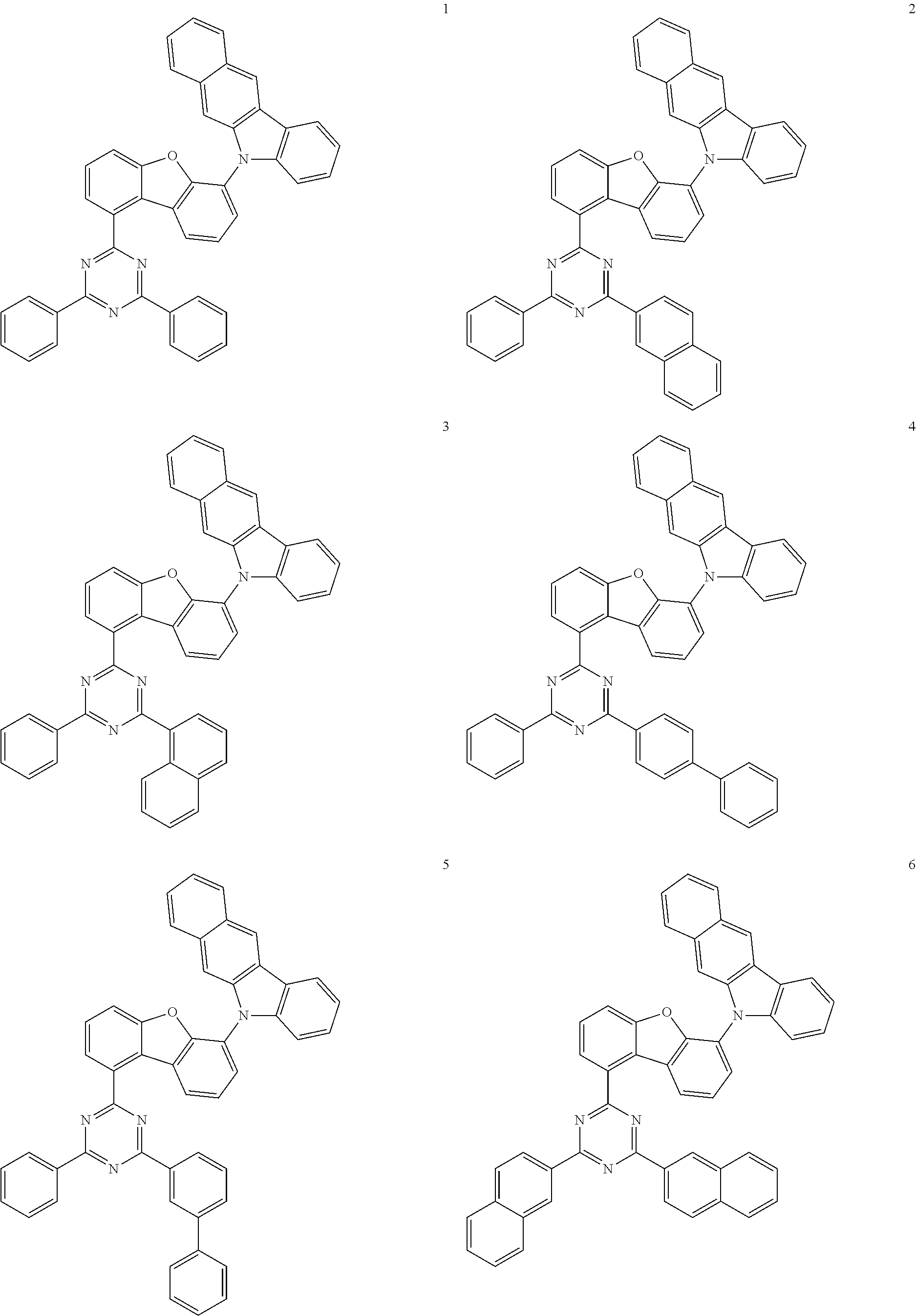

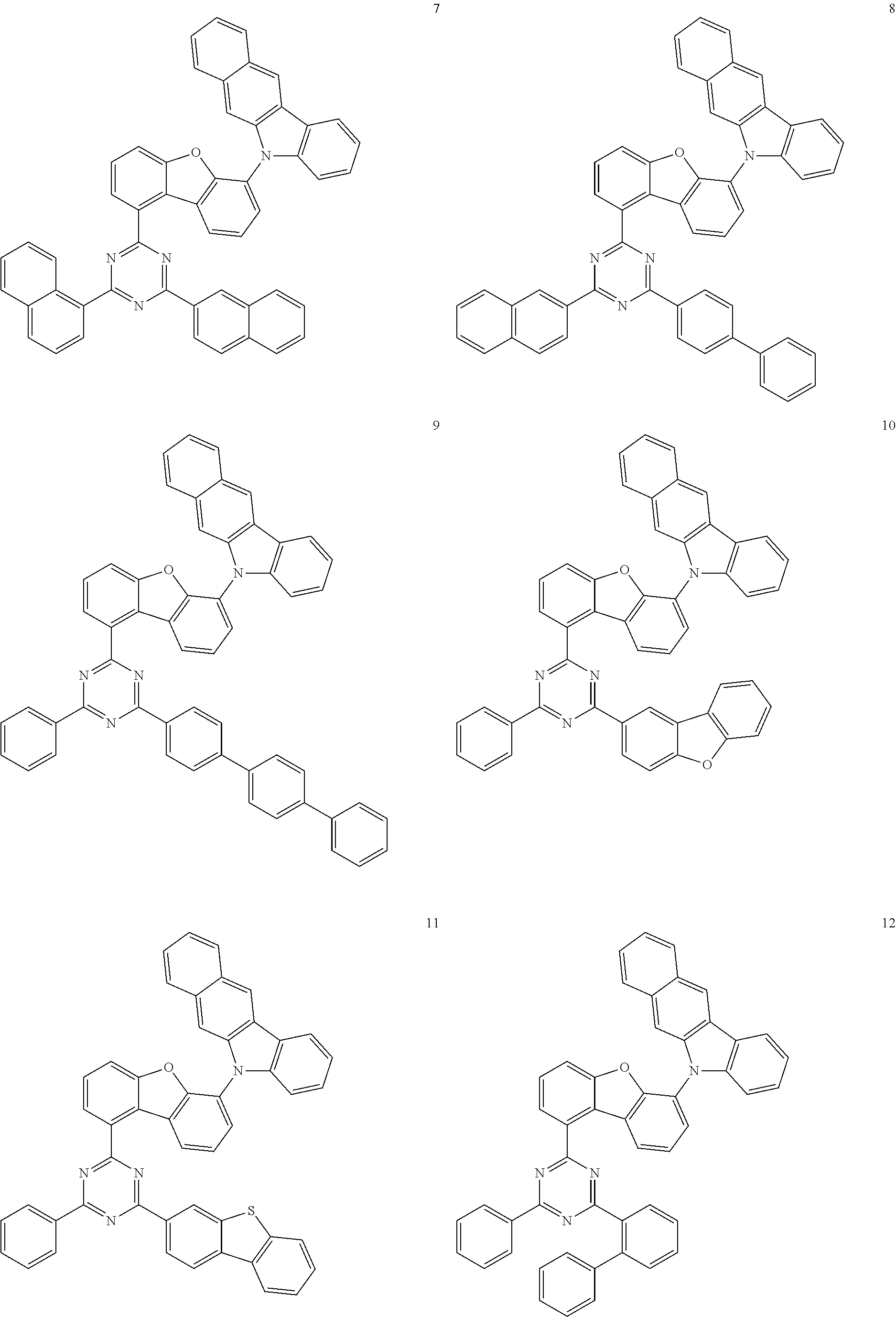

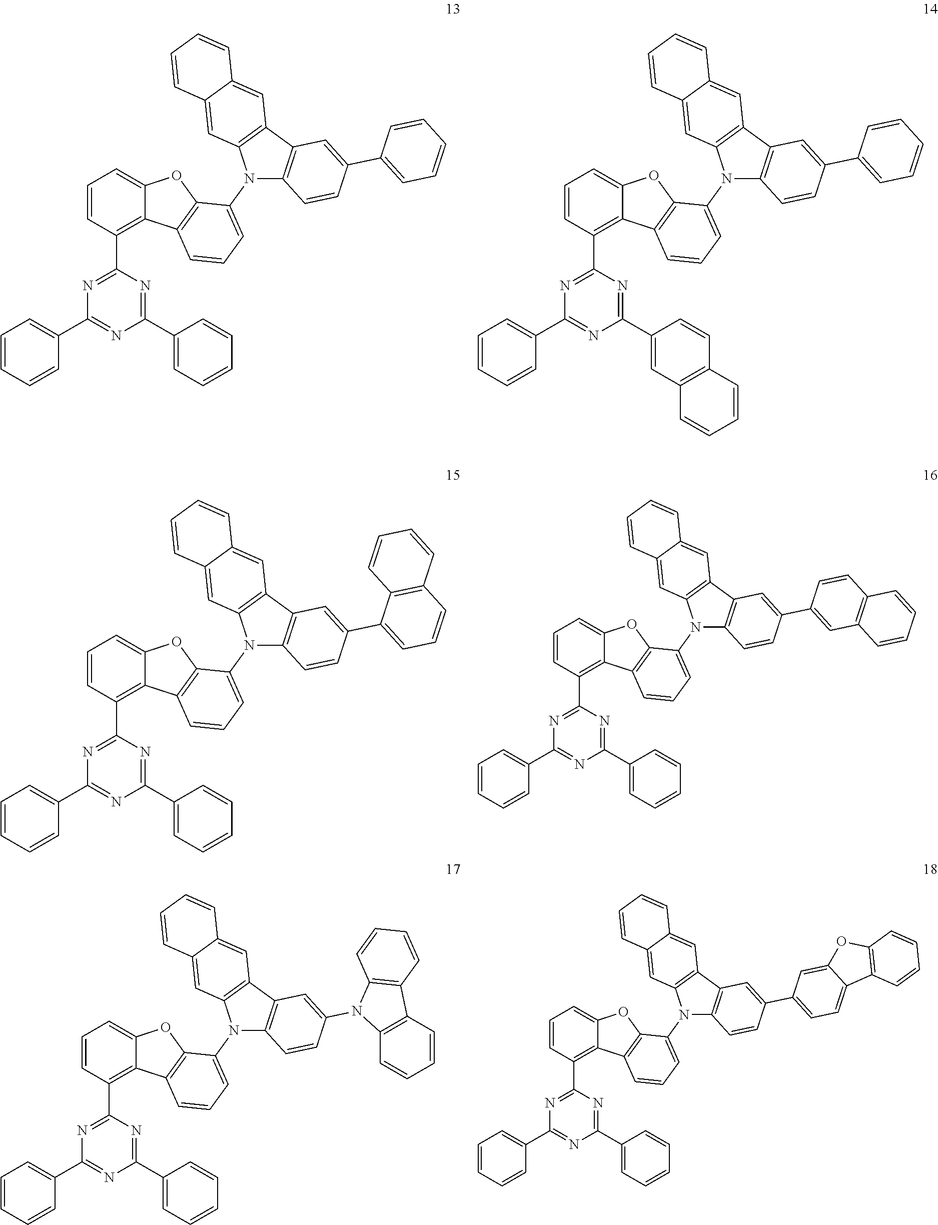

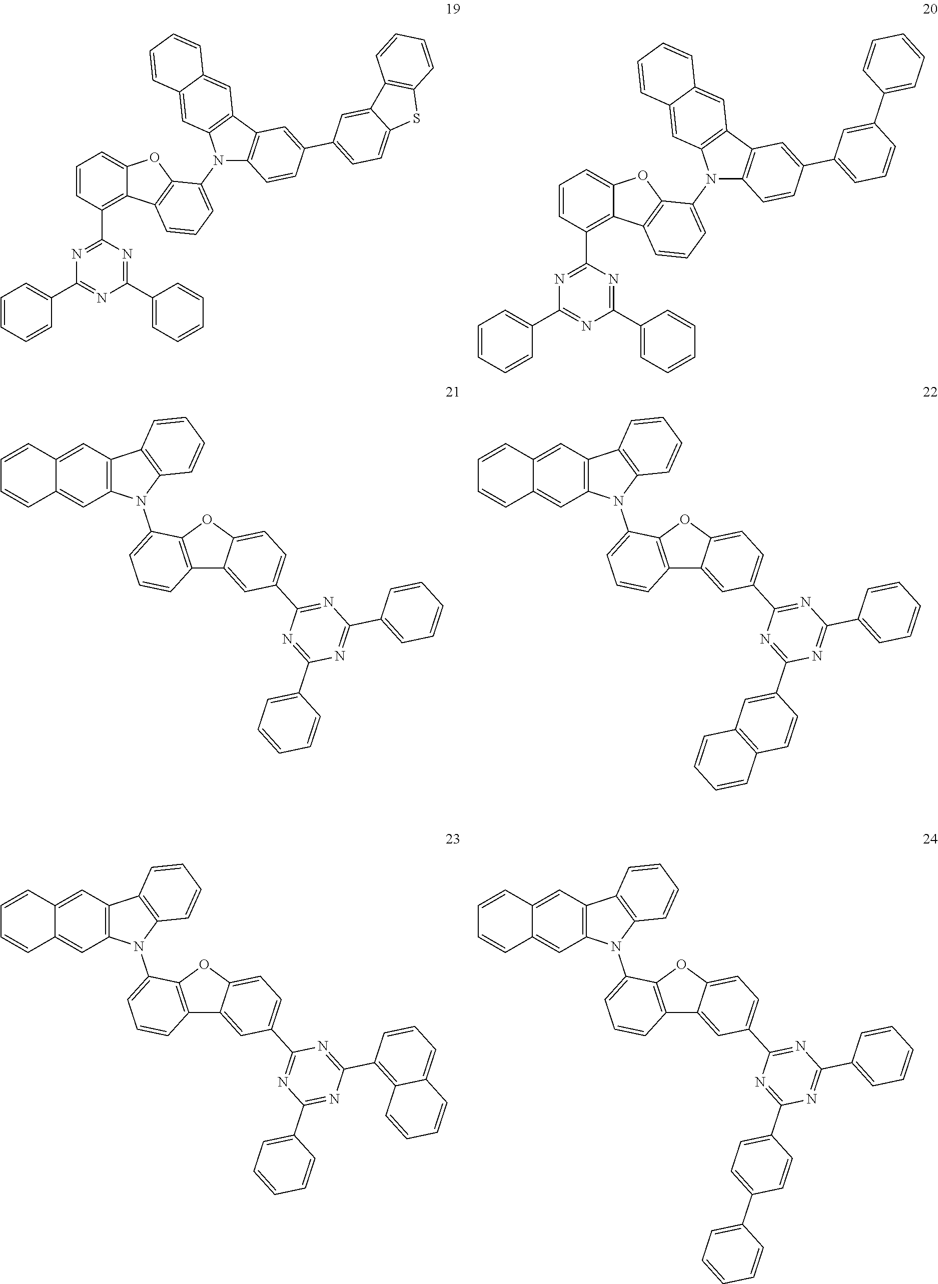

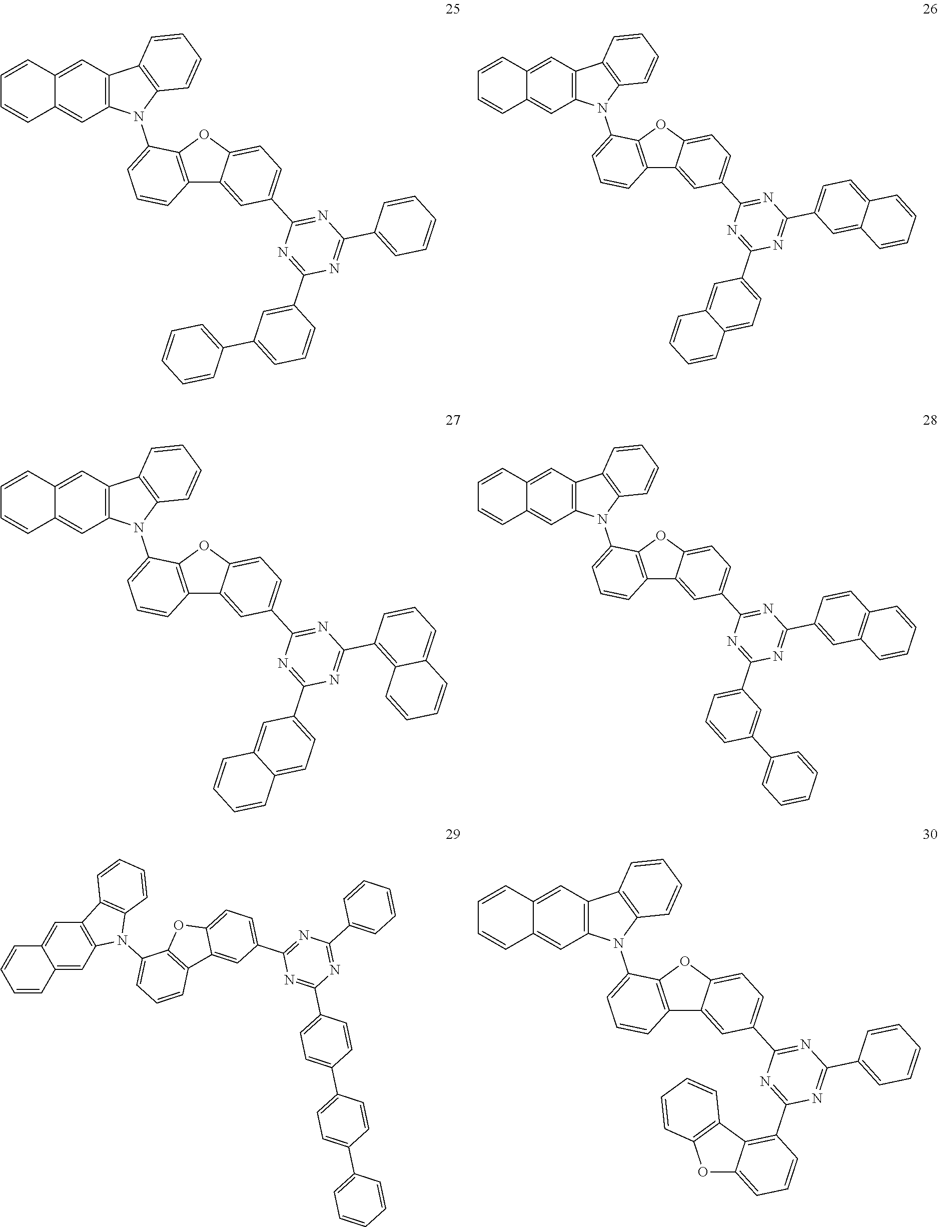

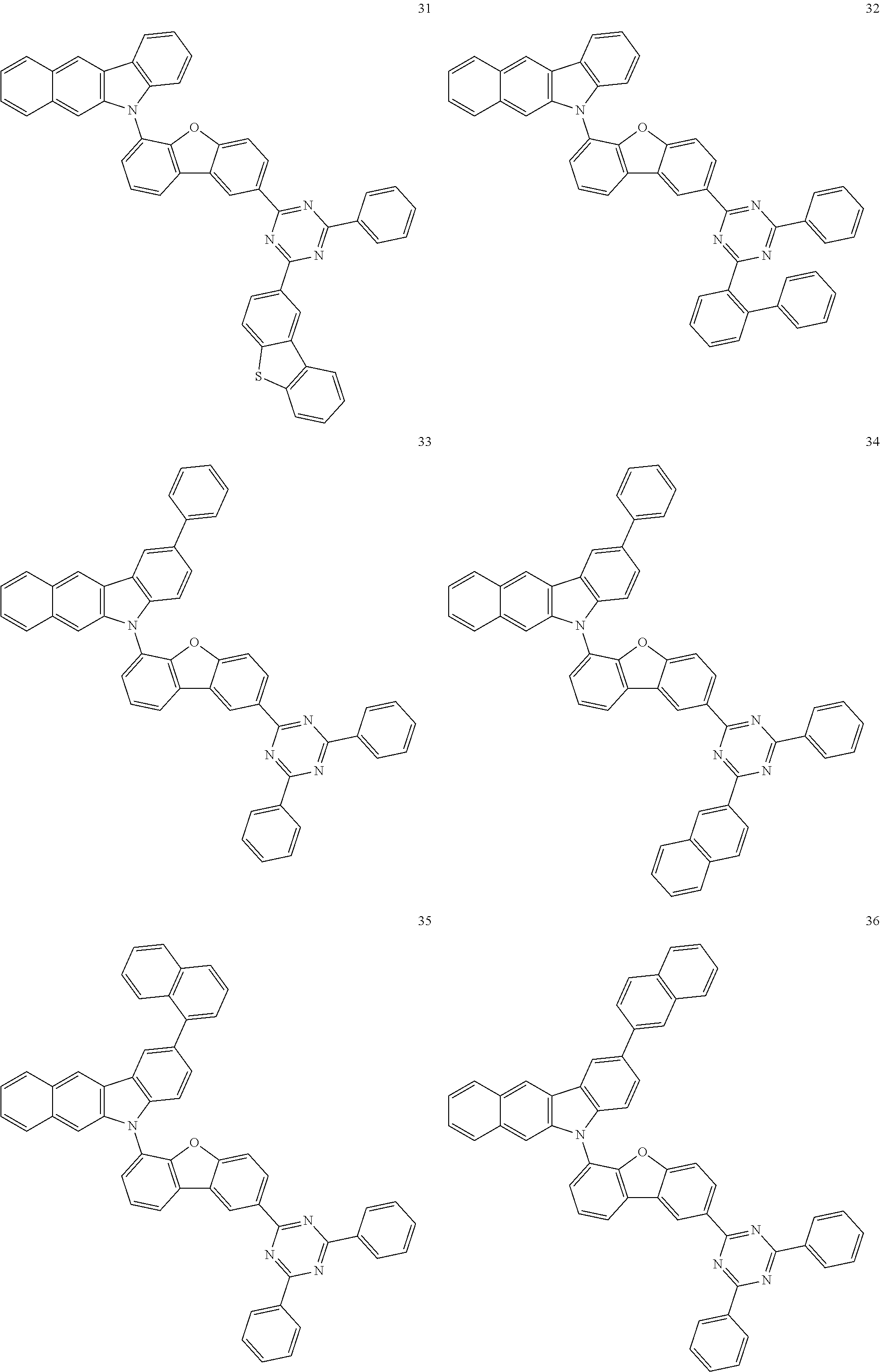

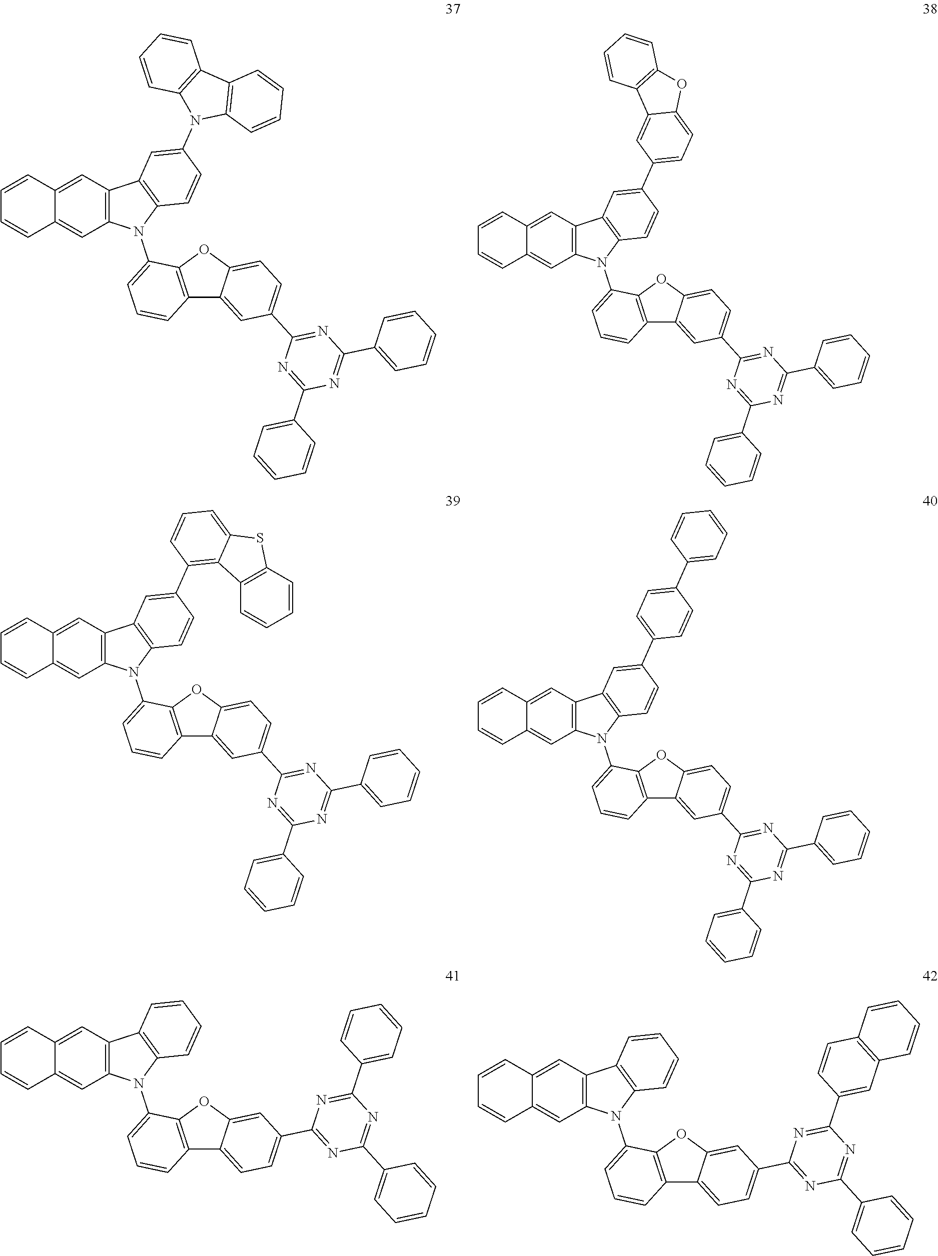

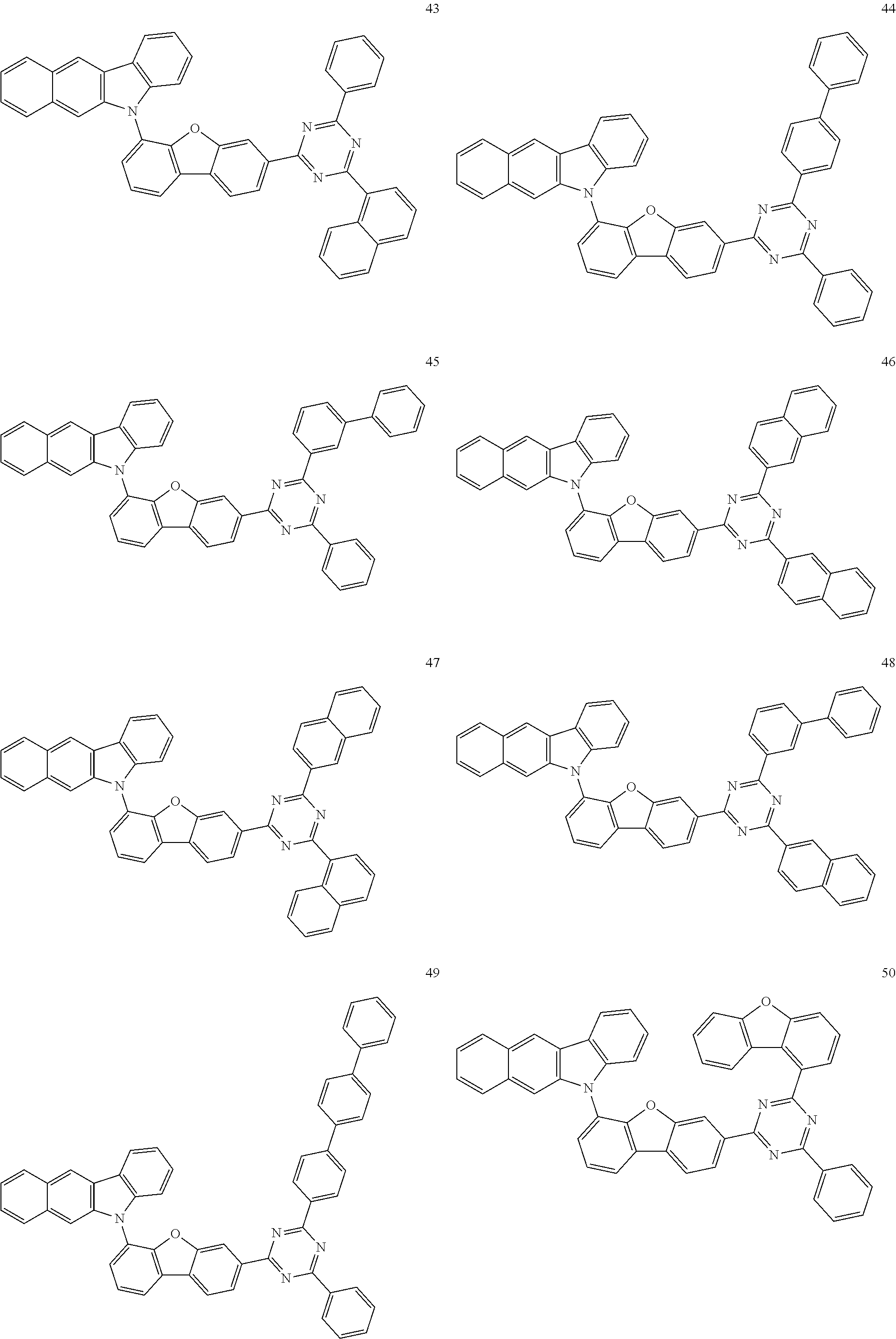

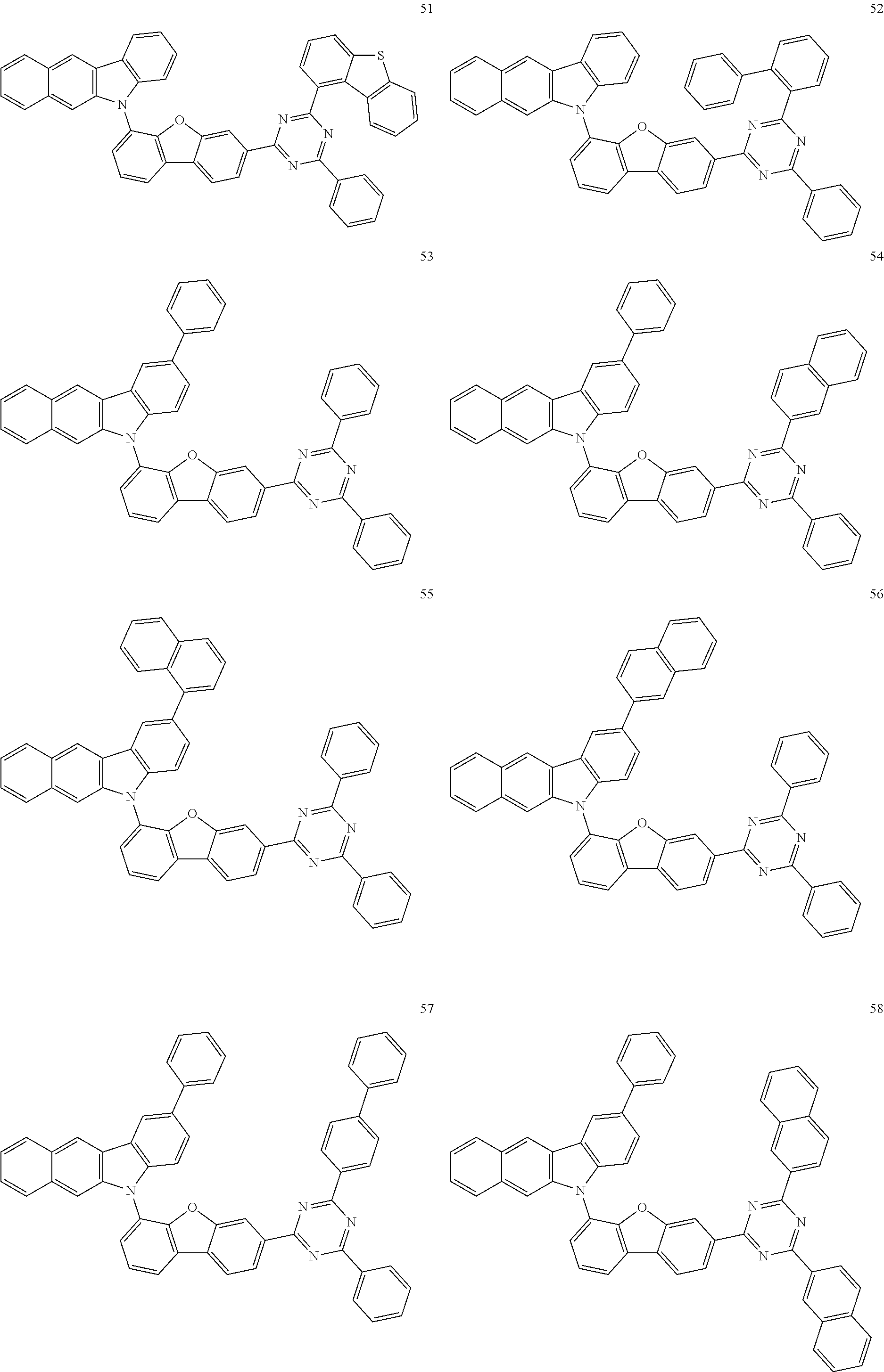

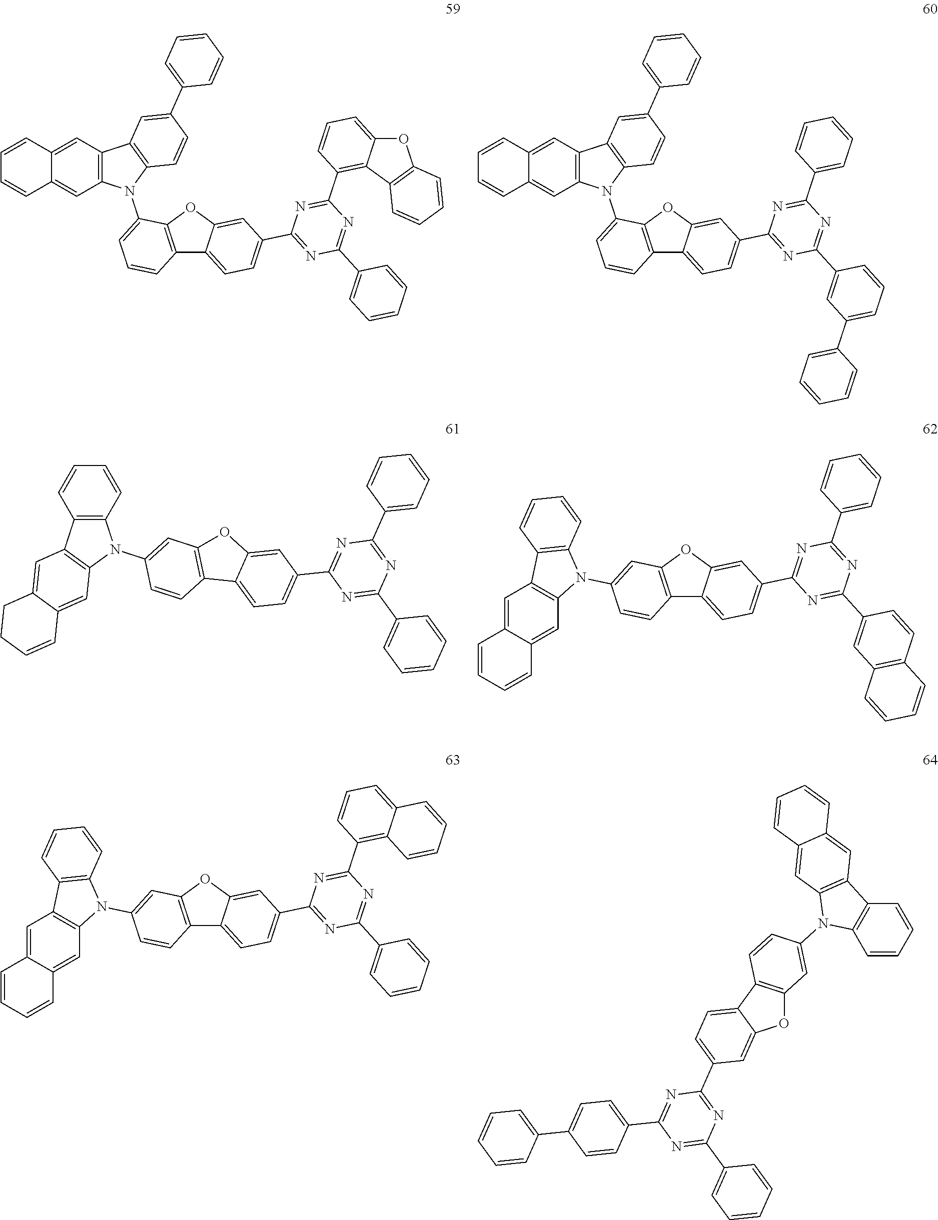

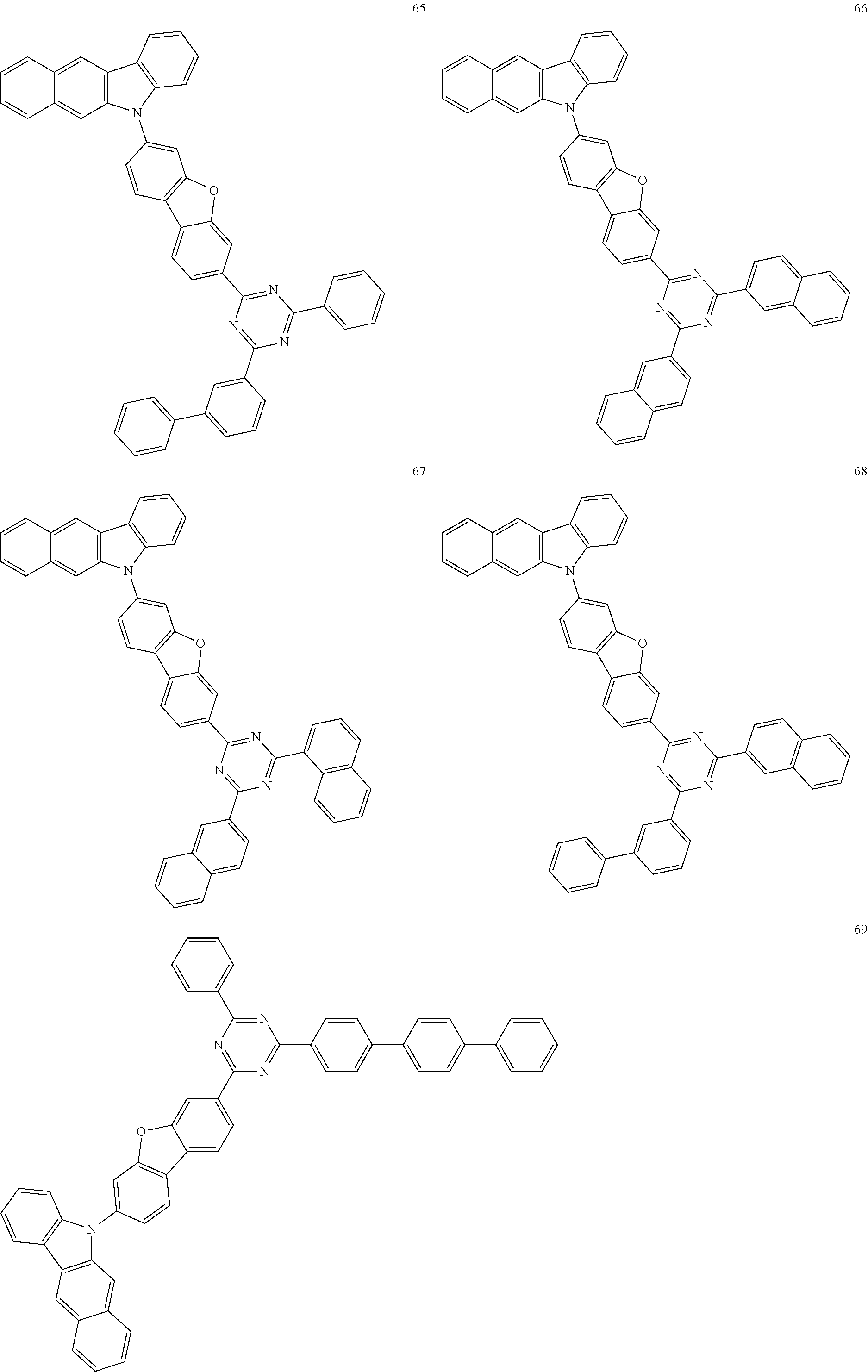

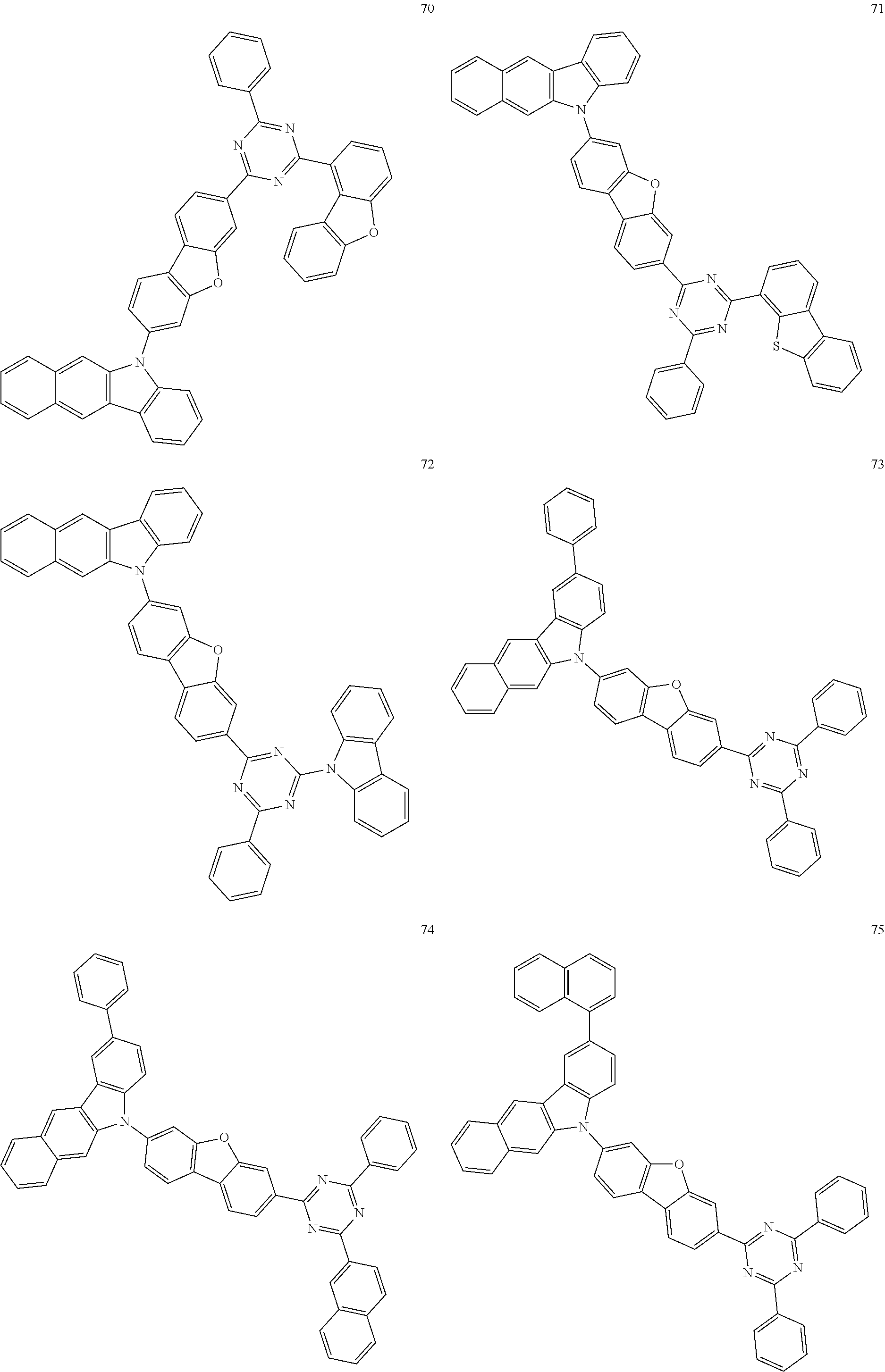

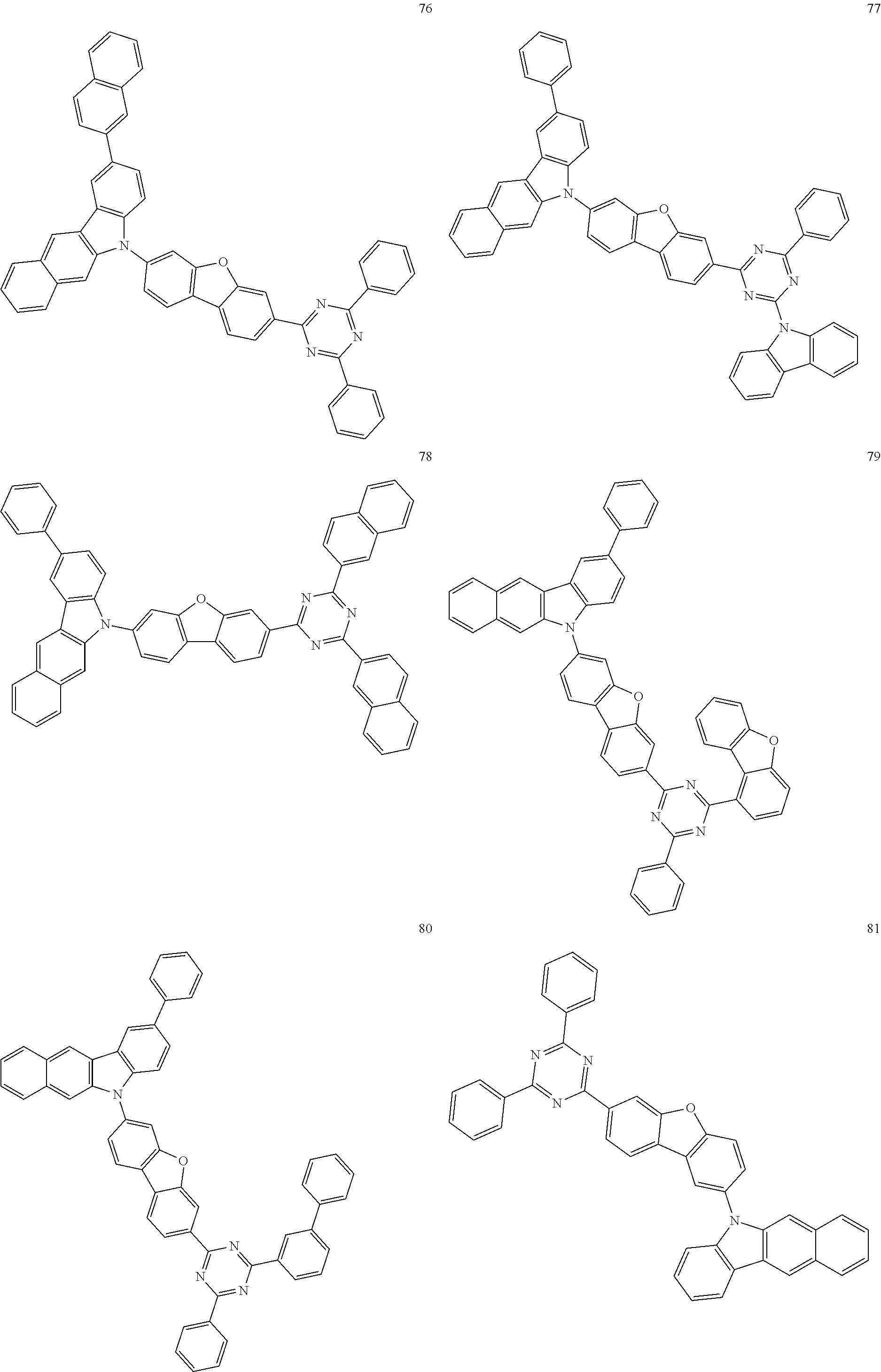

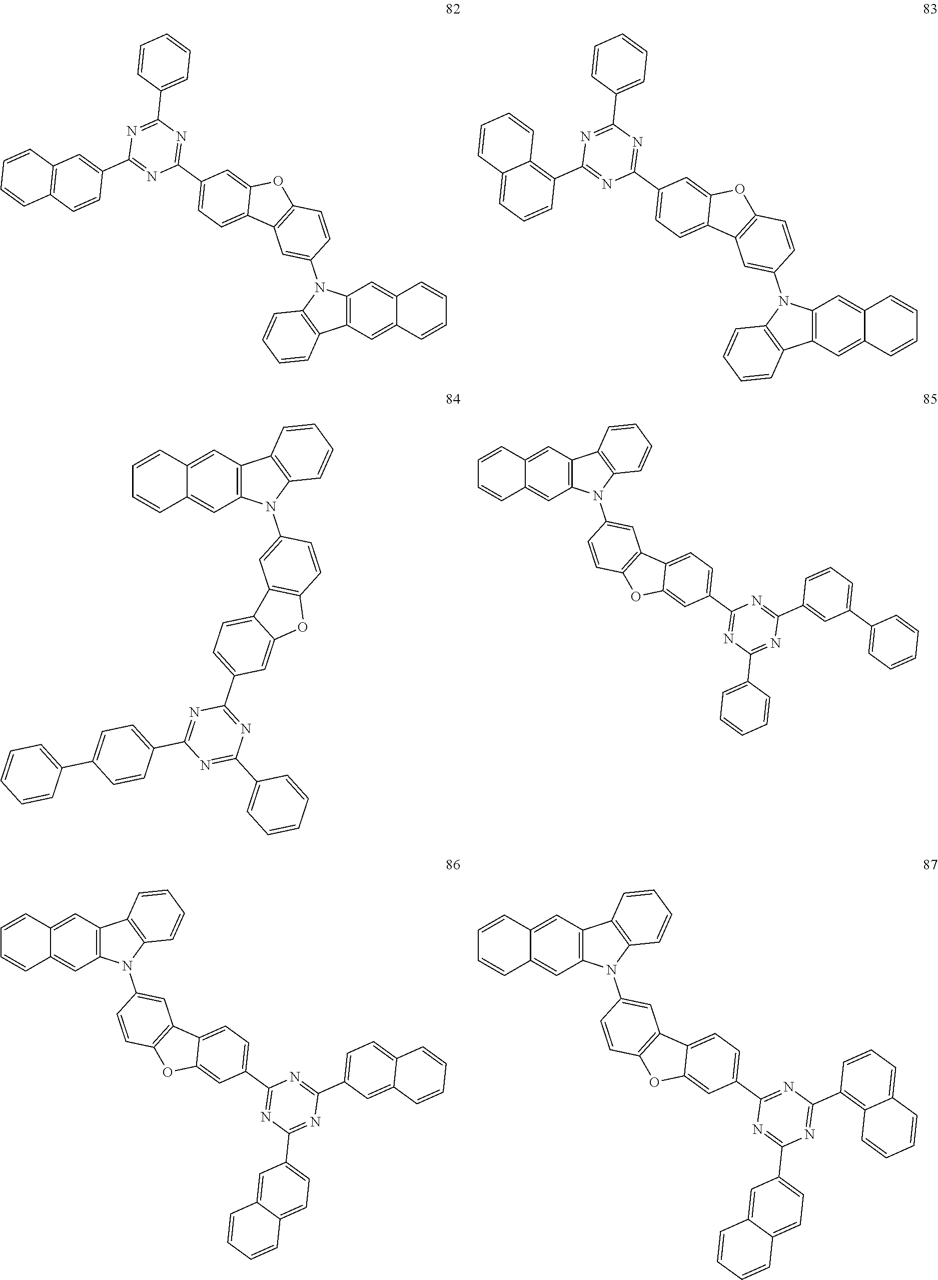

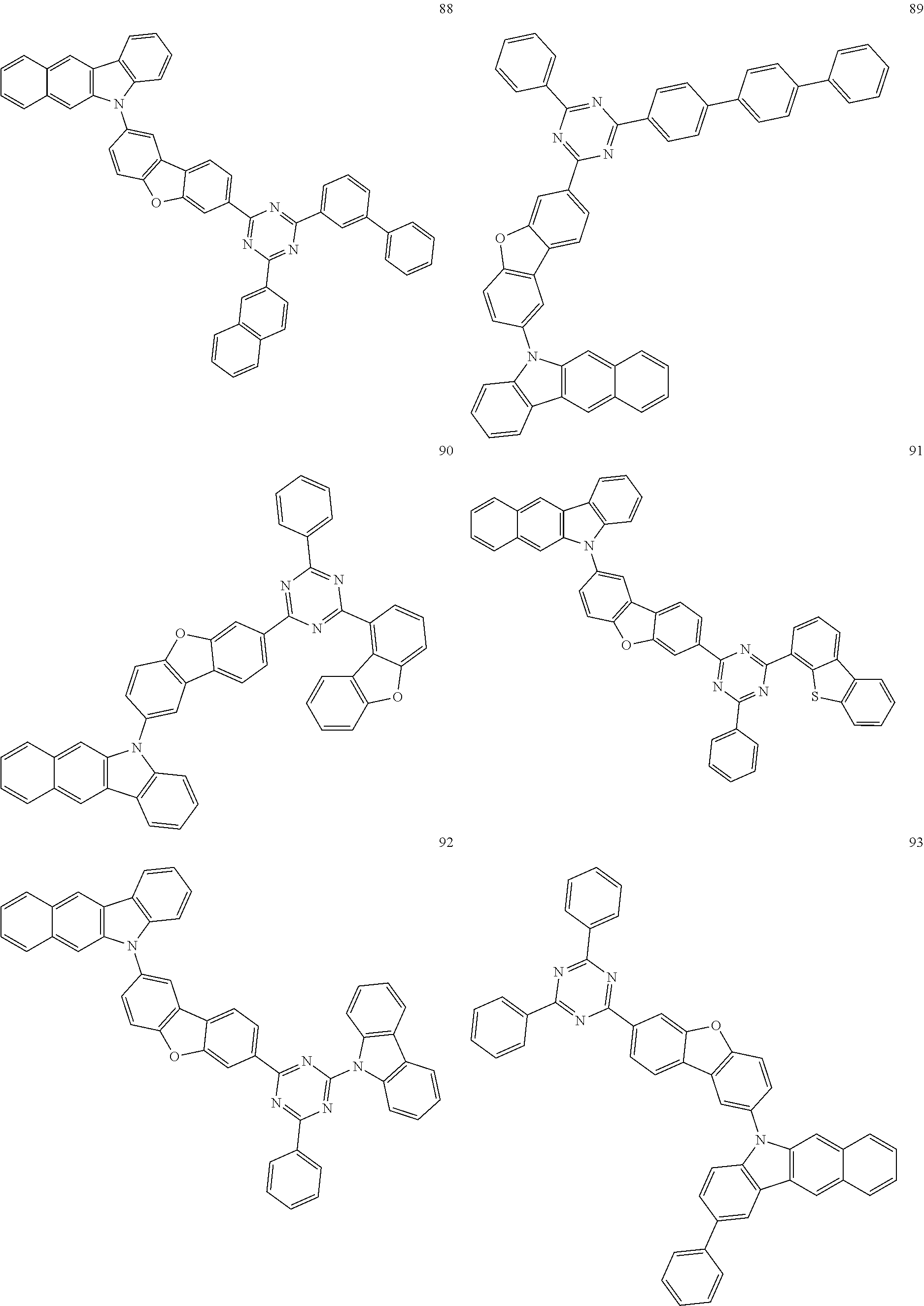

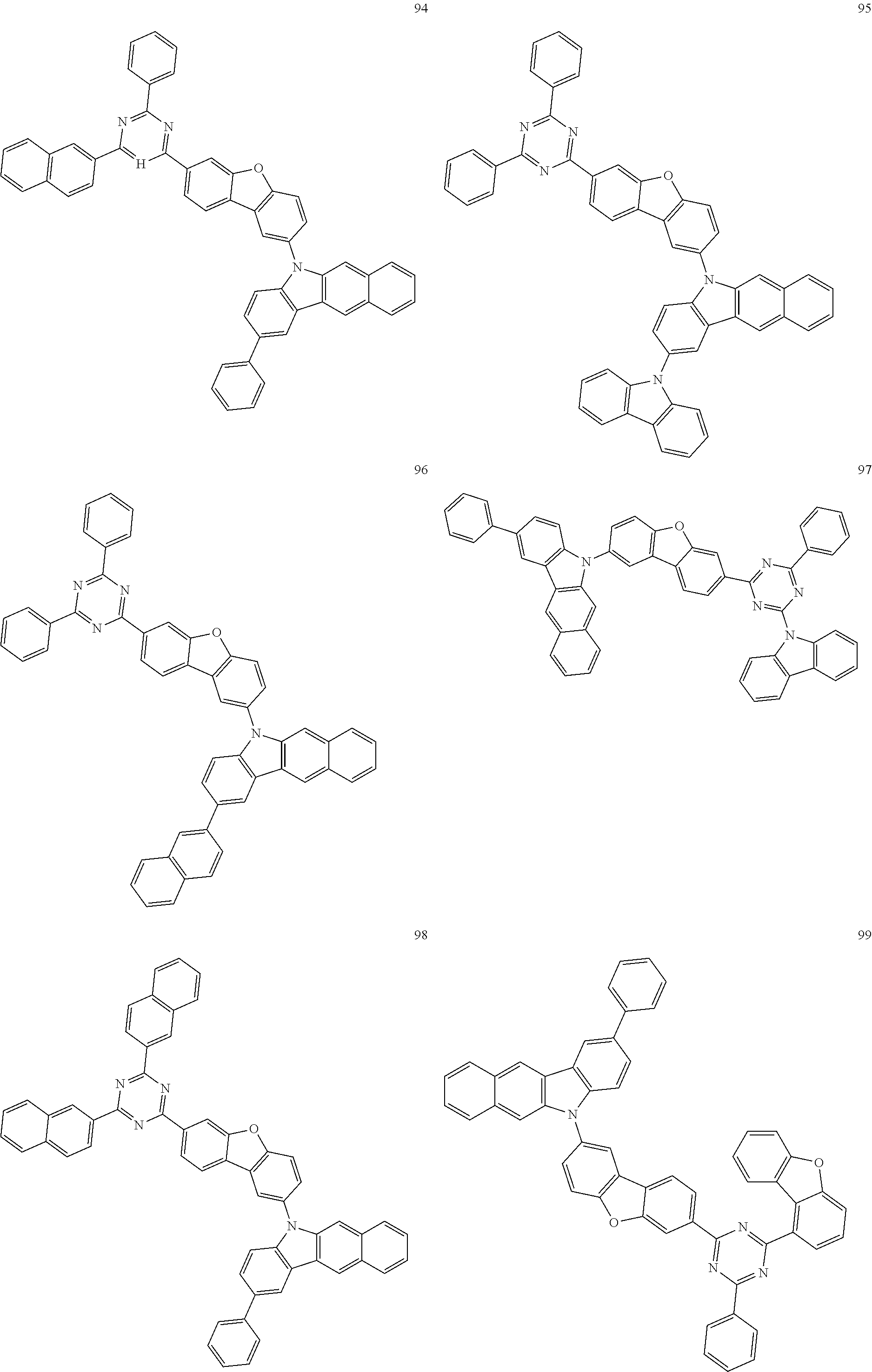

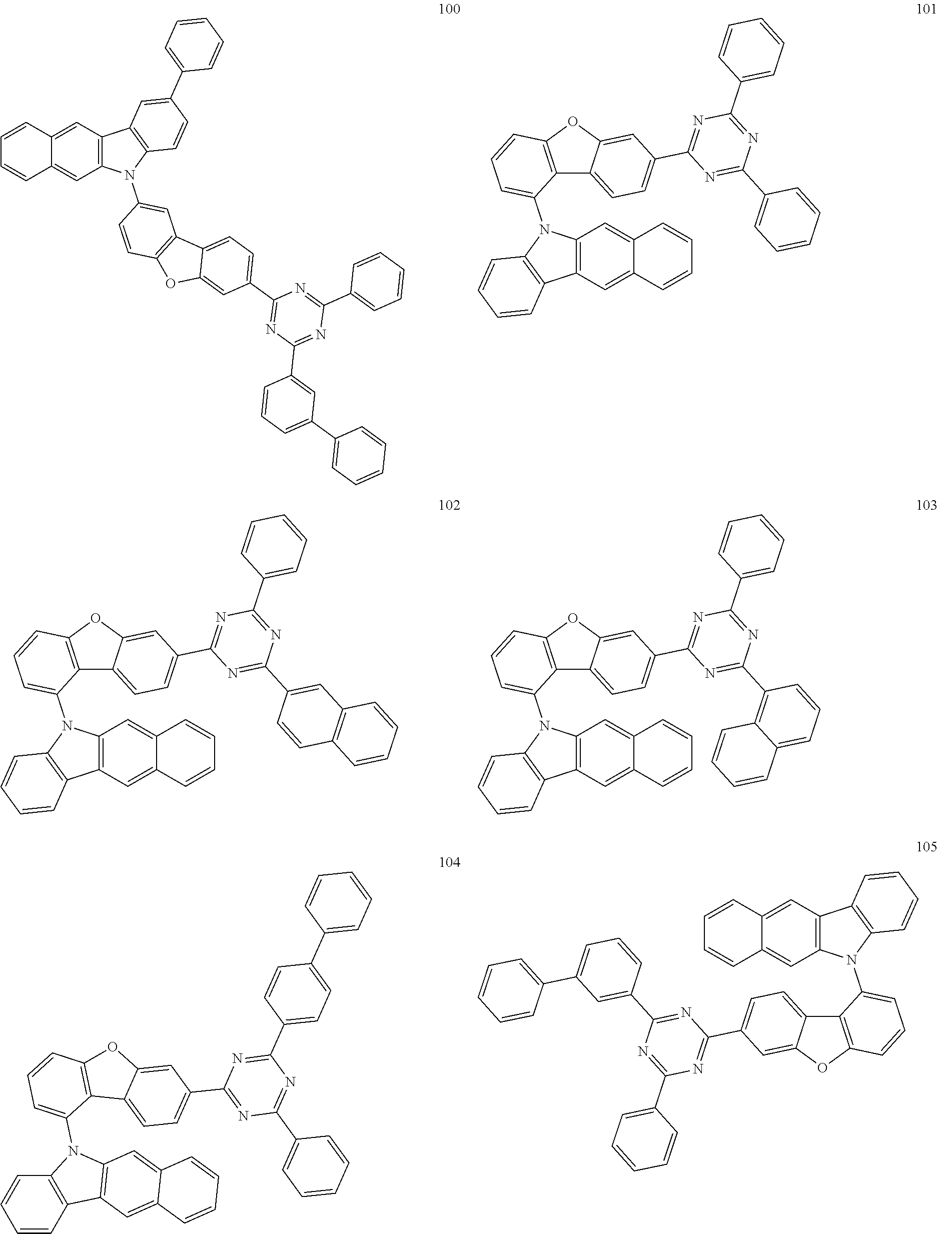

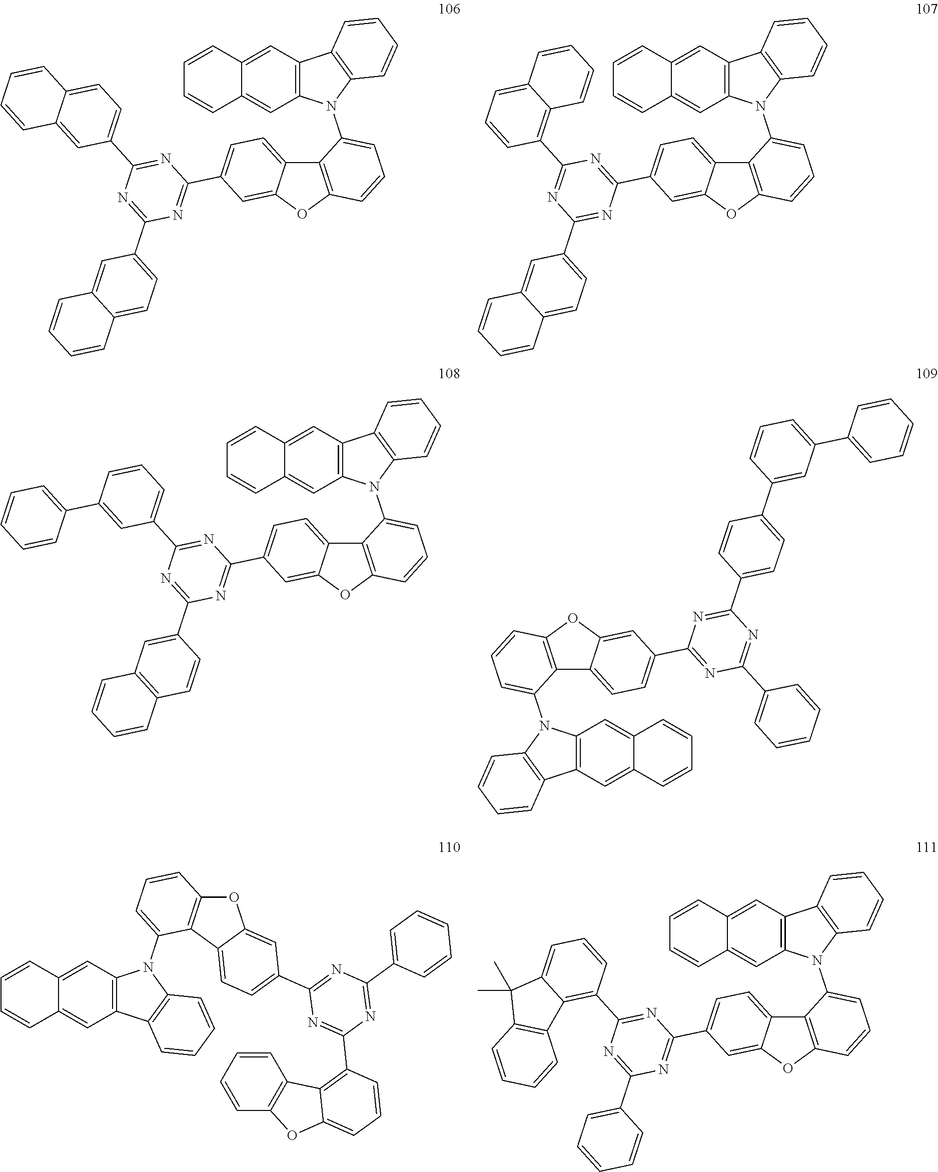

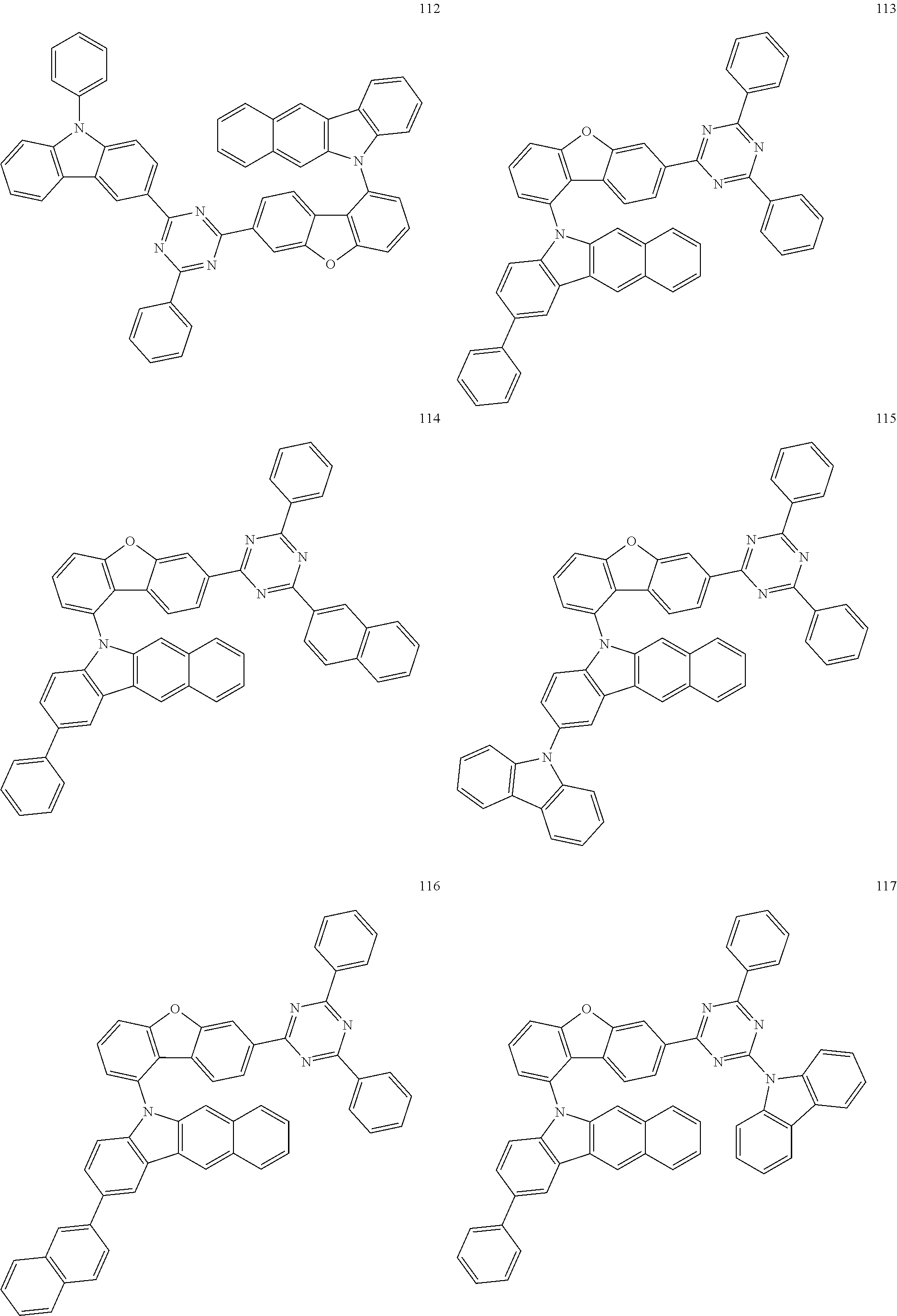

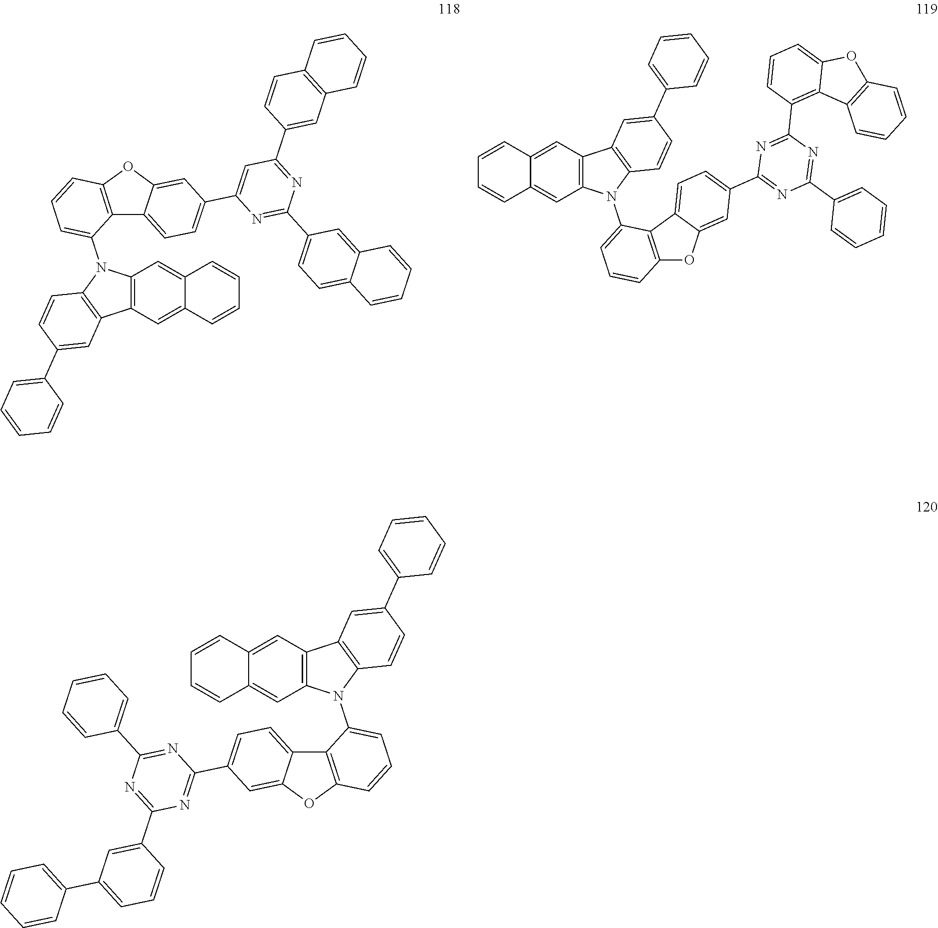 [SMILES: c1ccc(-c2ccc3c(c2)c2cc4ccccc4cc2n3-c2cccc3oc4cc(-c5cc(-c6ccc7ccccc7c6)nc(-c6ccc7ccccc7c6)n5)ccc4c23)cc1 ; c1ccc(-c2ccc3c(c2)c2cc4ccccc4cc2n3-c2cccc3oc4cc(-c5nc(-c6ccccc6)nc(-c6cccc7oc8ccccc8c67)n5)ccc4c23)cc1 ; c1ccc(-c2cccc(-c3nc(-c4ccccc4)nc(-c4ccc5c(c4)oc4cccc(-n6c7ccc(-c8ccccc8)cc7c7cc8ccccc8cc76)c45)n3)c2)cc1]

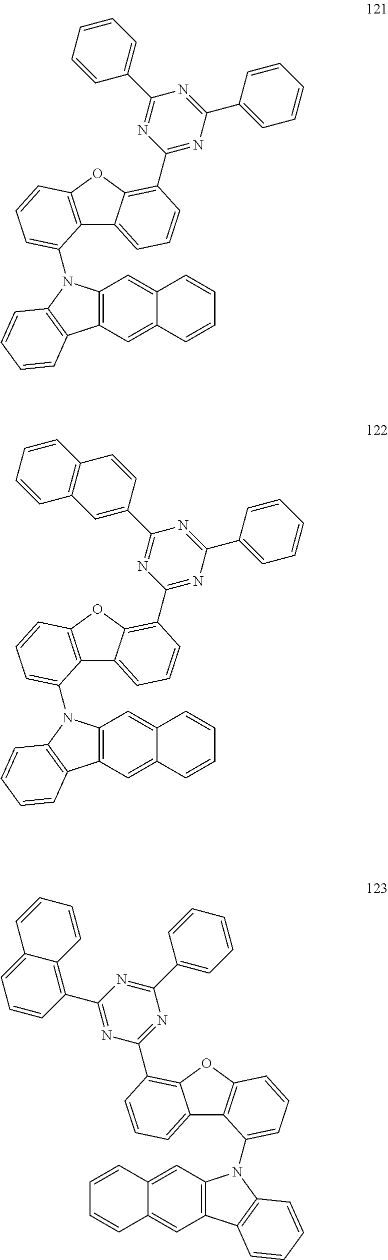 [SMILES: c1ccc(-c2nc(-c3ccccc3)nc(-c3cccc4c3oc3cccc(-n5c6ccccc6c6cc7ccccc7cc65)c34)n2)cc1 ; c1ccc(-c2nc(-c3ccc4ccccc4c3)nc(-c3cccc4c3oc3cccc(-n5c6ccccc6c6cc7ccccc7cc65)c34)n2)cc1 ; c1ccc(-c2nc(-c3cccc4ccccc34)nc(-c3cccc4c3oc3cccc(-n5c6ccccc6c6cc7ccccc7cc65)c34)n2)cc1]

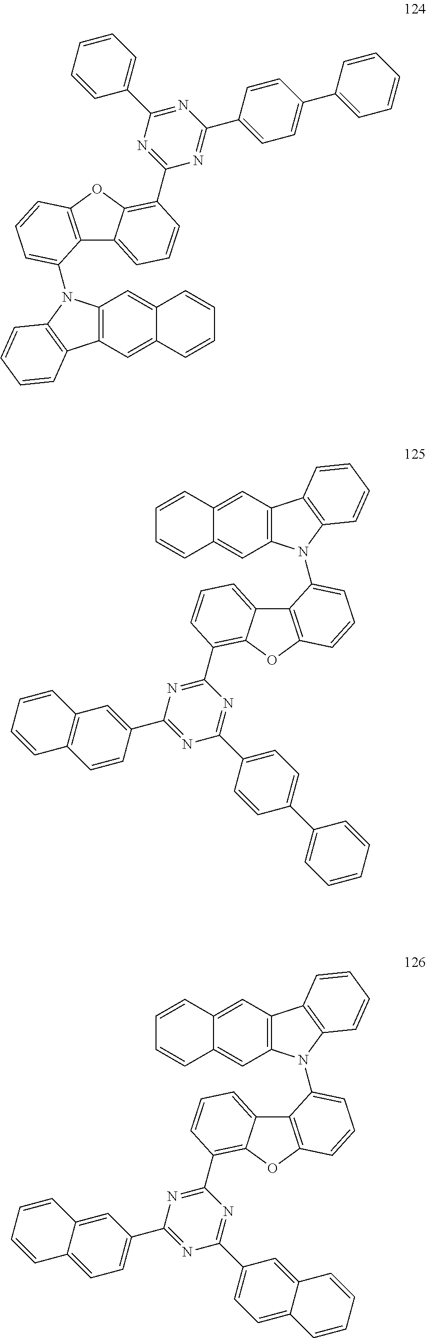 [SMILES: c1ccc(-c2ccc(-c3nc(-c4ccccc4)nc(-c4cccc5c4oc4cccc(-n6c7ccccc7c7cc8ccccc8cc76)c45)n3)cc2)cc1 ; c1ccc(-c2ccc(-c3nc(-c4ccc5ccccc5c4)nc(-c4cccc5c4oc4cccc(-n6c7ccccc7c7cc8ccccc8cc76)c45)n3)cc2)cc1 ; c1ccc2cc(-c3nc(-c4ccc5ccccc5c4)nc(-c4cccc5c4oc4cccc(-n6c7ccccc7c7cc8ccccc8cc76)c45)n3)ccc2c1]

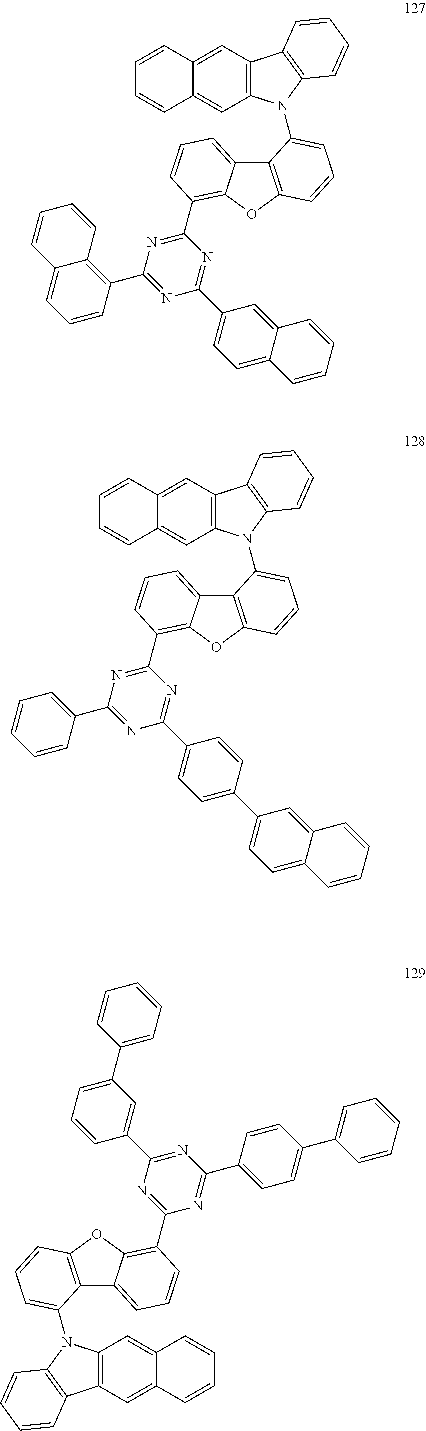 [SMILES: c1ccc2cc(-c3nc(-c4cccc5ccccc45)nc(-c4cccc5c4oc4cccc(-n6c7ccccc7c7cc8ccccc8cc76)c45)n3)ccc2c1 ; c1ccc(-c2nc(-c3ccc(-c4ccc5ccccc5c4)cc3)nc(-c3cccc4c3oc3cccc(-n5c6ccccc6c6cc7ccccc7cc65)c34)n2)cc1 ; c1ccc(-c2ccc(-c3nc(-c4cccc(-c5ccccc5)c4)nc(-c4cccc5c4oc4cccc(-n6c7ccccc7c7cc8ccccc8cc76)c45)n3)cc2)cc1]

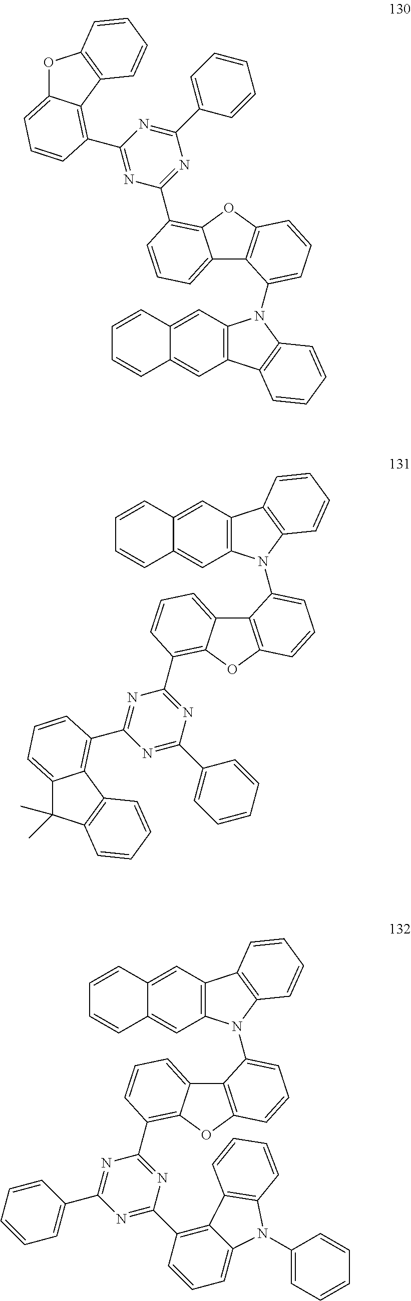 [SMILES: c1ccc(-c2nc(-c3cccc4c3oc3cccc(-n5c6ccccc6c6cc7ccccc7cc65)c34)nc(-c3cccc4oc5ccccc5c34)n2)cc1 ; CC1(C)c2ccccc2-c2c(-c3nc(-c4ccccc4)nc(-c4cccc5c4oc4cccc(-n6c7ccccc7c7cc8ccccc8cc76)c45)n3)cccc21 ; c1ccc(-c2nc(-c3cccc4c3oc3cccc(-n5c6ccccc6c6cc7ccccc7cc65)c34)nc(-c3cccc4c3c3ccccc3n4-c3ccccc3)n2)cc1]

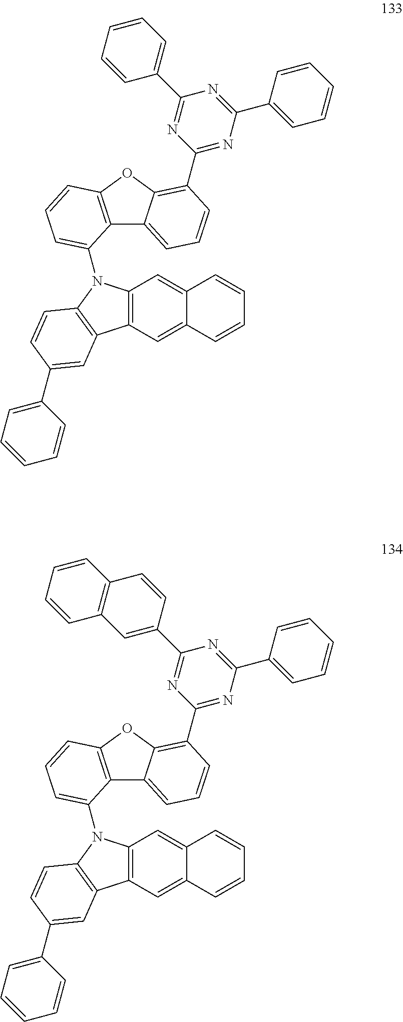 [SMILES: c1ccc(-c2ccc3c(c2)c2cc4ccccc4cc2n3-c2cccc3oc4c(-c5nc(-c6ccccc6)nc(-c6ccccc6)n5)cccc4c23)cc1 ; c1ccc(-c2ccc3c(c2)c2cc4ccccc4cc2n3-c2cccc3oc4c(-c5nc(-c6ccccc6)nc(-c6ccc7ccccc7c6)n5)cccc4c23)cc1]

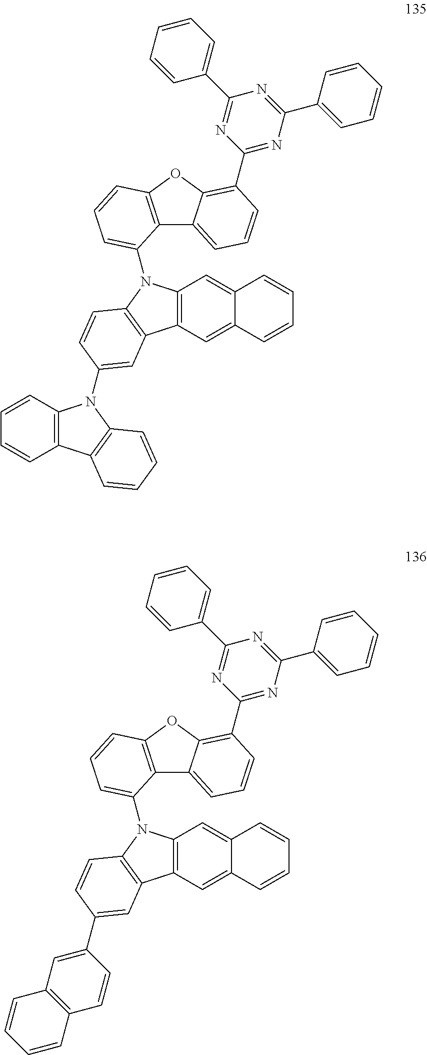 [SMILES: c1ccc(-c2nc(-c3ccccc3)nc(-c3cccc4c3oc3cccc(-n5c6ccc(-n7c8ccccc8c8ccccc87)cc6c6cc7ccccc7cc65)c34)n2)cc1 ; c1ccc(-c2nc(-c3ccccc3)nc(-c3cccc4c3oc3cccc(-n5c6ccc(-c7ccc8ccccc8c7)cc6c6cc7ccccc7cc65)c34)n2)cc1]

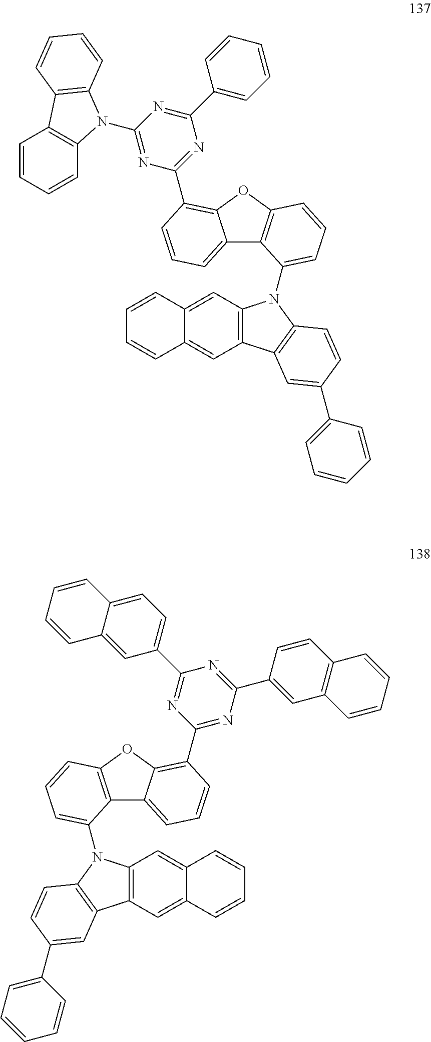 [SMILES: c1ccc(-c2ccc3c(c2)c2cc4ccccc4cc2n3-c2cccc3oc4c(-c5nc(-c6ccccc6)nc(-n6c7ccccc7c7ccccc76)n5)cccc4c23)cc1 ; c1ccc(-c2ccc3c(c2)c2cc4ccccc4cc2n3-c2cccc3oc4c(-c5nc(-c6ccc7ccccc7c6)nc(-c6ccc7ccccc7c6)n5)cccc4c23)cc1]

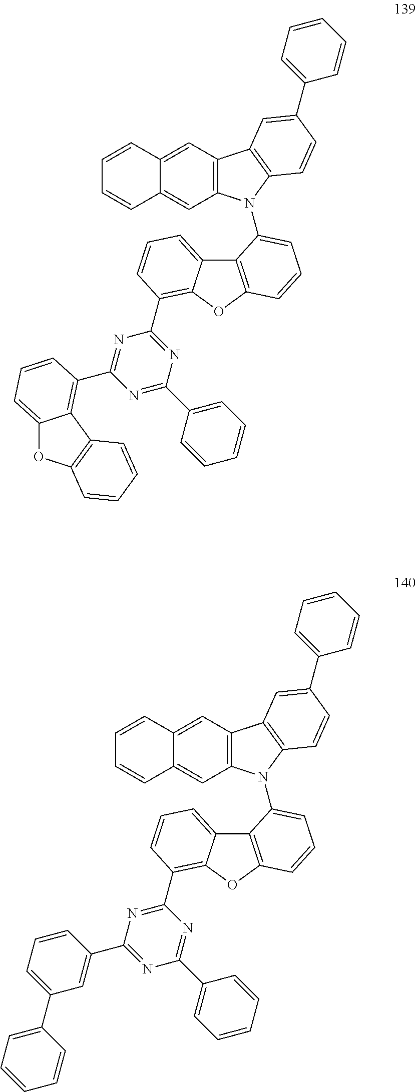 [SMILES: c1ccc(-c2ccc3c(c2)c2cc4ccccc4cc2n3-c2cccc3oc4c(-c5nc(-c6ccccc6)nc(-c6cccc7oc8ccccc8c67)n5)cccc4c23)cc1 ; c1ccc(-c2cccc(-c3nc(-c4ccccc4)nc(-c4cccc5c4oc4cccc(-n6c7ccc(-c8ccccc8)cc7c7cc8ccccc8cc76)c45)n3)c2)cc1]

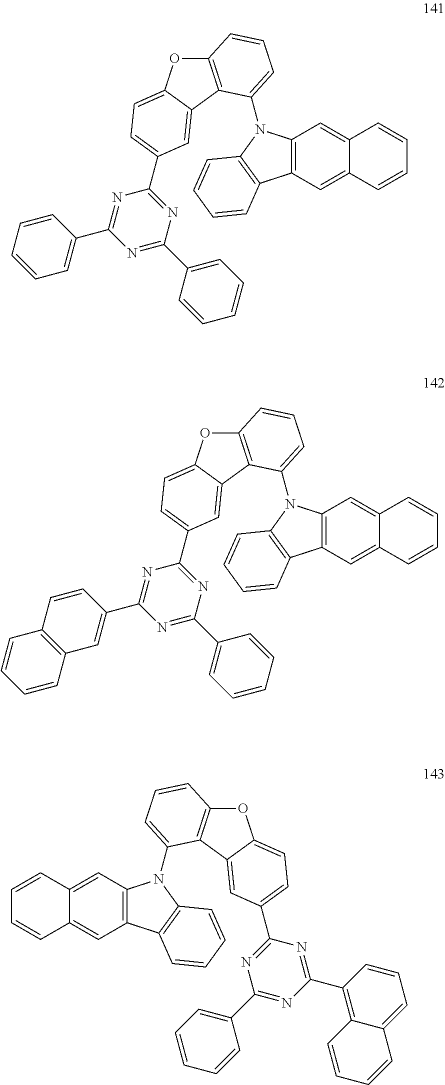 [SMILES: c1ccc(-c2nc(-c3ccccc3)nc(-c3ccc4oc5cccc(-n6c7ccccc7c7cc8ccccc8cc76)c5c4c3)n2)cc1 ; c1ccc(-c2nc(-c3ccc4ccccc4c3)nc(-c3ccc4oc5cccc(-n6c7ccccc7c7cc8ccccc8cc76)c5c4c3)n2)cc1 ; c1ccc(-c2nc(-c3ccc4oc5cccc(-n6c7ccccc7c7cc8ccccc8cc76)c5c4c3)nc(-c3cccc4ccccc34)n2)cc1]

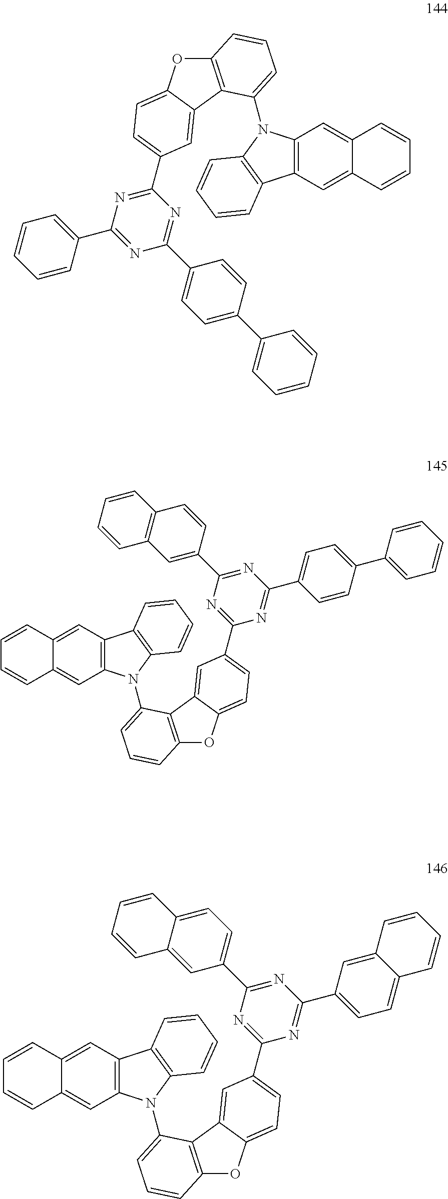 [SMILES: c1ccc(-c2ccc(-c3nc(-c4ccccc4)nc(-c4ccc5oc6cccc(-n7c8ccccc8c8cc9ccccc9cc87)c6c5c4)n3)cc2)cc1 ; c1ccc(-c2ccc(-c3nc(-c4ccc5ccccc5c4)nc(-c4ccc5oc6cccc(-n7c8ccccc8c8cc9ccccc9cc87)c6c5c4)n3)cc2)cc1 ; c1ccc2cc(-c3nc(-c4ccc5ccccc5c4)nc(-c4ccc5oc6cccc(-n7c8ccccc8c8cc9ccccc9cc87)c6c5c4)n3)ccc2c1]

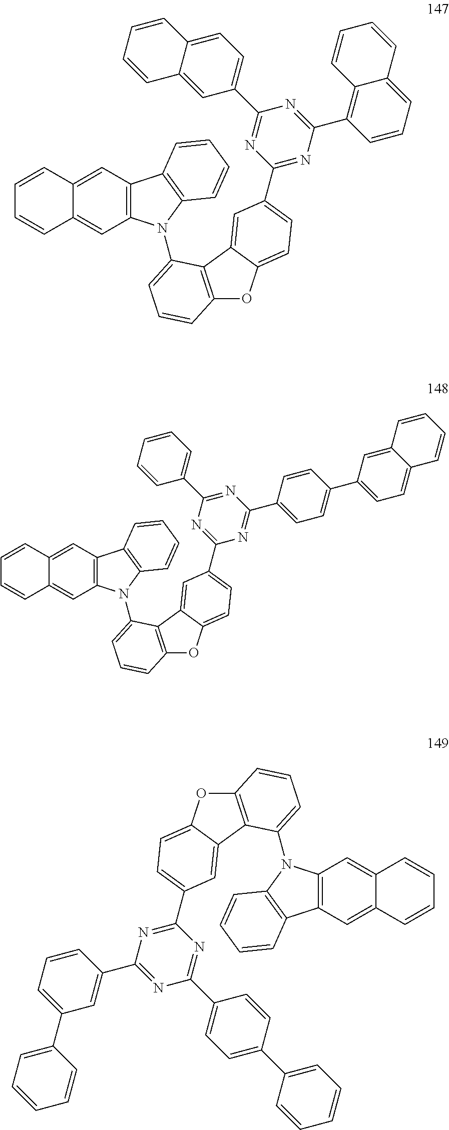 [SMILES: c1ccc2cc(-c3nc(-c4ccc5oc6cccc(-n7c8ccccc8c8cc9ccccc9cc87)c6c5c4)nc(-c4cccc5ccccc45)n3)ccc2c1 ; c1ccc(-c2nc(-c3ccc(-c4ccc5ccccc5c4)cc3)nc(-c3ccc4oc5cccc(-n6c7ccccc7c7cc8ccccc8cc76)c5c4c3)n2)cc1 ; c1ccc(-c2ccc(-c3nc(-c4cccc(-c5ccccc5)c4)nc(-c4ccc5oc6cccc(-n7c8ccccc8c8cc9ccccc9cc87)c6c5c4)n3)cc2)cc1]

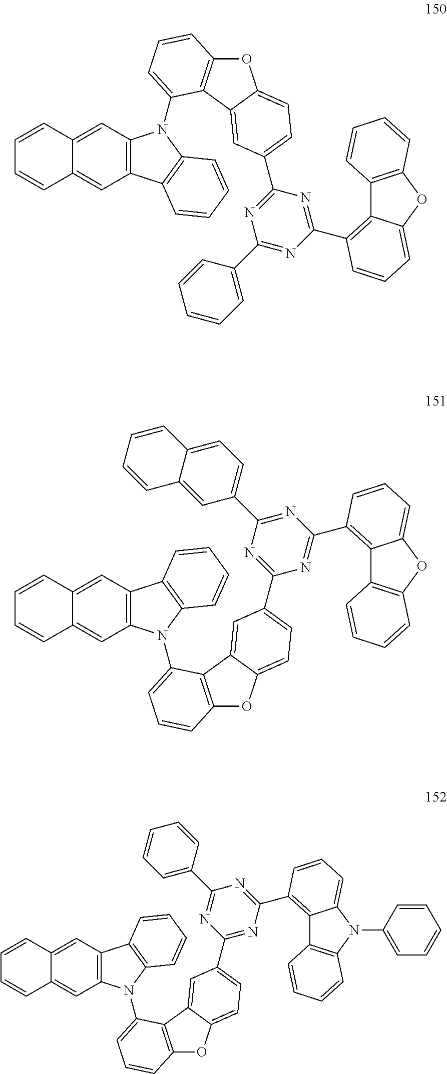 [SMILES: c1ccc(-c2nc(-c3ccc4oc5cccc(-n6c7ccccc7c7cc8ccccc8cc76)c5c4c3)nc(-c3cccc4oc5ccccc5c34)n2)cc1 ; c1ccc2cc(-c3nc(-c4ccc5oc6cccc(-n7c8ccccc8c8cc9ccccc9cc87)c6c5c4)nc(-c4cccc5oc6ccccc6c45)n3)ccc2c1 ; c1ccc(-c2nc(-c3ccc4oc5cccc(-n6c7ccccc7c7cc8ccccc8cc76)c5c4c3)nc(-c3cccc4c3c3ccccc3n4-c3ccccc3)n2)cc1]

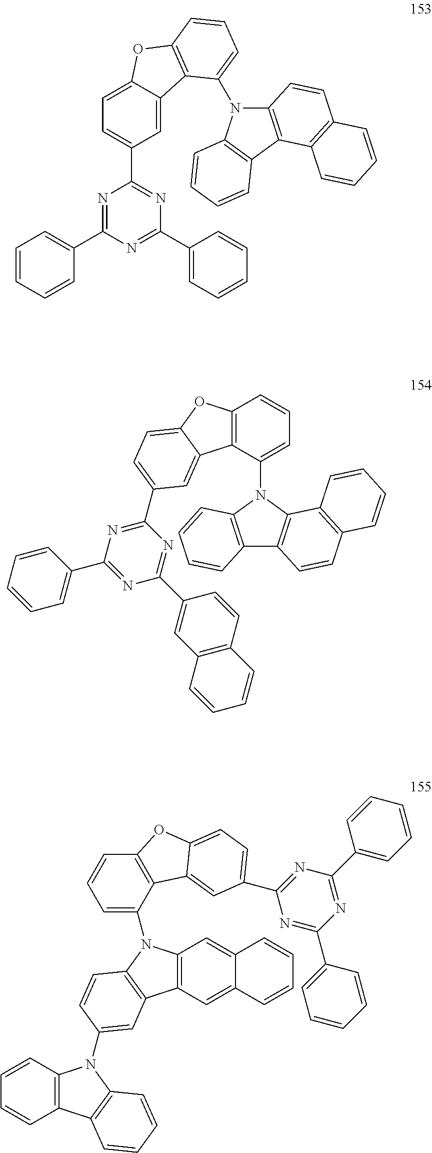 [SMILES: c1ccc(-c2nc(-c3ccccc3)nc(-c3ccc4oc5cccc(-n6c7ccccc7c7c8ccccc8ccc76)c5c4c3)n2)cc1 ; c1ccc(-c2nc(-c3ccc4ccccc4c3)nc(-c3ccc4oc5cccc(-n6c7ccccc7c7ccc8ccccc8c76)c5c4c3)n2)cc1 ; c1ccc(-c2nc(-c3ccccc3)nc(-c3ccc4oc5cccc(-n6c7ccc(-n8c9ccccc9c9ccccc98)cc7c7cc8ccccc8cc76)c5c4c3)n2)cc1]

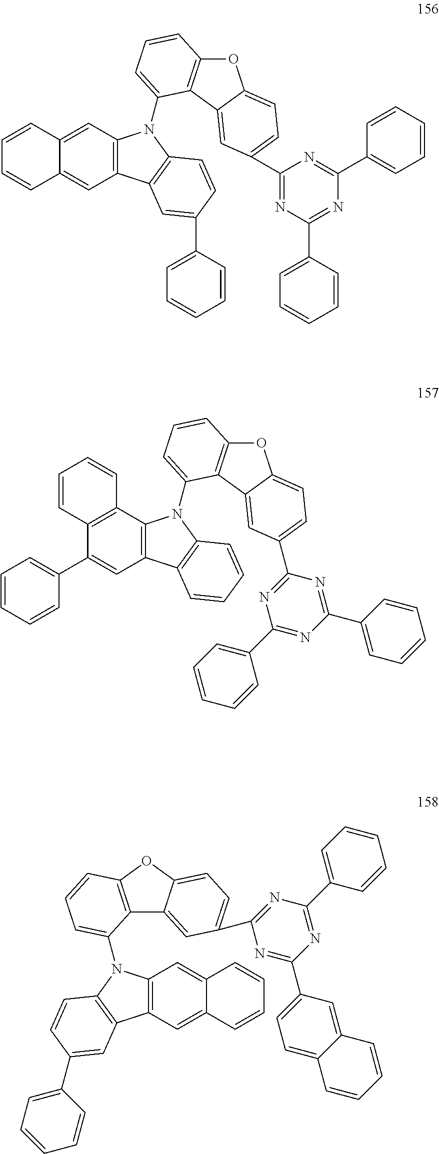 [SMILES: c1ccc(-c2ccc3c(c2)c2cc4ccccc4cc2n3-c2cccc3oc4ccc(-c5nc(-c6ccccc6)nc(-c6ccccc6)n5)cc4c23)cc1 ; c1ccc(-c2nc(-c3ccccc3)nc(-c3ccc4oc5cccc(-n6c7ccccc7c7cc(-c8ccccc8)c8ccccc8c76)c5c4c3)n2)cc1 ; c1ccc(-c2ccc3c(c2)c2cc4ccccc4cc2n3-c2cccc3oc4ccc(-c5nc(-c6ccccc6)nc(-c6ccc7ccccc7c6)n5)cc4c23)cc1]

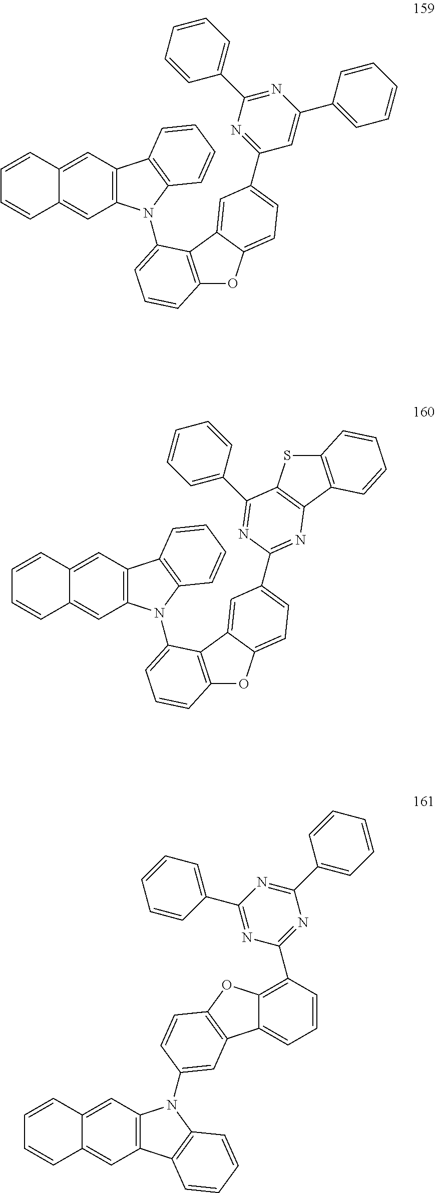 [SMILES: c1ccc(-c2cc(-c3ccc4oc5cccc(-n6c7ccccc7c7cc8ccccc8cc76)c5c4c3)nc(-c3ccccc3)n2)cc1 ; c1ccc(-c2nc(-c3ccc4oc5cccc(-n6c7ccccc7c7cc8ccccc8cc76)c5c4c3)nc3c2sc2ccccc23)cc1 ; c1ccc(-c2nc(-c3ccccc3)nc(-c3cccc4c3oc3ccc(-n5c6ccccc6c6cc7ccccc7cc65)cc34)n2)cc1]

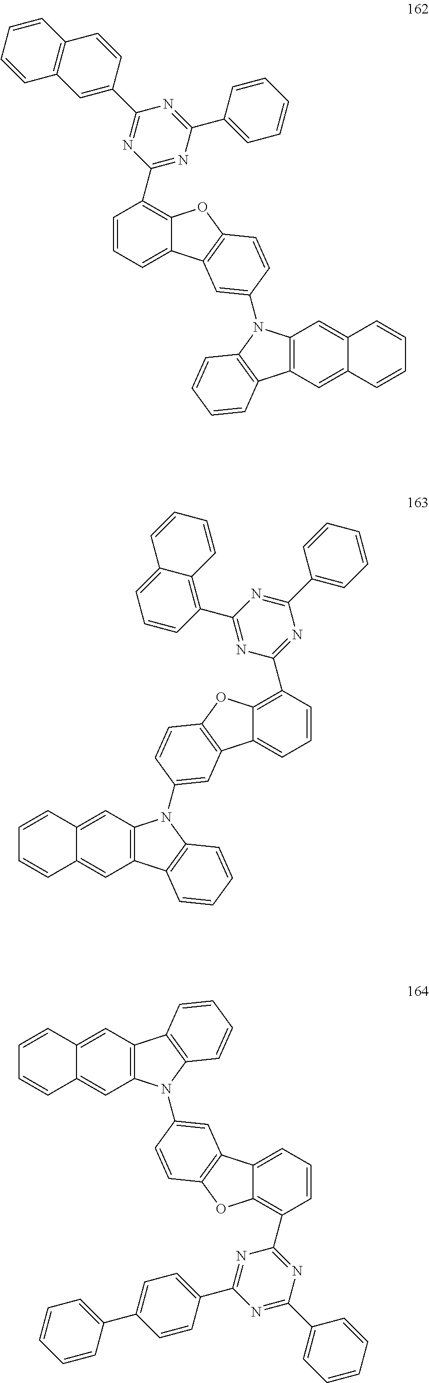 [SMILES: c1ccc(-c2nc(-c3ccc4ccccc4c3)nc(-c3cccc4c3oc3ccc(-n5c6ccccc6c6cc7ccccc7cc65)cc34)n2)cc1 ; c1ccc(-c2nc(-c3cccc4ccccc34)nc(-c3cccc4c3oc3ccc(-n5c6ccccc6c6cc7ccccc7cc65)cc34)n2)cc1 ; c1ccc(-c2ccc(-c3nc(-c4ccccc4)nc(-c4cccc5c4oc4ccc(-n6c7ccccc7c7cc8ccccc8cc76)cc45)n3)cc2)cc1]

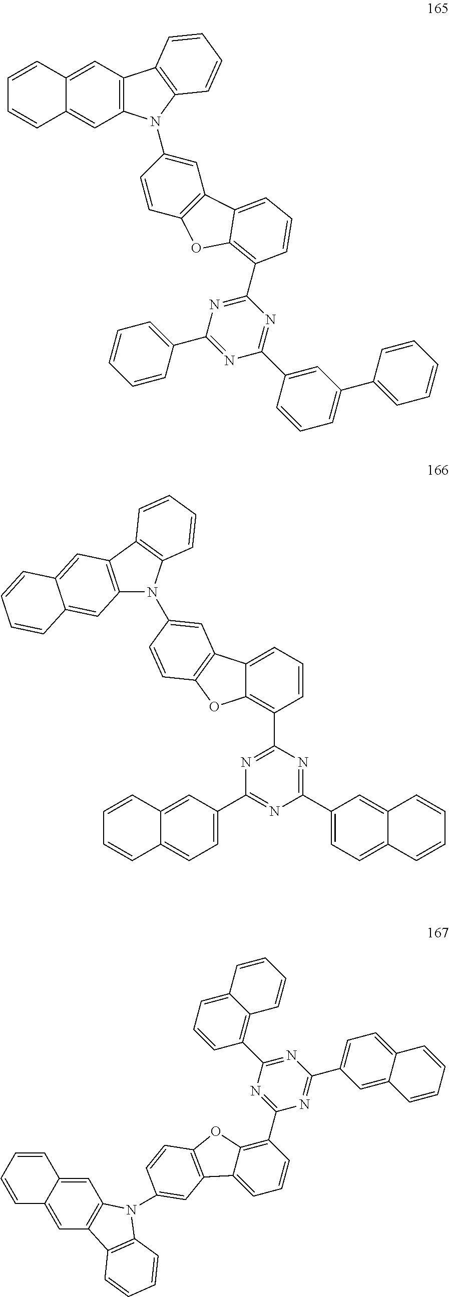 [SMILES: c1ccc(-c2cccc(-c3nc(-c4ccccc4)nc(-c4cccc5c4oc4ccc(-n6c7ccccc7c7cc8ccccc8cc76)cc45)n3)c2)cc1 ; c1ccc2cc(-c3nc(-c4ccc5ccccc5c4)nc(-c4cccc5c4oc4ccc(-n6c7ccccc7c7cc8ccccc8cc76)cc45)n3)ccc2c1 ; c1ccc2cc(-c3nc(-c4cccc5ccccc45)nc(-c4cccc5c4oc4ccc(-n6c7ccccc7c7cc8ccccc8cc76)cc45)n3)ccc2c1]

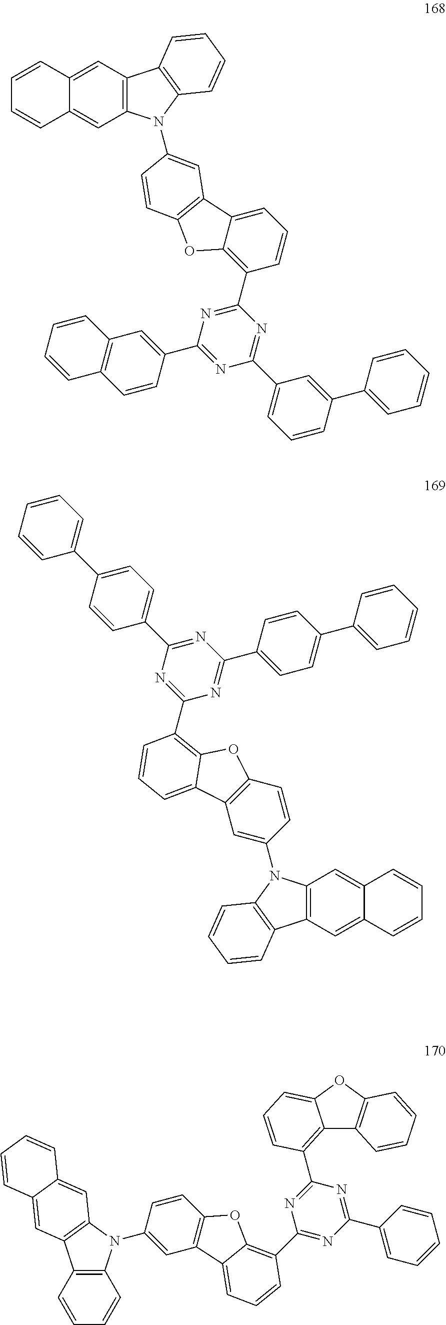 [SMILES: c1ccc(-c2cccc(-c3nc(-c4ccc5ccccc5c4)nc(-c4cccc5c4oc4ccc(-n6c7ccccc7c7cc8ccccc8cc76)cc45)n3)c2)cc1 ; c1ccc(-c2ccc(-c3nc(-c4ccc(-c5ccccc5)cc4)nc(-c4cccc5c4oc4ccc(-n6c7ccccc7c7cc8ccccc8cc76)cc45)n3)cc2)cc1 ; c1ccc(-c2nc(-c3cccc4c3oc3ccc(-n5c6ccccc6c6cc7ccccc7cc65)cc34)nc(-c3cccc4oc5ccccc5c34)n2)cc1]

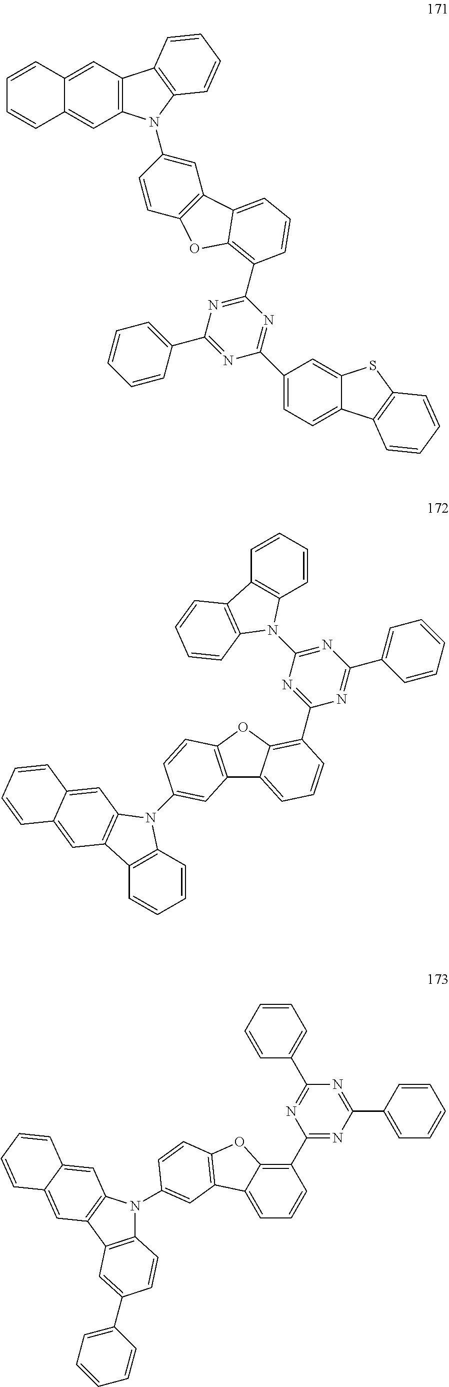 [SMILES: c1ccc(-c2nc(-c3ccc4c(c3)sc3ccccc34)nc(-c3cccc4c3oc3ccc(-n5c6ccccc6c6cc7ccccc7cc65)cc34)n2)cc1 ; c1ccc(-c2nc(-c3cccc4c3oc3ccc(-n5c6ccccc6c6cc7ccccc7cc65)cc34)nc(-n3c4ccccc4c4ccccc43)n2)cc1 ; c1ccc(-c2ccc3c(c2)c2cc4ccccc4cc2n3-c2ccc3oc4c(-c5nc(-c6ccccc6)nc(-c6ccccc6)n5)cccc4c3c2)cc1]

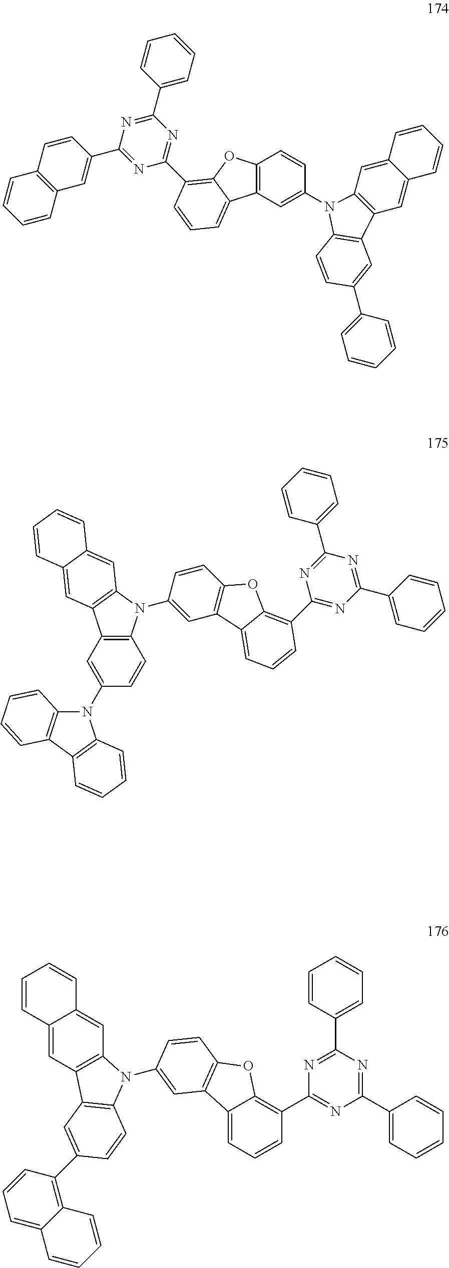 [SMILES: c1ccc(-c2ccc3c(c2)c2cc4ccccc4cc2n3-c2ccc3oc4c(-c5nc(-c6ccccc6)nc(-c6ccc7ccccc7c6)n5)cccc4c3c2)cc1 ; c1ccc(-c2nc(-c3ccccc3)nc(-c3cccc4c3oc3ccc(-n5c6ccc(-n7c8ccccc8c8ccccc87)cc6c6cc7ccccc7cc65)cc34)n2)cc1 ; c1ccc(-c2nc(-c3ccccc3)nc(-c3cccc4c3oc3ccc(-n5c6ccc(-c7cccc8ccccc78)cc6c6cc7ccccc7cc65)cc34)n2)cc1]

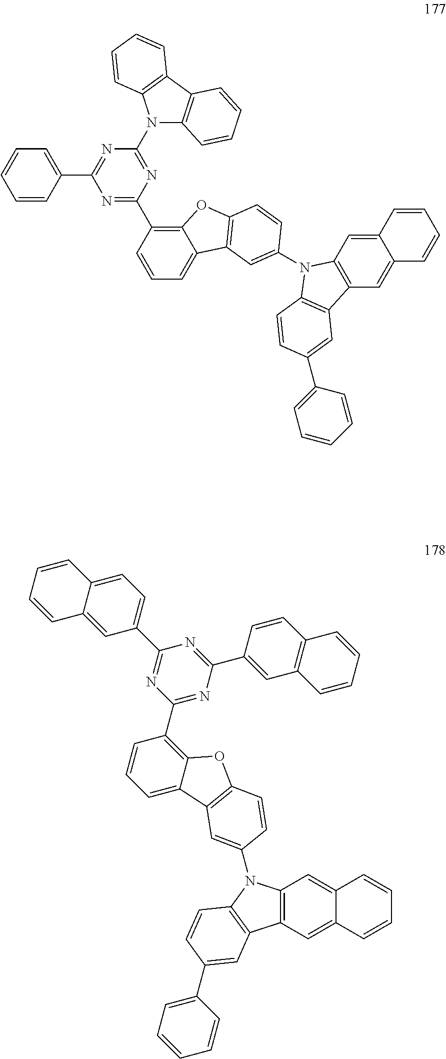 [SMILES: c1ccc(-c2ccc3c(c2)c2cc4ccccc4cc2n3-c2ccc3oc4c(-c5nc(-c6ccccc6)nc(-n6c7ccccc7c7ccccc76)n5)cccc4c3c2)cc1 ; c1ccc(-c2ccc3c(c2)c2cc4ccccc4cc2n3-c2ccc3oc4c(-c5nc(-c6ccc7ccccc7c6)nc(-c6ccc7ccccc7c6)n5)cccc4c3c2)cc1]

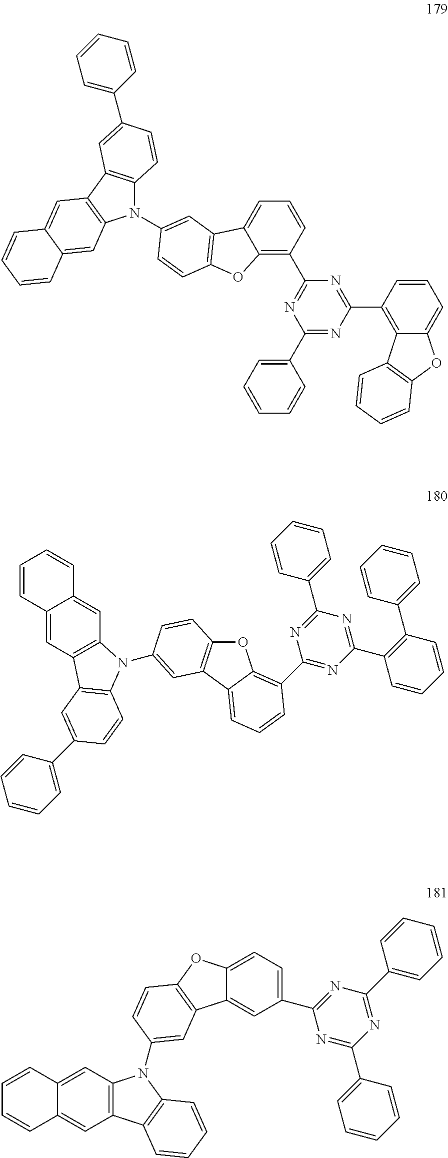 [SMILES: c1ccc(-c2ccc3c(c2)c2cc4ccccc4cc2n3-c2ccc3oc4c(-c5nc(-c6ccccc6)nc(-c6cccc7oc8ccccc8c67)n5)cccc4c3c2)cc1 ; c1ccc(-c2ccc3c(c2)c2cc4ccccc4cc2n3-c2ccc3oc4c(-c5nc(-c6ccccc6)nc(-c6ccccc6-c6ccccc6)n5)cccc4c3c2)cc1 ; c1ccc(-c2nc(-c3ccccc3)nc(-c3ccc4oc5ccc(-n6c7ccccc7c7cc8ccccc8cc76)cc5c4c3)n2)cc1]

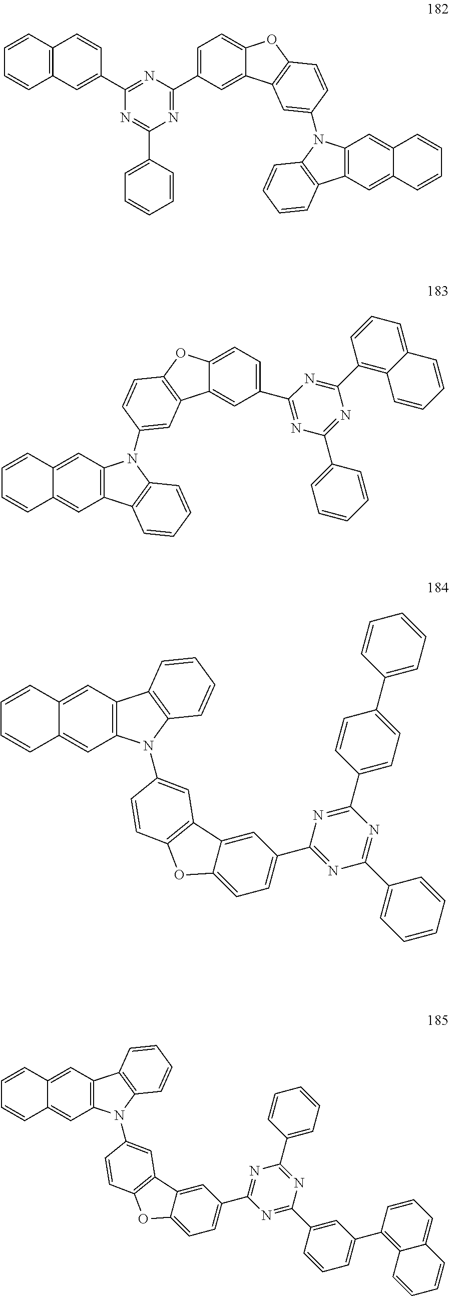 [SMILES: c1ccc(-c2nc(-c3ccc4ccccc4c3)nc(-c3ccc4oc5ccc(-n6c7ccccc7c7cc8ccccc8cc76)cc5c4c3)n2)cc1 ; c1ccc(-c2nc(-c3ccc4oc5ccc(-n6c7ccccc7c7cc8ccccc8cc76)cc5c4c3)nc(-c3cccc4ccccc34)n2)cc1 ; c1ccc(-c2ccc(-c3nc(-c4ccccc4)nc(-c4ccc5oc6ccc(-n7c8ccccc8c8cc9ccccc9cc87)cc6c5c4)n3)cc2)cc1 ; c1ccc(-c2nc(-c3cccc(-c4cccc5ccccc45)c3)nc(-c3ccc4oc5ccc(-n6c7ccccc7c7cc8ccccc8cc76)cc5c4c3)n2)cc1]

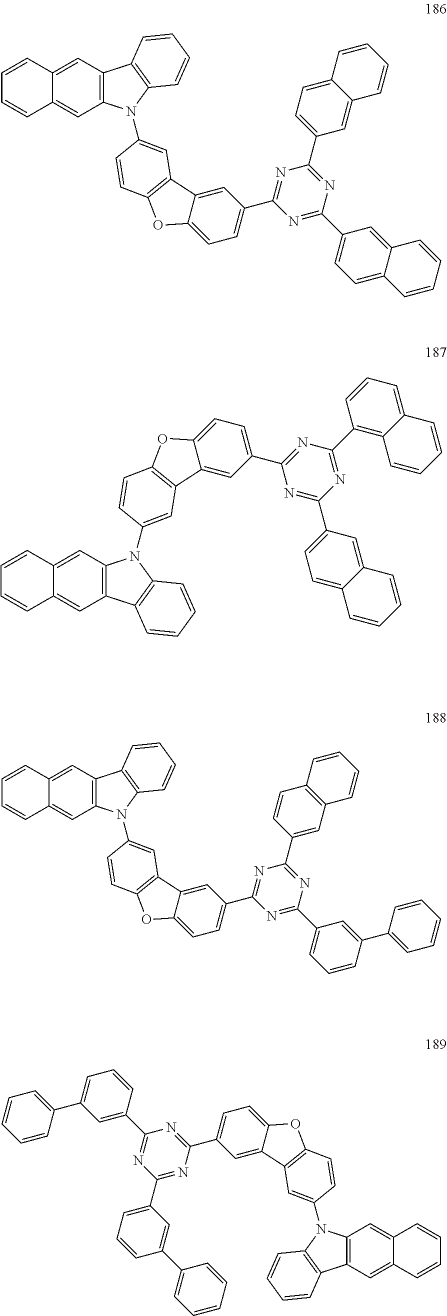 [SMILES: c1ccc2cc(-c3nc(-c4ccc5ccccc5c4)nc(-c4ccc5oc6ccc(-n7c8ccccc8c8cc9ccccc9cc87)cc6c5c4)n3)ccc2c1 ; c1ccc2cc(-c3nc(-c4ccc5oc6ccc(-n7c8ccccc8c8cc9ccccc9cc87)cc6c5c4)nc(-c4cccc5ccccc45)n3)ccc2c1 ; c1ccc(-c2cccc(-c3nc(-c4ccc5ccccc5c4)nc(-c4ccc5oc6ccc(-n7c8ccccc8c8cc9ccccc9cc87)cc6c5c4)n3)c2)cc1 ; c1ccc(-c2cccc(-c3nc(-c4cccc(-c5ccccc5)c4)nc(-c4ccc5oc6ccc(-n7c8ccccc8c8cc9ccccc9cc87)cc6c5c4)n3)c2)cc1]

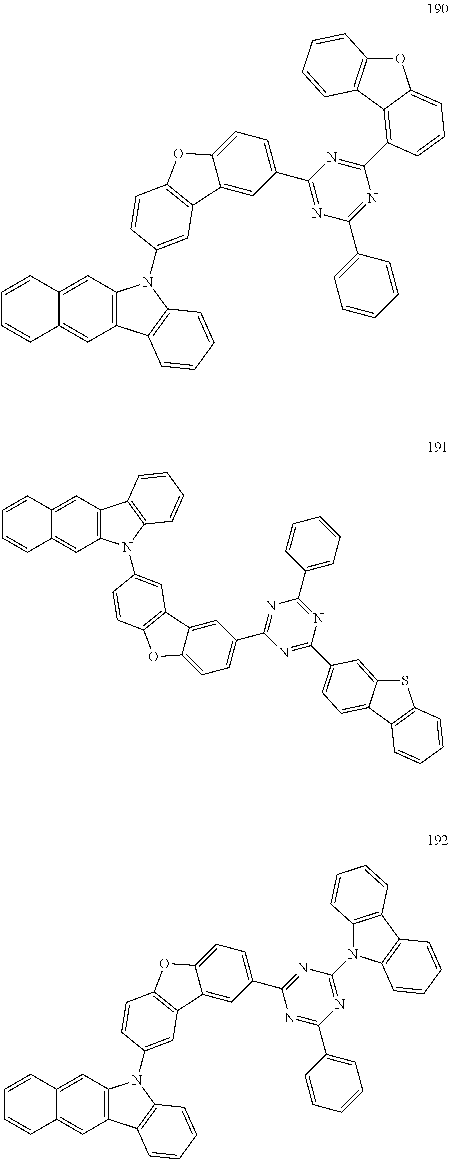 [SMILES: c1ccc(-c2nc(-c3ccc4oc5ccc(-n6c7ccccc7c7cc8ccccc8cc76)cc5c4c3)nc(-c3cccc4oc5ccccc5c34)n2)cc1 ; c1ccc(-c2nc(-c3ccc4c(c3)sc3ccccc34)nc(-c3ccc4oc5ccc(-n6c7ccccc7c7cc8ccccc8cc76)cc5c4c3)n2)cc1 ; c1ccc(-c2nc(-c3ccc4oc5ccc(-n6c7ccccc7c7cc8ccccc8cc76)cc5c4c3)nc(-n3c4ccccc4c4ccccc43)n2)cc1]

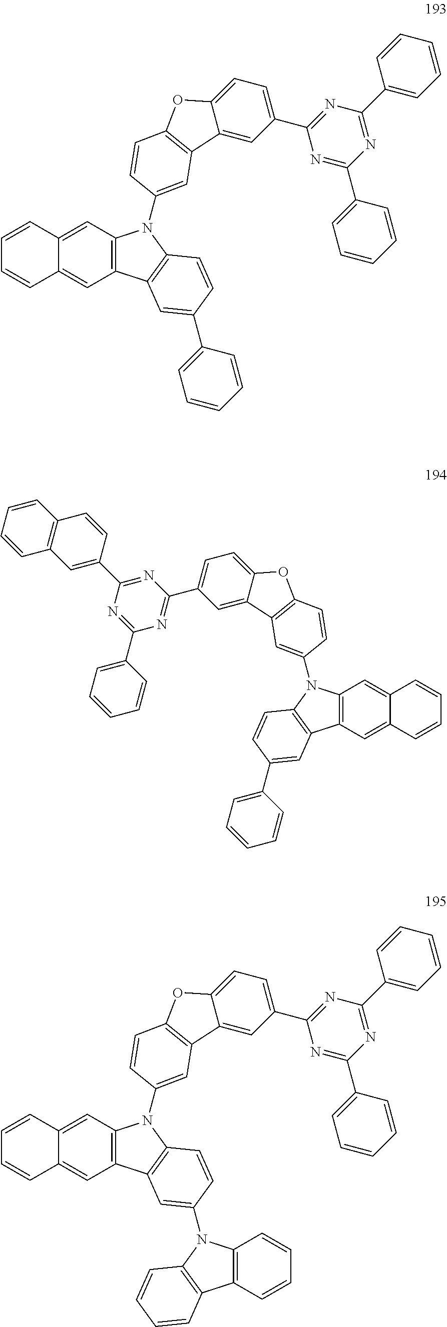 [SMILES: c1ccc(-c2ccc3c(c2)c2cc4ccccc4cc2n3-c2ccc3oc4ccc(-c5nc(-c6ccccc6)nc(-c6ccccc6)n5)cc4c3c2)cc1 ; c1ccc(-c2ccc3c(c2)c2cc4ccccc4cc2n3-c2ccc3oc4ccc(-c5nc(-c6ccccc6)nc(-c6ccc7ccccc7c6)n5)cc4c3c2)cc1 ; c1ccc(-c2nc(-c3ccccc3)nc(-c3ccc4oc5ccc(-n6c7ccc(-n8c9ccccc9c9ccccc98)cc7c7cc8ccccc8cc76)cc5c4c3)n2)cc1]

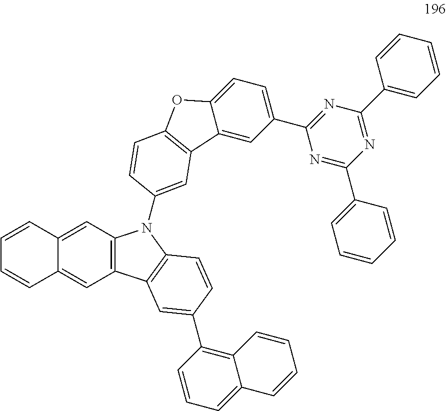 [SMILES: c1ccc(-c2nc(-c3ccccc3)nc(-c3ccc4oc5ccc(-n6c7ccc(-c8cccc9ccccc89)cc7c7cc8ccccc8cc76)cc5c4c3)n2)cc1]

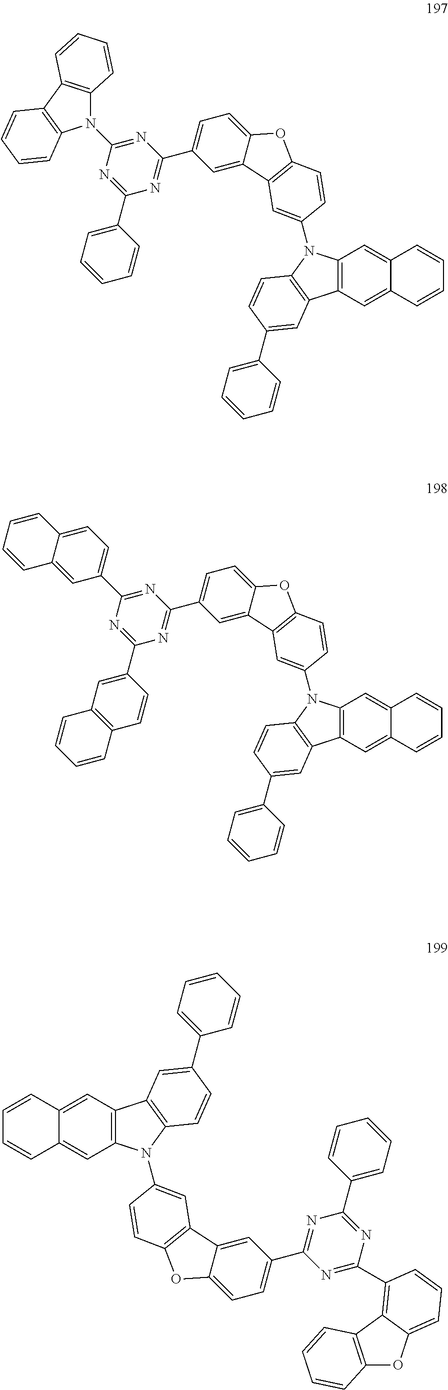 [SMILES: c1ccc(-c2ccc3c(c2)c2cc4ccccc4cc2n3-c2ccc3oc4ccc(-c5nc(-c6ccccc6)nc(-n6c7ccccc7c7ccccc76)n5)cc4c3c2)cc1 ; c1ccc(-c2ccc3c(c2)c2cc4ccccc4cc2n3-c2ccc3oc4ccc(-c5nc(-c6ccc7ccccc7c6)nc(-c6ccc7ccccc7c6)n5)cc4c3c2)cc1 ; c1ccc(-c2ccc3c(c2)c2cc4ccccc4cc2n3-c2ccc3oc4ccc(-c5nc(-c6ccccc6)nc(-c6cccc7oc8ccccc8c67)n5)cc4c3c2)cc1]

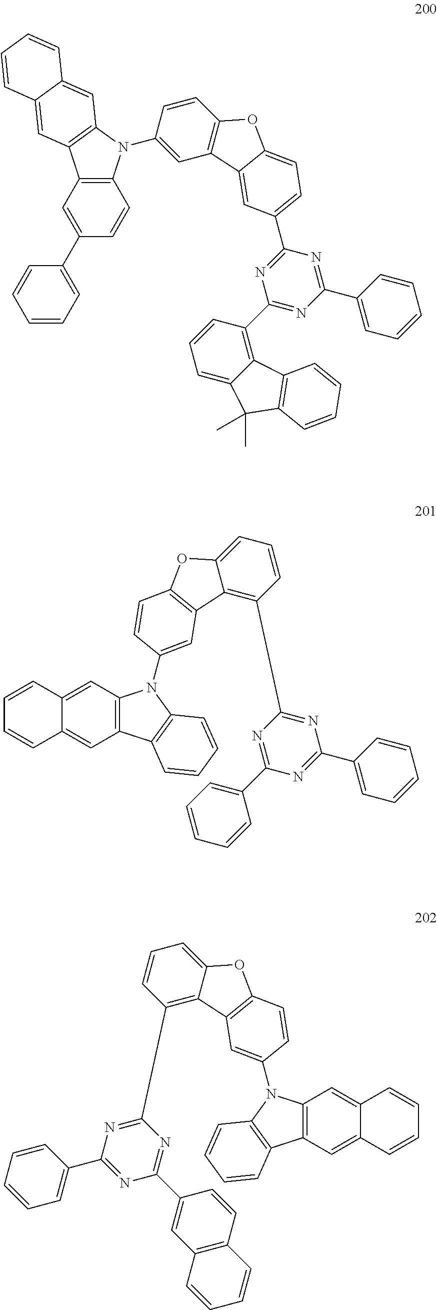 [SMILES: CC1(C)c2ccccc2-c2c(-c3nc(-c4ccccc4)nc(-c4ccc5oc6ccc(-n7c8ccc(-c9ccccc9)cc8c8cc9ccccc9cc87)cc6c5c4)n3)cccc21 ; c1ccc(-c2nc(-c3ccccc3)nc(-c3cccc4oc5ccc(-n6c7ccccc7c7cc8ccccc8cc76)cc5c34)n2)cc1 ; c1ccc(-c2nc(-c3ccc4ccccc4c3)nc(-c3cccc4oc5ccc(-n6c7ccccc7c7cc8ccccc8cc76)cc5c34)n2)cc1]

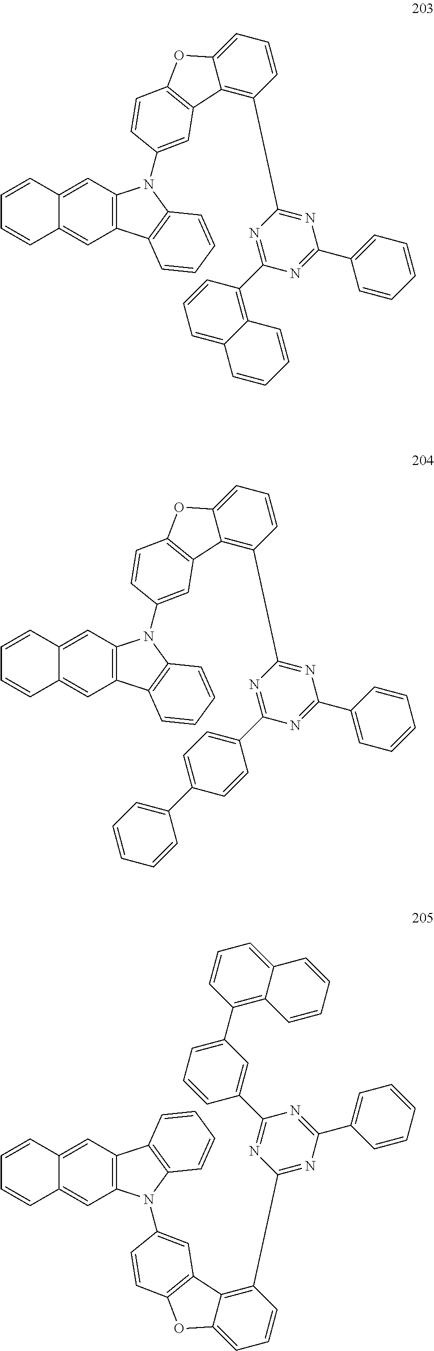 [SMILES: c1ccc(-c2nc(-c3cccc4ccccc34)nc(-c3cccc4oc5ccc(-n6c7ccccc7c7cc8ccccc8cc76)cc5c34)n2)cc1 ; c1ccc(-c2ccc(-c3nc(-c4ccccc4)nc(-c4cccc5oc6ccc(-n7c8ccccc8c8cc9ccccc9cc87)cc6c45)n3)cc2)cc1 ; c1ccc(-c2nc(-c3cccc(-c4cccc5ccccc45)c3)nc(-c3cccc4oc5ccc(-n6c7ccccc7c7cc8ccccc8cc76)cc5c34)n2)cc1]

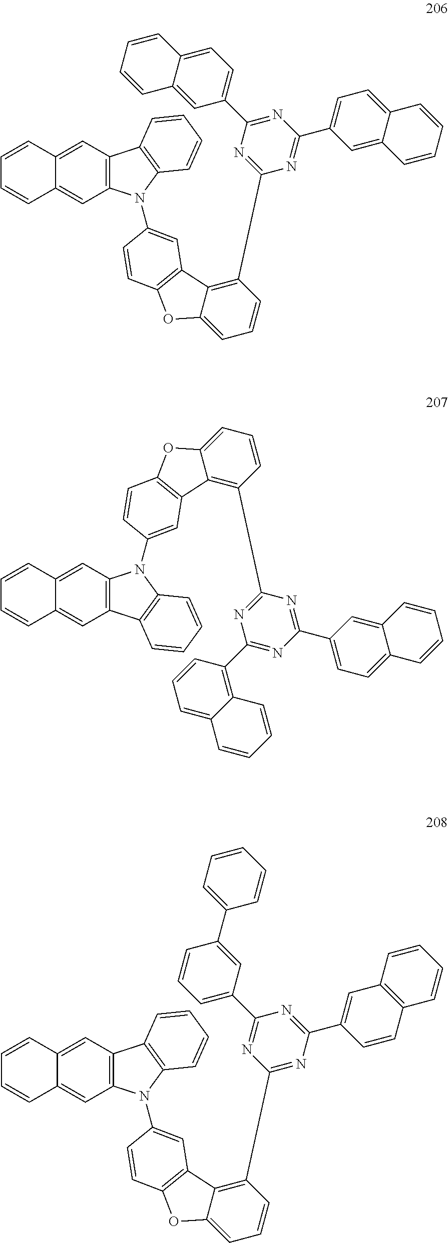 [SMILES: c1ccc2cc(-c3nc(-c4ccc5ccccc5c4)nc(-c4cccc5oc6ccc(-n7c8ccccc8c8cc9ccccc9cc87)cc6c45)n3)ccc2c1 ; c1ccc2cc(-c3nc(-c4cccc5ccccc45)nc(-c4cccc5oc6ccc(-n7c8ccccc8c8cc9ccccc9cc87)cc6c45)n3)ccc2c1 ; c1ccc(-c2cccc(-c3nc(-c4ccc5ccccc5c4)nc(-c4cccc5oc6ccc(-n7c8ccccc8c8cc9ccccc9cc87)cc6c45)n3)c2)cc1]

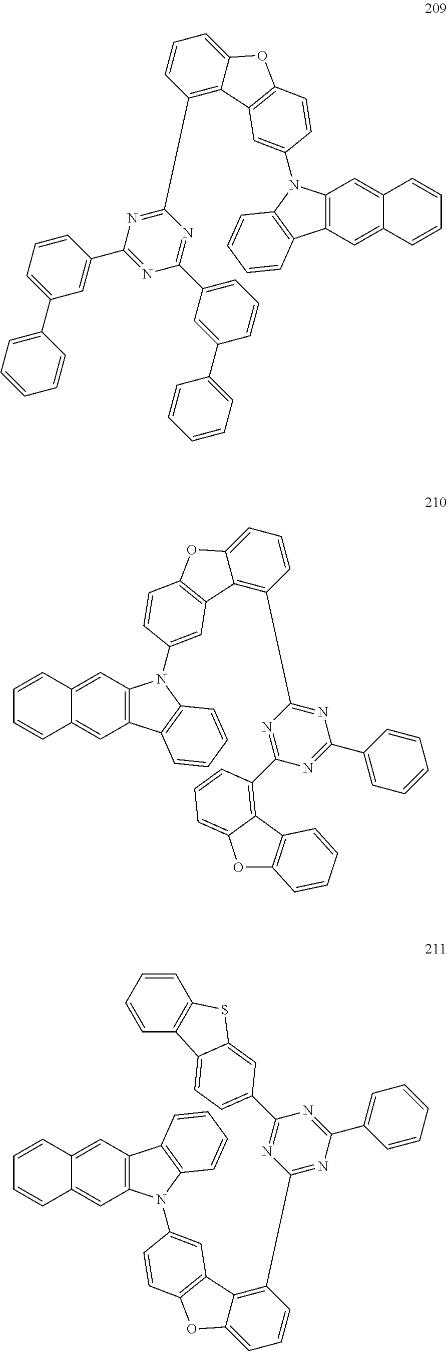 [SMILES: c1ccc(-c2cccc(-c3nc(-c4cccc(-c5ccccc5)c4)nc(-c4cccc5oc6ccc(-n7c8ccccc8c8cc9ccccc9cc87)cc6c45)n3)c2)cc1 ; c1ccc(-c2nc(-c3cccc4oc5ccccc5c34)nc(-c3cccc4oc5ccc(-n6c7ccccc7c7cc8ccccc8cc76)cc5c34)n2)cc1 ; c1ccc(-c2nc(-c3ccc4c(c3)sc3ccccc34)nc(-c3cccc4oc5ccc(-n6c7ccccc7c7cc8ccccc8cc76)cc5c34)n2)cc1]

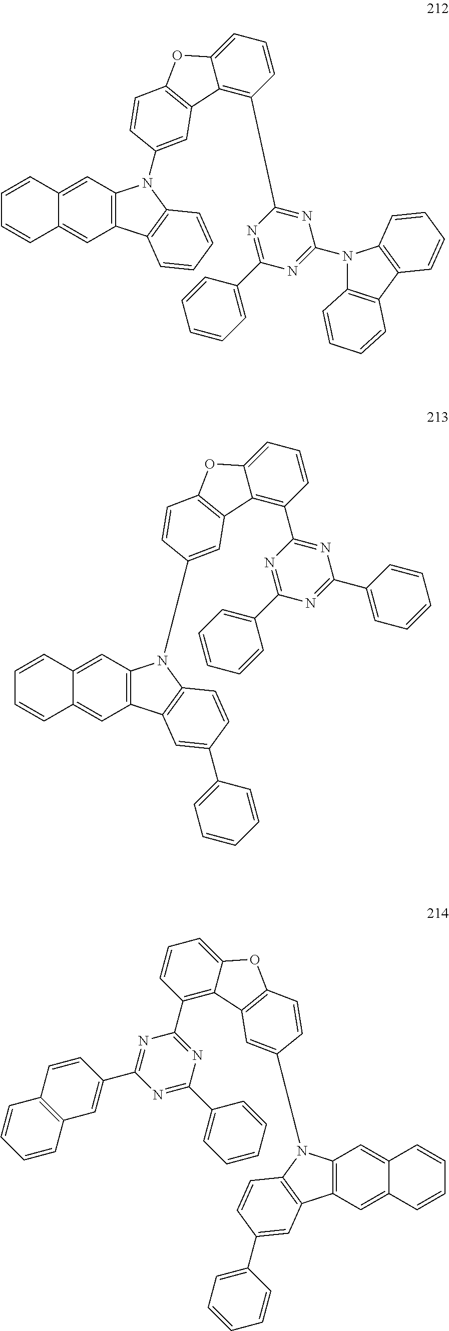 [SMILES: c1ccc(-c2nc(-c3cccc4oc5ccc(-n6c7ccccc7c7cc8ccccc8cc76)cc5c34)nc(-n3c4ccccc4c4ccccc43)n2)cc1 ; c1ccc(-c2ccc3c(c2)c2cc4ccccc4cc2n3-c2ccc3oc4cccc(-c5nc(-c6ccccc6)nc(-c6ccccc6)n5)c4c3c2)cc1 ; c1ccc(-c2ccc3c(c2)c2cc4ccccc4cc2n3-c2ccc3oc4cccc(-c5nc(-c6ccccc6)nc(-c6ccc7ccccc7c6)n5)c4c3c2)cc1]

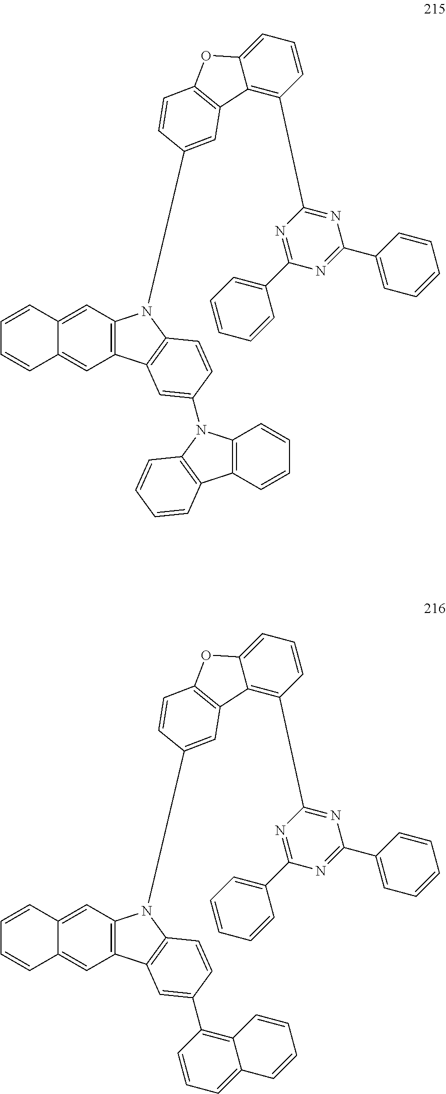 [SMILES: c1ccc(-c2nc(-c3ccccc3)nc(-c3cccc4oc5ccc(-n6c7ccc(-n8c9ccccc9c9ccccc98)cc7c7cc8ccccc8cc76)cc5c34)n2)cc1 ; c1ccc(-c2nc(-c3ccccc3)nc(-c3cccc4oc5ccc(-n6c7ccc(-c8cccc9ccccc89)cc7c7cc8ccccc8cc76)cc5c34)n2)cc1]

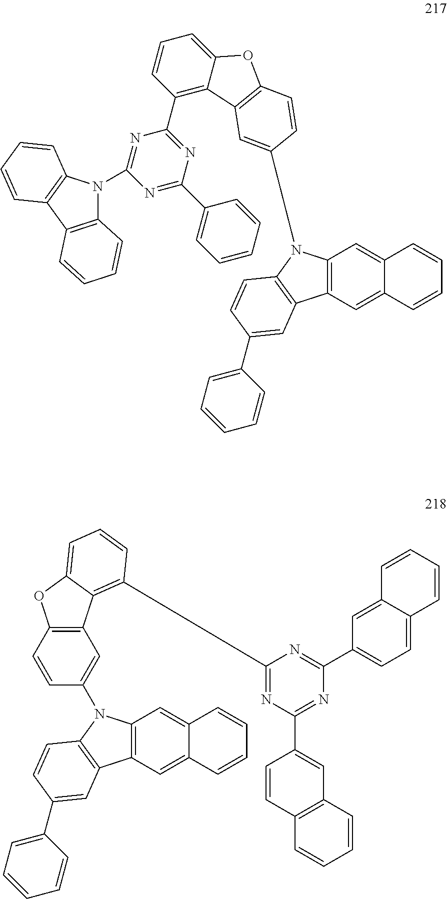 [SMILES: c1ccc(-c2ccc3c(c2)c2cc4ccccc4cc2n3-c2ccc3oc4cccc(-c5nc(-c6ccccc6)nc(-n6c7ccccc7c7ccccc76)n5)c4c3c2)cc1 ; c1ccc(-c2ccc3c(c2)c2cc4ccccc4cc2n3-c2ccc3oc4cccc(-c5nc(-c6ccc7ccccc7c6)nc(-c6ccc7ccccc7c6)n5)c4c3c2)cc1]

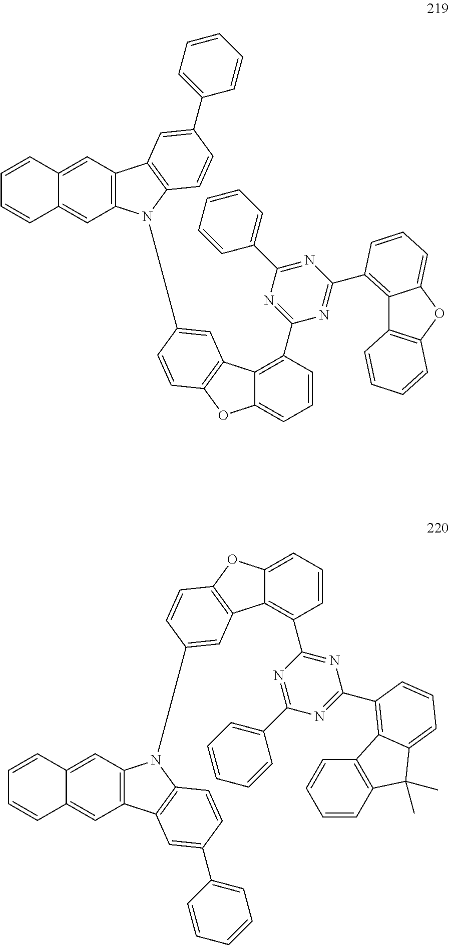 [SMILES: c1ccc(-c2ccc3c(c2)c2cc4ccccc4cc2n3-c2ccc3oc4cccc(-c5nc(-c6ccccc6)nc(-c6cccc7oc8ccccc8c67)n5)c4c3c2)cc1 ; CC1(C)c2ccccc2-c2c(-c3nc(-c4ccccc4)nc(-c4cccc5oc6ccc(-n7c8ccc(-c9ccccc9)cc8c8cc9ccccc9cc87)cc6c45)n3)cccc21]

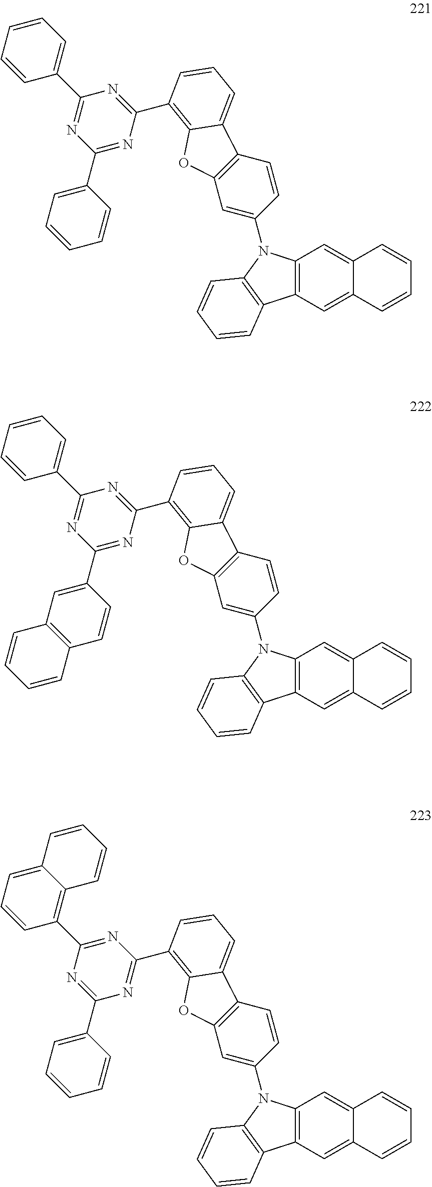 [SMILES: c1ccc(-c2nc(-c3ccccc3)nc(-c3cccc4c3oc3cc(-n5c6ccccc6c6cc7ccccc7cc65)ccc34)n2)cc1 ; c1ccc(-c2nc(-c3ccc4ccccc4c3)nc(-c3cccc4c3oc3cc(-n5c6ccccc6c6cc7ccccc7cc65)ccc34)n2)cc1 ; c1ccc(-c2nc(-c3cccc4ccccc34)nc(-c3cccc4c3oc3cc(-n5c6ccccc6c6cc7ccccc7cc65)ccc34)n2)cc1]

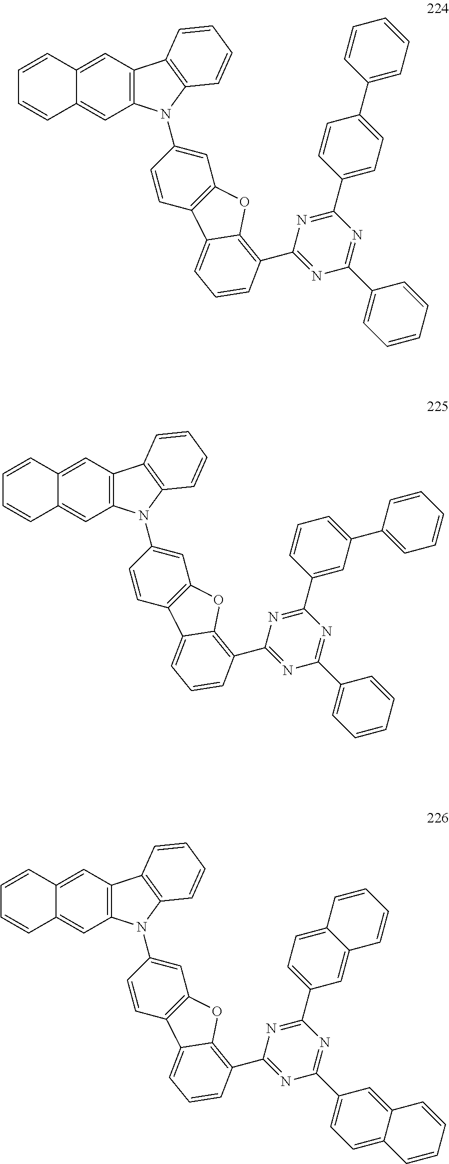 [SMILES: c1ccc(-c2ccc(-c3nc(-c4ccccc4)nc(-c4cccc5c4oc4cc(-n6c7ccccc7c7cc8ccccc8cc76)ccc45)n3)cc2)cc1 ; c1ccc(-c2cccc(-c3nc(-c4ccccc4)nc(-c4cccc5c4oc4cc(-n6c7ccccc7c7cc8ccccc8cc76)ccc45)n3)c2)cc1 ; c1ccc2cc(-c3nc(-c4ccc5ccccc5c4)nc(-c4cccc5c4oc4cc(-n6c7ccccc7c7cc8ccccc8cc76)ccc45)n3)ccc2c1]

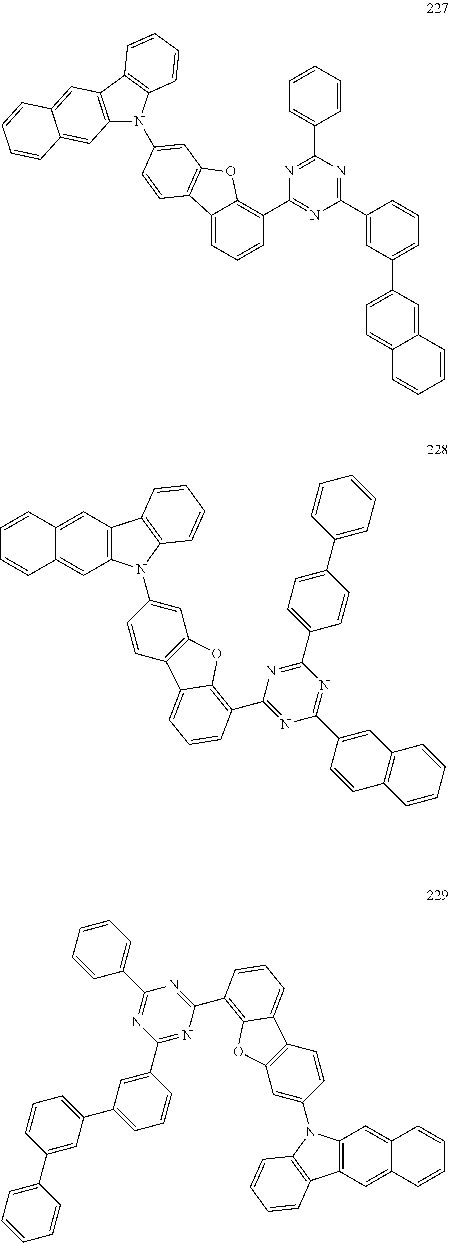 [SMILES: c1ccc(-c2nc(-c3cccc(-c4ccc5ccccc5c4)c3)nc(-c3cccc4c3oc3cc(-n5c6ccccc6c6cc7ccccc7cc65)ccc34)n2)cc1 ; c1ccc(-c2ccc(-c3nc(-c4ccc5ccccc5c4)nc(-c4cccc5c4oc4cc(-n6c7ccccc7c7cc8ccccc8cc76)ccc45)n3)cc2)cc1 ; c1ccc(-c2cccc(-c3cccc(-c4nc(-c5ccccc5)nc(-c5cccc6c5oc5cc(-n7c8ccccc8c8cc9ccccc9cc87)ccc56)n4)c3)c2)cc1]

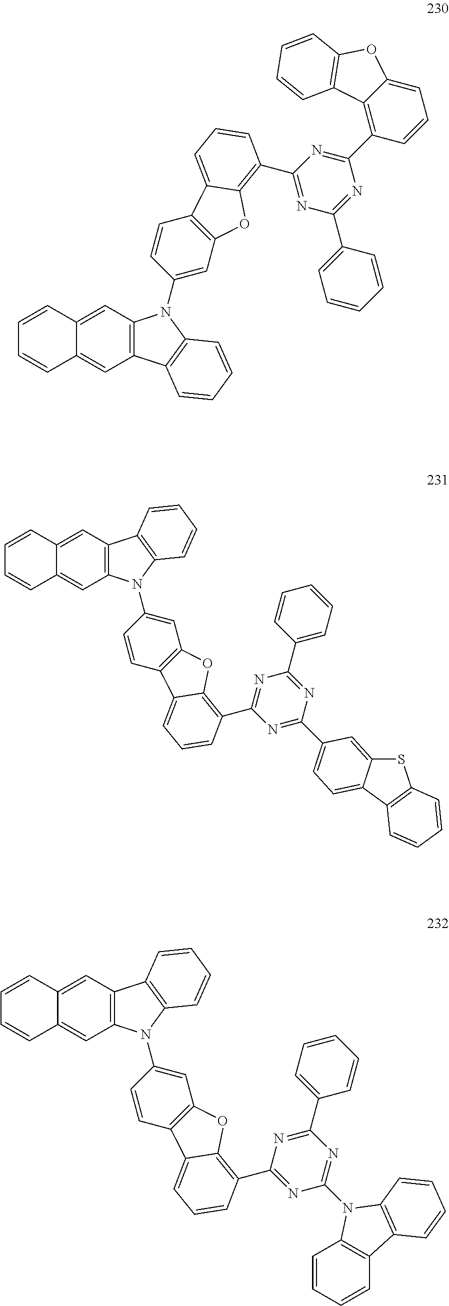 [SMILES: c1ccc(-c2nc(-c3cccc4c3oc3cc(-n5c6ccccc6c6cc7ccccc7cc65)ccc34)nc(-c3cccc4oc5ccccc5c34)n2)cc1 ; c1ccc(-c2nc(-c3ccc4c(c3)sc3ccccc34)nc(-c3cccc4c3oc3cc(-n5c6ccccc6c6cc7ccccc7cc65)ccc34)n2)cc1 ; c1ccc(-c2nc(-c3cccc4c3oc3cc(-n5c6ccccc6c6cc7ccccc7cc65)ccc34)nc(-n3c4ccccc4c4ccccc43)n2)cc1]

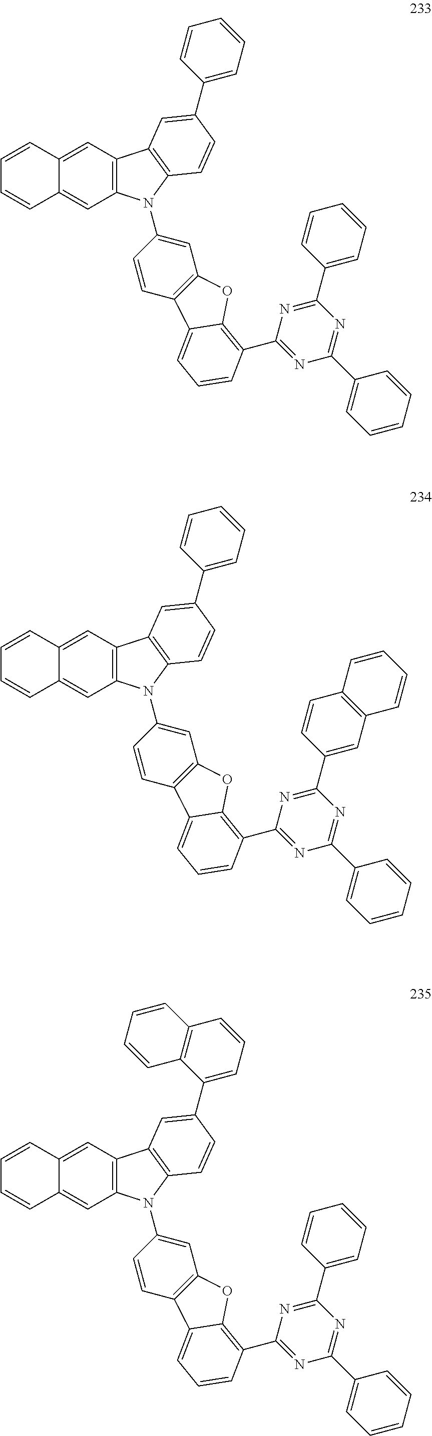 [SMILES: c1ccc(-c2ccc3c(c2)c2cc4ccccc4cc2n3-c2ccc3c(c2)oc2c(-c4nc(-c5ccccc5)nc(-c5ccccc5)n4)cccc23)cc1 ; c1ccc(-c2ccc3c(c2)c2cc4ccccc4cc2n3-c2ccc3c(c2)oc2c(-c4nc(-c5ccccc5)nc(-c5ccc6ccccc6c5)n4)cccc23)cc1 ; c1ccc(-c2nc(-c3ccccc3)nc(-c3cccc4c3oc3cc(-n5c6ccc(-c7cccc8ccccc78)cc6c6cc7ccccc7cc65)ccc34)n2)cc1]

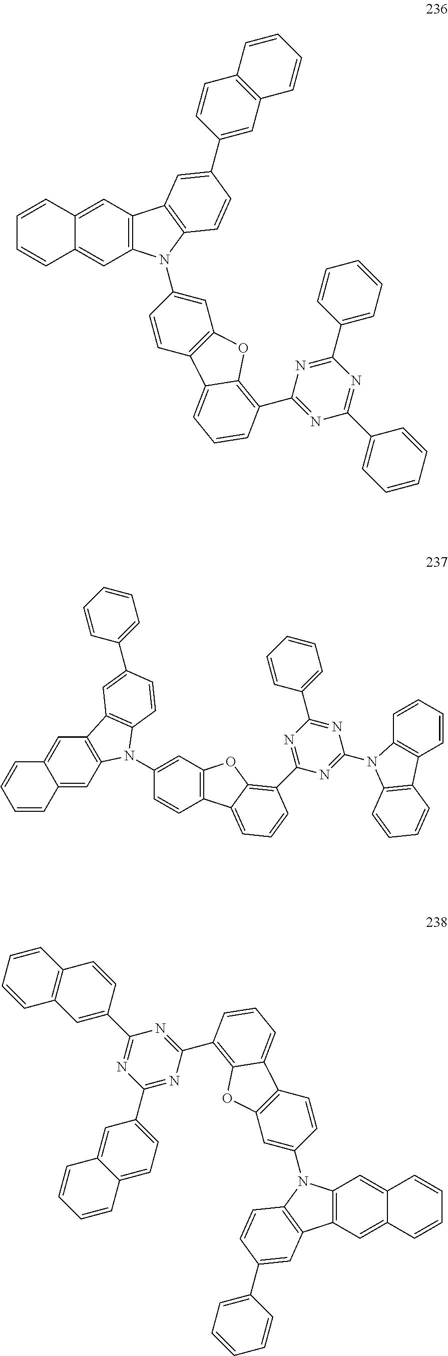 [SMILES: c1ccc(-c2nc(-c3ccccc3)nc(-c3cccc4c3oc3cc(-n5c6ccc(-c7ccc8ccccc8c7)cc6c6cc7ccccc7cc65)ccc34)n2)cc1 ; c1ccc(-c2ccc3c(c2)c2cc4ccccc4cc2n3-c2ccc3c(c2)oc2c(-c4nc(-c5ccccc5)nc(-n5c6ccccc6c6ccccc65)n4)cccc23)cc1 ; c1ccc(-c2ccc3c(c2)c2cc4ccccc4cc2n3-c2ccc3c(c2)oc2c(-c4nc(-c5ccc6ccccc6c5)nc(-c5ccc6ccccc6c5)n4)cccc23)cc1]

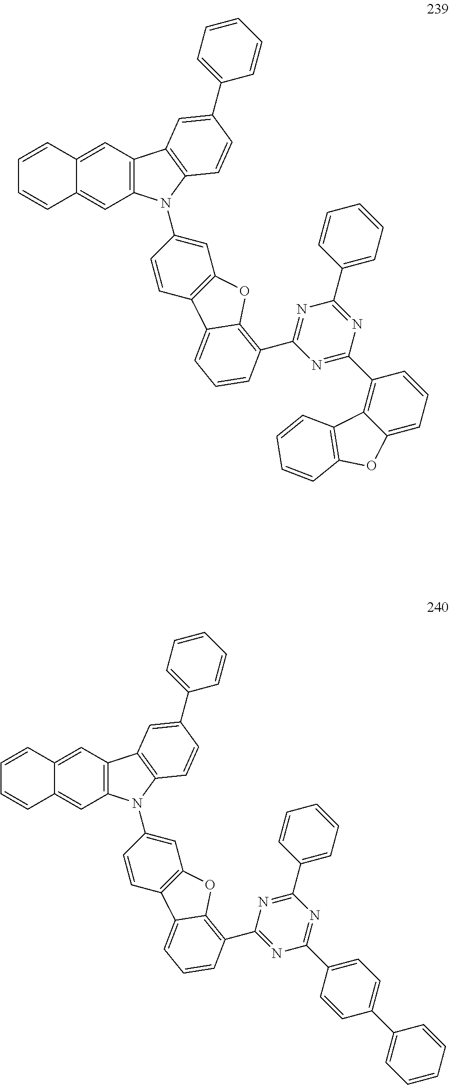 [SMILES: c1ccc(-c2ccc3c(c2)c2cc4ccccc4cc2n3-c2ccc3c(c2)oc2c(-c4nc(-c5ccccc5)nc(-c5cccc6oc7ccccc7c56)n4)cccc23)cc1 ; c1ccc(-c2ccc(-c3nc(-c4ccccc4)nc(-c4cccc5c4oc4cc(-n6c7ccc(-c8ccccc8)cc7c7cc8ccccc8cc76)ccc45)n3)cc2)cc1]

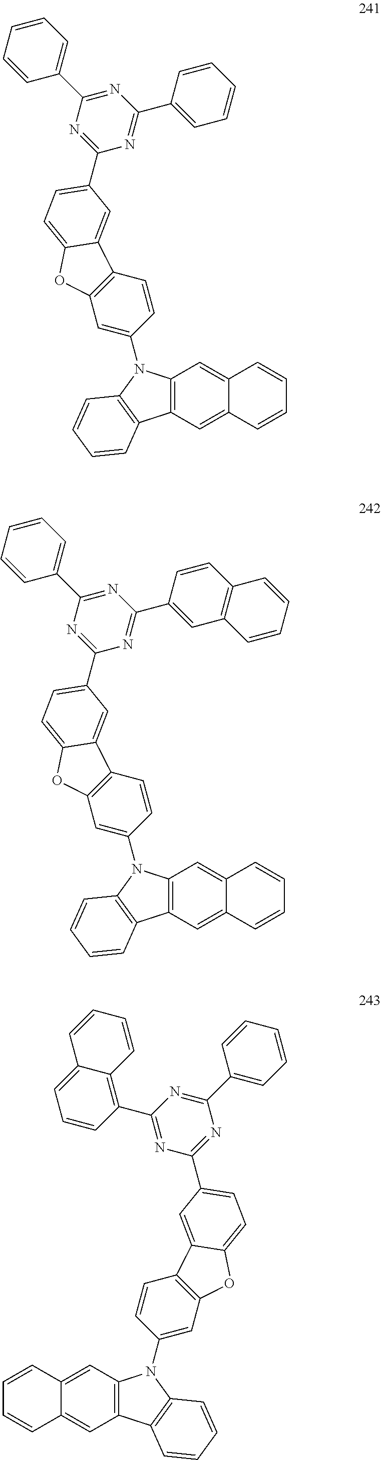 [SMILES: c1ccc(-c2nc(-c3ccccc3)nc(-c3ccc4oc5cc(-n6c7ccccc7c7cc8ccccc8cc76)ccc5c4c3)n2)cc1 ; c1ccc(-c2nc(-c3ccc4ccccc4c3)nc(-c3ccc4oc5cc(-n6c7ccccc7c7cc8ccccc8cc76)ccc5c4c3)n2)cc1 ; c1ccc(-c2nc(-c3ccc4oc5cc(-n6c7ccccc7c7cc8ccccc8cc76)ccc5c4c3)nc(-c3cccc4ccccc34)n2)cc1]

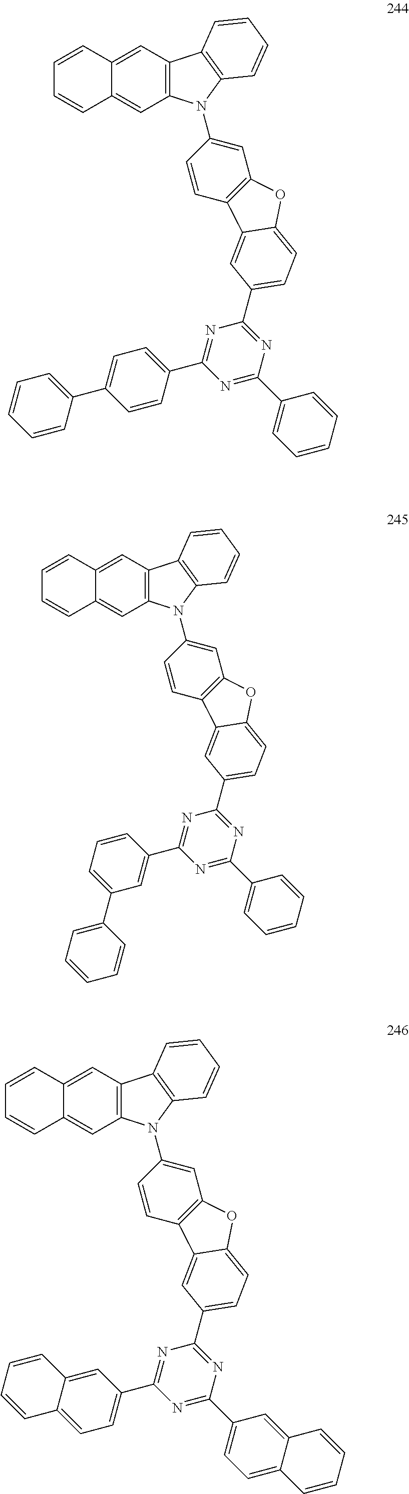 [SMILES: c1ccc(-c2ccc(-c3nc(-c4ccccc4)nc(-c4ccc5oc6cc(-n7c8ccccc8c8cc9ccccc9cc87)ccc6c5c4)n3)cc2)cc1 ; c1ccc(-c2cccc(-c3nc(-c4ccccc4)nc(-c4ccc5oc6cc(-n7c8ccccc8c8cc9ccccc9cc87)ccc6c5c4)n3)c2)cc1 ; c1ccc2cc(-c3nc(-c4ccc5ccccc5c4)nc(-c4ccc5oc6cc(-n7c8ccccc8c8cc9ccccc9cc87)ccc6c5c4)n3)ccc2c1]

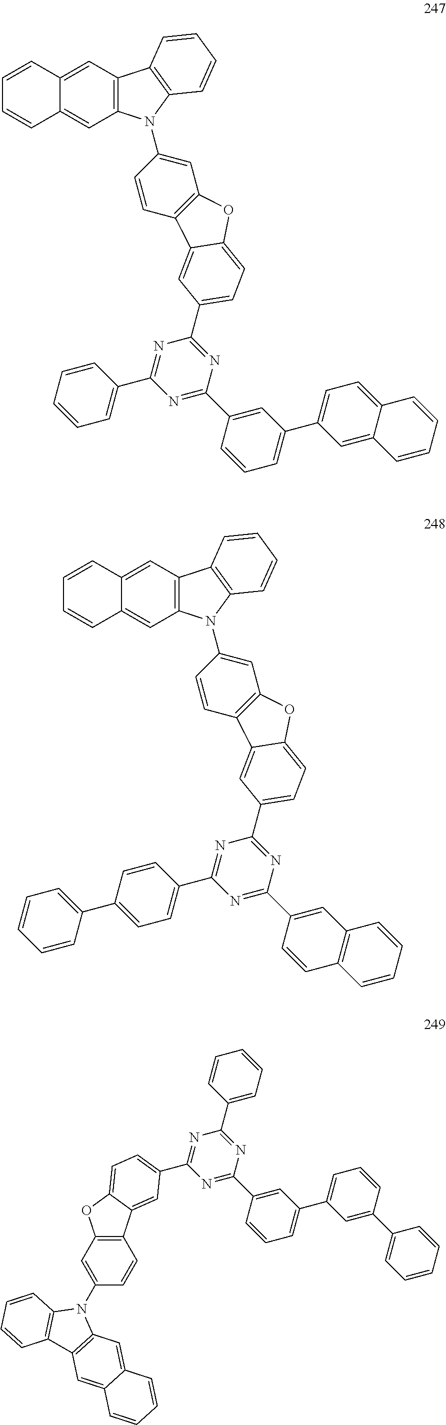 [SMILES: c1ccc(-c2nc(-c3cccc(-c4ccc5ccccc5c4)c3)nc(-c3ccc4oc5cc(-n6c7ccccc7c7cc8ccccc8cc76)ccc5c4c3)n2)cc1 ; c1ccc(-c2ccc(-c3nc(-c4ccc5ccccc5c4)nc(-c4ccc5oc6cc(-n7c8ccccc8c8cc9ccccc9cc87)ccc6c5c4)n3)cc2)cc1 ; c1ccc(-c2cccc(-c3cccc(-c4nc(-c5ccccc5)nc(-c5ccc6oc7cc(-n8c9ccccc9c9cc%10ccccc%10cc98)ccc7c6c5)n4)c3)c2)cc1]

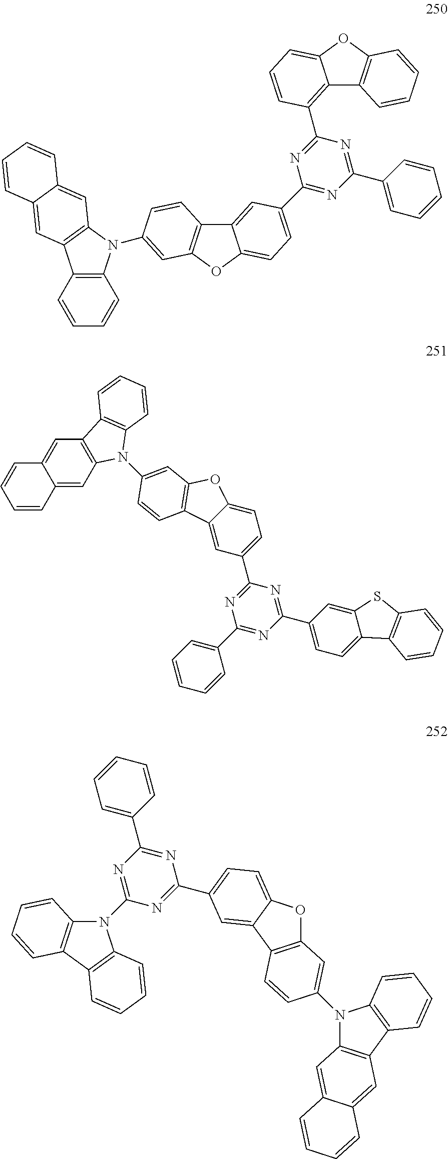 [SMILES: c1ccc(-c2nc(-c3ccc4oc5cc(-n6c7ccccc7c7cc8ccccc8cc76)ccc5c4c3)nc(-c3cccc4oc5ccccc5c34)n2)cc1 ; c1ccc(-c2nc(-c3ccc4c(c3)sc3ccccc34)nc(-c3ccc4oc5cc(-n6c7ccccc7c7cc8ccccc8cc76)ccc5c4c3)n2)cc1 ; c1ccc(-c2nc(-c3ccc4oc5cc(-n6c7ccccc7c7cc8ccccc8cc76)ccc5c4c3)nc(-n3c4ccccc4c4ccccc43)n2)cc1]

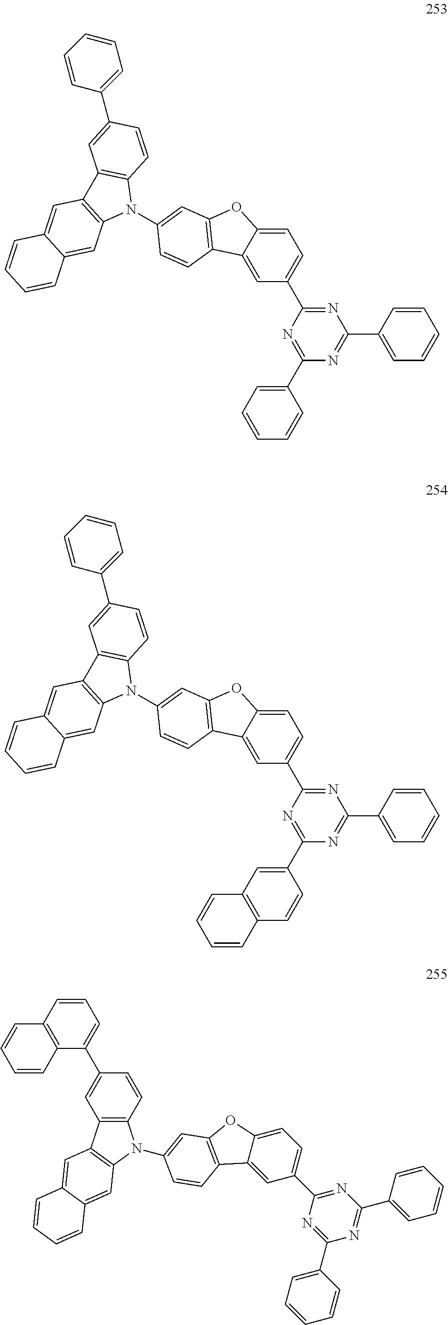 [SMILES: c1ccc(-c2ccc3c(c2)c2cc4ccccc4cc2n3-c2ccc3c(c2)oc2ccc(-c4nc(-c5ccccc5)nc(-c5ccccc5)n4)cc23)cc1 ; c1ccc(-c2ccc3c(c2)c2cc4ccccc4cc2n3-c2ccc3c(c2)oc2ccc(-c4nc(-c5ccccc5)nc(-c5ccc6ccccc6c5)n4)cc23)cc1 ; c1ccc(-c2nc(-c3ccccc3)nc(-c3ccc4oc5cc(-n6c7ccc(-c8cccc9ccccc89)cc7c7cc8ccccc8cc76)ccc5c4c3)n2)cc1]

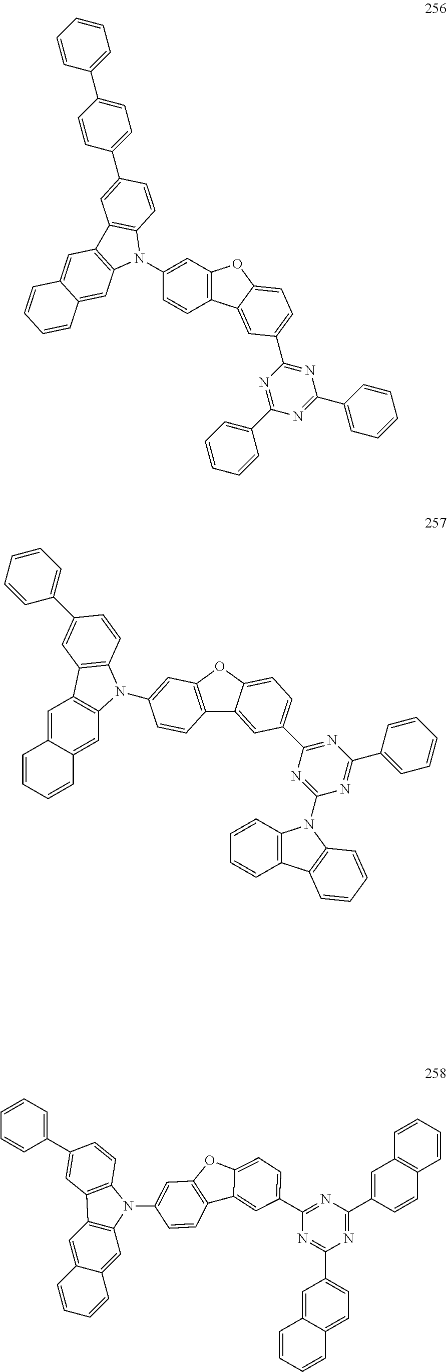 [SMILES: c1ccc(-c2ccc(-c3ccc4c(c3)c3cc5ccccc5cc3n4-c3ccc4c(c3)oc3ccc(-c5nc(-c6ccccc6)nc(-c6ccccc6)n5)cc34)cc2)cc1 ; c1ccc(-c2ccc3c(c2)c2cc4ccccc4cc2n3-c2ccc3c(c2)oc2ccc(-c4nc(-c5ccccc5)nc(-n5c6ccccc6c6ccccc65)n4)cc23)cc1 ; c1ccc(-c2ccc3c(c2)c2cc4ccccc4cc2n3-c2ccc3c(c2)oc2ccc(-c4nc(-c5ccc6ccccc6c5)nc(-c5ccc6ccccc6c5)n4)cc23)cc1]

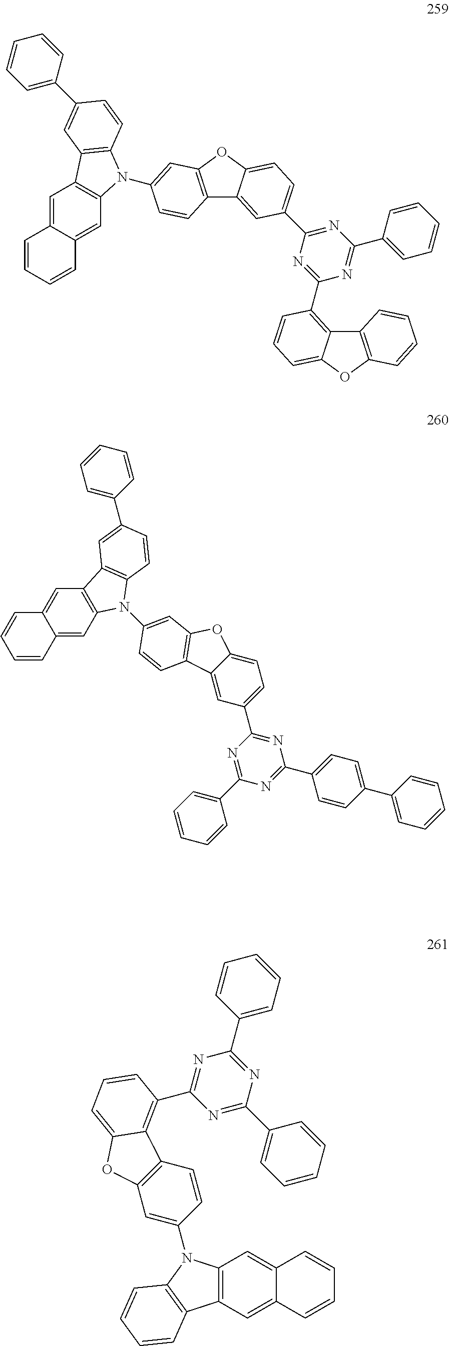 [SMILES: c1ccc(-c2ccc3c(c2)c2cc4ccccc4cc2n3-c2ccc3c(c2)oc2ccc(-c4nc(-c5ccccc5)nc(-c5cccc6oc7ccccc7c56)n4)cc23)cc1 ; c1ccc(-c2ccc(-c3nc(-c4ccccc4)nc(-c4ccc5oc6cc(-n7c8ccc(-c9ccccc9)cc8c8cc9ccccc9cc87)ccc6c5c4)n3)cc2)cc1 ; c1ccc(-c2nc(-c3ccccc3)nc(-c3cccc4oc5cc(-n6c7ccccc7c7cc8ccccc8cc76)ccc5c34)n2)cc1]

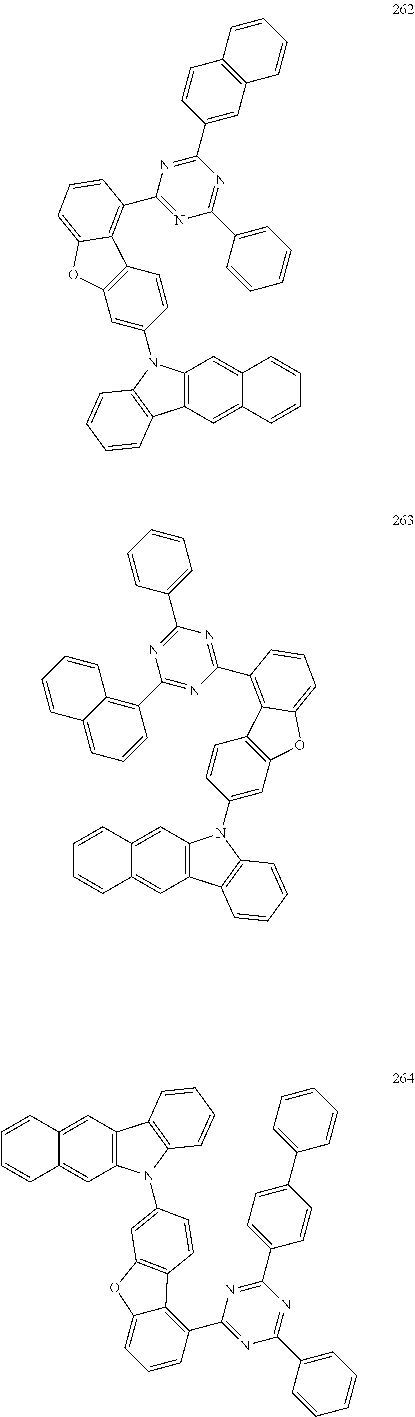 [SMILES: c1ccc(-c2nc(-c3ccc4ccccc4c3)nc(-c3cccc4oc5cc(-n6c7ccccc7c7cc8ccccc8cc76)ccc5c34)n2)cc1 ; c1ccc(-c2nc(-c3cccc4ccccc34)nc(-c3cccc4oc5cc(-n6c7ccccc7c7cc8ccccc8cc76)ccc5c34)n2)cc1 ; c1ccc(-c2ccc(-c3nc(-c4ccccc4)nc(-c4cccc5oc6cc(-n7c8ccccc8c8cc9ccccc9cc87)ccc6c45)n3)cc2)cc1]

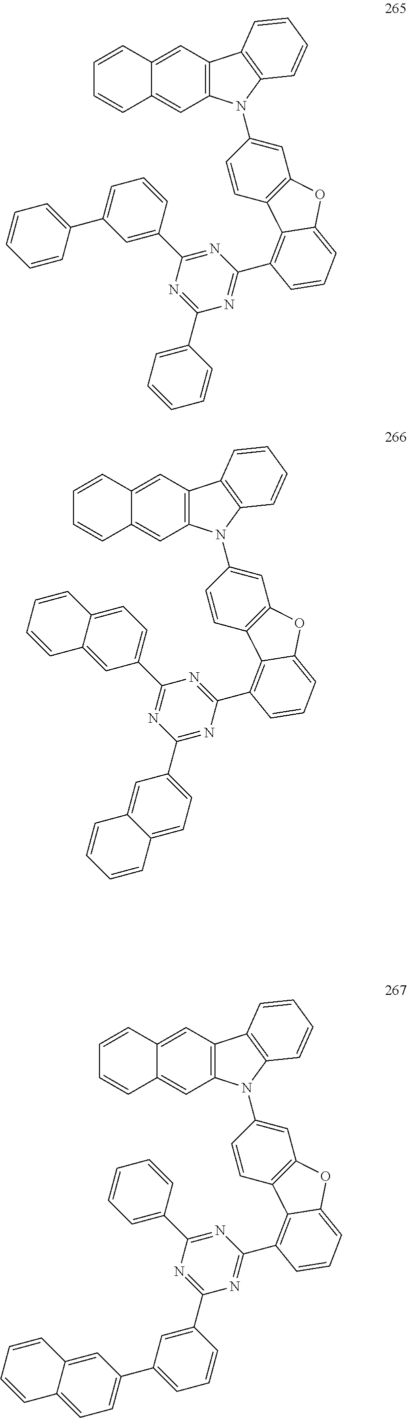 [SMILES: c1ccc(-c2cccc(-c3nc(-c4ccccc4)nc(-c4cccc5oc6cc(-n7c8ccccc8c8cc9ccccc9cc87)ccc6c45)n3)c2)cc1 ; c1ccc2cc(-c3nc(-c4ccc5ccccc5c4)nc(-c4cccc5oc6cc(-n7c8ccccc8c8cc9ccccc9cc87)ccc6c45)n3)ccc2c1 ; c1ccc(-c2nc(-c3cccc(-c4ccc5ccccc5c4)c3)nc(-c3cccc4oc5cc(-n6c7ccccc7c7cc8ccccc8cc76)ccc5c34)n2)cc1]

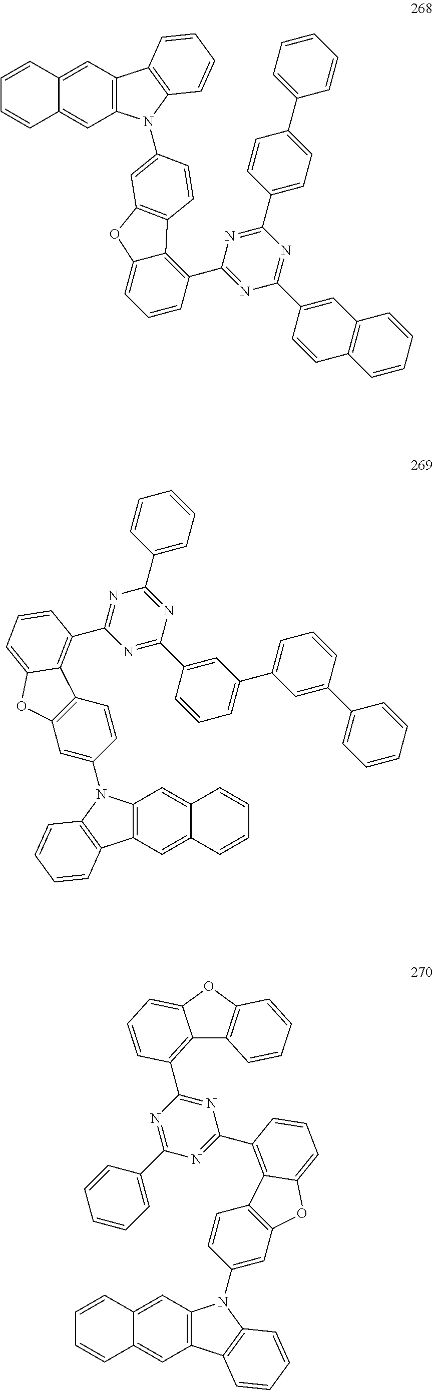 [SMILES: c1ccc(-c2ccc(-c3nc(-c4ccc5ccccc5c4)nc(-c4cccc5oc6cc(-n7c8ccccc8c8cc9ccccc9cc87)ccc6c45)n3)cc2)cc1 ; c1ccc(-c2cccc(-c3cccc(-c4nc(-c5ccccc5)nc(-c5cccc6oc7cc(-n8c9ccccc9c9cc%10ccccc%10cc98)ccc7c56)n4)c3)c2)cc1 ; c1ccc(-c2nc(-c3cccc4oc5ccccc5c34)nc(-c3cccc4oc5cc(-n6c7ccccc7c7cc8ccccc8cc76)ccc5c34)n2)cc1]

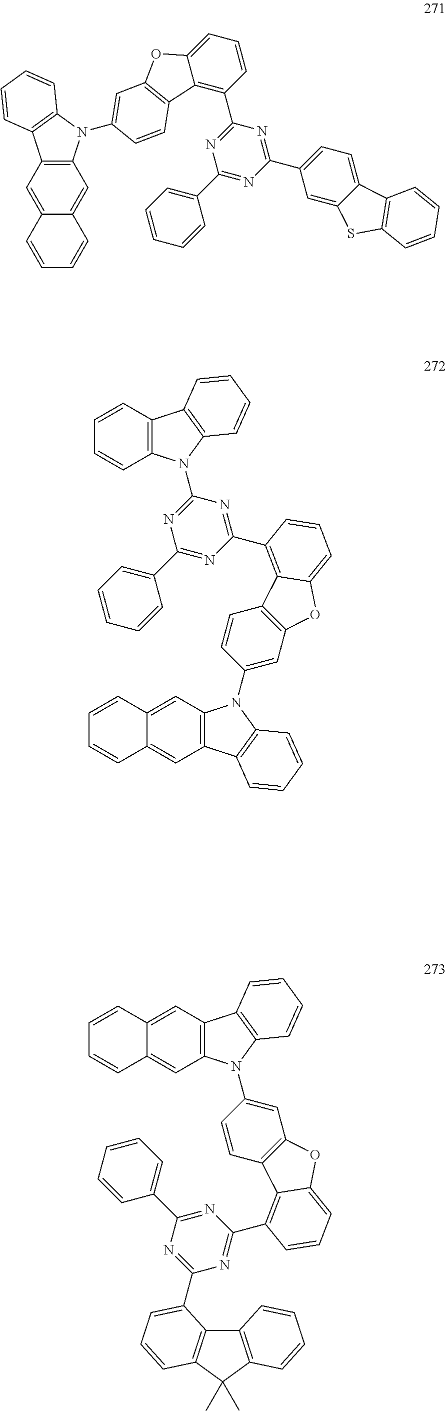 [SMILES: c1ccc(-c2nc(-c3ccc4c(c3)sc3ccccc34)nc(-c3cccc4oc5cc(-n6c7ccccc7c7cc8ccccc8cc76)ccc5c34)n2)cc1 ; c1ccc(-c2nc(-c3cccc4oc5cc(-n6c7ccccc7c7cc8ccccc8cc76)ccc5c34)nc(-n3c4ccccc4c4ccccc43)n2)cc1 ; CC1(C)c2ccccc2-c2c(-c3nc(-c4ccccc4)nc(-c4cccc5oc6cc(-n7c8ccccc8c8cc9ccccc9cc87)ccc6c45)n3)cccc21]

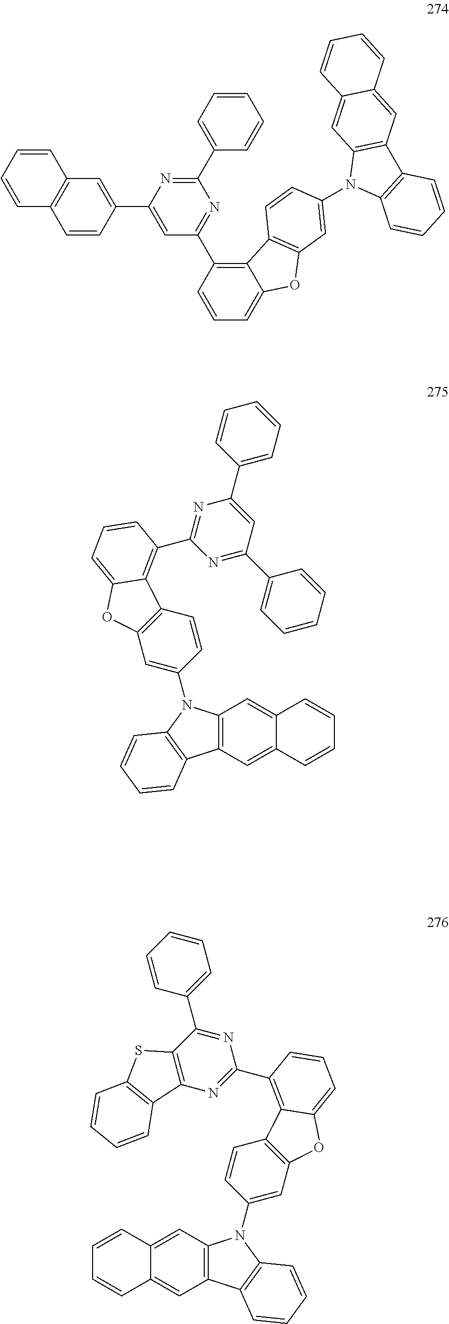 [SMILES: c1ccc(-c2nc(-c3ccc4ccccc4c3)cc(-c3cccc4oc5cc(-n6c7ccccc7c7cc8ccccc8cc76)ccc5c34)n2)cc1 ; c1ccc(-c2cc(-c3ccccc3)nc(-c3cccc4oc5cc(-n6c7ccccc7c7cc8ccccc8cc76)ccc5c34)n2)cc1 ; c1ccc(-c2nc(-c3cccc4oc5cc(-n6c7ccccc7c7cc8ccccc8cc76)ccc5c34)nc3c2sc2ccccc23)cc1]

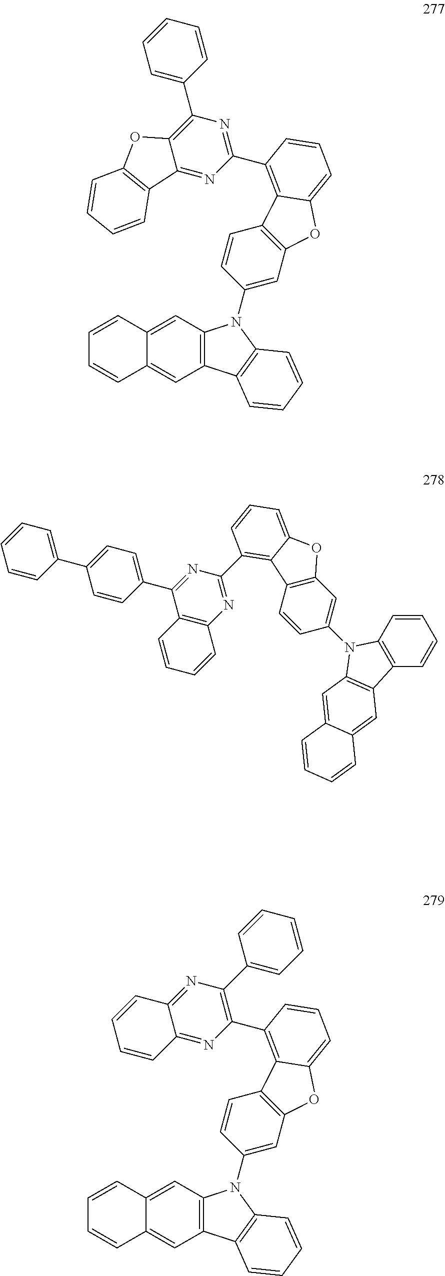 [SMILES: c1ccc(-c2nc(-c3cccc4oc5cc(-n6c7ccccc7c7cc8ccccc8cc76)ccc5c34)nc3c2oc2ccccc23)cc1 ; c1ccc(-c2ccc(-c3nc(-c4cccc5oc6cc(-n7c8ccccc8c8cc9ccccc9cc87)ccc6c45)nc4ccccc34)cc2)cc1 ; c1ccc(-c2nc3ccccc3nc2-c2cccc3oc4cc(-n5c6ccccc6c6cc7ccccc7cc65)ccc4c23)cc1]

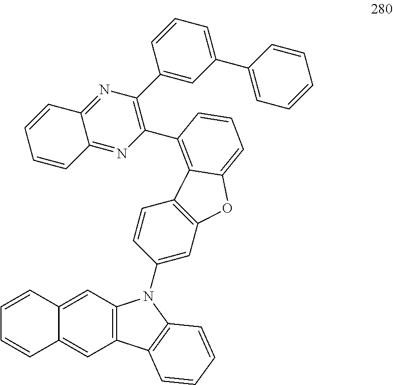 [SMILES: c1ccc(-c2cccc(-c3nc4ccccc4nc3-c3cccc4oc5cc(-n6c7ccccc7c7cc8ccccc8cc76)ccc5c34)c2)cc1]

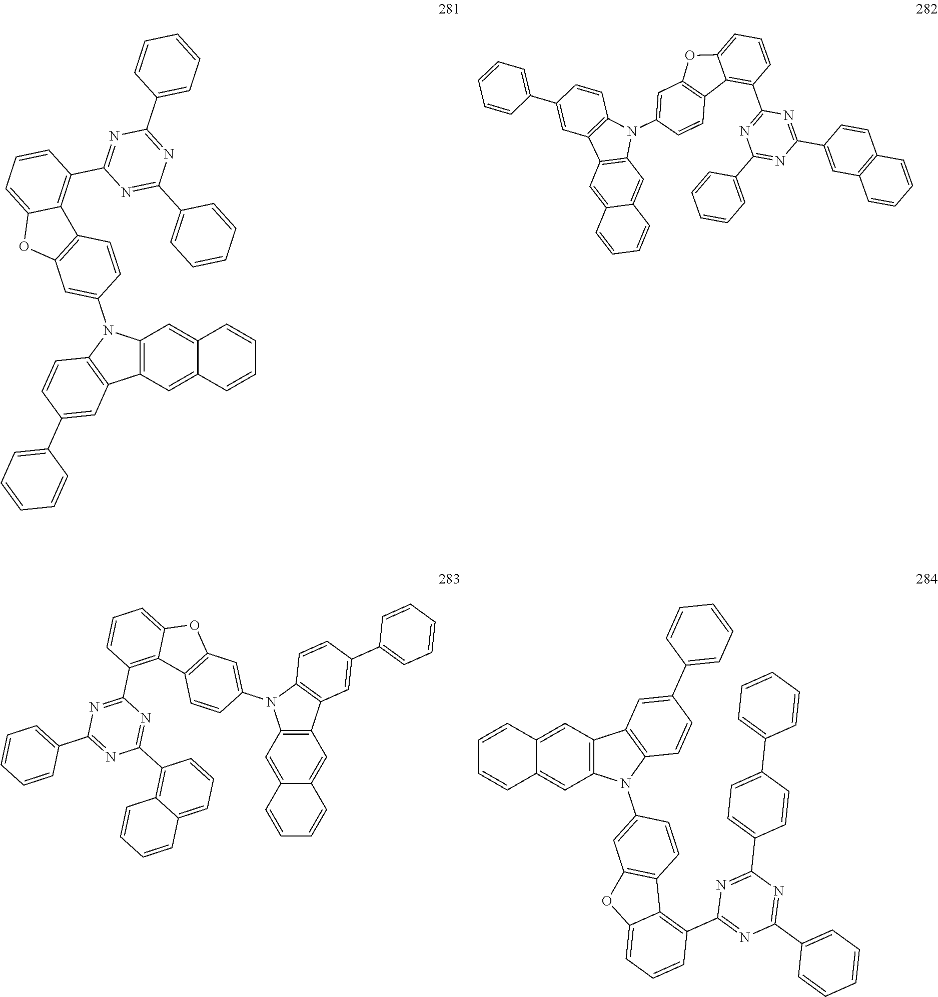 [SMILES: c1ccc(-c2ccc3c(c2)c2cc4ccccc4cc2n3-c2ccc3c(c2)oc2cccc(-c4nc(-c5ccccc5)nc(-c5ccccc5)n4)c23)cc1 ; c1ccc(-c2ccc3c(c2)c2cc4ccccc4cc2n3-c2ccc3c(c2)oc2cccc(-c4nc(-c5ccccc5)nc(-c5ccc6ccccc6c5)n4)c23)cc1 ; c1ccc(-c2ccc3c(c2)c2cc4ccccc4cc2n3-c2ccc3c(c2)oc2cccc(-c4nc(-c5ccccc5)nc(-c5cccc6ccccc56)n4)c23)cc1 ; c1ccc(-c2ccc(-c3nc(-c4ccccc4)nc(-c4cccc5oc6cc(-n7c8ccc(-c9ccccc9)cc8c8cc9ccccc9cc87)ccc6c45)n3)cc2)cc1]

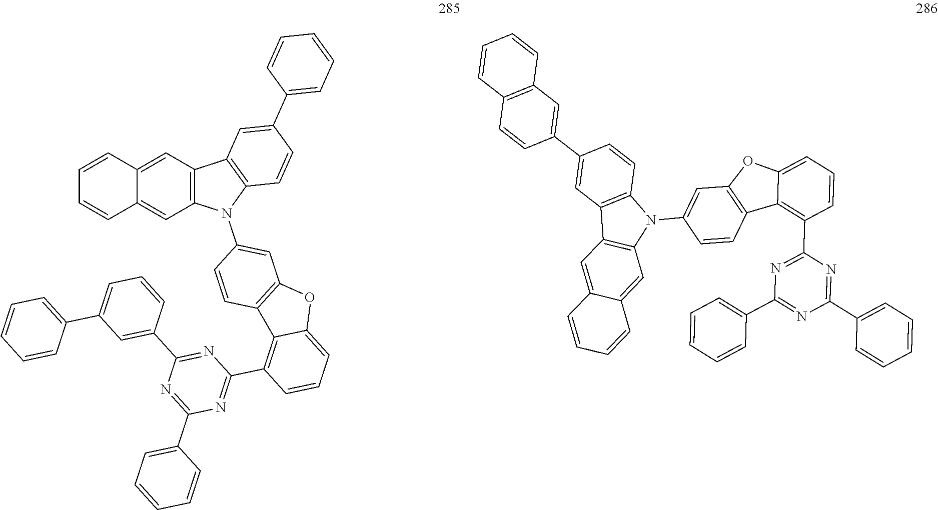 [SMILES: c1ccc(-c2cccc(-c3nc(-c4ccccc4)nc(-c4cccc5oc6cc(-n7c8ccc(-c9ccccc9)cc8c8cc9ccccc9cc87)ccc6c45)n3)c2)cc1 ; c1ccc(-c2nc(-c3ccccc3)nc(-c3cccc4oc5cc(-n6c7ccc(-c8ccc9ccccc9c8)cc7c7cc8ccccc8cc76)ccc5c34)n2)cc1]

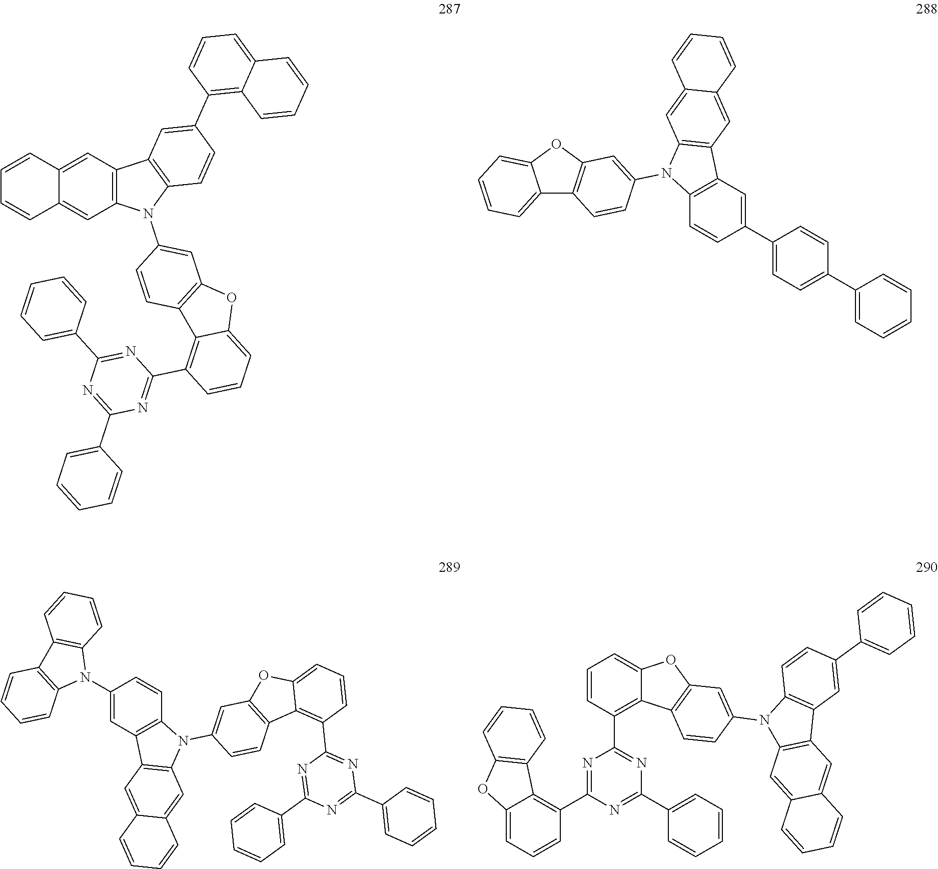 [SMILES: c1ccc(-c2nc(-c3ccccc3)nc(-c3cccc4oc5cc(-n6c7ccc(-c8cccc9ccccc89)cc7c7cc8ccccc8cc76)ccc5c34)n2)cc1 ; c1ccc(-c2ccc(-c3ccc4c(c3)c3cc5ccccc5cc3n4-c3ccc4c(c3)oc3ccccc34)cc2)cc1 ; c1ccc(-c2nc(-c3ccccc3)nc(-c3cccc4oc5cc(-n6c7ccc(-n8c9ccccc9c9ccccc98)cc7c7cc8ccccc8cc76)ccc5c34)n2)cc1 ; c1ccc(-c2ccc3c(c2)c2cc4ccccc4cc2n3-c2ccc3c(c2)oc2cccc(-c4nc(-c5ccccc5)nc(-c5cccc6oc7ccccc7c56)n4)c23)cc1]

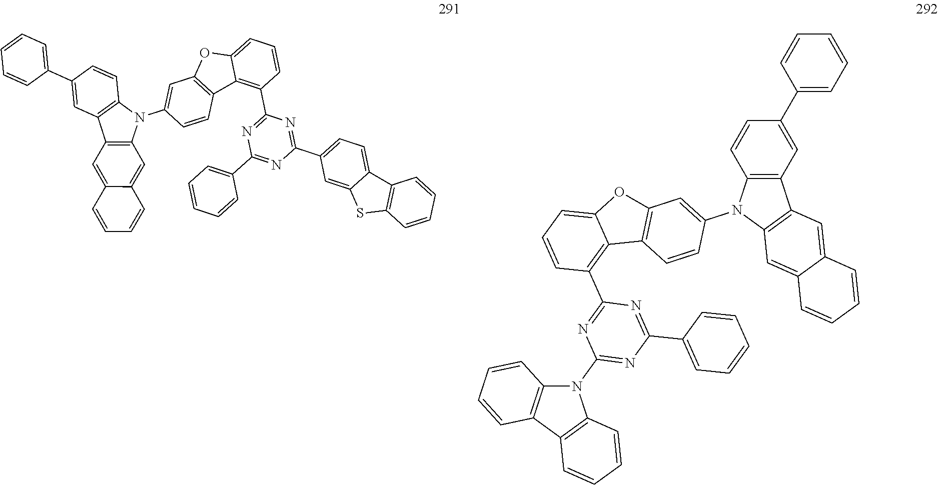 [SMILES: c1ccc(-c2ccc3c(c2)c2cc4ccccc4cc2n3-c2ccc3c(c2)oc2cccc(-c4nc(-c5ccccc5)nc(-c5ccc6c(c5)sc5ccccc56)n4)c23)cc1 ; c1ccc(-c2ccc3c(c2)c2cc4ccccc4cc2n3-c2ccc3c(c2)oc2cccc(-c4nc(-c5ccccc5)nc(-n5c6ccccc6c6ccccc65)n4)c23)cc1]

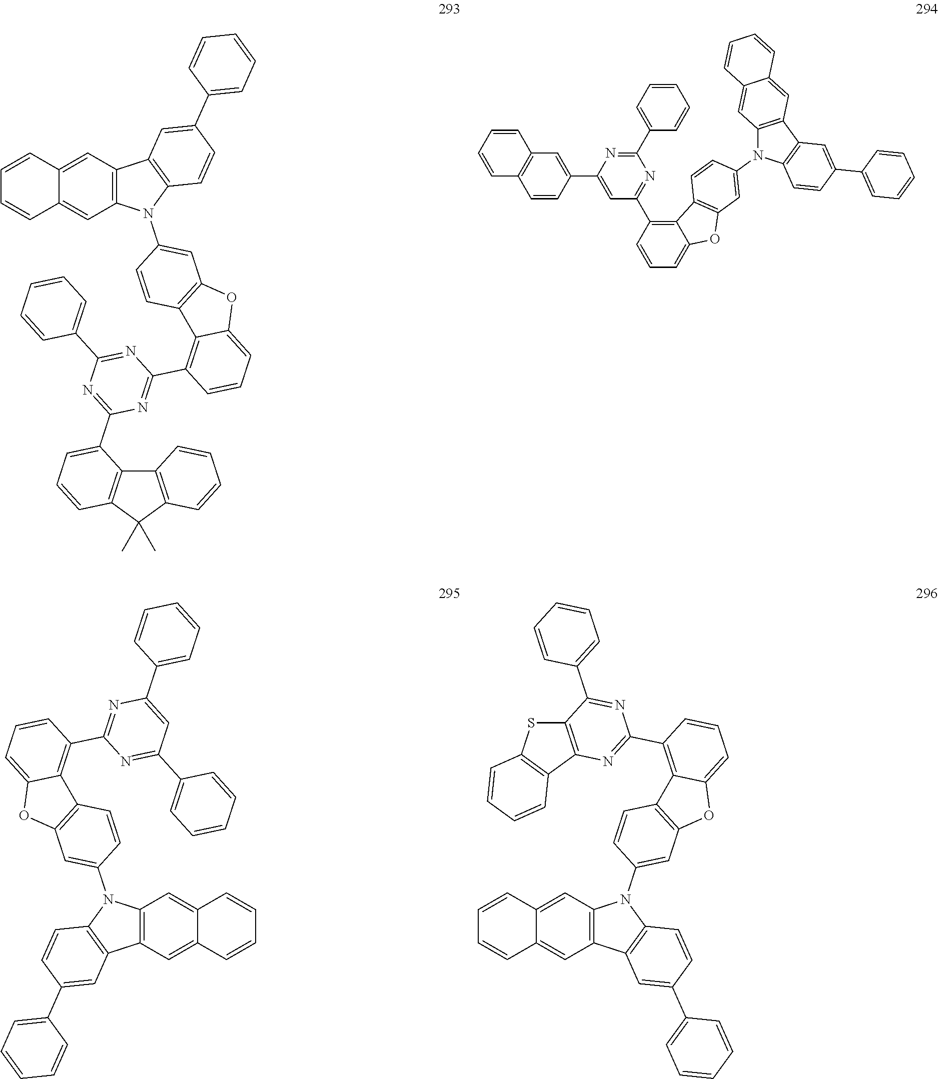 [SMILES: CC1(C)c2ccccc2-c2c(-c3nc(-c4ccccc4)nc(-c4cccc5oc6cc(-n7c8ccc(-c9ccccc9)cc8c8cc9ccccc9cc87)ccc6c45)n3)cccc21 ; c1ccc(-c2ccc3c(c2)c2cc4ccccc4cc2n3-c2ccc3c(c2)oc2cccc(-c4cc(-c5ccc6ccccc6c5)nc(-c5ccccc5)n4)c23)cc1 ; c1ccc(-c2ccc3c(c2)c2cc4ccccc4cc2n3-c2ccc3c(c2)oc2cccc(-c4nc(-c5ccccc5)cc(-c5ccccc5)n4)c23)cc1 ; c1ccc(-c2ccc3c(c2)c2cc4ccccc4cc2n3-c2ccc3c(c2)oc2cccc(-c4nc(-c5ccccc5)c5sc6ccccc6c5n4)c23)cc1]

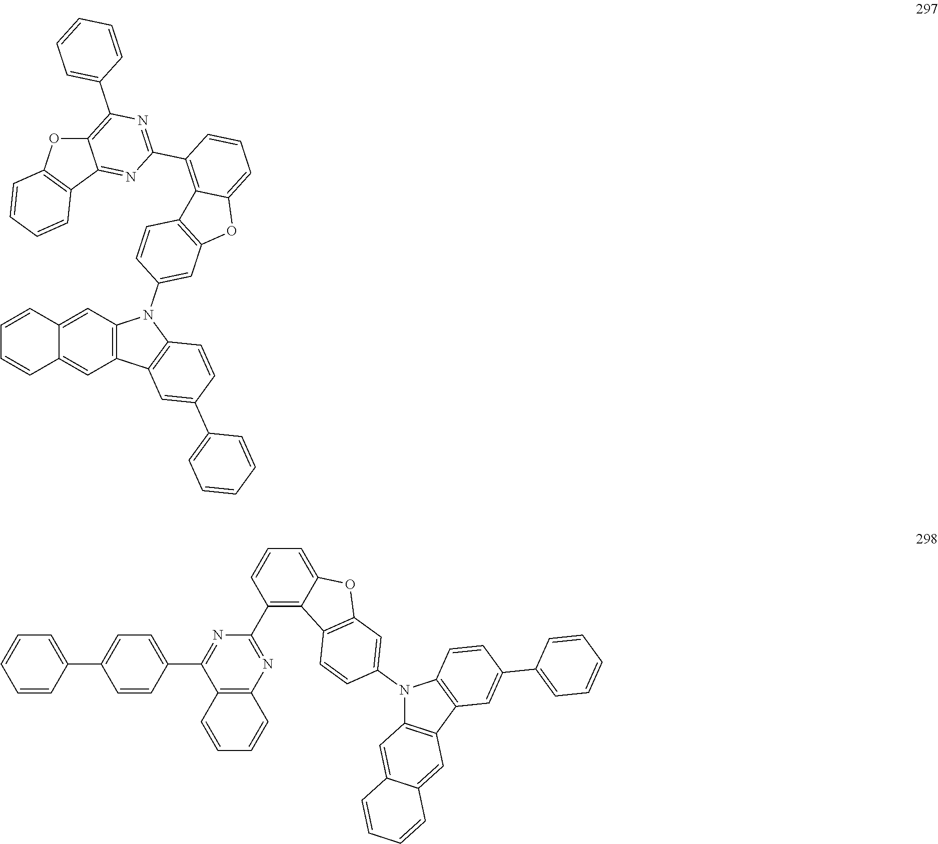 [SMILES: c1ccc(-c2ccc3c(c2)c2cc4ccccc4cc2n3-c2ccc3c(c2)oc2cccc(-c4nc(-c5ccccc5)c5oc6ccccc6c5n4)c23)cc1 ; c1ccc(-c2ccc(-c3nc(-c4cccc5oc6cc(-n7c8ccc(-c9ccccc9)cc8c8cc9ccccc9cc87)ccc6c45)nc4ccccc34)cc2)cc1]

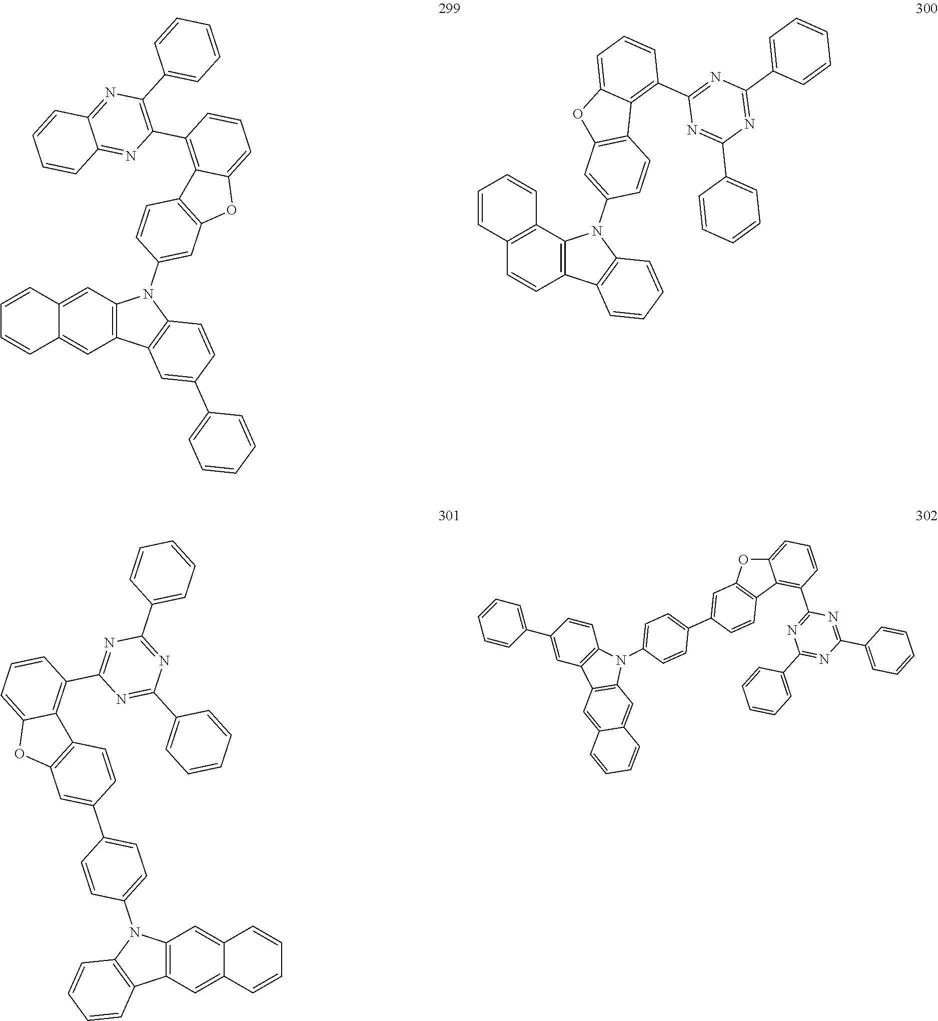 [SMILES: c1ccc(-c2ccc3c(c2)c2cc4ccccc4cc2n3-c2ccc3c(c2)oc2cccc(-c4nc5ccccc5nc4-c4ccccc4)c23)cc1 ; c1ccc(-c2nc(-c3ccccc3)nc(-c3cccc4oc5cc(-n6c7ccccc7c7ccc8ccccc8c76)ccc5c34)n2)cc1 ; c1ccc(-c2nc(-c3ccccc3)nc(-c3cccc4oc5cc(-c6ccc(-n7c8ccccc8c8cc9ccccc9cc87)cc6)ccc5c34)n2)cc1 ; c1ccc(-c2ccc3c(c2)c2cc4ccccc4cc2n3-c2ccc(-c3ccc4c(c3)oc3cccc(-c5nc(-c6ccccc6)nc(-c6ccccc6)n5)c34)cc2)cc1]

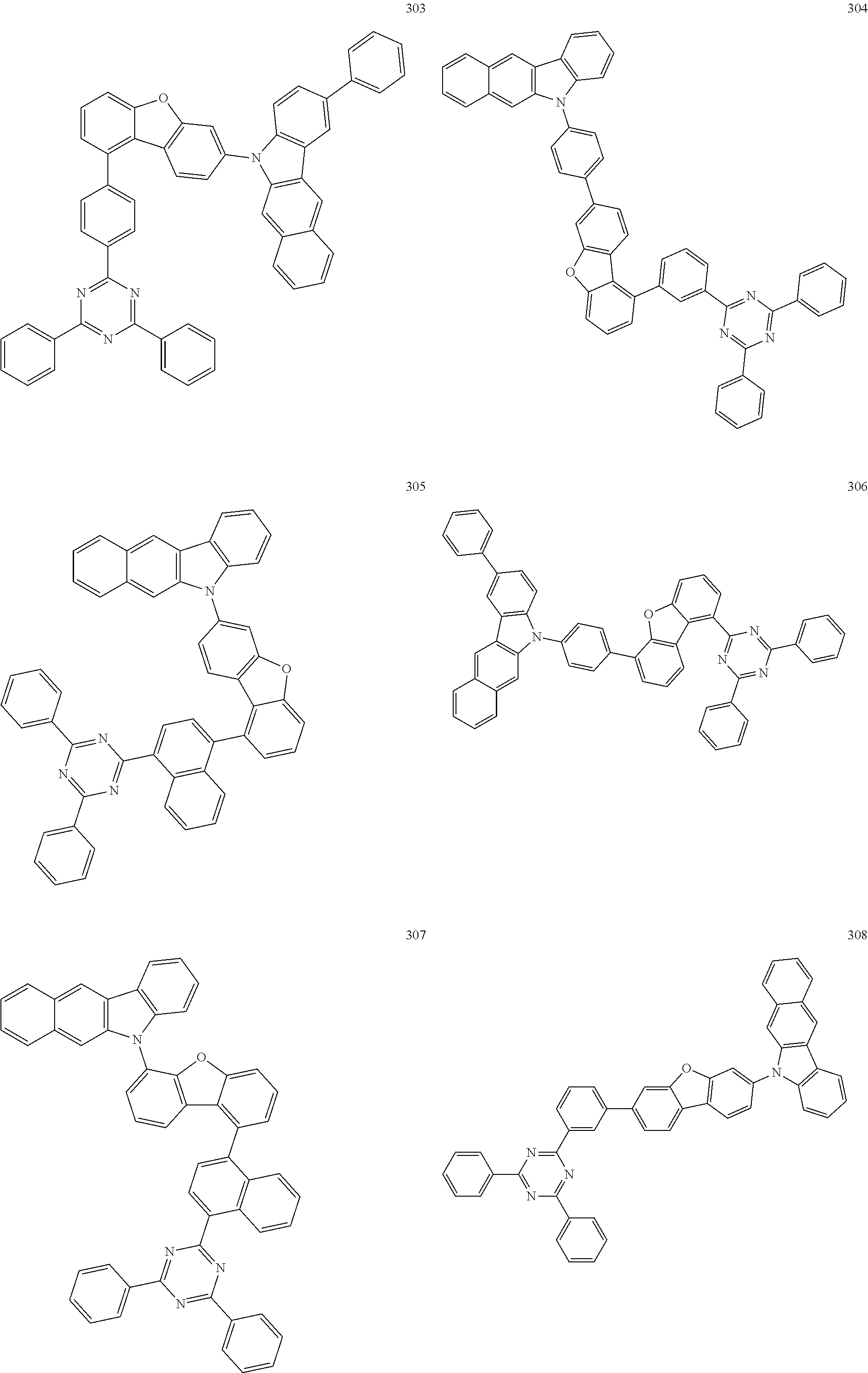

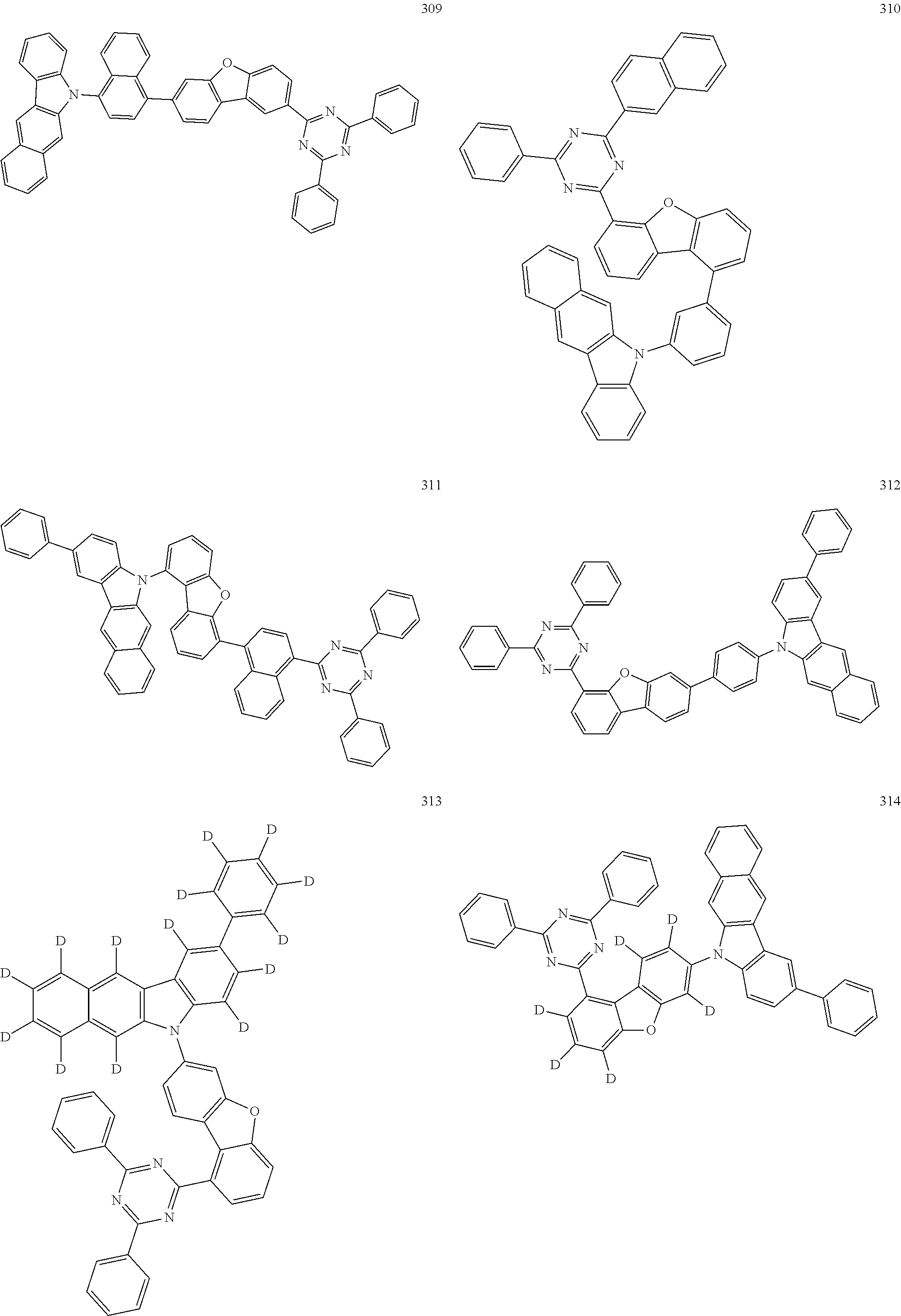

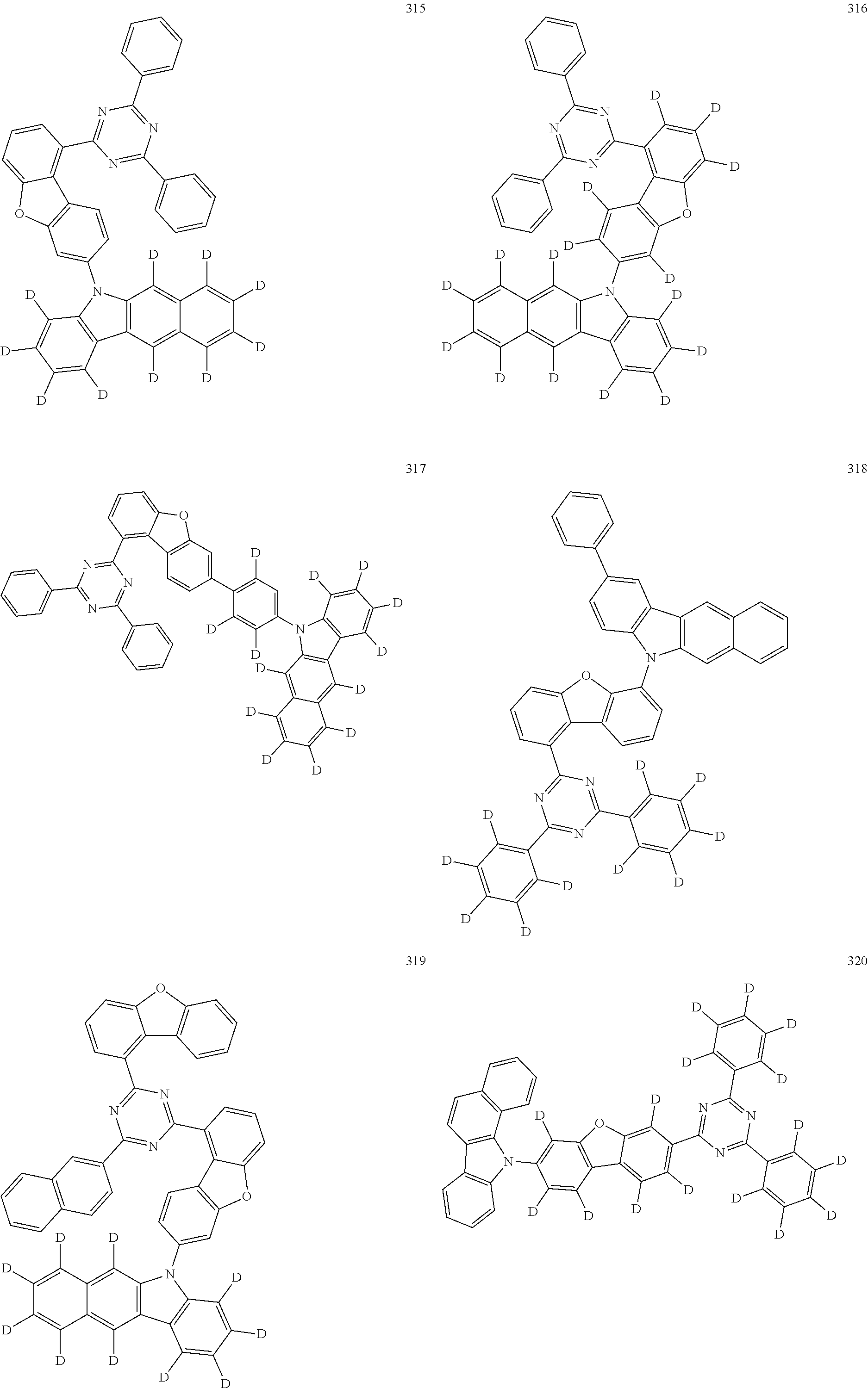

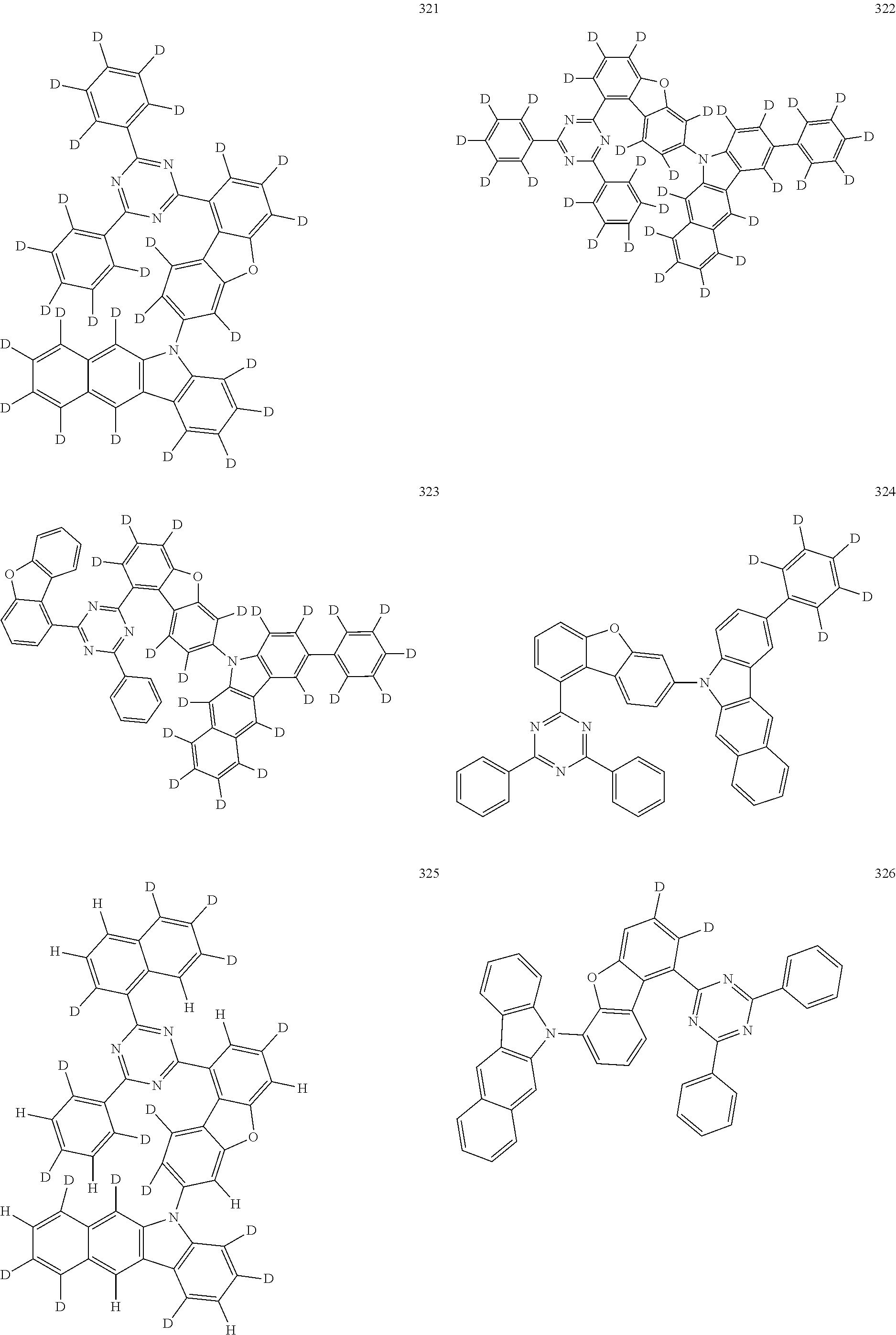

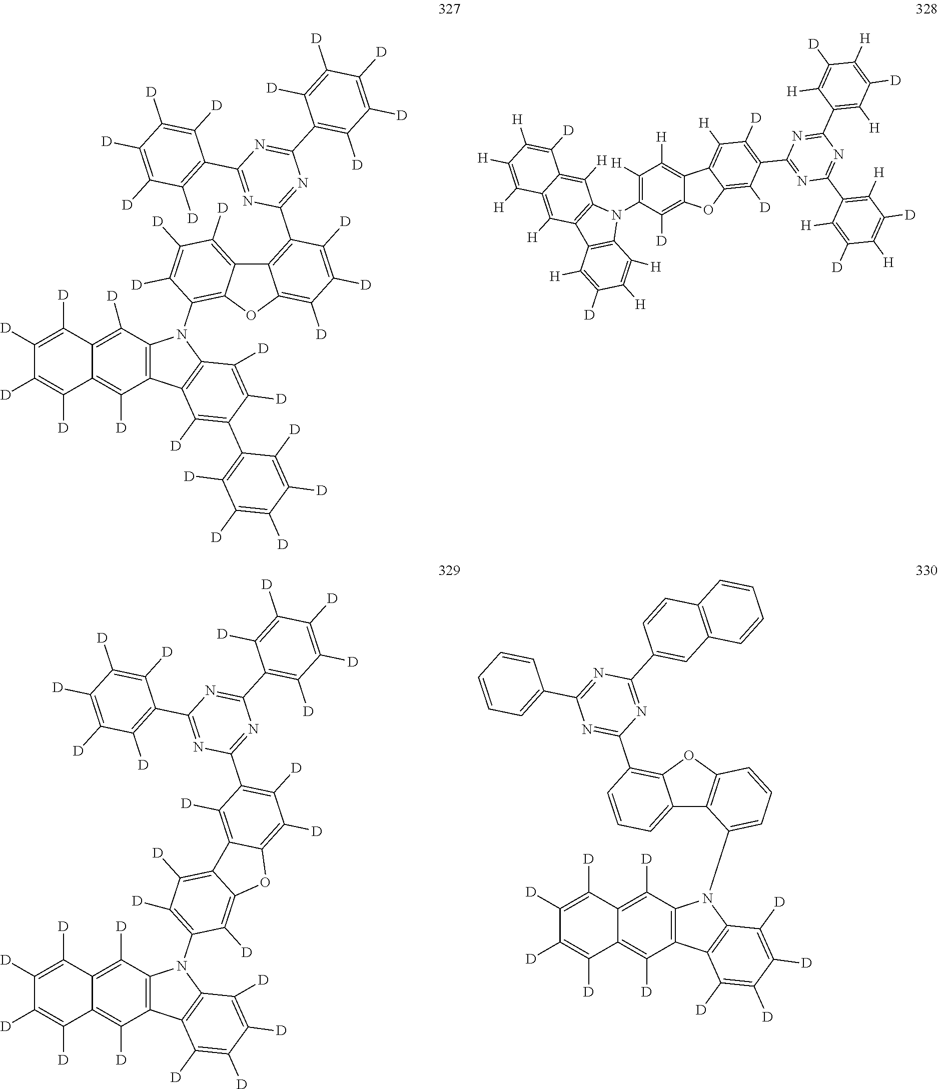

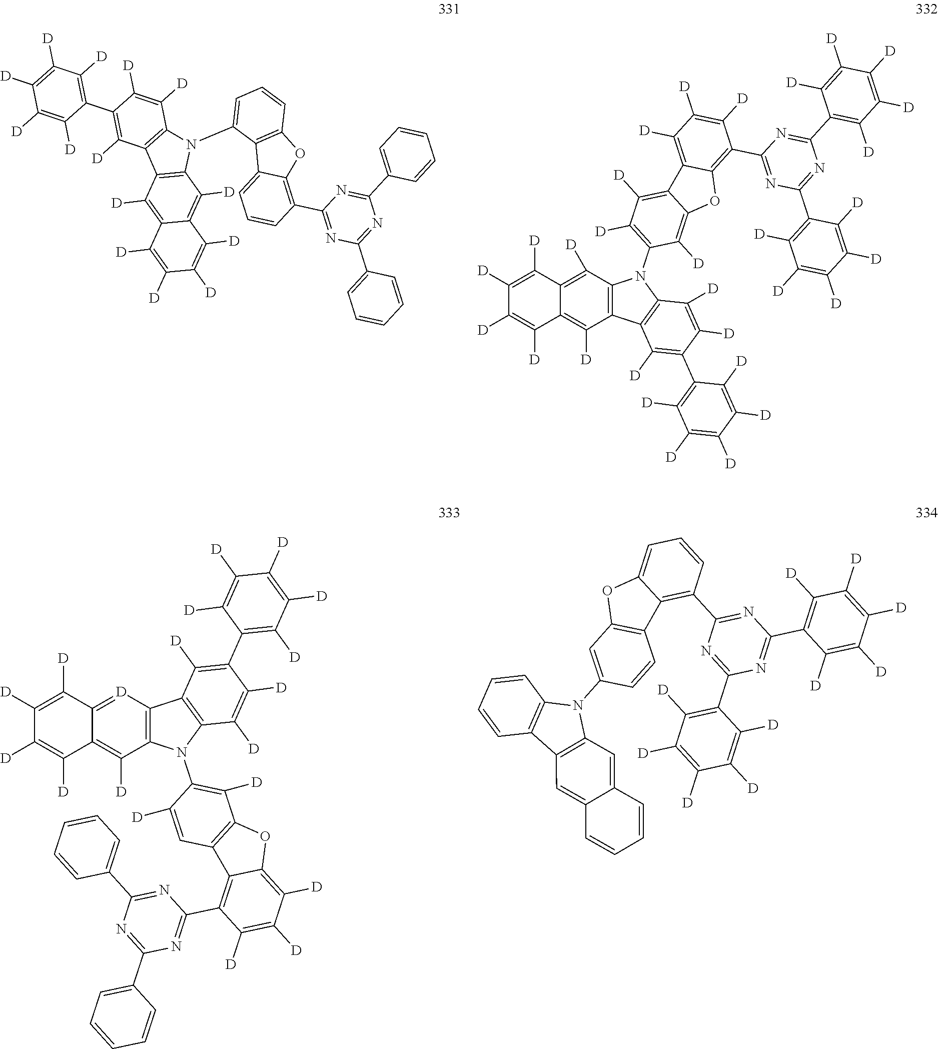

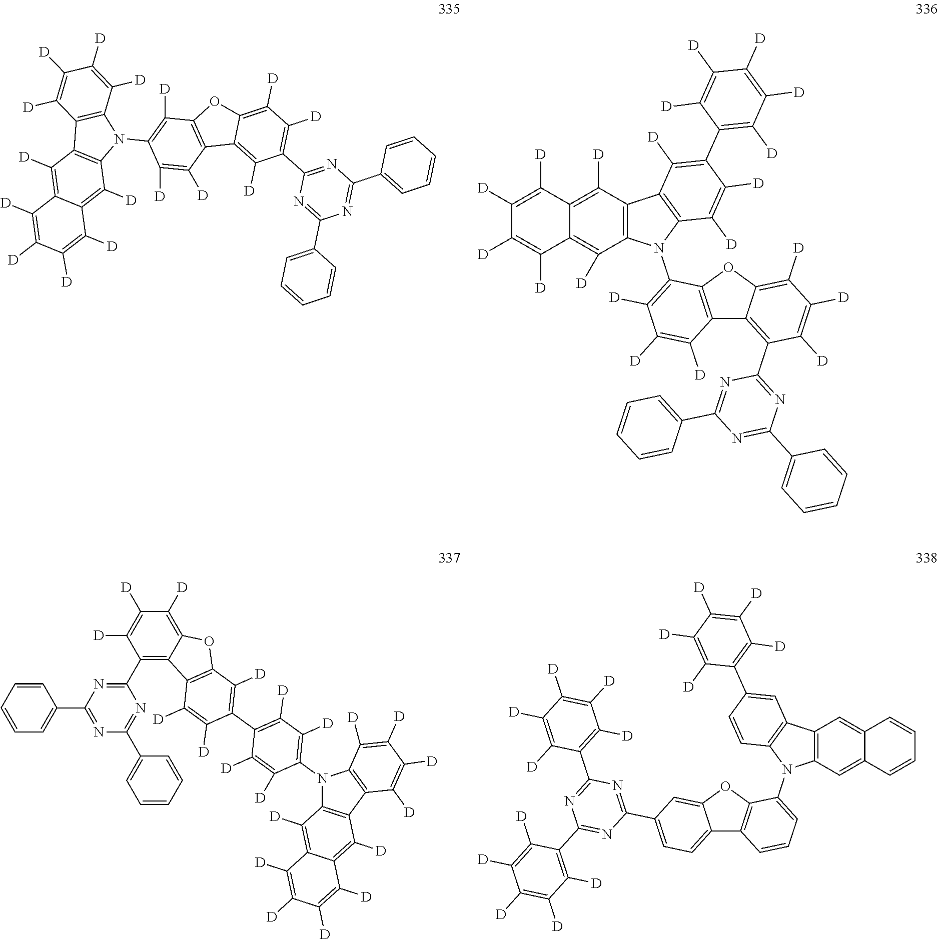

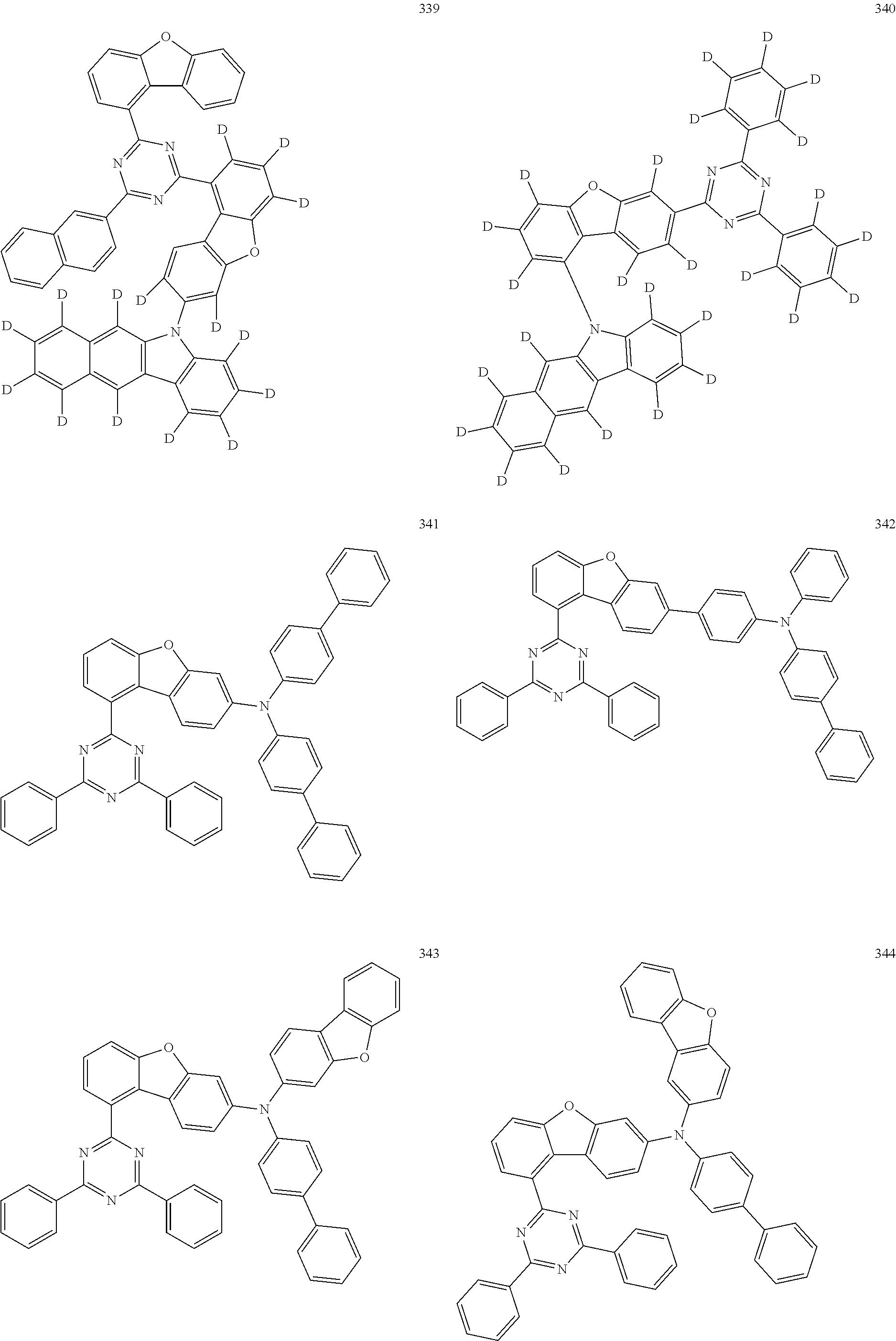

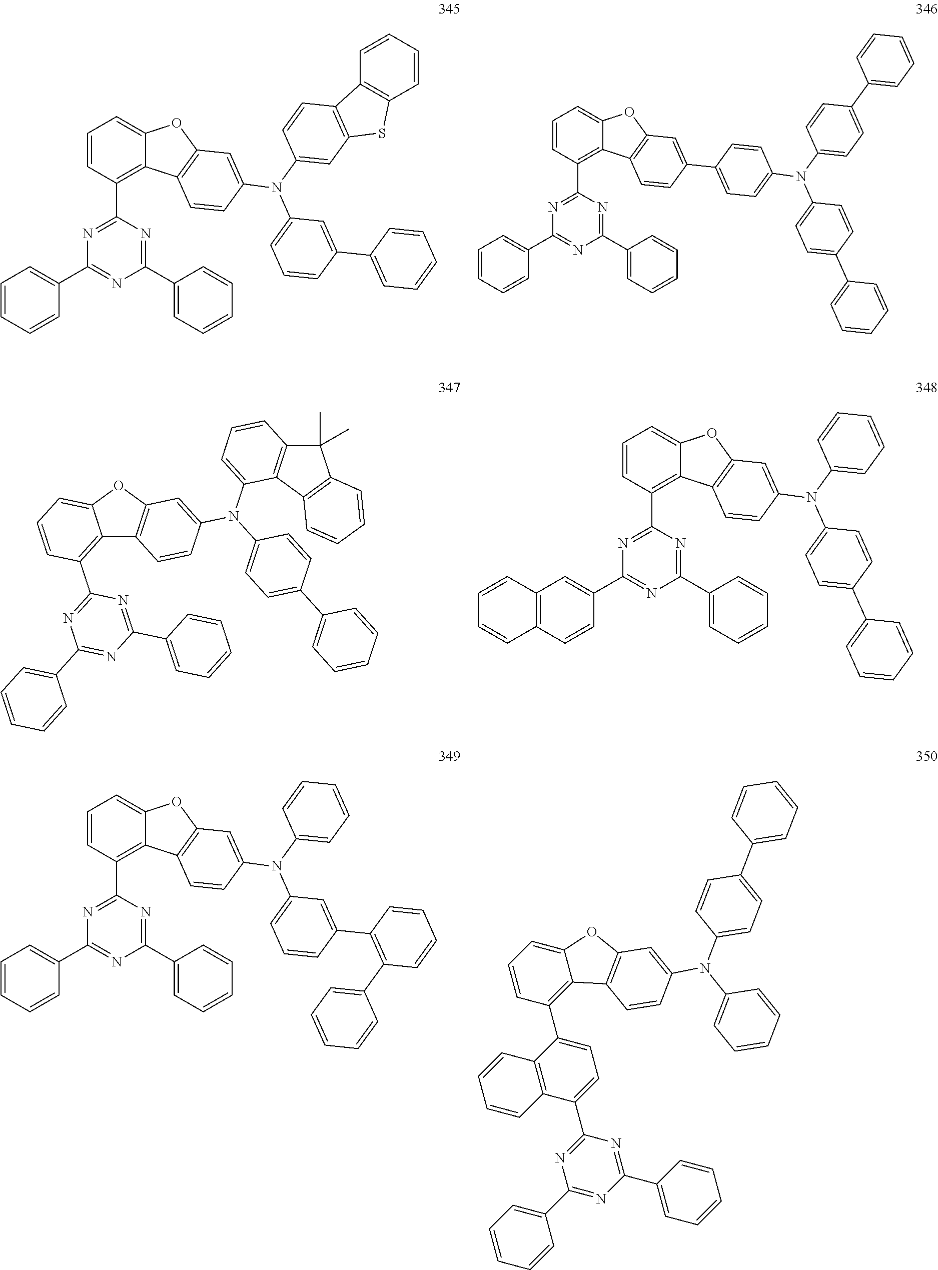

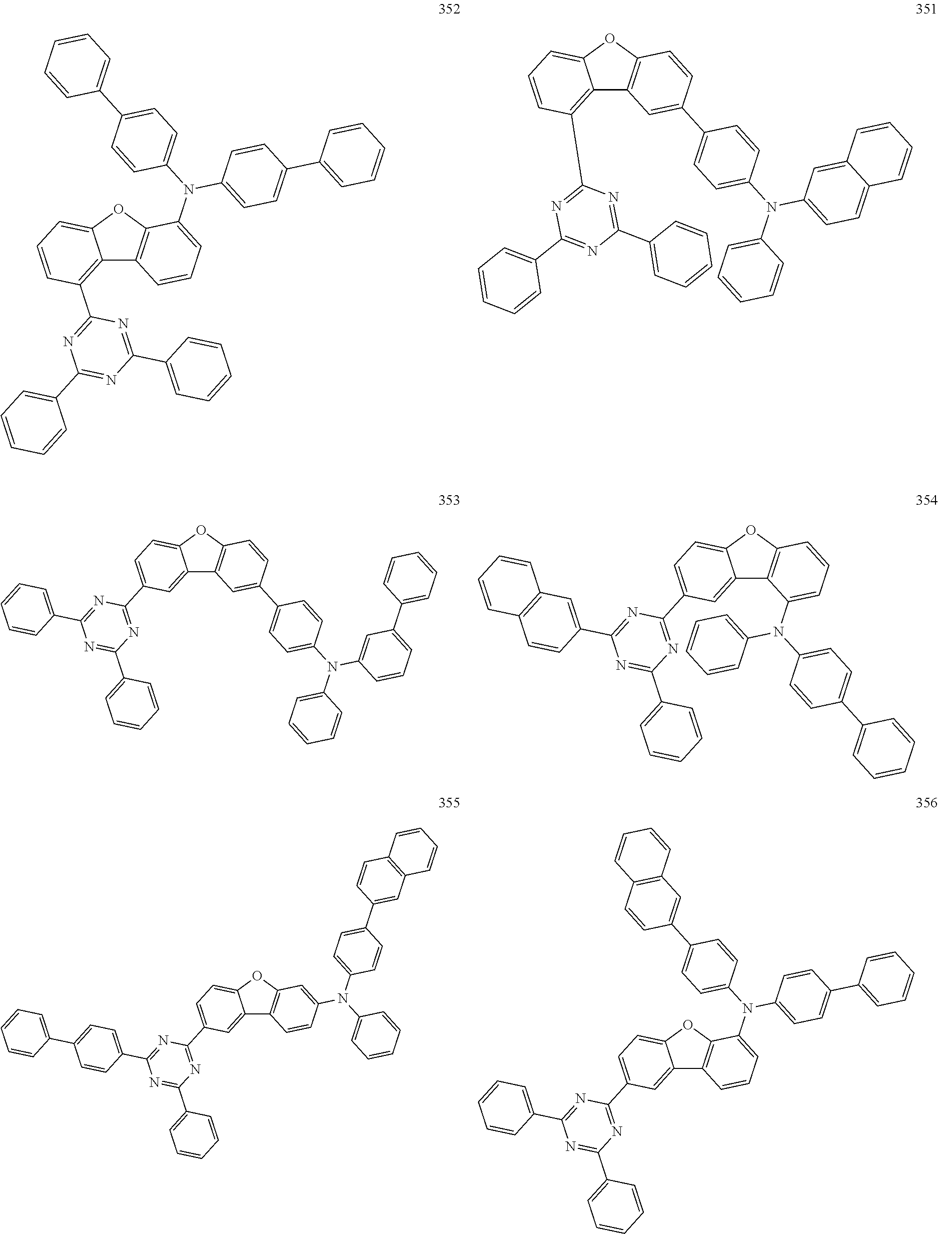

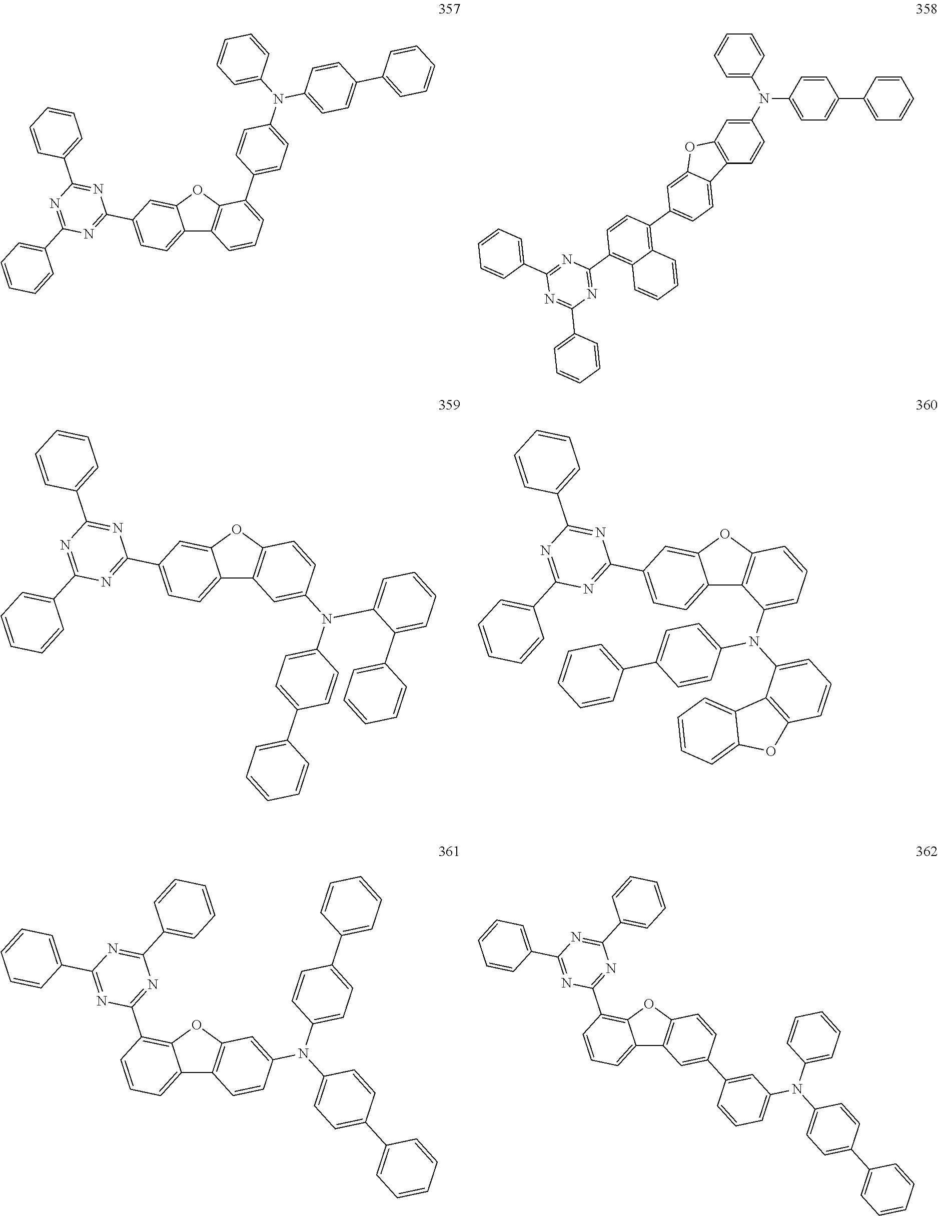

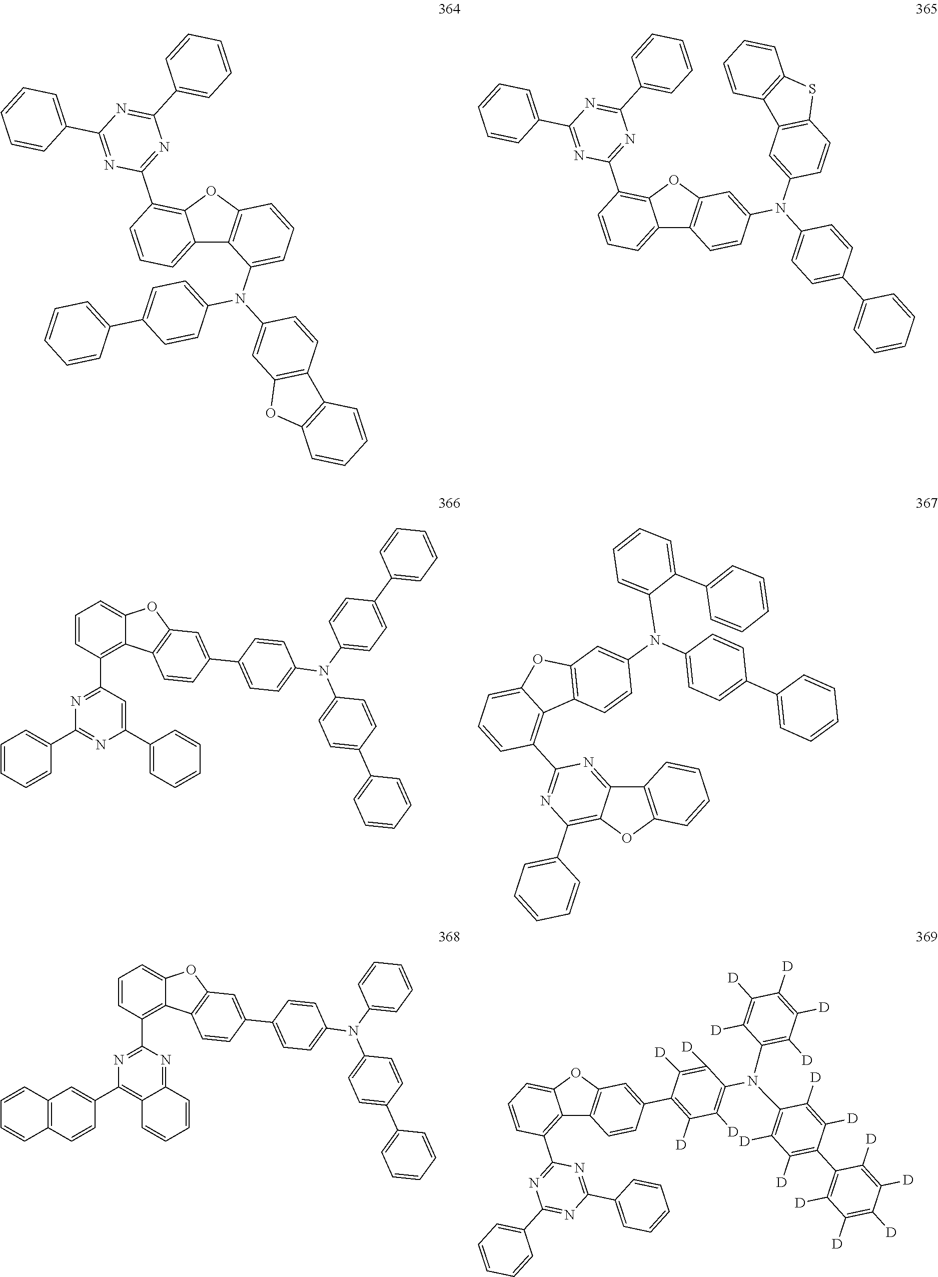

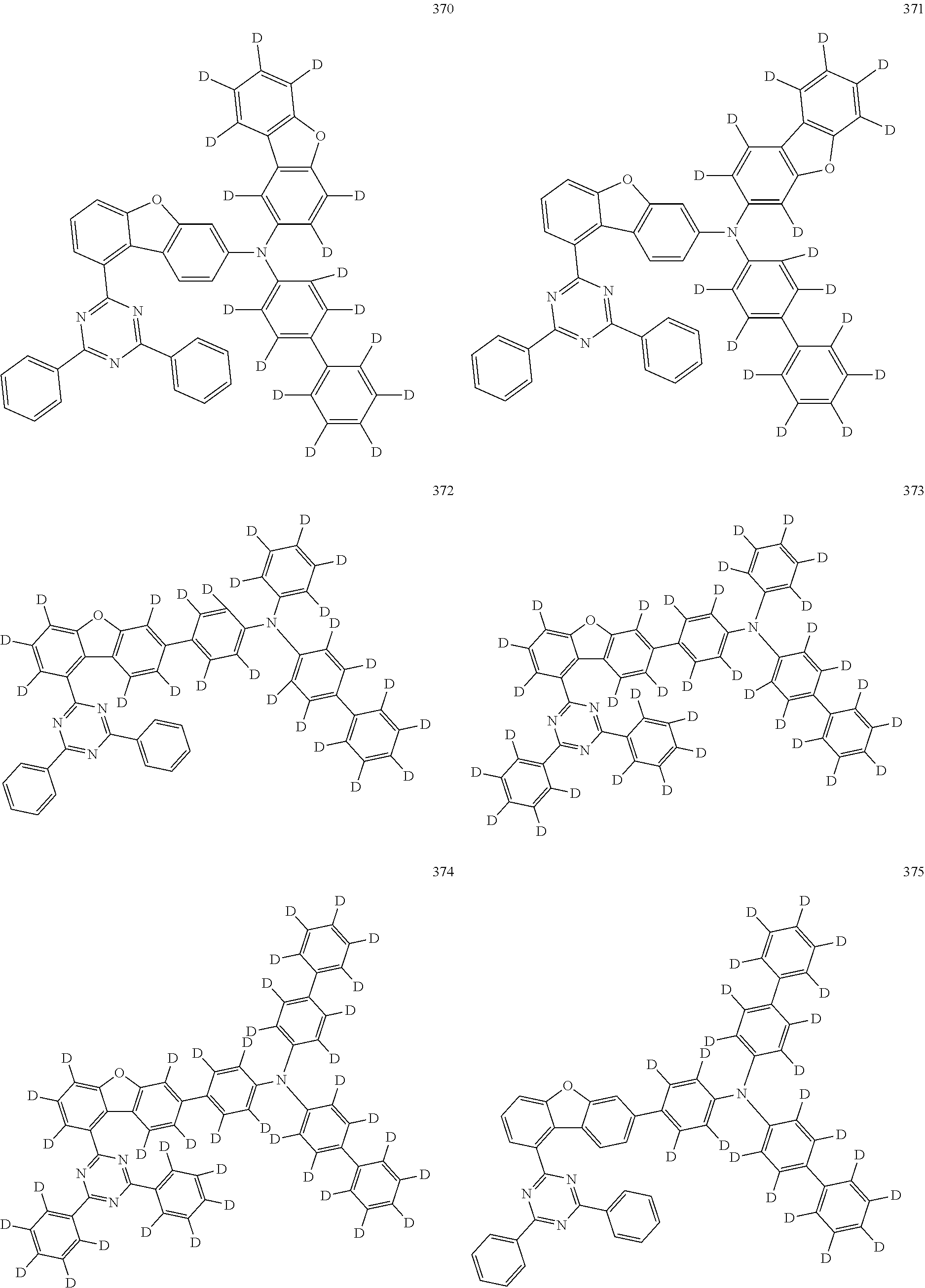

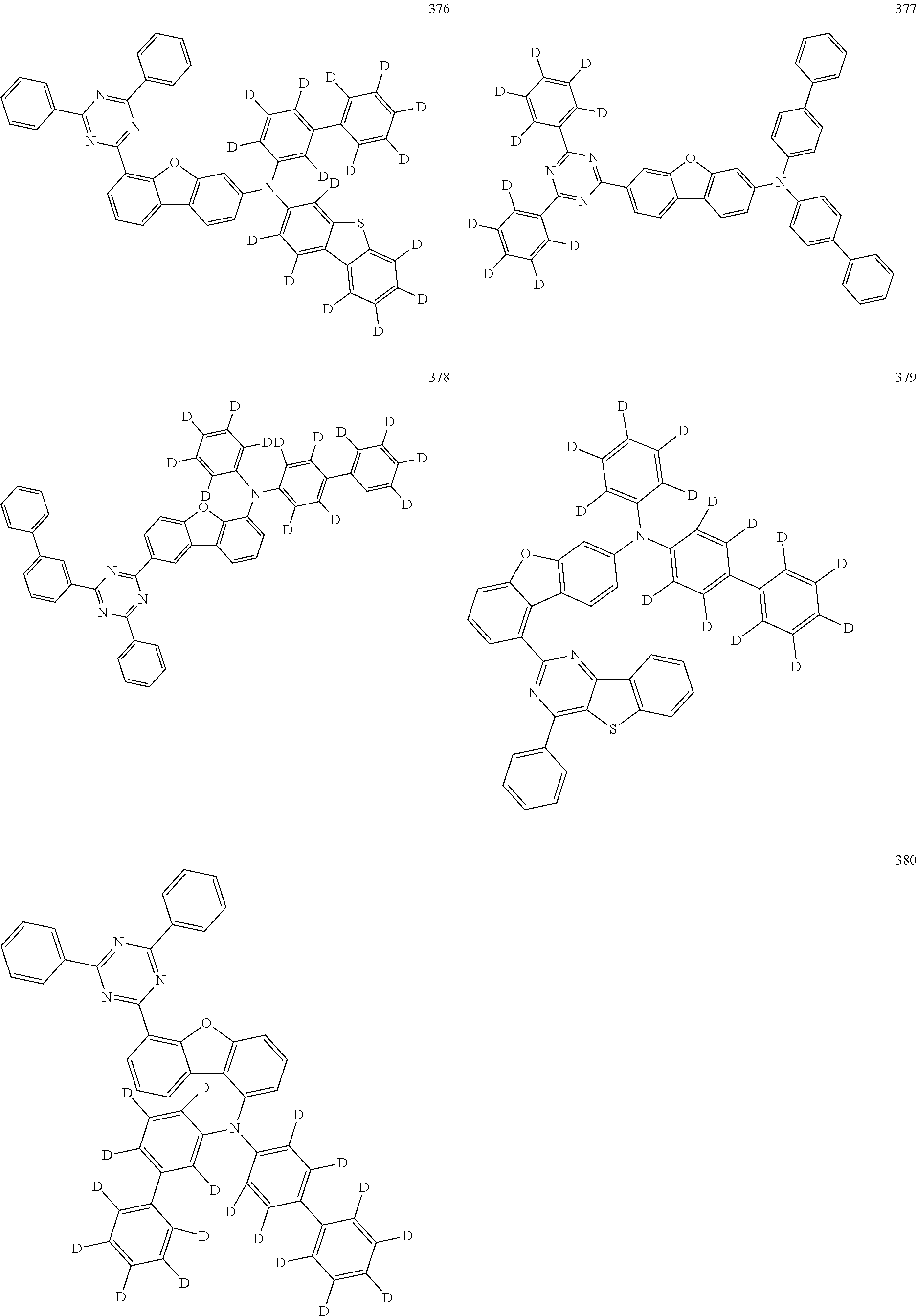

Further, various substituents may be introduced into the structure of Chemical Formula 1 to synthesize a compound having inherent characteristics of a substituent introduced. For example, a substituent usually used for a light emitting layer material used when manufacturing an organic light emitting device may be introduced into the core structure to synthesize a material which satisfies conditions required for a light emitting layer.

In addition, it is possible to finely adjust an energy band-gap by introducing various substituents into the structure of Chemical Formula 1, and meanwhile, it is possible to improve characteristics at the interface between organic materials and diversify the use of the material.

In an exemplary embodiment of the present application, Chemical Formula 2 may be represented by any one of the following compounds.

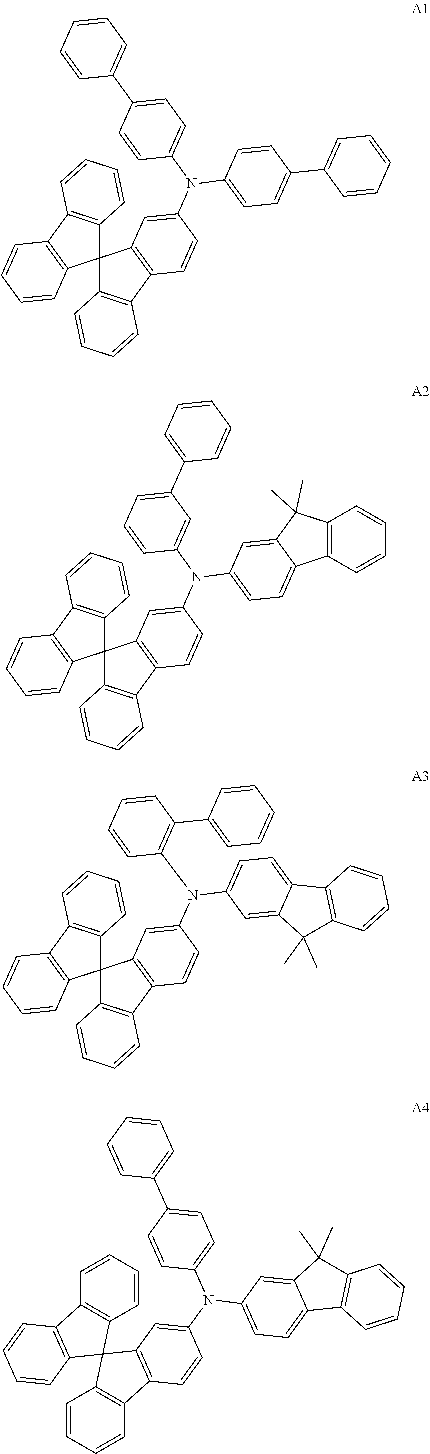 [SMILES: c1ccc(-c2ccc(N(c3ccc(-c4ccccc4)cc3)c3ccc4c(c3)C3(c5ccccc5-c5ccccc53)c3ccccc3-4)cc2)cc1 ; CC1(C)c2ccccc2-c2ccc(N(c3cccc(-c4ccccc4)c3)c3ccc4c(c3)C3(c5ccccc5-c5ccccc53)c3ccccc3-4)cc21 ; CC1(C)c2ccccc2-c2ccc(N(c3ccc4c(c3)C3(c5ccccc5-c5ccccc53)c3ccccc3-4)c3ccccc3-c3ccccc3)cc21 ; CC1(C)c2ccccc2-c2ccc(N(c3ccc(-c4ccccc4)cc3)c3ccc4c(c3)C3(c5ccccc5-c5ccccc53)c3ccccc3-4)cc21]

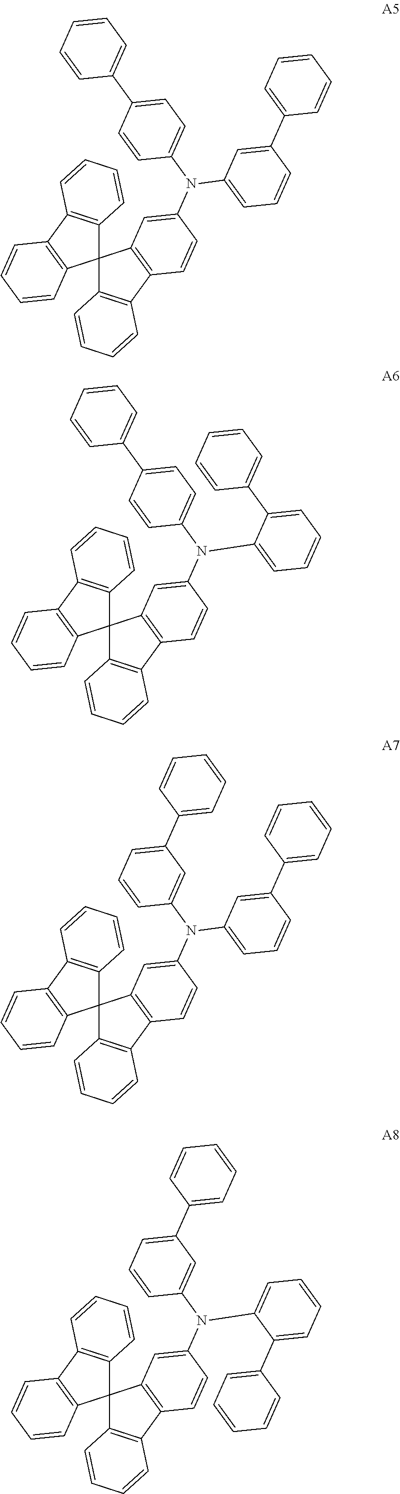

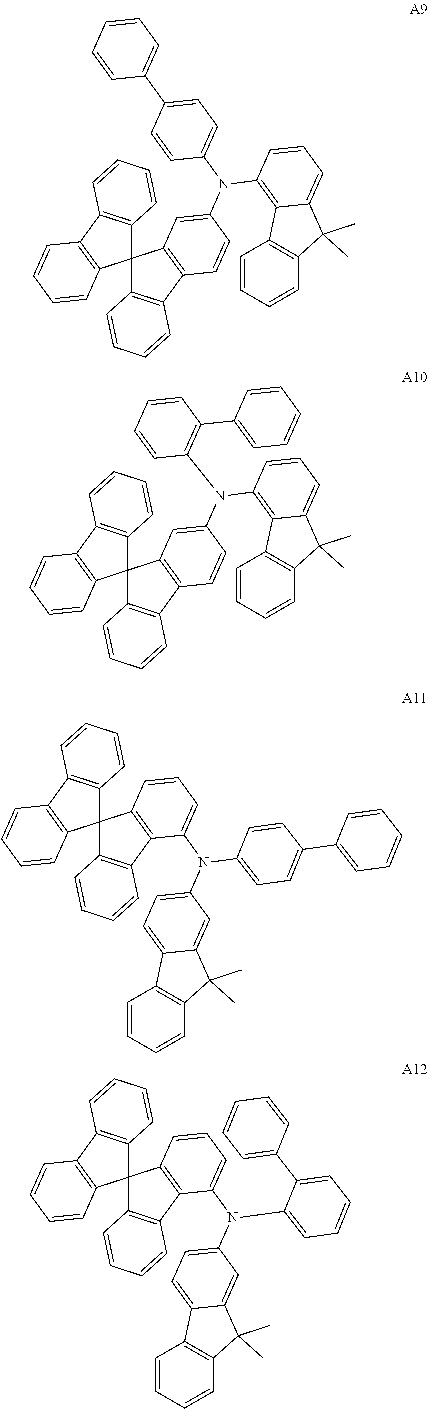

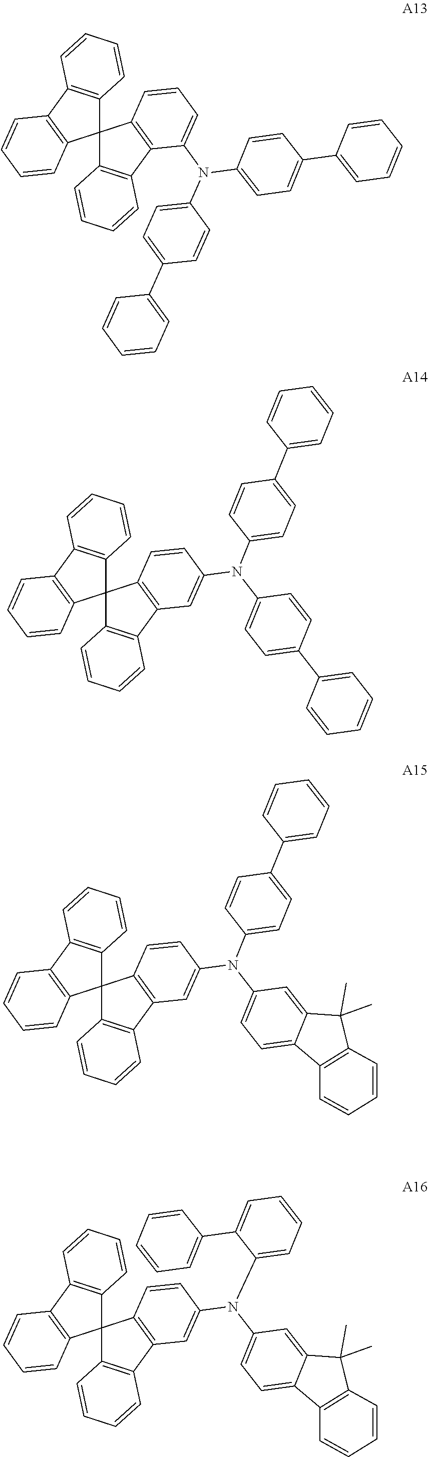 [SMILES: c1ccc(-c2ccc(N(c3ccc(-c4ccccc4)cc3)c3cccc4c3-c3ccccc3C43c4ccccc4-c4ccccc43)cc2)cc1 ; c1ccc(-c2ccc(N(c3ccc(-c4ccccc4)cc3)c3ccc4c(c3)-c3ccccc3C43c4ccccc4-c4ccccc43)cc2)cc1 ; CC1(C)c2ccccc2-c2ccc(N(c3ccc(-c4ccccc4)cc3)c3ccc4c(c3)-c3ccccc3C43c4ccccc4-c4ccccc43)cc21 ; CC1(C)c2ccccc2-c2ccc(N(c3ccc4c(c3)-c3ccccc3C43c4ccccc4-c4ccccc43)c3ccccc3-c3ccccc3)cc21]

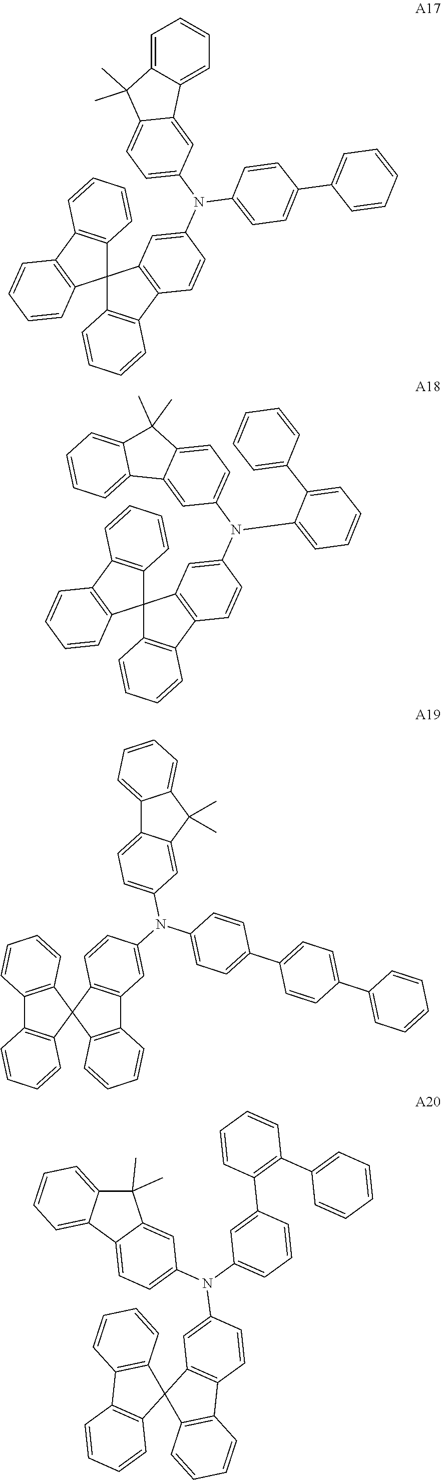

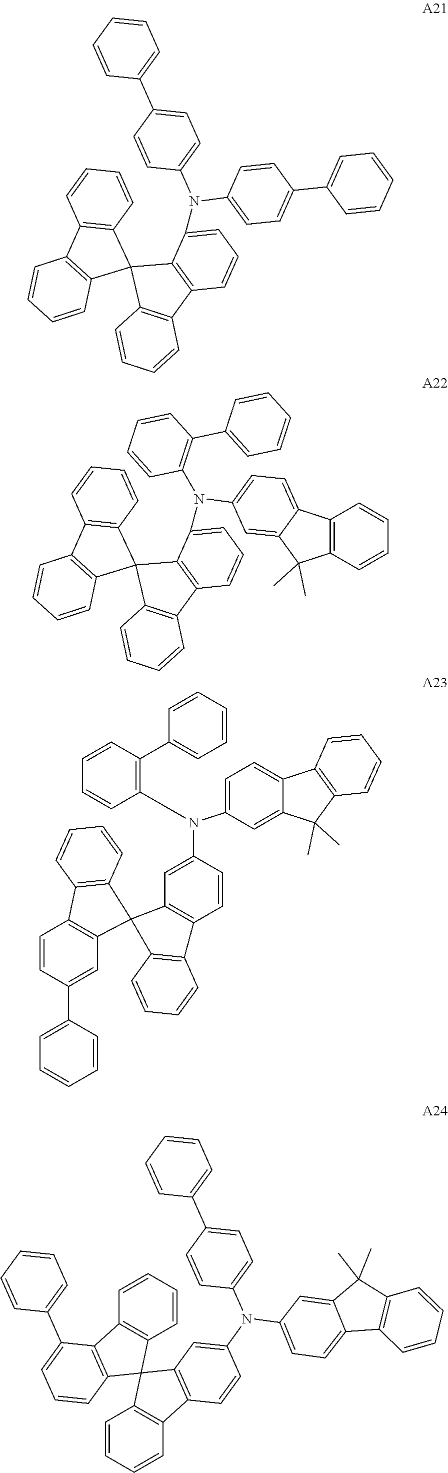

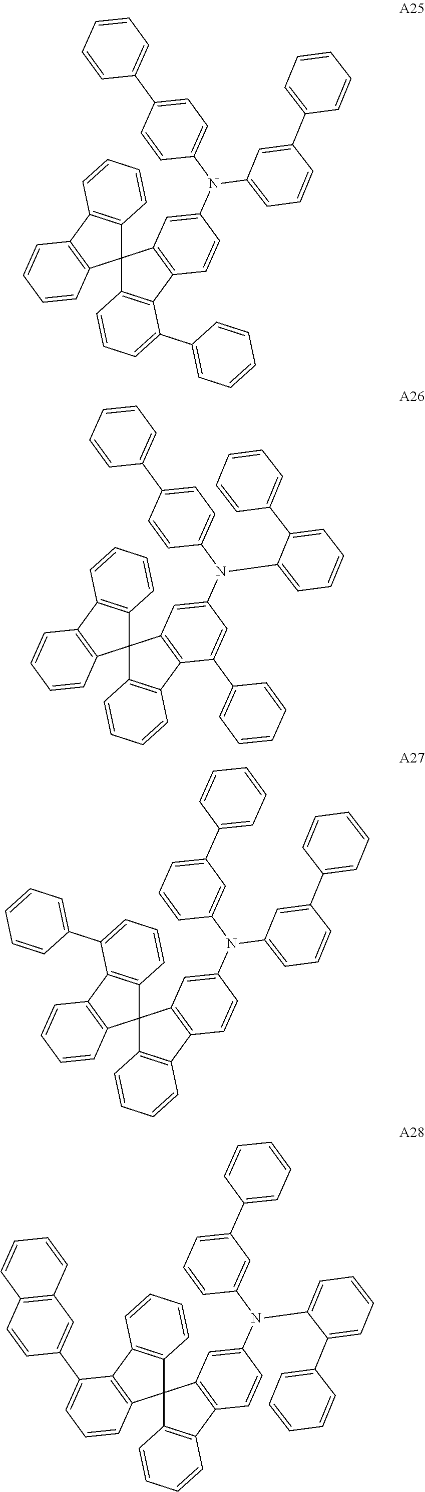

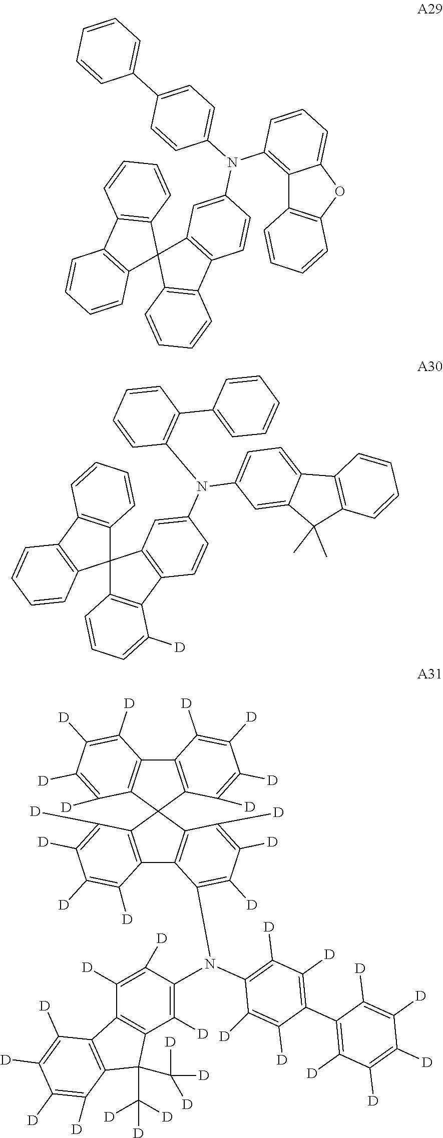

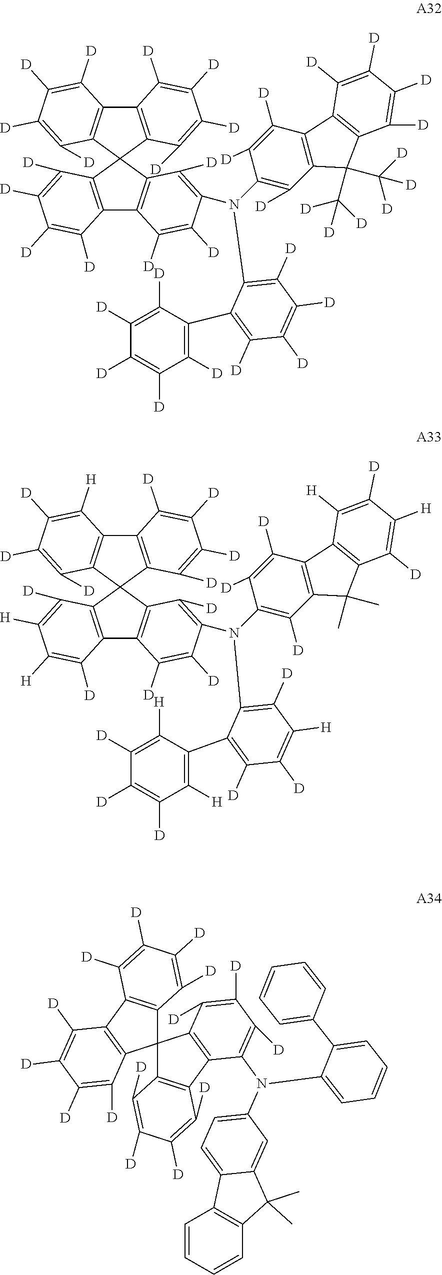

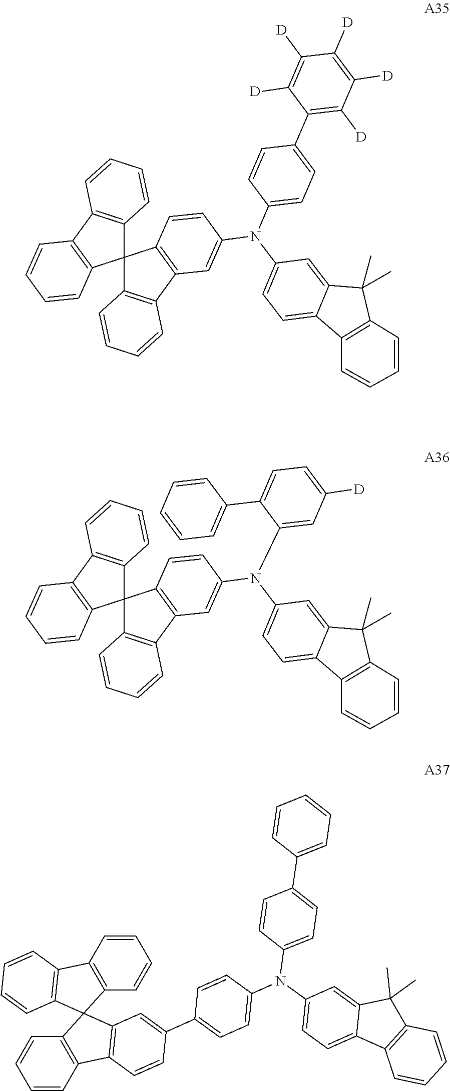 [SMILES: [2H]c1c([2H])c([2H])c(-c2ccc(N(c3ccc4c(c3)-c3ccccc3C43c4ccccc4-c4ccccc43)c3ccc4c(c3)C(C)(C)c3ccccc3-4)cc2)c([2H])c1[2H] ; [2H]c1ccc(-c2ccccc2)c(N(c2ccc3c(c2)-c2ccccc2C32c3ccccc3-c3ccccc32)c2ccc3c(c2)C(C)(C)c2ccccc2-3)c1 ; CC1(C)c2ccccc2-c2ccc(N(c3ccc(-c4ccccc4)cc3)c3ccc(-c4ccc5c(c4)C4(c6ccccc6-c6ccccc64)c4ccccc4-5)cc3)cc21]

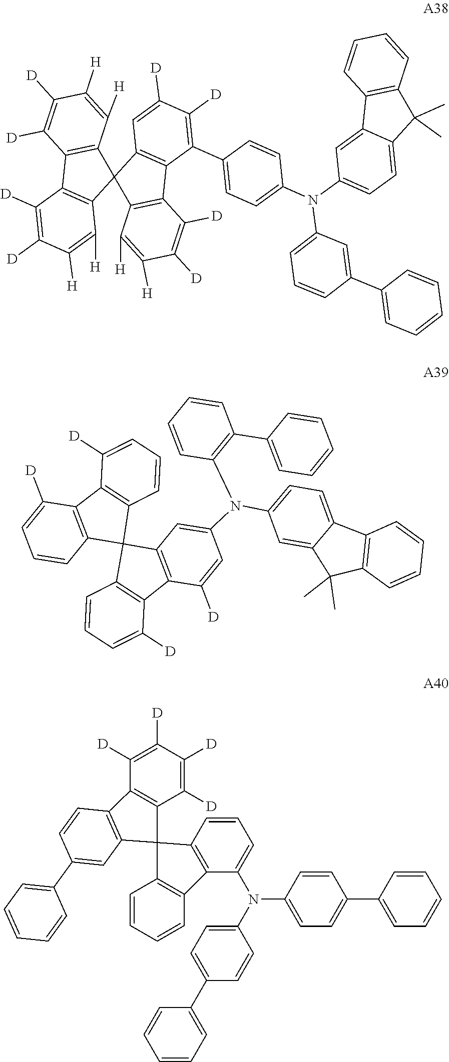 [SMILES: [2H]c1ccc2c(c1[2H])-c1c(ccc([2H])c1[2H])C21c2ccc([2H])c([2H])c2-c2c1cc([2H])c([2H])c2-c1ccc(N(c2cccc(-c3ccccc3)c2)c2ccc3c(c2)-c2ccccc2C3(C)C)cc1 ; [2H]c1cccc2c1-c1c([2H])cccc1C21c2cccc([2H])c2-c2c([2H])cc(N(c3ccc4c(c3)C(C)(C)c3ccccc3-4)c3ccccc3-c3ccccc3)cc21 ; [2H]c1c([2H])c([2H])c2c(c1[2H])-c1ccc(-c3ccccc3)cc1C21c2ccccc2-c2c(N(c3ccc(-c4ccccc4)cc3)c3ccc(-c4ccccc4)cc3)cccc21]

Further, various substituents may be introduced into the structure of Chemical Formula 2 to synthesize a compound having inherent characteristics of a substituent introduced. For example, a substituent usually used for a hole transport material used when manufacturing an organic light emitting device may be introduced into the core structure to synthesize a material which satisfies conditions required for a hole transport material.

In addition, it is possible to finely adjust an energy band-gap by introducing various substituents into the structure of Chemical Formula 1, and meanwhile, it is possible to improve characteristics at the interface between organic materials and diversify the use of the material.

In an exemplary embodiment of the present application, the organic material layer may further include one or more of an electron blocking layer, a hole injection layer, a hole blocking layer and an electron transport layer.

In an exemplary embodiment of the present application, the organic material layer may further include an electron blocking layer, a hole injection layer, a hole blocking layer and an electron transport layer.

In an exemplary embodiment of the present application, the light emitting layer may include the heterocyclic compound represented by Chemical Formula 1 as a host.

In an exemplary embodiment of the present application, the light emitting layer may include the heterocyclic compound represented by Chemical Formula 1 as a red host.

In an exemplary embodiment of the present application, the light emitting layer may include the heterocyclic compound represented by Chemical Formula 1 as a green host.

In an exemplary embodiment of the present application, the light emitting layer may include the heterocyclic compound represented by Chemical Formula 1 as a blue host.

In an exemplary embodiment of the present application, the light emitting layer may include the heterocyclic compound represented by Chemical Formula 1 as a yellow host.

In an exemplary embodiment of the present specification, the deuterium content of Chemical Formula 1 may be 0% to 100%.

In an exemplary embodiment of the present specification, the deuterium content of Chemical Formula 1 may be 0%.

In an exemplary embodiment of the present specification, the deuterium content of Chemical Formula 1 may be 30% to 100%.

In an exemplary embodiment of the present specification, the deuterium content of Chemical Formula 1 may be 50% to 100%.

In an exemplary embodiment of the present specification, the deuterium content of Chemical Formula 1 may be 70% to 100%.

In an exemplary embodiment of the present specification, the deuterium content of Chemical Formula 1 may be 100%.

In an exemplary embodiment of the present specification, the deuterium content of Chemical Formula 2 may be 0% to 100%.

In an exemplary embodiment of the present specification, the deuterium content of Chemical Formula 2 may be 0%.

In an exemplary embodiment of the present specification, the deuterium content of Chemical Formula 2 may be 30% to 100%.

In an exemplary embodiment of the present specification, the deuterium content of Chemical Formula 2 may be 50% to 100%.

In an exemplary embodiment of the present specification, the deuterium content of Chemical Formula 2 may be 70% to 100%.

In an exemplary embodiment of the present specification, the deuterium content of Chemical Formula 2 may be 100%.

In an exemplary embodiment of the present specification, the deuterium content of the heterocyclic compound of Chemical Formula 1 and the compound of Chemical Formula 2 satisfies the above range, the photochemical characteristics of a compound which includes deuterium and a compound which does not include deuterium are almost similar, but when deposited on a thin film, the deuterium-containing material tends to be packed with a narrower intermolecular distance.

Accordingly, when an electron only device (EOD) and a hole only device (HOD) are manufactured and the current density thereof according to voltage is confirmed, it can be confirmed that in the heterocyclic compound of Chemical Formula 1 of the present invention, a compound including deuterium exhibits much more balanced charge transport characteristics than a compound which does not include deuterium.

Further, when the surface of a thin film is observed using an atomic force microscope (AFM), it can be confirmed that the thin film made of a compound including deuterium is deposited with a more uniform surface without any aggregated portion.

Additionally, since the single bond dissociation energy of carbon and deuterium is higher than the single bond dissociation energy of carbon and hydrogen, among the heterocyclic compound of Chemical Formula 1 and the compound of Chemical Formula 2 in the present invention, in the case of a compound in which the deuterium content satisfies the above range, the stability of the total molecules is enhanced, so that there is an effect that the service life of the device is improved.

In an exemplary embodiment of the present specification, the deuterium content of Chemical Formula 1 and Chemical Formula 2 may be each 0%, or 10% to 100%.

In an exemplary embodiment of the present specification, the deuterium content of Chemical Formula 1 and Chemical Formula 2 may be each 0%, or 15% to 100%.

In an exemplary embodiment of the present specification, the deuterium content of Chemical Formula 1 and Chemical Formula 2 may be each 0%, or 20% to 100%.

In an exemplary embodiment of the present specification, the deuterium content of Chemical Formula 1 and Chemical Formula 2 may be each 0%, or 50% to 100%.

In an exemplary embodiment of the present specification, the deuterium content of Chemical Formula 1 and Chemical Formula 2 may be each 0% or 100%.

In another exemplary embodiment of the present specification, provided is an organic light emitting device in which the light emitting layer includes one or more of the heterocyclic compounds of Chemical Formula 1.

In an exemplary embodiment of the present specification, the light emitting layer includes a host, and the host may include one or more of the heterocyclic compound of Chemical Formula 1.

In an exemplary embodiment of the present specification, the light emitting layer includes a host, the host includes a green host, and the green host may include one or more of the heterocyclic compounds of Chemical Formula 1.

In an exemplary embodiment of the present specification, the light emitting layer includes a host, the host includes a red host, and the red host may include one or more of the heterocyclic compounds of Chemical Formula 1.

In an exemplary embodiment of the present specification, the organic material layer includes a light emitting layer, the light emitting layer includes a host, the host includes a blue host, and the blue host may include one or more of the heterocyclic compounds of Chemical Formula 1.

In an exemplary embodiment of the present specification, the light emitting layer may include the heterocyclic compound of Chemical Formula 1 as a P-type host.

In an exemplary embodiment of the present specification, the light emitting layer may include the heterocyclic compound of Chemical Formula 1 as an N-type host.

In an exemplary embodiment of the present specification, the hole transport layer may include one or more of the compounds of Chemical Formula 2.

The organic material layer of the organic light emitting device of the present invention may be composed of a single-layered structure, but may be composed of a multi-layered structure in which two or more organic material layers are stacked. For example, the organic light emitting device of the present invention may have a structure including a hole injection layer, a hole transport layer, a light emitting layer, an electron transport layer, an electron injection layer, and the like as organic material layers. However, the structure of the organic light emitting device is not limited thereto, and may include a fewer number of organic material layers.

In an exemplary embodiment of the present specification, the first electrode may be a positive electrode, and the second electrode may be a negative electrode.

In another exemplary embodiment of the present specification, the first electrode may be a negative electrode, and the second electrode may be a positive electrode.

The organic light emitting device according to an exemplary embodiment of the present specification may be manufactured by typical methods and materials for manufacturing an organic light emitting device, except that a light emitting layer having one or more layers is formed using the heterocyclic compound of the above-described Chemical Formula 1 or a hole transport layer having one or more layers is formed using the above-described compound of Chemical Formula 2.

The heterocyclic compound of Chemical Formula 1 may be formed as a light emitting layer by not only the vacuum deposition method but also the solution coating method during the manufacture of an organic light emitting device, and the compound of Chemical Formula 2 may be formed as a hole transport layer by the method described above during the manufacture of an organic light emitting device. Herein, the solution coating method means spin coating, dip coating, inkjet printing, screen printing, a spray method, roll coating, and the like, but is not limited thereto.

In an exemplary embodiment of the present specification, the organic light emitting device may be a blue organic light emitting device, the heterocyclic compound of Chemical Formula 1 is used as a material for the light emitting layer of the blue organic light emitting device, and the compound of Chemical Formula 2 may be used as a material for the hole transport layer of the blue organic light emitting device.

In another exemplary embodiment of the present specification, the organic light emitting device may be a green organic light emitting device, the heterocyclic compound of Chemical Formula 1 is used as a material for the light emitting layer of the green organic light emitting device, and the compound of Chemical Formula 2 may be used as a material for the hole transport layer of the green organic light emitting device.

In still another exemplary embodiment of the present specification, the organic light emitting device may be a red organic light emitting device, the heterocyclic compound of Chemical Formula 1 is used as a material for the light emitting layer of the red organic light emitting device, and the compound of Chemical Formula 2 may be used as a material for the hole transport layer of the red organic light emitting device.

The organic light emitting device of the present invention may further include one or more layers selected from the group consisting of a hole injection layer, an electron injection layer, an electron transport layer, an electron blocking layer, and a hole blocking layer.

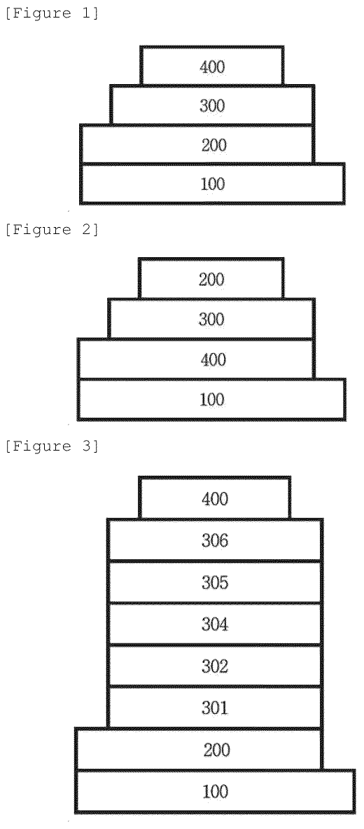

FIGS. 1 to 4 exemplify the stacking sequence of the electrodes and the organic material layer of the organic light emitting device according to an exemplary embodiment of the present specification. However, the scope of the present application is not intended to be limited by these drawings, and the structure of the organic light emitting device known in the art may also be applied to the present application.

According to FIG. 1, an organic light emitting device in which a positive electrode 200, an organic material layer 300, and a negative electrode 400 are sequentially stacked on a substrate 100 is illustrated. However, the organic light emitting device is not limited only to such a structure, and as in FIG. 2, an organic light emitting device in which a negative electrode, an organic material layer, and a positive electrode are sequentially stacked on a substrate may also be implemented.

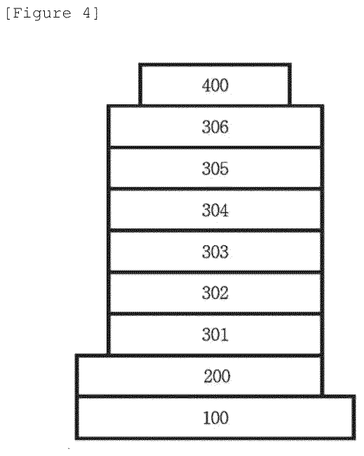

FIGS. 3 and 4 exemplify a case where an organic material layer is a multilayer. The organic light emitting device according to FIG. 3 includes a hole injection layer 301, a hole transport layer 302, a light emitting layer 304, an electron transport layer 305 and an electron injection layer 306, and the organic light emitting device according to FIG. 4 includes a hole injection layer 301, a hole transport layer 302, an electron blocking layer 303, a light emitting layer 304, an electron transport layer 305 and an electron injection layer 306. However, the scope of the present application is not limited by the stacking structure as described above, and if necessary, the other layers except for the light emitting layer may be omitted, and another necessary functional layer may be further added.

Specifically, the heterocyclic compound of Chemical Formula 1 is included in the light emitting layer 304, and the compound of Chemical Formula 2 may be included in the hole transport layer 302.

More specifically, the heterocyclic compound of Chemical Formula 1 is included as a red host in the light emitting layer 304, and the compound of Chemical Formula 2 may be included in the hole transport layer 302.

In the organic light emitting device according to an exemplary embodiment of the present specification, materials other than the heterocyclic compound of Chemical Formula 1 and the compound of Chemical Formula 2 will be exemplified below, but these materials are provided only for exemplification and are not for limiting the scope of the present application, and may be replaced with materials publicly known in the art.

As a positive electrode material, materials having a relatively high work function may be used, and a transparent conductive oxide, a metal or a conductive polymer, and the like may be used. Specific examples of the positive electrode material include: a metal such as vanadium, chromium, copper, zinc, and gold, or an alloy thereof; a metal oxide such as zinc oxide, indium oxide, indium tin oxide (ITO), and indium zinc oxide (IZO); a combination of a metal and an oxide, such as ZnO:Al or SnO₂:Sb; a conductive polymer such as poly(3-methylthiophene), poly[3,4-(ethylene-1,2-dioxy)thiophene] (PEDOT), polypyrrole, and polyaniline; and the like, but are not limited thereto.

As a negative electrode material, materials having a relatively low work function may be used, and a metal, a metal oxide, or a conductive polymer, and the like may be used. Specific examples of the negative electrode material include: a metal such as magnesium, calcium, sodium, potassium, titanium, indium, yttrium, lithium, gadolinium, aluminum, silver, tin, and lead, or an alloy thereof; a multi-layer structured material, such as LiF/Al or LiO₂/Al; and the like, but are not limited thereto.

As a hole injection material, a publicly-known hole injection material may also be used, and it is possible to use, for example, a phthalocyanine compound such as copper phthalocyanine disclosed in U.S. Pat. No. 4,356,429 or starburst-type amine derivatives described in the document [Advanced Material, 6, p. 677 (1994)], for example, tris(4-carbazoyl-9-ylphenyl)amine (TCTA), 4,4′,4″-tri[phenyl(m-tolyl)amino]triphenylamine (m-MTDATA), 1,3,5-tris[4-(3-methylphenylphenylamino)phenyl]benzene (m-MTDAPB), polyaniline/dodecylbenzenesulfonic acid or poly(3,4-ethylenedioxythiophene)/poly(4-styrenesulfonate), which is a soluble conductive polymer, polyaniline/camphor sulfonic acid or polyaniline/poly(4-styrenesulfonate), and the like.

As a hole transport material, a pyrazoline derivative, an arylamine-based derivative, a stilbene derivative, a triphenyldiamine derivative, and the like may be used, and a low-molecular weight or polymer material may also be used.

As an electron transport material, it is possible to use an oxadiazole derivative, anthraquinodimethane and a derivative thereof, benzoquinone and a derivative thereof, naphthoquinone and a derivative thereof, anthraquinone and a derivative thereof, tetracyanoanthraquinodimethane and a derivative thereof, a fluorenone derivative, diphenyldicyanoethylene and a derivative thereof, a diphenoquinone derivative, a metal complex of 8-hydroxyquinoline and a derivative thereof, and the like, and a low-molecular weight material and a polymer material may also be used.

As an electron injection material, for example, LiF is representatively used in the art, but the present application is not limited thereto.

As a light emitting material, a red, green, or blue light emitting material may be used, and if necessary, two or more light emitting materials may be mixed and used. In this case, two or more light emitting materials are deposited and used as an individual supply source, or pre-mixed to be deposited and used as one supply source. Further, a fluorescent material may also be used as the light emitting material, but may also be used as a phosphorescent material. As the light emitting material, it is also possible to use alone a material which emits light by combining holes and electrons each injected from a positive electrode and a negative electrode, but materials in which a host material and a dopant material are involved in light emission together may also be used.

When hosts of the light emitting material are mixed and used, the same series of hosts may also be mixed and used, and different series of hosts may also be mixed and used. For example, any two or more materials from N-type host materials or P-type host materials may be selected and used as a host material for a light emitting layer.

The organic light emitting device according to an exemplary embodiment of the present specification may be a top emission type, a bottom emission type, or a dual emission type according to the material to be used.

The heterocyclic compound of Chemical Formula 1 and the compound of Chemical Formula 2 according to an exemplary embodiment of the present application may act even in organic electronic devices including organic solar cells, organic photoconductors, organic transistors, and the like, based on the principle similar to those applied to organic light emitting devices.

In addition, it is possible to finely adjust an energy band gap by introducing various substituents into each structure of Chemical Formula 1 and Chemical Formula 2, and meanwhile, it is possible to improve characteristics at the interface between organic materials and diversify the use of material.

Hereinafter, the present specification will be described in more detail through Examples, but these Examples are provided only for exemplifying the present application, and are not intended to limit the scope of the present application.

### Preparation Examples

### <Preparation Example 1> Preparation of Compound 1

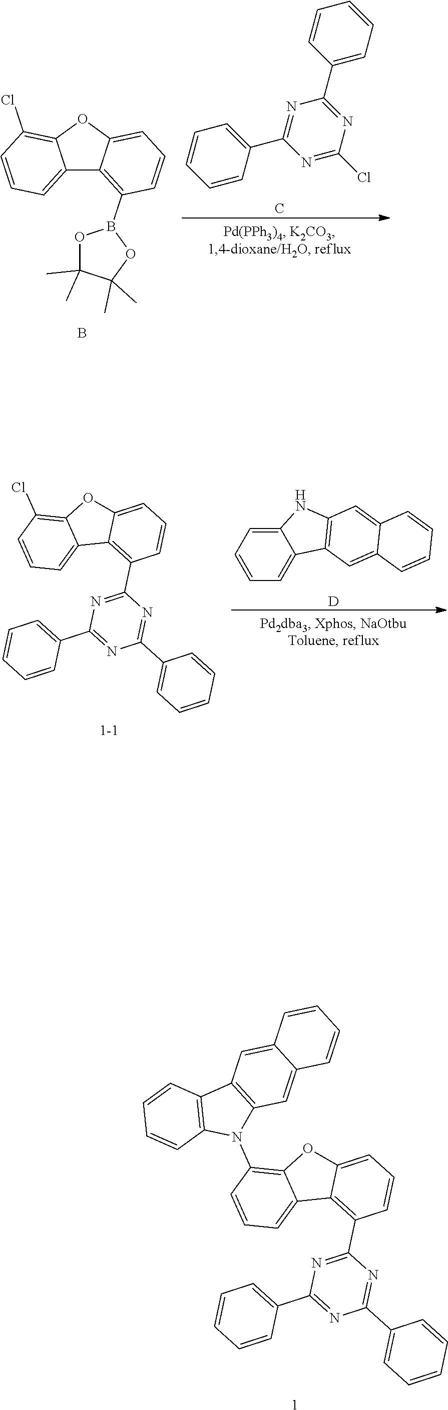

### 1) Preparation of Intermediate 1-1

After 9.5 g (28.9 mmol) of a compound 2-(6-chlorodibenzofuran-1-yl)-4,4,5,5-tetramethyl-1,3,2-dioxaborolane (B), 8.12 g (30.34 mmol) of 2-chloro-4,6-diphenyl-1,3,5-triazine (C), 1.67 g (1.45 mmol) of Pd(PPh₃)₄, and 6.13 g (57.8 mmol) of K₂CO₃ were dissolved in 100 mL/20 mL of 1,4-dioxane/H₂O, the resulting solution was refluxed at 130° C. for 4 hours. After the reaction was completed, a solid precipitated at room temperature was filtered.

After water was poured into the filtered solid, the water was removed using methanol, and then the residue was dissolved in DCM, and the resulting solution was purified by silica chromatography, and then recrystallized with DCM/MeOH to obtain 11.3 g (90%) of Intermediate 1-1.

### 2) Preparation of Compound 1

After 11.3 g (26.04 mmol) of Intermediate 1-1, 6.22 g (28.65 mmol) of 5H-benzo[b]carbazole (D), 1.19 g (1.3 mmol) of Pd₂dba₃, 1.24 g (2.6 mmol) of Xphos, and 5.01 g (52.09 mmol) of NaOtBu were dissolved in 120 mL of toluene, the resulting solution was refluxed at 130° C. for 3 hours.

After the reaction was completed, a solid precipitated at room temperature was filtered. After water was poured into the filtered solid, the water was removed using methanol, and then the residue was dissolved in DCM, and the resulting solution was purified by silica chromatography, and then recrystallized using DCM/acetone, and then 11 g (69%) of Target Compound 1 was obtained.

The following target compound was synthesized by performing synthesis in the same manner as in Preparation Example 1, except that in Preparation Example 1, Intermediate B in the following Table 1 was used instead of 2-(6-chlorodibenzofuran-1-yl)-4,4,5,5-tetramethyl-1,3,2-dioxaborolane (B), Intermediate C in the following Table 1 was used instead of 2-chloro-4,6-diphenyl-1,3,5-triazine (C), and Intermediate D in the following Table 1 was used instead of 5H-benzo[b]carbazole (D).

TABLE 1

| Compound | Intermediate | Intermediate | Intermediate | |
|---|---|---|---|---|
| No. | B | C | D | Yield |
| 13 | 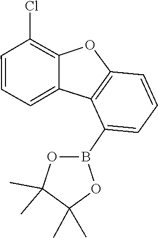 | 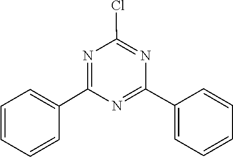 | 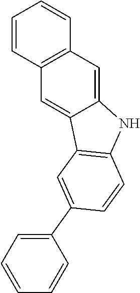 | 74% |
| 22 | 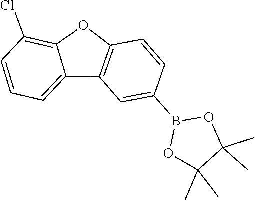 | 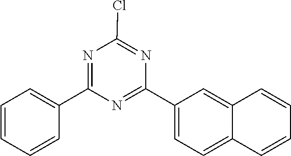 | 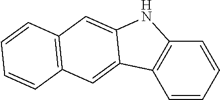 | 81% |
| 33 | 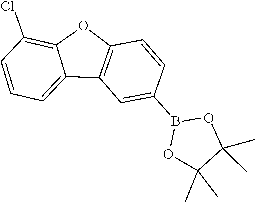 | 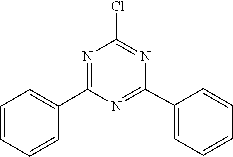 | 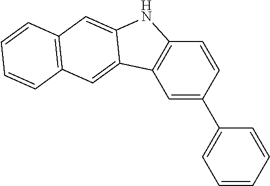 | 75% |
| 44 | 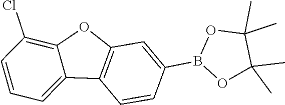 | 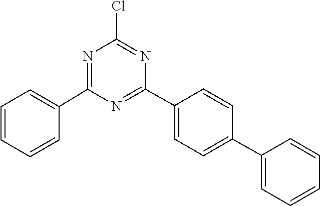 | 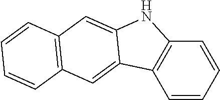 | 83% |
| 53 | 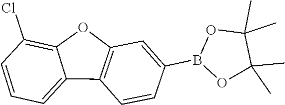 | 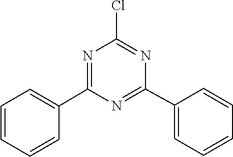 | 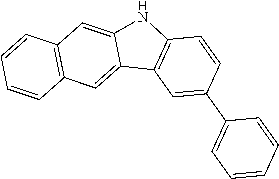 | 83% |
| 65 | 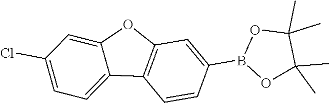 | 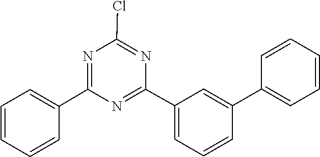 | 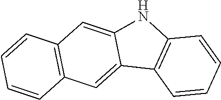 | 88% |
| 73 | 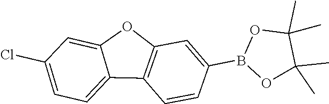 | 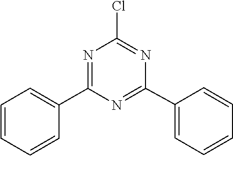 | 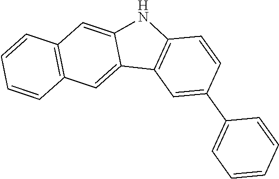 | 80% |
| 83 | 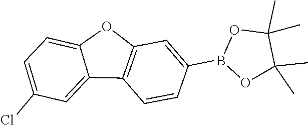 | 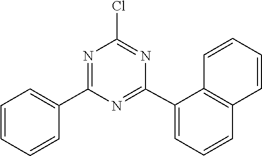 | 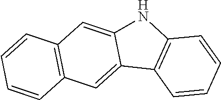 | 85% |
| 93 | 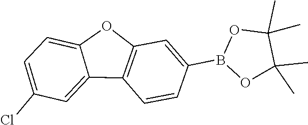 | 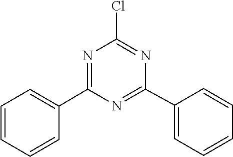 | 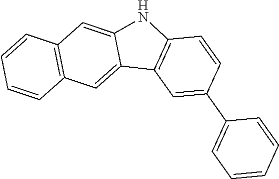 | 83% |
| 106 | 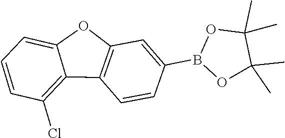 | 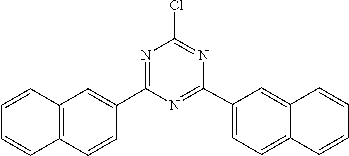 | 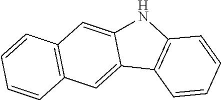 | 82% |
| 113 | 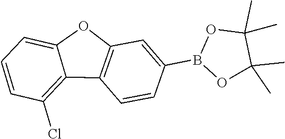 | 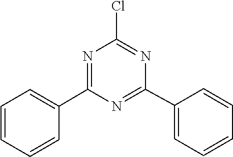 | 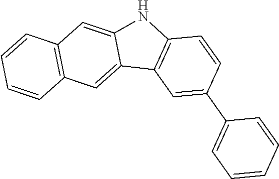 | 78% |
| 130 | 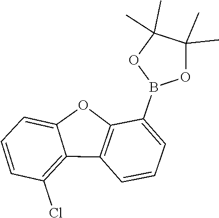 | 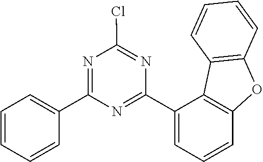 | 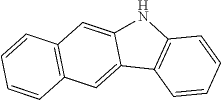 | 90% |
| 133 | 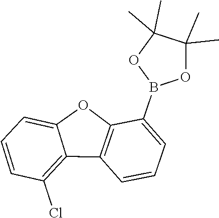 | 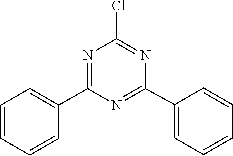 | 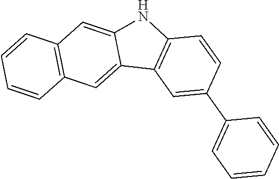 | 74% |
| 153 | 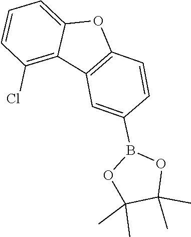 | 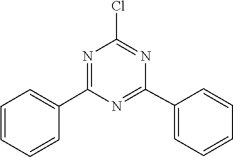 | 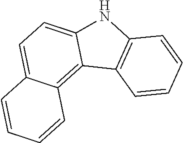 | 76% |
| 157 | 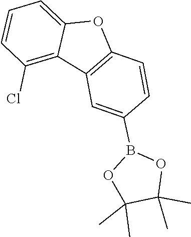 | 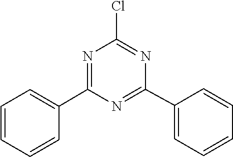 | 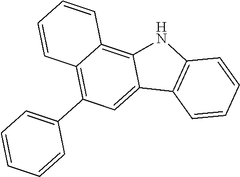 | 66% |
| 172 | 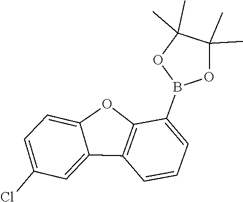 | 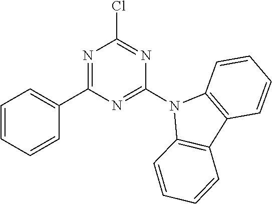 | 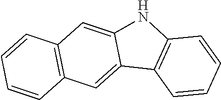 | 65% |
| 176 | 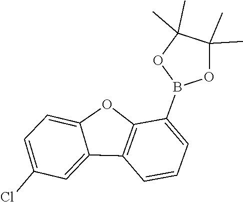 | 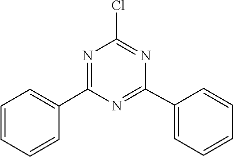 | 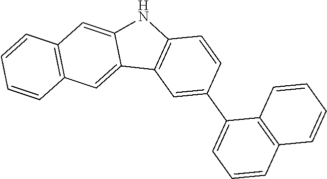 | 76% |
| 181 | 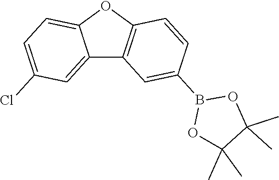 | 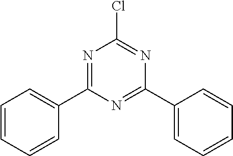 | 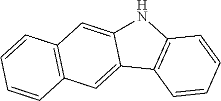 | 81% |
| 195 | 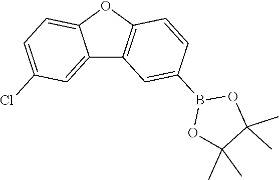 | 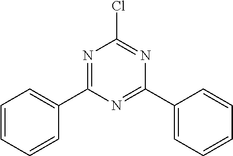 | 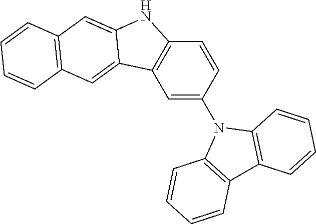 | 77% |
| 213 | 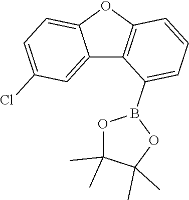 | 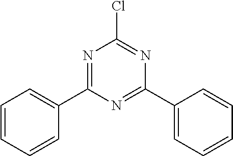 | 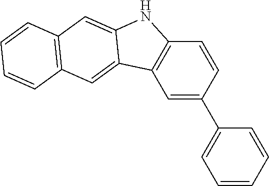 | 81% |
| 233 | 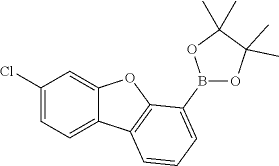 | 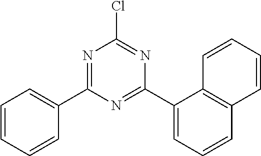 | 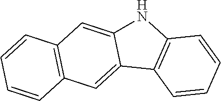 | 84% |
| 236 | 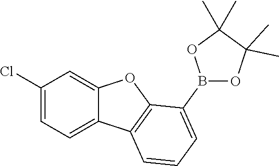 | 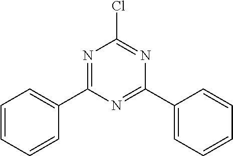 | 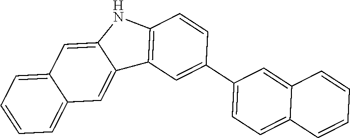 | 69% |
| 247 | 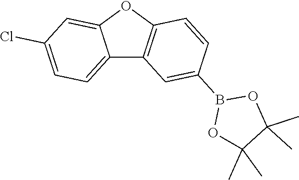 | 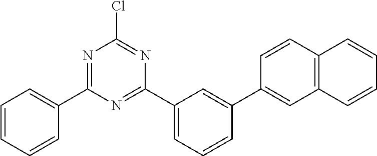 | 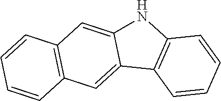 | 81% |
| 256 | 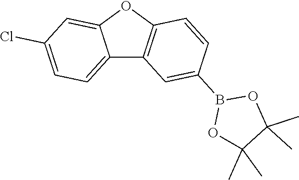 | 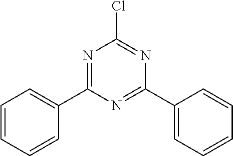 | 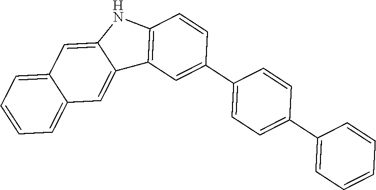 | 79% |
| 261 | 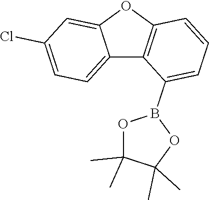 | 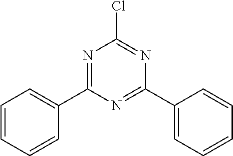 | 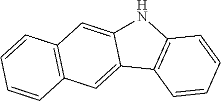 | 85% |
| 262 | 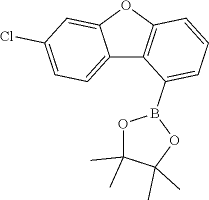 | 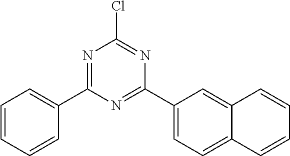 | 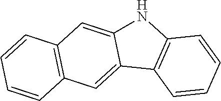 | 82% |
| 275 | 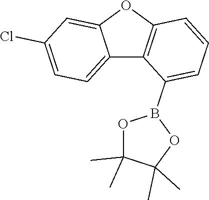 | 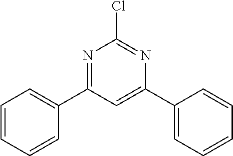 | 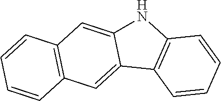 | 81% |
| 276 | 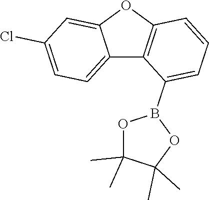 | 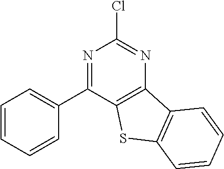 | 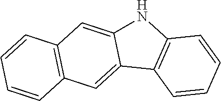 | 80% |
| 278 | 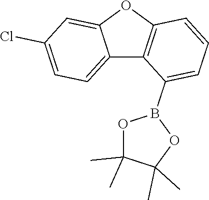 | 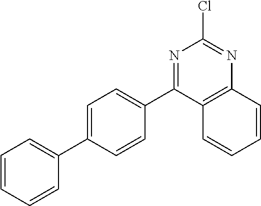 | 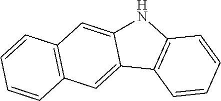 | 81% |
| 281 | 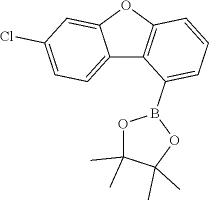 | 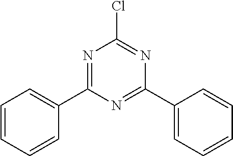 | 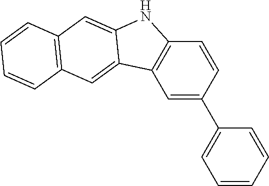 | 84% |
| 294 | 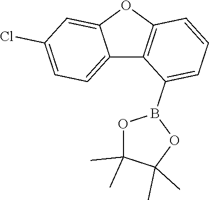 | 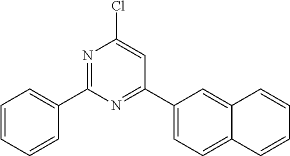 | 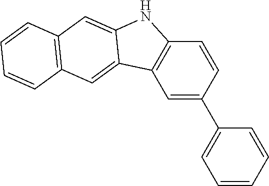 | 74% |
| 297 | 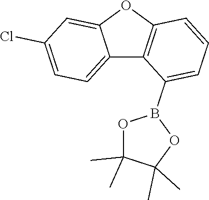 | 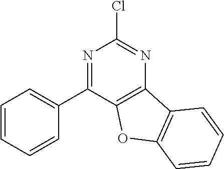 | 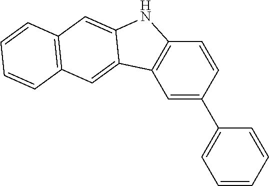 | 79% |
| 299 | 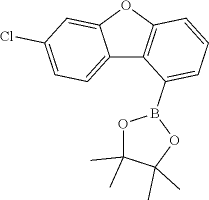 | 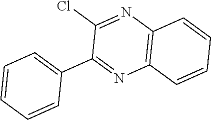 | 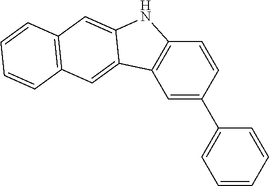 | 78% |
| 305 | 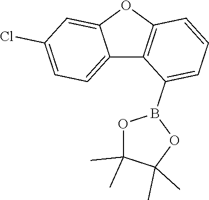 | 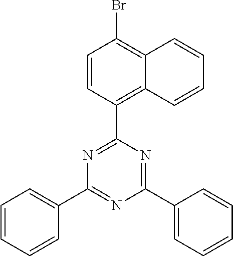 | 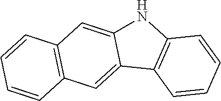 | 84% |
| 313 | 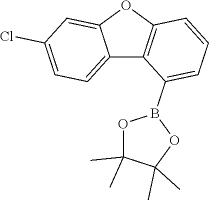 | 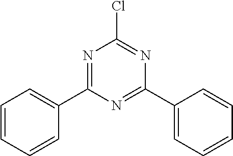 | 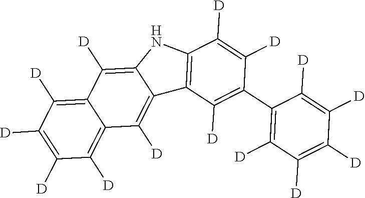 | 79% |
| 315 | 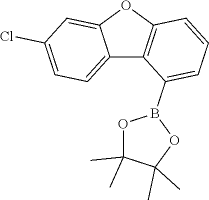 | 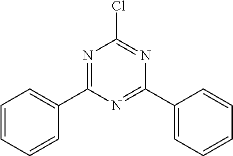 | 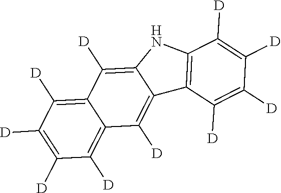 | 83% |
| 316 | 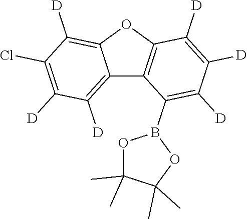 | 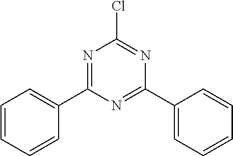 | 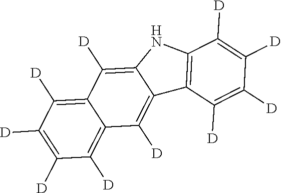 | 72% |
| 318 | 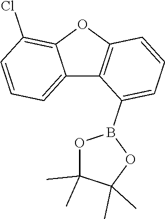 | 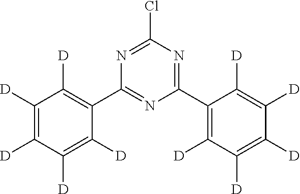 | 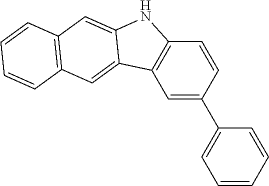 | 69% |
| 328 | 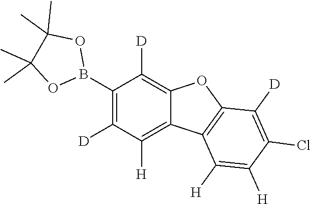 | 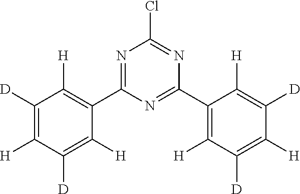 | 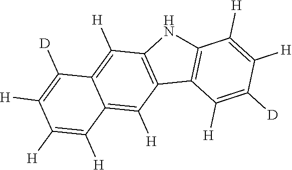 | 58% |
| 330 | 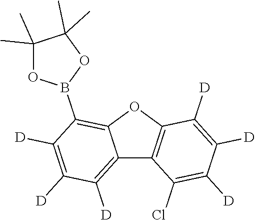 | 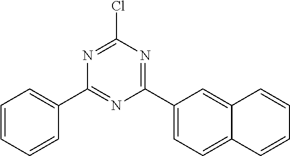 | 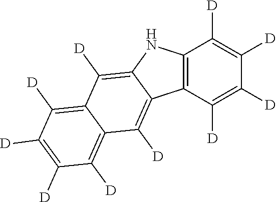 | 79% |
| 344 | 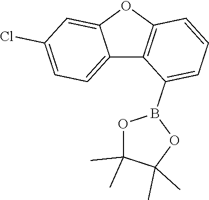 | 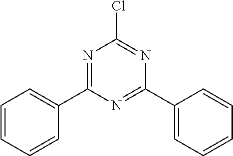 | 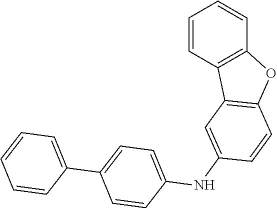 | 84% |
| 349 | 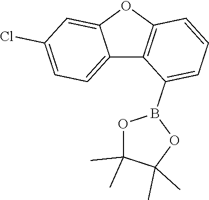 | 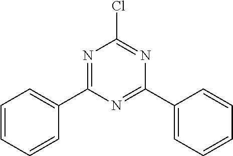 | 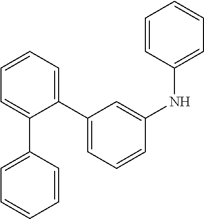 | 73% |

### <Preparation Example 2> Preparation of Compound 301

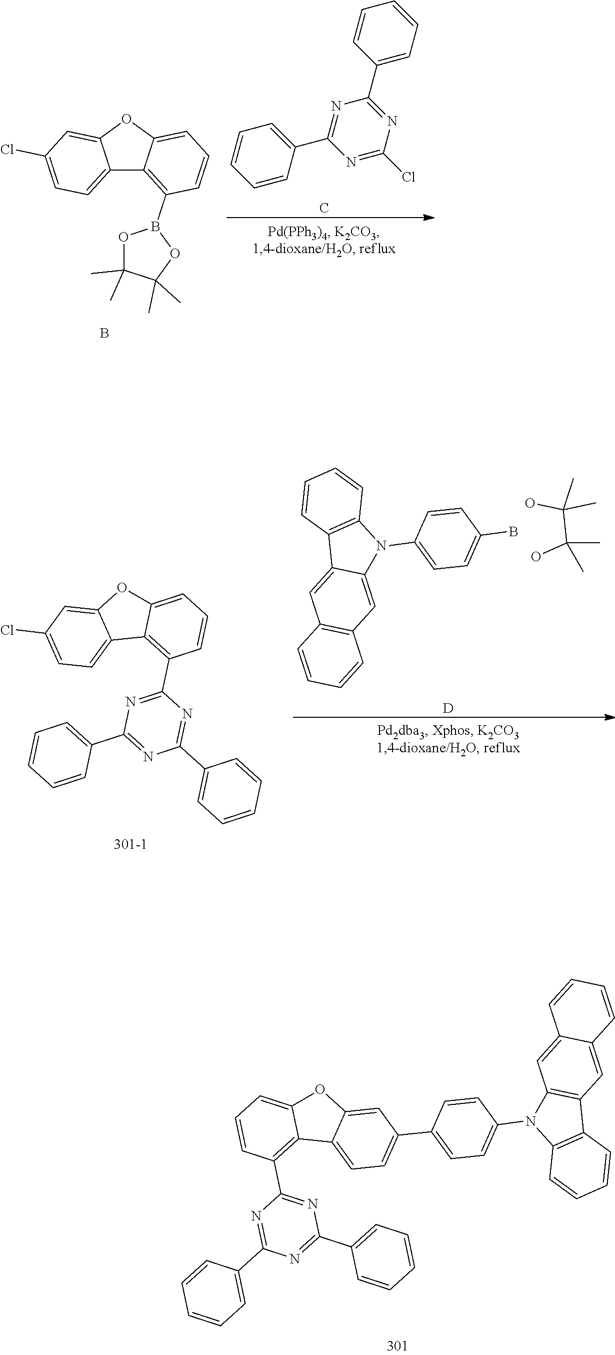

### 1) Preparation of Intermediate 301-1

After 8 g (24.35 mmol) of a compound 2-(7-chlorodibenzofuran-1-yl)-4,4,5,5-tetramethyl-1,3,2-dioxaborolane (B), 6.84 g (25.56 mmol) of 2-chloro-4,6-diphenyl-1,3,5-triazine (C), 1.41 g (1.22 mmol) of Pd(PPh₃)₄, and 5.16 g (48.69 mmol) of K₂CO₃ were dissolved in 80 mL/16 mL of 1,4-dioxane/H₂O, the resulting solution was refluxed at 130° C. for 3 hours.

After the reaction was completed, a precipitated solid was filtered at room temperature, water was poured into the filtered solid, and then water was removed using methanol.

The solid was dissolved in DCM, the resulting solution was purified by silica chromatography, and then recrystallized with DCM/MeOH to obtain 9.7 g (92%) of Intermediate 301-1.

### 2) Preparation of Compound 301

After 9.7 g (22.36 mmol) of Intermediate 301-1, 8.74 g (23.47 mmol) of 5-(4-(4,4,5,5-tetramethyl-1,3,2-dioxaborolan-2-yl)phenyl)-5H-benzo[b]carbazole (D), 1.02 g (1.12 mmol) of Pd₂dba₃, 1.07 g (2.24 mmol) of Xphos, and 4.74 g (44.71 mmol) of K₂CO₃ were 100 mL/20 mL of 1,4-dioxane/H₂O, the resulting solution was refluxed at 130° C. for 5 hours.

After the reaction was completed, a precipitated solid was filtered at room temperature, water was poured into the filtered solid, and then water was removed using methanol.

After the residue was dissolved in DCM and the resulting solution was purified by silica chromatography, recrystallization was performed using DCM/acetone, and then 12.7 g (82%) of Target Compound 301 was obtained.

The following target compound was synthesized by performing synthesis in the same manner as in Preparation Example 2, except that in Preparation Example 2, Intermediate B in the following Table 2 was used instead of 2-(7-chlorodibenzofuran-1-yl)-4,4,5,5-tetramethyl-1,3,2-dioxaborolane (B), Intermediate C in the following Table 2 was used instead of 2-chloro-4,6-diphenyl-1,3,5-triazine (C), and Intermediate D in the following Table 2 was used instead of 5-(4-(4,4,5,5-tetramethyl-1,3,2-dioxaborolan-2-yl)phenyl)-5H-benzo[b]carbazole (D).

TABLE 2

| Compound | Intermediate | Intermediate | Intermediate | |
|---|---|---|---|---|
| No. | B | C | D | Yield |
| 342 | 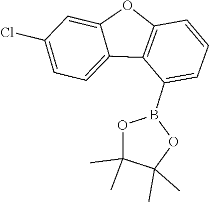 | 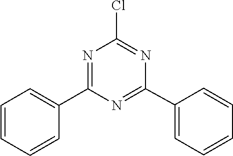 | 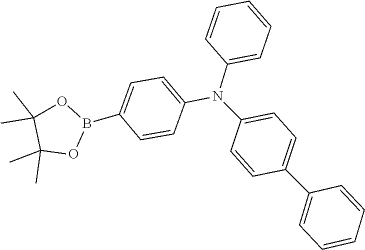 | 80% |
| 369 | 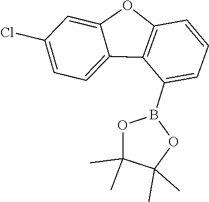 | 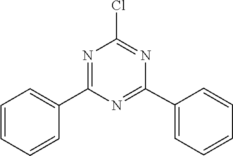 | 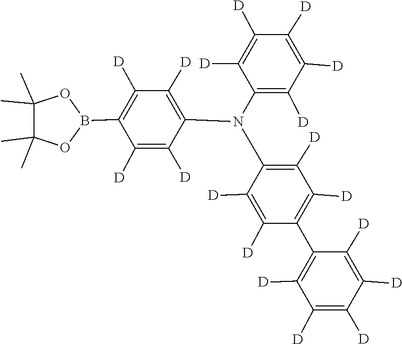 | 74% |

### <Preparation Example 3> Preparation of Compound 321

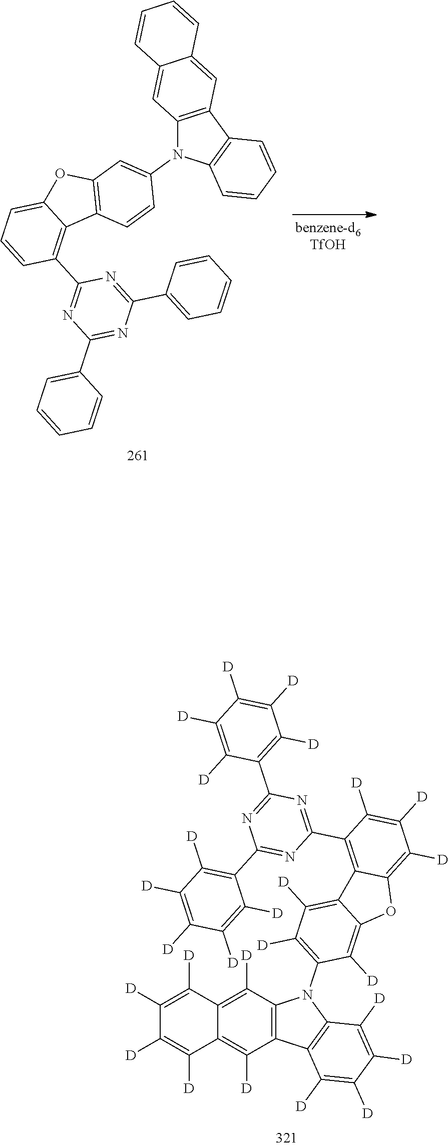 [SMILES: c1ccc(-c2nc(-c3ccccc3)nc(-c3cccc4oc5cc(-n6c7ccccc7c7cc8ccccc8cc76)ccc5c34)n2)cc1 ; [2H]c1c([2H])c([2H])c(-c2nc(-c3c([2H])c([2H])c([2H])c([2H])c3[2H])nc(-c3c([2H])c([2H])c([2H])c4oc5c([2H])c(-n6c7c([2H])c([2H])c([2H])c([2H])c7c7c([2H])c8c([2H])c([2H])c([2H])c([2H])c8c([2H])c76)c([2H])c([2H])c5c34)n2)c([2H])c1[2H]]

8 g (13.01 mmol) of Compound 261 synthesized using the method of Preparation Example 1 was dissolved in 80 mL of benzene-d₆.

After the temperature was adjusted to 0° C. using an ice bath, 8.2 mL (91.1 mmol, TfOH) of trifluoromethanesulfonic acid was slowly added dropwise thereto. Thereafter, the resulting mixture was stirred at 60° C. for 1 hour.

After a mixed solution completely reacted was cooled to room temperature, an ice bath was mounted, and then the mixed solution was neutralized using a K₃PO₄ aqueous solution. Thereafter, extraction was performed using DCM and distilled water, and the organic layer was treated with MgSO₄ and then concentrated.

After the residue was dissolved in DCM and the resulting solution was purified by silica chromatography, a solid was precipitated using methanol and filtered to obtain 7 g (84%) of Compound 321.

The following target compound was synthesized by performing synthesis in the same manner as in Preparation Example 3, except that Compound E in the following Table 3 was used instead of Compound 261 in Preparation Example 3.

TABLE 3

| Compound | | | |
|---|---|---|---|
| No. | Compound E | Target Compound | Yield |
| 322 | 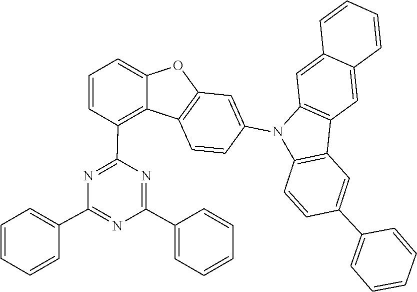 [SMILES: c1ccc(-c2ccc3c(c2)c2cc4ccccc4cc2n3-c2ccc3c(c2)oc2cccc(-c4nc(-c5ccccc5)nc(-c5ccccc5)n4)c23)cc1] | 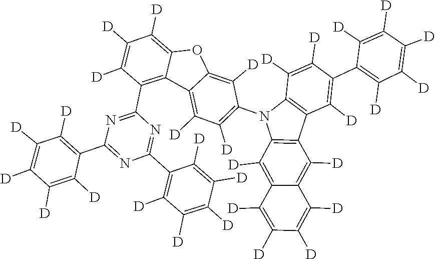 [SMILES: [2H]c1c([2H])c([2H])c(-c2nc(-c3c([2H])c([2H])c([2H])c([2H])c3[2H])nc(-c3c([2H])c([2H])c([2H])c4oc5c([2H])c(-n6c7c([2H])c([2H])c(-c8c([2H])c([2H])c([2H])c([2H])c8[2H])c([2H])c7c7c([2H])c8c([2H])c([2H])c([2H])c([2H])c8c([2H])c76)c([2H])c([2H])c5c34)n2)c([2H])c1[2H]] | 90% |
| 327 | 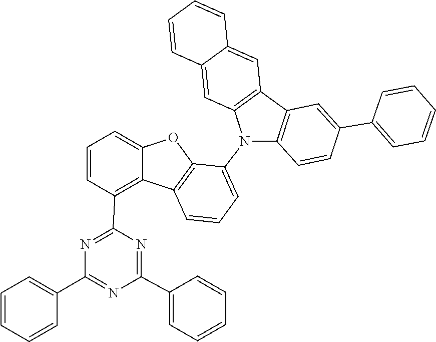 [SMILES: c1ccc(-c2ccc3c(c2)c2cc4ccccc4cc2n3-c2cccc3c2oc2cccc(-c4nc(-c5ccccc5)nc(-c5ccccc5)n4)c23)cc1] | 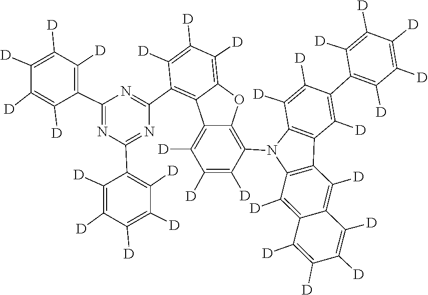 [SMILES: [2H]c1c([2H])c([2H])c(-c2nc(-c3c([2H])c([2H])c([2H])c([2H])c3[2H])nc(-c3c([2H])c([2H])c([2H])c4oc5c(-n6c7c([2H])c([2H])c(-c8c([2H])c([2H])c([2H])c([2H])c8[2H])c([2H])c7c7c([2H])c8c([2H])c([2H])c([2H])c([2H])c8c([2H])c76)c([2H])c([2H])c([2H])c5c34)n2)c([2H])c1[2H]] | 91% |
| 374 | 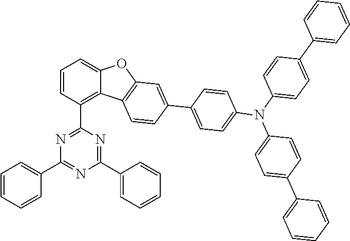 [SMILES: c1ccc(-c2ccc(N(c3ccc(-c4ccccc4)cc3)c3ccc(-c4ccc5c(c4)oc4cccc(-c6nc(-c7ccccc7)nc(-c7ccccc7)n6)c45)cc3)cc2)cc1] | 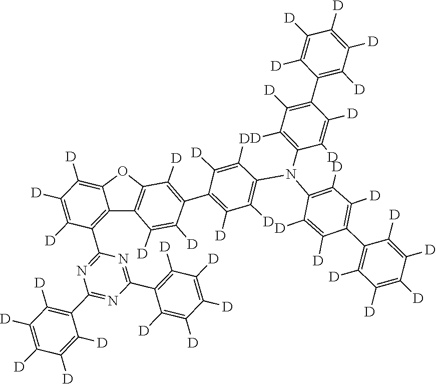 [SMILES: [2H]c1c([2H])c([2H])c(-c2nc(-c3c([2H])c([2H])c([2H])c([2H])c3[2H])nc(-c3c([2H])c([2H])c([2H])c4oc5c([2H])c(-c6c([2H])c([2H])c(N(c7c([2H])c([2H])c(-c8c([2H])c([2H])c([2H])c([2H])c8[2H])c([2H])c7[2H])c7c([2H])c([2H])c(-c8c([2H])c([2H])c([2H])c([2H])c8[2H])c([2H])c7[2H])c([2H])c6[2H])c([2H])c([2H])c5c34)n2)c([2H])c1[2H]] | 84% |
| A32 | 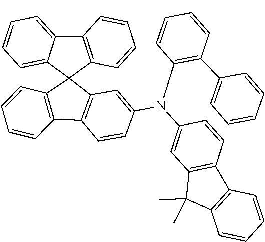 | 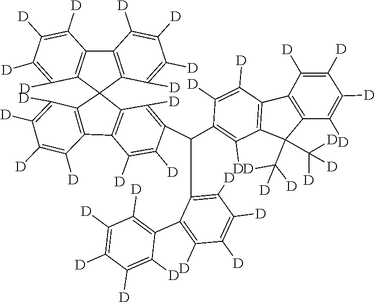 | 69% |

### <Preparation Example 4> Preparation of Compound A3

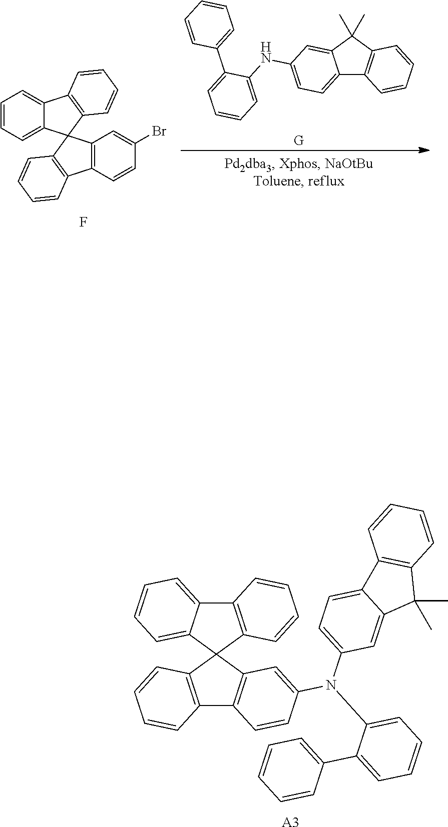

After 9 g (22.75 mmol) of a compound 2-bromo-9,9′-spirobi[9H-fluorene] (F), 8.63 g (23.88 mmol) of N-([1,1′-biphenyl]-2-yl)-9,9-dimethyl-9H-fluoren-2-amine (G), 1.04 g (1.14 mmol) of Pd₂dba₃, 1.08 g (2.27 mmol) of Xphos, and 4.37 g (45.49 mmol) of NaOtBu were dissolved in 100 mL of toluene, the resulting solution was refluxed at 130° C. for 4 hours.

After the reaction was completed, water was poured thereinto at room temperature, and then extraction was performed using DCM and distilled water. After the organic layer was treated with MgSO₄, the solvent was concentrated. After the residue was dissolved in DCM and the resulting solution was purified by silica chromatography, recrystallization was performed using DCM/methanol, and then 14 g (91%) of Target Compound A3 was obtained.

The following target compound was synthesized by performing synthesis in the same manner as in Preparation Example 4, except that in Preparation Example 4, Intermediate F in the following Table 4 was used instead of 2-bromo-9,9′-spirobi[9H-fluorene] (F) and Intermediate G in the following Table 4 was used instead of N-([1,1′-biphenyl]-2-yl)-9,9-dimethyl-9H-fluoren-2-amine (G).

TABLE 4

| Compound | Intermediate | Intermediate | |
|---|---|---|---|
| No. | F | G | Yield |
| A4 | 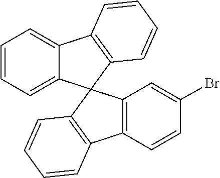 | 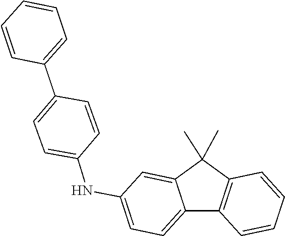 | 83% |
| A13 | 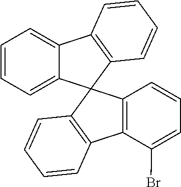 | 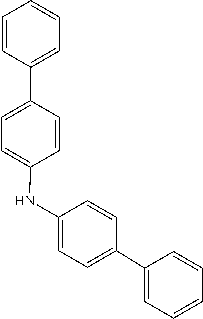 | 81% |
| A28 | 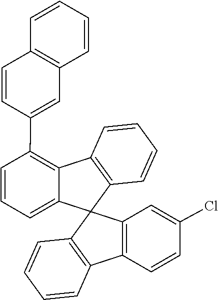 | 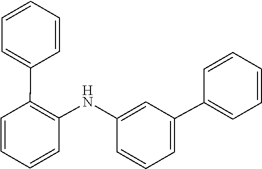 | 62% |

The following Tables 5 and 6 are the ¹H NMR data and FD-MS data of the synthesized compounds, and it can be confirmed through the following data that the desired compound was synthesized.

TABLE 5

| Compound No. | ¹H NMR (CDCl₃, 400 MHz) |
|---|---|
| 1 | δ = 8.55 (d, 1H), 8.36 (d, 2H), 8.28 (d, 1H), 8.11 (d, |
| | 1H), 7.94 (d, 2H), 7.82~7.69 (m, 4H), 7.57~7.35 (m, |
| | 12H), 7.16 (t, 1H) |
| 13 | δ = 8.36~8.28 (m, 6H), 8.13 (d, 1H), 8.11 (d, 1H), |
| | 7.94 (d, 1H), 7.89 (s, 1H), 7.82~7.69 (m, 6H), |
| | 7.57~7.40 (m, 13H), 7.31 (d, 1H) |
| 22 | δ = 9.09 (s, 1H), 8.55 (d, 1H), 8.49 (d, 1H), 8.36 (d, |
| | 2H), 8.28 (d, 1H), 8.16~7.31 (m, 21H), 7.16 (t, 1H) |
| 33 | δ = 8.36~8.28 (m, 6H), 8.13 (d, 1H), 8.11 (d, 1H), |
| | 7.94~7.69 (m, 9H), 7.55~7.40 (m, 12H), 7.31 (d, 1H) |
| 44 | δ = 8.55 (d, 1H), 8.36 (d, 2H), 8.28 (d, 1H), 8.11 (d, |
| | 1H), 8.03~7.94 (m, 5H), 7.82~7.69 (m, 6H), |
| | 7.55~7.25 (m, 13H), 7.16 (t, 1H) |
| 53 | δ = 8.36 (d, 4H), 8.30 (d, 1H), 8.28 (d, 1H), 8.13 (d, |
| | 1H), 8.11 (d, 1H), 7.94 (d, 1H), 7.89 (s, 1H), |
| | 7.82~7.69 (m, 6H), 7.55~7.40(m, 12H), 7.31 (d, 1H) |
| 65 | δ = 8.55 (d, 1H), 8.38~8.28 (m, 4H), 8.11 (d, 1H), |
| | 8.03~7.94 (m, 4H), 7.82~7.35(m, 18H), 7.25(d, 1H), |
| | 7.16 (t, 1H) |
| 73 | δ = 8.36~8.28 (m, 6H), 8.13 (d, 1H), 8.11 (d, 1H), |
| | 8.03 (d, 1H), 7.98 (d, 1H), 7.89(s, 1H), 7.82~7.69(m, |
| | 6H), 7.55~7.40 (m, 12H), 7.25 (d, 1H) |
| 83 | δ = 8.97 (d, 1H), 8.55 (d, 1H), 8.36~8.25 (m, 4H), |
| | 8.15~7.94 (m, 6H), 7.82~7.50 (m, 12H), 7.40 (s, 1H), |
| | 7.35 (t, 1H), 7.31 (d, 1H), 7.16 (t, 1H) |
| 93 | δ = 8.36~8.28 (m, 6H), 8.13 (d, 1H), 8.11 (d, 1H), |
| | 8.03 (d, 1H), 7.89 (s, 1H), 7.82~7.69 (m, 7H), 7. 61 (s, |
| | 1H), 7.55~7.40 (m, 11H), 7.31 (d, 1H) |
| 106 | δ = 9.09 (s, 2H), 8.55 (d, 1H), 8.49 (d, 2H), 8.28 (d, |
| | 1H), 8.16~7.94 (m, 9H), 7.82~7.52 (m, 11H), 7.40 (s, |
| | 1H), 7.35 (t, 1H), 7.25 (d, 1H), 7.16 (t, 1H) |
| 113 | δ = 8.36~8.28 (m, 6H), 8.13 (d, 1H), 8.11 (d, 1H), |
| | 8.03 (d, 1H), 7.89 (s, 1H), 7.82~7.69 (m, 6H), |
| | 7.55~7.40 (m, 13H), 7.25 (d, 1H) |
| 130 | δ = 8.55 (d, 1H), 8.36~8.28 (m, 3H), 8.11 (d, 1H), |
| | 8.08 (d, 1H), 7.98~7.69 (m, 7H), 7.57~7.51 (m, 9H), |
| | 7.40~7.25 (m, 5H), 7.16 (t, 1H) |
| 133 | δ = 8.36~8.28 (m, 6H), 8.13~8.08 (m, 3H), 7.89 (s, 1H), |
| | 7.88 (d, 1H), 7.75~7.69 (m, 4H), 7.55~7.40 (m, 14H), |
| | 7.25 (d, 1H) |
| 153 | δ = 8.55 (d, 2H), 8.36 (d, 4H), 7.99~7.79(m, 5H), |
| | 7.65~7.50 (m, 12H), 7.35 (t, 1H), 7.16 (t, 1H), |
| 157 | δ = 8.97 (d, 1H), 8.55 (d, 1H), 8.36 (m, 4H), 8.12 (d, |
| | 1H), 7.94~7.79 (m, 6H), 7.59~7.35 (m, 15H), 7.25 (d, |
| | 1H) <7.16 (s, 1H) |
| 172 | δ = 8.55 (d, 2H), 8.36 (d, 2H), 8.28 (d, 1H), 8.19 (d, |
| | 1H), 8.11~8.08 (m, 2H), 7.94 (d, 2H), 7.88 (d, 1H), |
| | 7.75~7.69 (m, 3H), 7.61~7.50 (m, 8H), 7.40 (s, 1H), |
| | 7.35 (t, 2H), 7.16 (t, 3H) |
| 176 | δ = 8.95 (d, 1H), 8.50 (d, 1H), 8.36~8.28 (m, 6H), |
| | 8.20~8.08 (m, 5H), 7.89 (s, 1H), 7.88 (d, 1H), |
| | 7.77~7.69 (m, 4H), 7.55~7.50 (m, 9H), 7.40 (s, 1H), |
| | 7.39 (t, 1H), 7.31 (d, 1H) |
| 181 | δ = 8.55 (d, 1H), 8.36 (d, 4H), 8.28 (d, 1H), 8.11 (d, |
| | 1H), 7.94~7.69 (m, 7H), 7.61 (s, 1H), 7.55 (s, 1H), |
| | 7.50 (t, 6H), 7.40 (s, 1H), 7.35 (t, 1H), 7.31 (d, 1H), |
| | 7.16 (t, 1H) |
| 195 | δ = 8.55 (d, 1H), 8.36 (d, 4H), 8.28 (d, 1H), 8.19(d, |
| | 1H), 8.11 (d, 1H), 8.08 (d, 1H), 7.94~7.67 (m, 9H), |
| | 7.61~7.50 (m, 10H), 7.40 (s, 1H), 7.35 (t, 1H), 7.31 (d, |
| | 1H), 7.20 (t, 1H), 7.16 (t, 1H) |
| 213 | δ = 8.36~8.28 (m, 6H), 8.13 (d, 1H), 8.11 (d, 1H), |
| | 7.89 (s, 1H), 7.82~7.69 (m, 7H), 7.61~7.40 (m, 13H), |
| | 7.31 (d, 1H) |
| 223 | δ = 8.97 (d, 1H), 8.55 (d, 1H), 8.36~8.25 (m, 4H), |
| | 8.15~7.88 (m, 8H), 7.75~7.50 (m, 10H), 7.40 (s, 1H), |
| | 7.35 (t, 1H), 7.25 (d, 1H), 7.16 (t, 1H) |
| 236 | δ = 8.36~8.28 (m, 6H), 8.13~7.98 (m, 7H), 7.89 (s, 1H), |
| | 7.88 (d, 1H), 7.75~7.50 (m, 14H), 7.40 (s, 1H), 7.38 (d, |
| | 1H), 7.25 (d, 1H) |
| 247 | δ = 8.55 (d, 1H), 8.38~8.28(m, 4H), 8.06~7.50(m, |
| | 22H), 7.40 (s, 1H), 7.38 (d, 1H), 7.35 (t, 1H) |
| 256 | δ = 8.36~8.28 (m, 6H), 8.13 (d, 1H), 8.11 (d, 1H), |
| | 7.98 (d, 1H), 7.89~7.69 (m, 8H), 7.55~7.40 (m, 12H), |
| | 7.25 (m, 5H) |
| 261 | δ = 8.55 (d, 1H), 8.36 (d, 4H), 8.28 (d, 1H), 8.11 (d, |
| | 1H), 7.98 (d, 1H), 7.94 (d, 1H), 7.82~7.69 (m, 4H), |
| | 7.57~7.50 (m, 9H), 7.40 (s, 1H), 7.35(t, 1H), 7.25 (d, |
| | 1H), 7.16 (t, 1H) |
| 262 | δ = 9.09 (s, 1H), 8.55 (d, 1H), 8.49 (d, 1H), 8.36 (d, |
| | 2H), 8.28 (d, 1H), 8.16~7.94 (m, 6H), 7. 82~7.50 (m, |
| | 12H), 7.40 (s, 1H), 7.35 (t, 1H), 7.25 (d, 1H), 7.16 (t, |
| | 1H) |
| 275 | δ = 8.55 (d, 1H), 8.23 (d, 1H), 8.23 (s, 1H), 8.11 (d, |
| | 1H), 7.98~7.94 (m, 6H), 7.82~7.69 (m, 4H), |
| | 7.57~7.49 (m, 9H), 7.40 (s, 1H), 7.35 (t, 1H), 7.25 (d, |
| | 1H), 7.16 (t, 1H) |
| 276 | δ = 8.55 (d, 1H), 8.28 (d, 1H), 8.11~7.93 (m, 5H), |
| | 7.84~7.69 (m, 6H), 7.57~7.40 (m, 10H), 7.25(d, 1H), |
| | 7.16 (t, 1H) |
| 278 | δ = 8.55 (d, 1H), 8.30 (d, 2H), 8.28 (d, 1H), 8.13 (d, |
| | 1H), 8.11 (d, 1H), 7.98 (d, 1H), 7.94 (d, 1H), |
| | 7.85~7.69 (m, 10H), 7.58~7.35 (m, 9H), 7.25 (d, 1H), |
| | 7.16 (t, 1H) |
| 281 | δ = 8.36~8.28 (m, 6H), 8.13 (d, 1H), 8.11 (d, 1H), |
| | 7.98 (d, 1H), 7.89(s, 1H), 7.82~7.69(m, 6H), |
| | 7.57~7.40 (m, 13H), 7.25 (d, 1H) |
| 294 | δ = 8.46 (s, 1H), 8.35~8.23 (m, 5H), 8.13~7.98 (m, 7H), |
| | 7.89 (s, 1H), 7.82~7.41 (m, 18H), 7.25 (d, 1H) |
| 297 | δ = 8.30 (d, 1H), 8.28 (d, 1H), 8.13 (d, 1H), 8.11 (d, |
| | 1H), 7.98 (d, 1H), 7.89~7.36(m, 22H), 7.25 (d, 1H), |
| | 7.22 (t, 1H) |
| 299 | δ = 8.30~8.28 (m, 3H), 8.13~7.98 (m, 5H), |
| | 7.80~7.25 (m, 20H) |
| 301 | δ = 8.55 (d, 1H), 8.36 (d, 4H), 8.28 (d, 1H), 8.11 (d, |
| | 1H), 8.03 (d, 1H), 7.94~7.91 (m, 5H), 7.82~7.69 (m, |
| | 6H), 7.57~7.50 (m, 8H), 7.40 (s, 1H), 7.35 (t, 1H), |
| | 7.16 (t, 1H) |
| 305 | δ = 9.02 (d, 1H), 8.95 (d, 1H), 8.55 (d, 1H), 8.36 (d, |
| | 4H), 8.28 (d, 1H), 8.11(d, 1H), 8.06(d, 1H), 7.98 (d, |
| | 1H), 7.94 (d, 1H), 7.84~7.69 (m, 5H), 7.57~7. 35 (m, |
| | 13H), 7.25 (d, 1H), 7.16 (t, 1H) |
| 313 | δ = 8.36 (d, 4H), 7.98 (d, 1H), 7.87 (d, 1H), 7.69 (d, |
| | 1H), 7.57~7.50 (m, 8H), 7.25 (d, 1H) |
| 315 | δ = 8.36 (d, 4H), 7.98 (d, 1H), 7.82 (d, 1H), 7.69(d, |
| | 1H), 7.57~7.50 (m, 8H), 7.25 (d, 1H) |
| 316 | δ = 8.36 (d, 4H), 7.50 (t, 6H) |
| 318 | δ = 8.30 (d, 1H), 8.28 (d, 1H), 8.13(d, 1H), 8.11 (d, |
| | 1H), 7.94~7.69 (m, 8H), 7.57~7.40 (m, 7H), |
| | 7.31 (d, 1H) |
| 328 | δ = 8.15 (d, 1H), 7.98~7.91 (m, 4H), |
| | 7.73~7.65 (m, 6H), 7.55~7.40 (m, 6H) |
| 330 | δ = 9.09 (s, 1H), 8.49 (d, 1H), 8.36 (d, 2H), |
| | 8.16~8.00 (m, 4H), 7.88 (d, 1H), 7.61~7.50 (m, 8H), |
| | 7.25 (d, 1H) |
| 342 | δ = 8.36 (d, 4H), 8.03 (d, 1H), 7.82~7.69(m, 6H), |
| | 7.57~7.37 (m, 18H), 7.24 (t, 2H), 7.08 (d, 2H), 7.00 (t, |
| | 1H) |
| 344 | δ = 8.36 (d, 4H), 8.22 (s, 1H), 8.03 (s, 1H), 7.98 (d, |
| | 1H), 7.82~7.69 (m, 5H), 7.57~7.31 (m, 18H), 6.97 (d, |
| | 1H), 6.91 (d, 1H) |
| 349 | δ = 8.36 (d, 4H), 8.03 (s, 1H), 7.96 (d, 2H), |
| | 7.82~7.79 (m, 4H), 7.69(d, 1H), 7.60~7.41 (m, 13H), |
| | 7.27~7.18 (m, 5H), 7.08(d, 2H), 7.00 (t, 1H), 6.91 (d, |
| | 1H) |
| 369 | δ = 8.36 (d, 4H), 8.03 (d, 1H), 7.82 (d, 2H), 7.76 (s, |
| | 1H), 7.69 (d, 1H), 7.57~7.50 (m, 7H) |
| A3 | δ = 8.10 (d, 1H), 7.90~7.86 (m, 6H), 7.55 (d, 2H), |
| | 7.43~7.27 (m, 17H), 7.16~7.08 (m, 5H), 1.69 (s, 6H) |
| A4 | δ = 7.90~7.86 (m, 6H), 7.75 (d, 2H), 7.55~7.27 (m, |
| | 21H), 7.16 (d, 2H), 1.69 (s, 6H) |
| A13 | δ = 7.90~7.89 (m, 3H), 7.75 (d, 4H), |
| | 7.55~7.24 (m, 24H) |
| A28 | δ = 8.10~7.99 (m, 4H), 7.90~7.75 (m, 6H), |
| | 7.63~7.06 (m, 29H) |

TABLE 6

| Compound | FD-Mass | Compound | FD-Mass |
|---|---|---|---|
| 1 | m/z = 614.71 | 13 | m/z = 690.81 |
| | (C43H26N4O, 614.21) | | (C49H30N4O, 690.24) |
| 22 | m/z = 664.77 | 33 | m/z = 690.81 |
| | (C47H28N4O, 664.23) | | (C49H30N4O, 690.24) |
| 44 | m/z = 690.81 | 53 | m/z = 690.81 |
| | (C49H30N4O, 690.24) | | (C49H30N4O, 690.24) |
| 65 | m/z = 690.81 | 73 | m/z = 690.81 |
| | (C49H30N4O, 690.24) | | (C49H30N4O, 690.24) |
| 83 | m/z = 664.77 | 93 | m/z = 690.81 |
| | (C47H28N4O, 664.23) | | (C49H30N4O, 690.24) |
| 106 | m/z = 714.83 | 113 | m/z = 690.81 |
| | (C51H30N4O, 714.24) | | (C49H30N4O, 690.24) |
| 130 | m/z = 704.79 | 133 | m/z = 690.81 |
| | (C49H28N4O2, 704.22) | | (C49H30N4O, 690.24) |
| 153 | m/z = 614.71 | 157 | m/z = 690.81 |
| | (C43H26N4O, 614.21) | | (C49H30N4O, 690.24) |
| 172 | m/z = 703.80 | 176 | m/z = 740.87 |
| | (C49H29N5O, 703.24) | | (C53H32N4O, 740.26) |
| 181 | m/z = 614.71 | 195 | m/z = 779.90 |
| | (C43H26N4O, 614.21) | | (C55H33N5O, 779.27) |
| 213 | m/z = 690.81 | 223 | m/z = 664.77 |
| | (C49H30N4O, 690.24) | | (C47H28N4O, 664.23) |
| 236 | m/z = 740.87 | 247 | m/z = 740.87 |
| | (C53H32N4O, 740.26) | | (C53H32N4O, 740.26) |
| 256 | m/z = 766.90 | 261 | m/z = 614.71 |
| | (C55H34N4O, 766.27) | | (C43H26N4O, 614.21) |
| 262 | m/z = 664.77 | 275 | m/z = 613.72 |
| | (C47H28N4O, 664.23) | | (C44H27N3O, 613.22) |
| 276 | m/z = 643.76 | 278 | m/z = 663.78 |
| | (C44H25N3OS, 643.17) | | (C48H29N3O, 663.23) |
| 281 | m/z = 690.81 | 294 | m/z = 739.88 |
| | (C49H30N4O, 690.24) | | (C54H33N3O, 739.26) |
| 297 | m/z = 703.80 | 299 | m/z = 663.78 |
| | (C50H29N3O2, 703.23) | | (C48H29N3O, 663.23) |
| 301 | m/z = 690.81 | 305 | m/z = 740.87 |
| | (C49H30N4O, 690.24) | | (C53H32N4O, 740.26) |
| 313 | m/z = 704.89 | 315 | m/z = 624.77 |
| | (C49H16D14N4O, 704.33) | | (C43H16D10N4O, |
| | | | 624.27) |
| 316 | m/z = 630.81 | 318 | m/z = 700.87 |
| | (C43H10D16N4O, 630.31) | | (C49H20D10N4O, |
| | | | 700.30) |
| 321 | m/z = 640.87 | 322 | m/z = 720.99 |
| | (C43D26N4O, 640.37) | | (C49D30N4O, 720.43) |
| 327 | m/z = 720.99 | 328 | m/z = 623.76 |
| | (C49D30N4O, 720.43) | | (C43H17D9N4O, 623.27) |
| 330 | m/z = 674.83 | 342 | m/z = 718.86 |
| | (C47H18D10N4O, 674.29) | | (C51H34N4O, 718.27) |
| 344 | m/z = 732.84 | 349 | m/z = 718.86 |
| | (C51H32N4O2. 732.25) | | (C51H34N4O, 718.27) |
| 369 | m/z = 736.97 | 374 | m/z = 833.19 |
| | (C51H16D18N4O, 736.39) | | (C57D38N4O, 832.54) |
| A3 | m/z = 675.88 (C52H37N, | A4 | m/z = 675.88 (C52H37N, |
| | 675.29) | | 675.29) |
| A13 | m/z = 635.81 (C49H33N, | A28 | m/z = 761.97 (C59H39N, |
| | 635.26) | | 761.31) |
| A32 | m/z = 713.10 (C52D37N, | | |
| | 712.52) | | |

### <Example 1> Manufacture of Organic Light Emitting Device

A glass substrate, in which ITO was thinly coated to have a thickness of 1,200 Å, was ultrasonically washed with distilled water and soap for a substrate. When the washing with distilled water was finished, the glass substrate was ultrasonically washed with a solvent such as acetone, methanol, and isopropyl alcohol, dried and then was subjected to UVO treatment for 5 to 15 minutes using UV in a UV cleaning machine. Thereafter, the substrate was transferred to a plasma washing machine (PT), and then was subjected to plasma treatment in a vacuum state for an ITO surface treatment and in order to remove a residual film, and was transferred to a thermal deposition apparatus for organic deposition.

50 Å of a hole injection layer 4,4′,4″-tris[2-naphthyl(phenyl)amino]triphenylamine (2-TNATA) and 1200 Å of a hole transport layer A3, which are common layers, were formed on the ITO transparent electrode (positive electrode). A light emitting layer was thermally vacuum deposited thereon as follows. The light emitting layer was deposited to have a thickness of 150 Å by depositing Compound 1 described in the following Table 7 as a red host and doping a host with an Ir compound at 1 to 3 wt % using (piq)₂(Ir)_{(acac)} as a red phosphorescent dopant.

Thereafter, a yellow phosphorescent light emitting layer and a green phosphorescent light emitting layer, which were adjacent, were deposited. The yellow light emitting layer was deposited to have a thickness of 120 Å by doping a host Bepp₂ at 15 to 25 wt % using Ir(dmppy)₂(dpp) as a dopant, and the green light emitting layer was deposited to have a thickness of 250 Å by doping a host CBP at 5 to 10 wt % using Ir(ppy)₃ as a dopant. Bphen as a hole blocking layer was deposited to have a thickness of 30 Å, and Alq₃ as an electron transport layer was deposited to have a thickness of 250 Å thereon. Finally, an organic light emitting device was manufactured by depositing lithium fluoride (LiF) to have a thickness of 10 Å on the electron transport layer to form an electron injection layer, and then depositing an aluminum (Al) negative electrode to have a thickness of 1,000 Å on the electron injection layer to form a negative electrode.

### <Examples 2 to 56> Manufacture of Organic Light Emitting Device

An organic light emitting device was manufactured in the same manner as in Example 1, except that each compound for forming the hole transport layer and the light emitting layer was changed as shown in the following Table 7.

### <Comparative Examples 1 to 36> Manufacture of Organic Light Emitting Device

An organic light emitting device was manufactured in the same manner as in Example 1, except that each compound for forming the hole transport layer and the light emitting layer was changed as shown in the following Table 7.

For the organic light emitting device manufactured as described above, electroluminescence (EL) characteristics were measured by M7000 manufactured by McScience Inc., and based on the measurement result thereof, T₉₀ was measured by a service life measurement device (M6000) manufactured by McScience Inc., when the reference luminance was 6,000 cd/m². The characteristics of the organic light emitting device of the present invention are as shown in the following Table 7.

Each of the compounds R-1, R-2, R-3, R-4, R-5 and H-1 used in the following Table 7 is as follows.

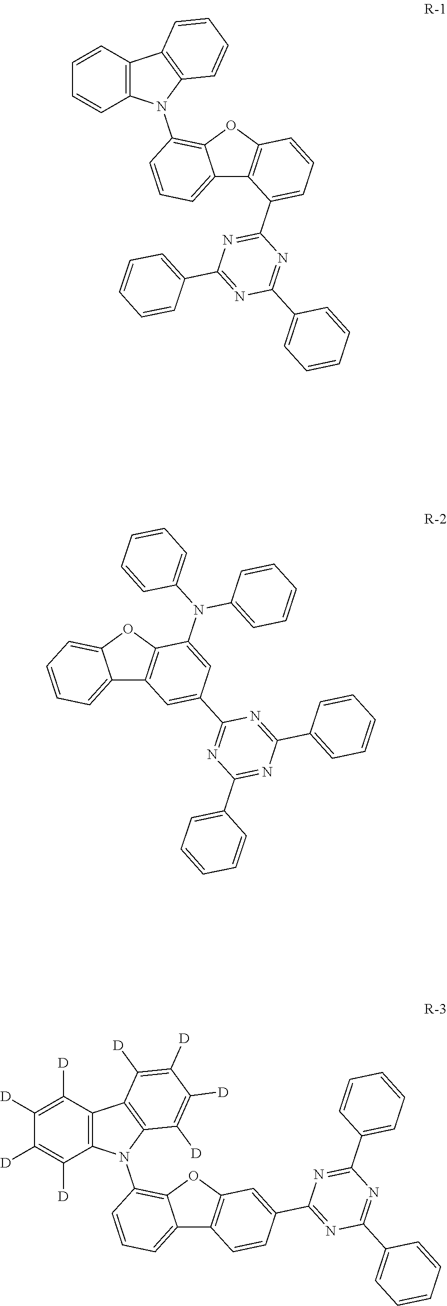 [SMILES: c1ccc(-c2nc(-c3ccccc3)nc(-c3cccc4oc5c(-n6c7ccccc7c7ccccc76)cccc5c34)n2)cc1 ; c1ccc(-c2nc(-c3ccccc3)nc(-c3cc(N(c4ccccc4)c4ccccc4)c4oc5ccccc5c4c3)n2)cc1 ; [2H]c1c([2H])c([2H])c2c(c1[2H])c1c([2H])c([2H])c([2H])c([2H])c1n2-c1cccc2c1oc1cc(-c3nc(-c4ccccc4)nc(-c4ccccc4)n3)ccc12]

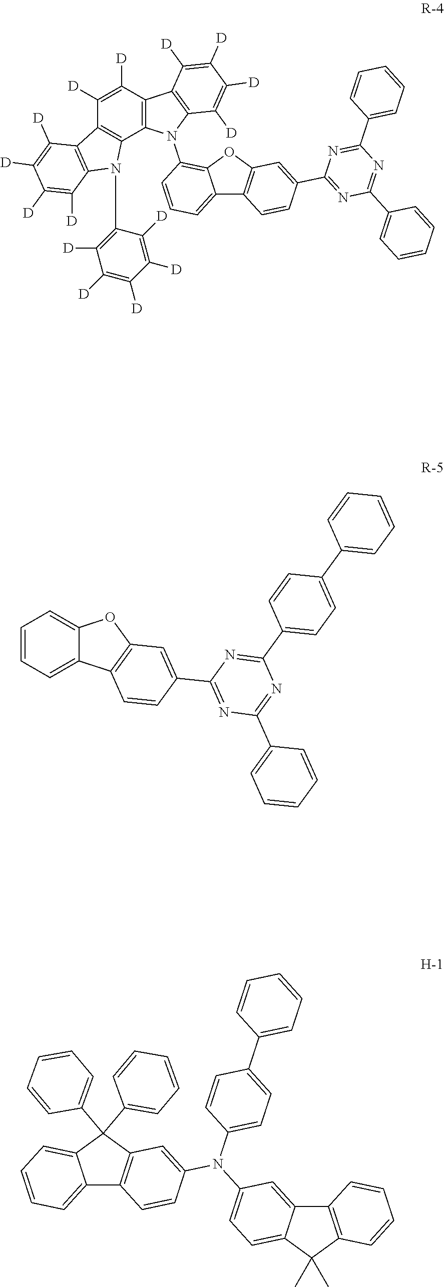 [SMILES: [2H]c1c([2H])c([2H])c(-n2c3c([2H])c([2H])c([2H])c([2H])c3c3c([2H])c([2H])c4c5c([2H])c([2H])c([2H])c([2H])c5n(-c5cccc6c5oc5cc(-c7nc(-c8ccccc8)nc(-c8ccccc8)n7)ccc56)c4c32)c([2H])c1[2H] ; c1ccc(-c2ccc(-c3nc(-c4ccccc4)nc(-c4ccc5c(c4)oc4ccccc45)n3)cc2)cc1 ; CC1(C)c2ccccc2-c2cc(N(c3ccc(-c4ccccc4)cc3)c3ccc4c(c3)C(c3ccccc3)(c3ccccc3)c3ccccc3-4)ccc21]

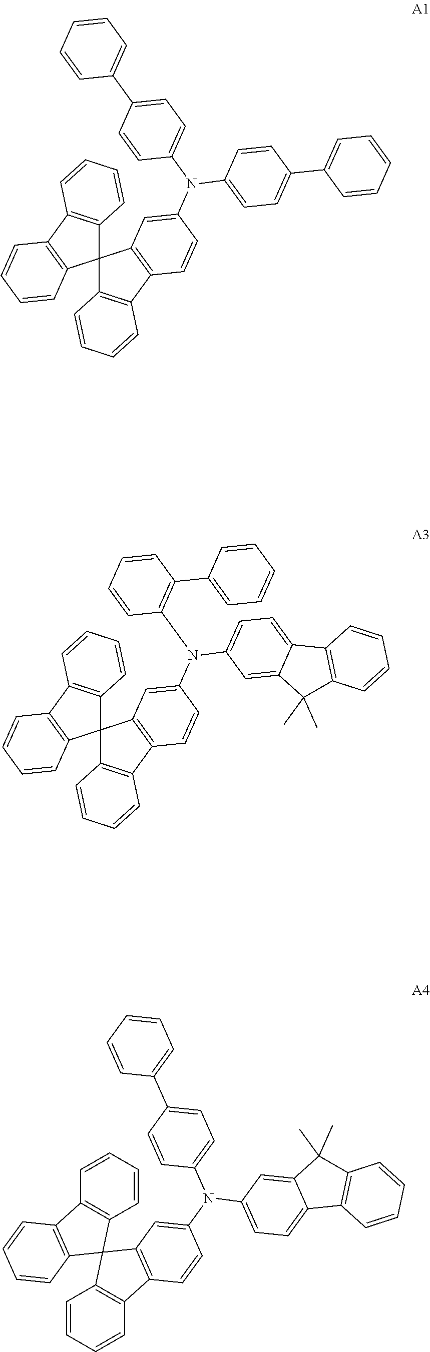 [SMILES: c1ccc(-c2ccc(N(c3ccc(-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc4c(c3)C3(c5ccccc5-c5ccccc53)c3ccccc3-4)c3ccccc3-c3ccccc3)cc21 ; CC1(C)c2ccccc2-c2ccc(N(c3ccc(-c4ccccc4)cc3)c3ccc4c(c3)C3(c5ccccc5-c5ccccc53)c3ccccc3-4)cc21]

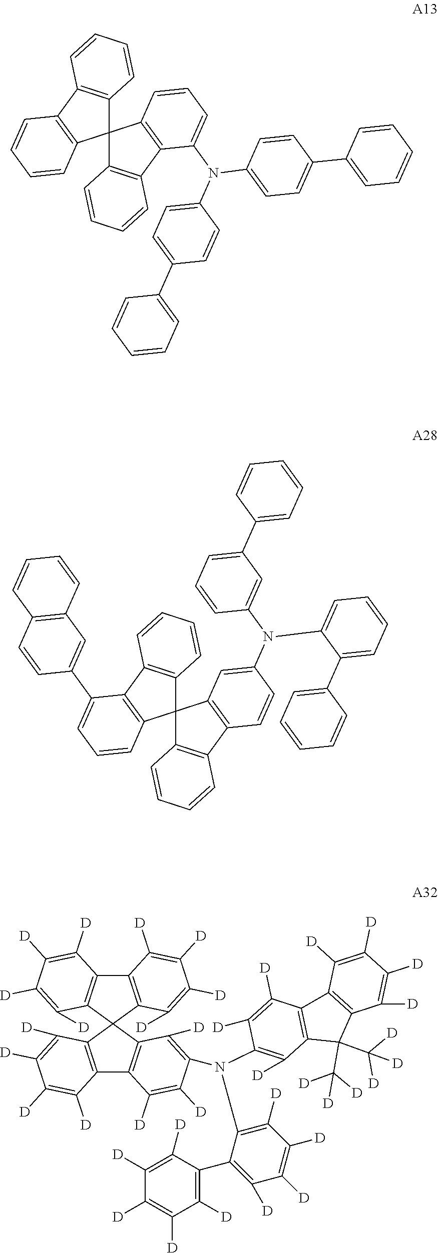 [SMILES: c1ccc(-c2ccc(N(c3ccc(-c4ccccc4)cc3)c3cccc4c3-c3ccccc3C43c4ccccc4-c4ccccc43)cc2)cc1 ; c1ccc(-c2cccc(N(c3ccc4c(c3)C3(c5ccccc5-4)c4ccccc4-c4c(-c5ccc6ccccc6c5)cccc43)c3ccccc3-c3ccccc3)c2)cc1 ; [2H]c1c([2H])c([2H])c(-c2c([2H])c([2H])c([2H])c([2H])c2N(c2c([2H])c([2H])c3c(c2[2H])C2(c4c([2H])c([2H])c([2H])c([2H])c4-c4c([2H])c([2H])c([2H])c([2H])c42)c2c([2H])c([2H])c([2H])c([2H])c2-3)c2c([2H])c([2H])c3c(c2[2H])C(C([2H])([2H])[2H])(C([2H])([2H])[2H])c2c([2H])c([2H])c([2H])c([2H])c2-3)c([2H])c1[2H]]

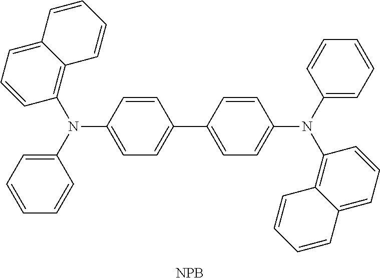 [SMILES: c1ccc(N(c2ccc(-c3ccc(N(c4ccccc4)c4cccc5ccccc45)cc3)cc2)c2cccc3ccccc23)cc1 ; "NPB"]

TABLE 7

| | Hole | Light | | | |
|---|---|---|---|---|---|
| | transport | emitting | Driving | | Service |
| | layer | layer | voltage | Efficiency | life |
| No. | Compound | Compound | (V) | (cd/A) | (T₉₀) |
| Example 1 | A3 | 1 | 4.18 | 55.67 | 121 |
| Example 2 | A4 | 13 | 4.15 | 57.21 | 123 |
| Example 3 | A13 | 22 | 4.20 | 55.93 | 115 |
| Example 4 | A28 | 22 | 4.33 | 50.01 | 99 |
| Example 5 | A4 | 33 | 4.14 | 57.02 | 117 |
| Example 6 | A3 | 44 | 4.13 | 53.86 | 118 |
| Example 7 | A32 | 44 | 4.13 | 53.14 | 122 |
| Example 8 | A4 | 53 | 4.11 | 54.24 | 118 |
| Example 9 | A13 | 65 | 4.21 | 54.30 | 109 |
| Example 10 | A1 | 73 | 4.20 | 55.01 | 108 |
| Example 11 | A3 | 83 | 4.27 | 49.98 | 110 |
| Example 12 | A4 | 93 | 4.24 | 51.07 | 109 |
| Example 13 | A3 | 106 | 4.17 | 58.22 | 117 |
| Example 14 | A3 | 113 | 4.14 | 60.03 | 115 |
| Example 15 | A32 | 113 | 4.13 | 58.97 | 130 |
| Example 16 | A4 | 130 | 4.13 | 59.00 | 120 |
| Example 17 | A4 | 133 | 4.11 | 61.88 | 118 |
| Example 18 | A3 | 153 | 4.34 | 50.01 | 102 |
| Example 19 | A4 | 157 | 4.38 | 49.42 | 105 |
| Example 20 | A3 | 172 | 4.38 | 48.97 | 100 |
| Example 21 | A3 | 176 | 4.36 | 49.34 | 102 |
| Example 22 | A13 | 181 | 4.37 | 48.64 | 109 |
| Example 23 | A3 | 195 | 4.36 | 52.11 | 105 |
| Example 24 | A13 | 213 | 4.32 | 49.99 | 112 |
| Example 25 | A13 | 223 | 4.38 | 49.02 | 114 |
| Example 26 | A3 | 236 | 4.37 | 50.01 | 113 |
| Example 27 | A3 | 247 | 4.39 | 48.20 | 101 |
| Example 28 | A4 | 256 | 4.38 | 47.99 | 112 |
| Example 29 | A3 | 261 | 4.07 | 58.67 | 145 |
| Example 30 | A4 | 261 | 4.08 | 57.13 | 139 |
| Example 31 | A3 | 262 | 4.04 | 60.12 | 140 |
| Example 32 | A3 | 275 | 4.10 | 56.97 | 124 |
| Example 33 | A4 | 276 | 4.18 | 58.21 | 121 |
| Example 34 | A4 | 278 | 4.13 | 59.03 | 125 |
| Example 35 | A3 | 281 | 4.06 | 62.88 | 140 |
| Example 36 | A3 | 294 | 4.04 | 63.21 | 132 |
| Example 37 | A3 | 297 | 4.16 | 59.66 | 125 |
| Example 38 | A4 | 299 | 4.14 | 59.22 | 127 |
| Example 39 | A3 | 301 | 4.03 | 50.20 | 104 |
| Example 40 | A4 | 305 | 4.33 | 58.32 | 103 |
| Example 41 | A4 | 313 | 3.98 | 61.97 | 173 |
| Example 42 | A4 | 315 | 4.05 | 58.71 | 170 |
| Example 43 | A4 | 316 | 4.03 | 57.94 | 171 |
| Example 44 | A3 | 318 | 4.12 | 56.77 | 123 |
| Example 45 | A3 | 321 | 3.96 | 60.94 | 175 |
| Example 46 | A3 | 322 | 3.97 | 60.58 | 174 |
| Example 47 | A13 | 327 | 4.13 | 57.77 | 166 |
| Example 48 | A4 | 328 | 4.20 | 55.01 | 152 |
| Example 49 | A4 | 330 | 4.11 | 61.88 | 149 |
| Example 50 | A3 | 342 | 4.08 | 60.13 | 103 |
| Example 51 | A4 | 342 | 4.10 | 59.87 | 102 |
| Example 52 | A3 | 344 | 4.10 | 59.21 | 104 |
| Example 53 | A13 | 344 | 4.15 | 58.62 | 98 |
| Example 54 | A3 | 349 | 4.25 | 58.61 | 100 |
| Example 55 | A4 | 369 | 4.07 | 59.24 | 135 |
| Example 56 | A4 | 374 | 4.08 | 60.11 | 141 |
| Comparative | NPB | R-1 | 5.31 | 28.10 | 59 |
| Example 1 | | | | | |
| Comparative | | R-2 | 4.95 | 32.01 | 48 |
| Example 2 | | | | | |
| Comparative | | R-3 | 5.29 | 26.23 | 61 |
| Example 3 | | | | | |
| Comparative | | R-4 | 5.33 | 24.85 | 62 |
| Example 4 | | | | | |
| Comparative | | R-5 | 4.81 | 26.77 | 24 |
| Example 5 | | | | | |
| Comparative | A3 | R-1 | 4.80 | 31.35 | 74 |
| Example 6 | | | | | |
| Comparative | A4 | | 4.78 | 32.18 | 76 |
| Example 7 | | | | | |
| Comparative | A13 | | 4.83 | 31.35 | 73 |
| Example 8 | | | | | |
| Comparative | A3 | R-2 | 4.57 | 38.10 | 65 |
| Example 9 | | | | | |
| Comparative | A4 | | 4.52 | 39.22 | 69 |
| Example 10 | | | | | |
| Comparative | A13 | | 4.60 | 37.98 | 61 |
| Example 11 | | | | | |
| Comparative | A3 | R-3 | 4.91 | 30.74 | 82 |
| Example 12 | | | | | |
| Comparative | A3 | R-4 | 5.02 | 33.12 | 79 |
| Example 13 | | | | | |
| Comparative | A4 | R-4 | 4.97 | 35.07 | 78 |
| Example 14 | | | | | |
| Comparative | A13 | R-4 | 5.11 | 32.96 | 79 |
| Example 15 | | | | | |
| Comparative | A4 | R-5 | 4.72 | 39.04 | 30 |
| Example 16 | | | | | |
| Comparative | NPB | 1 | 4.67 | 34.25 | 91 |
| Example 17 | | | | | |
| Comparative | | 13 | 4.68 | 36.11 | 90 |
| Example 18 | | | | | |
| Comparative | | 22 | 4.71 | 35.23 | 84 |
| Example 19 | | | | | |
| Comparative | | 33 | 4.70 | 36.08 | 87 |
| Example 20 | | | | | |
| Comparative | | 53 | 4.64 | 35.22 | 86 |
| Example 21 | | | | | |
| Comparative | | 65 | 4.74 | 35.26 | 78 |
| Example 22 | | | | | |
| Comparative | | 83 | 4.81 | 32.34 | 76 |
| Example 23 | | | | | |
| Comparative | | 106 | 4.69 | 37.11 | 94 |
| Example 24 | | | | | |
| Comparative | | 133 | 4.67 | 37.21 | 96 |
| Example 25 | | | | | |
| Comparative | | 176 | 4.80 | 33.41 | 80 |
| Example 26 | | | | | |
| Comparative | | 181 | 4.79 | 33.54 | 83 |
| Example 27 | | | | | |
| Comparative | | 236 | 4.79 | 33.87 | 79 |
| Example 28 | | | | | |
| Comparative | | 261 | 4.63 | 40.12 | 88 |
| Example 29 | | | | | |
| Comparative | | 262 | 4.62 | 39.12 | 89 |
| Example 30 | | | | | |
| Comparative | | 281 | 4.58 | 41.21 | 84 |
| Example 31 | | | | | |
| Comparative | | 313 | 4.63 | 40.12 | 87 |
| Example 32 | | | | | |
| Comparative | | 322 | 4.52 | 41.22 | 90 |
| Example 33 | | | | | |
| Comparative | | 328 | 4.48 | 43.01 | 82 |
| Example 34 | | | | | |
| Comparative | H-1 | 342 | 4.49 | 39.37 | 81 |
| Example 35 | | | | | |
| Comparative | | 374 | 4.51 | 40.14 | 91 |
| Example 36 | | | | | |

Table 7 shows the basic characteristics of the organic light emitting devices (Comparative Examples 1 to 5) in which existing compounds are used, the organic light emitting devices (Comparative Examples 6 to 16) in which the compound represented by Chemical Formula 2 is used as a hole transport layer, but an existing compound is used as a material for the light emitting layer, and the organic light emitting devices (Comparative Examples 17 to 36) in which the compound represented by Chemical Formula 1 is used as a material for the light emitting layer, but an existing compound is used as a material for the hole transport layer.

Comparing the example group and the comparative example group, it was confirmed that when the compounds represented by Chemical Formulae 1 and 2 are used as materials for the light emitting layer and the hole transport layer, respectively, the example group and the comparative example group exhibit lower driving voltage, higher efficiency, and longer service life than existing organic light emitting devices. Meanwhile, when Comparative Examples 1 to 16 are compared, Comparative Examples 6 to 16, in which the compounds represented by Chemical Formula 2 were used, had improved efficiency and service life compared to Comparative Examples 1 to 5, in which existing compounds were used as materials for the hole transport layer. However, it was not possible to exhibit the efficiency and service life at the levels of the examples.

The organic light emitting device of the present invention includes a compound having an arylamine-substituted structure including spirobifluorene as shown in Chemical Formula 2 between the positive electrode and the light emitting layer to provide the device with appropriate hole mobility, thereby exhibiting more improved efficiency.

Furthermore, it was confirmed that a structure such as Chemical Formula 1 with hole stability by substituting one side of the dibenzofuran structure with a nitrogen-containing ring having the ability to inject electrons and introducing a carbazole or amine group fused to the other unsubstituted benzene ring exhibits long service life while exhibiting low driving voltage and improved efficiency by providing an appropriate energy level to the device.

What is claimed is:

1. An organic light emitting device comprising:
a first electrode;
a second electrode provided to face the first electrode; and
an organic material layer having one or more layers provided between the first electrode and the second electrode,
wherein the organic material layer comprises a light emitting layer and a hole transport layer,
the light emitting layer comprises a heterocyclic compound represented by the following Chemical Formula 1, and
the hole transport layer comprises a compound represented by the following Chemical Formula 2: 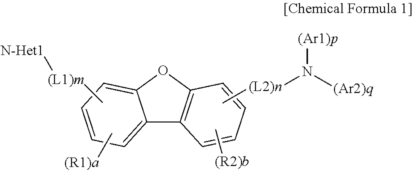
in Chemical Formula 1,
R1 and R2 are the same as or different from each other, and are each independently selected from the group consisting of hydrogen; deuterium; a halogen; —CN; a substituted or unsubstituted C1 to C60 alkyl group; a substituted or unsubstituted C2 to C60 alkenyl group; a substituted or unsubstituted C2 to C60 alkynyl group; a substituted or unsubstituted C1 to C60 alkoxy group; a substituted or unsubstituted C3 to C60 cycloalkyl group; a substituted or unsubstituted C2 to C60 heterocycloalkyl group; a substituted or unsubstituted C6 to C60 aryl group; a substituted or unsubstituted C2 to C60 heteroaryl group; —P(═O)RR′; and —SiRR′R″,
L1 and L2 are the same as or different from each other, and are each independently a direct bond; a substituted or unsubstituted C6 to C60 arylene group; or a substituted or unsubstituted C2 to C60 heteroarylene group,
Ar1 and Ar2 are the same as or different from each other, and are each independently a substituted or unsubstituted C6 to C60 aryl group; or a substituted or unsubstituted C2 to C60 heteroaryl group, or two or more adjacent groups are bonded to each other to form a substituted or unsubstituted benzocarbazole ring,
N-Het1 is a heteroaryl group which is substituted or unsubstituted and includes one or more N's,
a and b are each an integer from 0 to 3,
m and n are each an integer from 0 to 4,
p and q are each an integer from 1 to 4,
when a, b, m, n, p and q are 2 or higher, substituents in the parenthesis are the same as or different from each other, 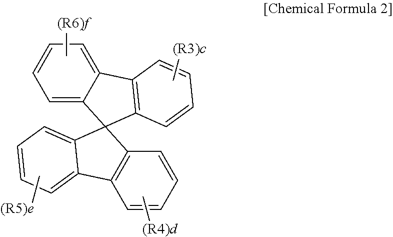
in Chemical Formula 2,
R3 to R6 are the same as or different from each other, and are each independently selected from the group consisting of hydrogen; deuterium; a halogen; —CN; a substituted or unsubstituted C1 to C60 alkyl group; a substituted or unsubstituted C2 to C60 alkenyl group; a substituted or unsubstituted C2 to C60 alkynyl group; a substituted or unsubstituted C1 to C60 alkoxy group; a substituted or unsubstituted C3 to C60 cycloalkyl group; a substituted or unsubstituted C2 to C60 heterocycloalkyl group; a substituted or unsubstituted C6 to C60 aryl group; a substituted or unsubstituted C2 to C60 heteroaryl group; —P(═O)RR′; —SiRR′R″; and the following Chemical Formula 3, and one of R3 to R6 is the following Chemical Formula 3, 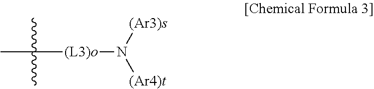
in Chemical Formula 3, 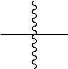
is a moiety linked to Chemical Formula 2,
L3 is a direct bond; a substituted or unsubstituted C6 to C60 arylene group; or a substituted or unsubstituted C2 to C60 heteroarylene group,
Ar3 and Ar4 are the same as or different from each other, and are each independently a substituted or unsubstituted C6 to C60 aryl group; or a substituted or unsubstituted C2 to C60 heteroaryl group,
c, d, e and f are each an integer from 0 to 4,
o is an integer of 0 to 4, and
s and t are each an integer from 1 to 4,
when c, d, e, f, o, s and t are 2 or higher, substituents in the parenthesis are the same as or different from each other, and
R, R′ and R″ are the same as or different from each other, and are each independently a substituted or unsubstituted C1 to C60 alkyl group; a substituted or unsubstituted C6 to C60 aryl group; or a substituted or unsubstituted C2 to C60 heteroaryl group.

2. The organic light emitting device of claim 1, wherein Chemical Formula 1 is represented by any one of Chemical Formulae 1-1 to 1-16: 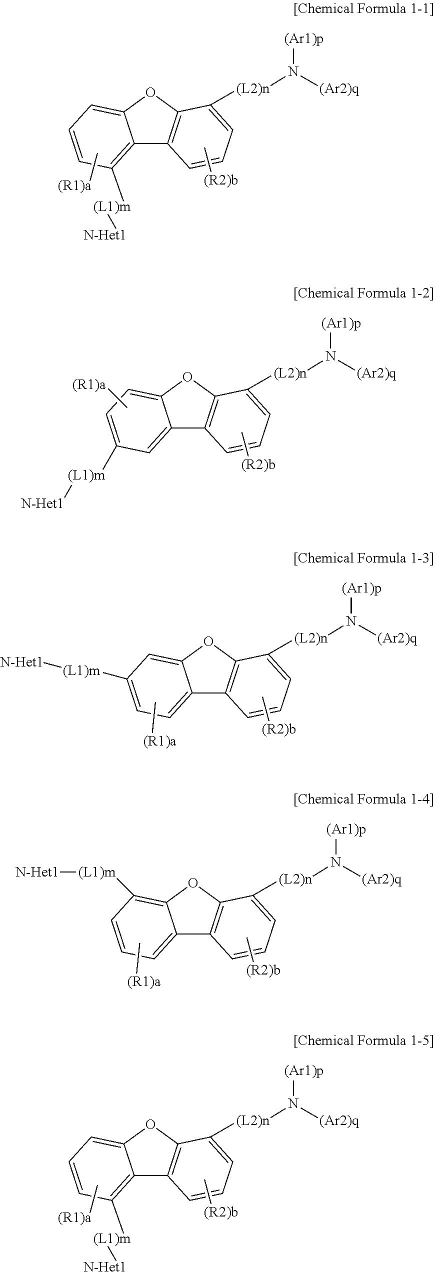 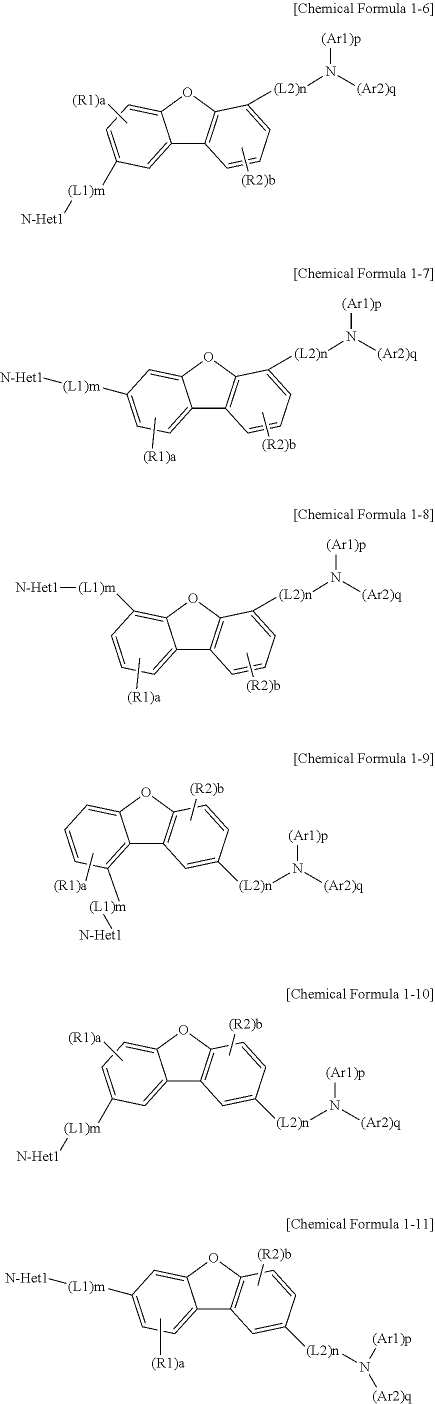 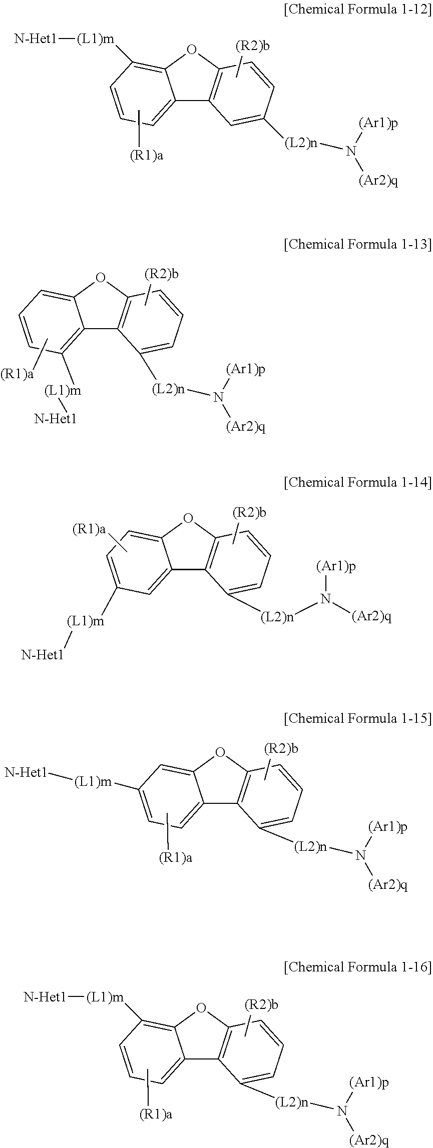
in Chemical Formulae 1-1 to 1-16,
the definition of each substituent is the same as the definition in Chemical Formula 1.

3. The organic light emitting device of claim 1,
wherein 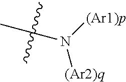
of Chemical Formula 1 is represented by the following Structural Formula A or the following Structural Formula B: 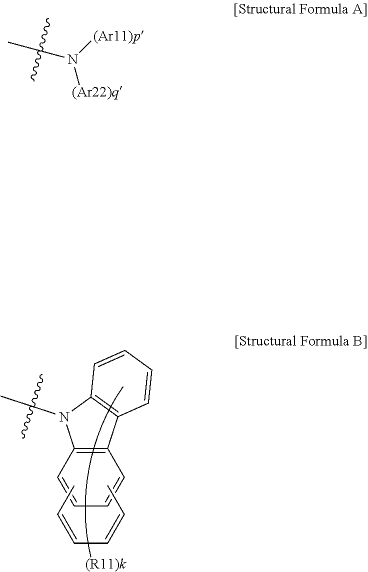
in Structural Formulae A and B, 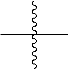
is a moiety linked to L2,
Ar11 and Ar22 are the same as or different from each other, and are each independently a substituted or unsubstituted C6 to C60 aryl group; or a substituted or unsubstituted C2 to C60 heteroaryl group,
p′ and q′ are each an integer from 1 to 4, and when each of p′ and q′ is 2 or higher, substituents in the parenthesis are the same as or different from each other,
R11 is a substituted or unsubstituted C6 to C60 aryl group; or a substituted or unsubstituted C2 to C60 heteroaryl group, and
k is an integer from 0 to 10, and when k is 2 or higher, R11's are the same as or different from each other.

4. The organic light emitting device of claim 1, wherein Chemical Formula 2 is represented by any one of the following Chemical Formulae 2-1 to 2-4: 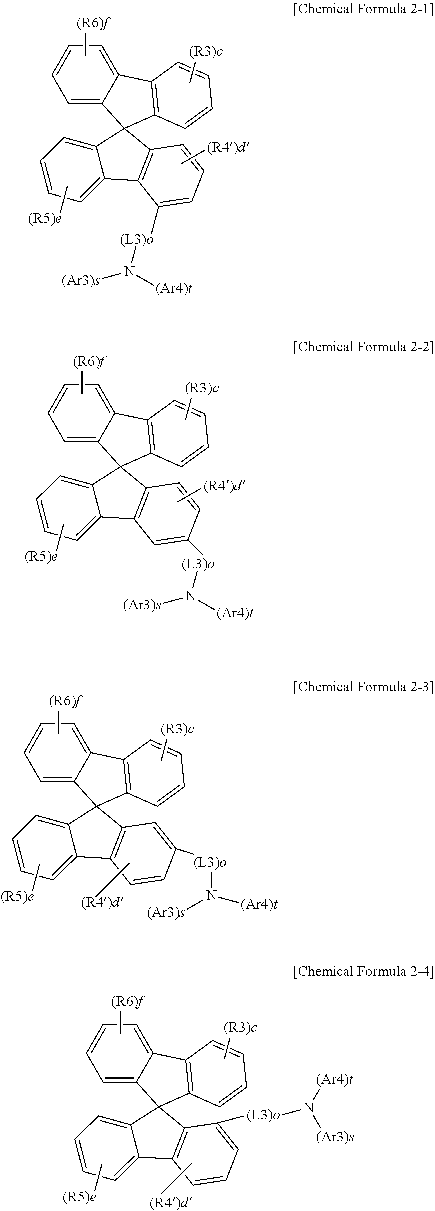
in Chemical Formulae 2-1 to 2-4,
the definitions of R3, R5, R6, L3, Ar3, Ar4, c, f, e, o, s and t are the same as those defined in Chemical Formula 2,
R4′ is selected from the group consisting of hydrogen; deuterium; a halogen; —CN; a substituted or unsubstituted C1 to C60 alkyl group; a substituted or unsubstituted C2 to C60 alkenyl group; a substituted or unsubstituted C2 to C60 alkynyl group; a substituted or unsubstituted C1 to C60 alkoxy group; a substituted or unsubstituted C3 to C60 cycloalkyl group; a substituted or unsubstituted C2 to C60 heterocycloalkyl group; a substituted or unsubstituted C6 to C60 aryl group; a substituted or unsubstituted C2 to C60 heteroaryl group; —P(═O)RR′; and —SiRR′R″,
R, R′ and R″ are the same as or different from each other, and are each independently a substituted or unsubstituted C1 to C60 alkyl group; a substituted or unsubstituted C6 to C60 aryl group; or a substituted or unsubstituted C2 to C60 heteroaryl group, and
d′ is an integer from 0 to 3, and when d′ is 2 or higher, R4's are the same as or different from each other.

5. The organic light emitting device of claim 1, wherein R1 and R2 are the same as or different from each other, and are each independently hydrogen; or deuterium.

6. The organic light emitting device of claim 1, wherein L1 and L2 are the same as or different from each other, and are each independently a direct bond; or a substituted or unsubstituted C6 to C20 arylene group.

7. The organic light emitting device of claim 1, wherein Ar1 and Ar2 are the same as or different from each other, and are each independently a substituted or unsubstituted C6 to C20 aryl group; or a substituted or unsubstituted C2 to C20 heteroaryl group, or two or more adjacent groups are bonded to each other to form a substituted or unsubstituted benzocarbazole ring.

8. The organic light emitting device of claim 1, wherein N-Het1 is a structure represented by the following Structural Formula N: 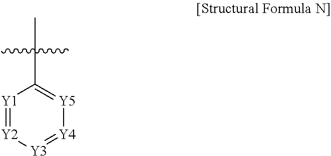
in Structural Formula N, 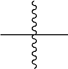
means a moiety linked to L1, and
Y1 to Y5 are the same as or different from each other, and are each independently CRa or N, at least one is N, and Ra is a substituted or unsubstituted C6 to C60 aryl group; or a substituted or unsubstituted C2 to C60 heteroaryl group, or two or more adjacent Ra groups are bonded to each other to form a ring.

9. The organic light emitting device of claim 1, wherein R3 to R6 are the same as or different from each other, and are each independently selected from the group consisting of hydrogen; deuterium; a substituted or unsubstituted C6 to C20 aryl group; and Chemical Formula 3, and one of R3 to R6 is Chemical Formula 3.

10. The organic light emitting device of claim 1, wherein L3 is a direct bond; or a substituted or unsubstituted C6 to C20 arylene group.

11. The organic light emitting device of claim 1, wherein Ar3 and Ar4 are the same as or different from each other, and are each independently a substituted or unsubstituted C6 to C20 aryl group; or a substituted or unsubstituted C2 to C20 heteroaryl group.

12. The organic light emitting device of claim 1, wherein a deuterium content of Chemical Formula 1 is 0% to 100%.

13. The organic light emitting device of claim 1, wherein a deuterium content of Chemical Formula 2 is 0% to 100%.

14. The organic light emitting device of claim 1, wherein Chemical Formula 1 is represented by any one of the following heterocyclic compounds:

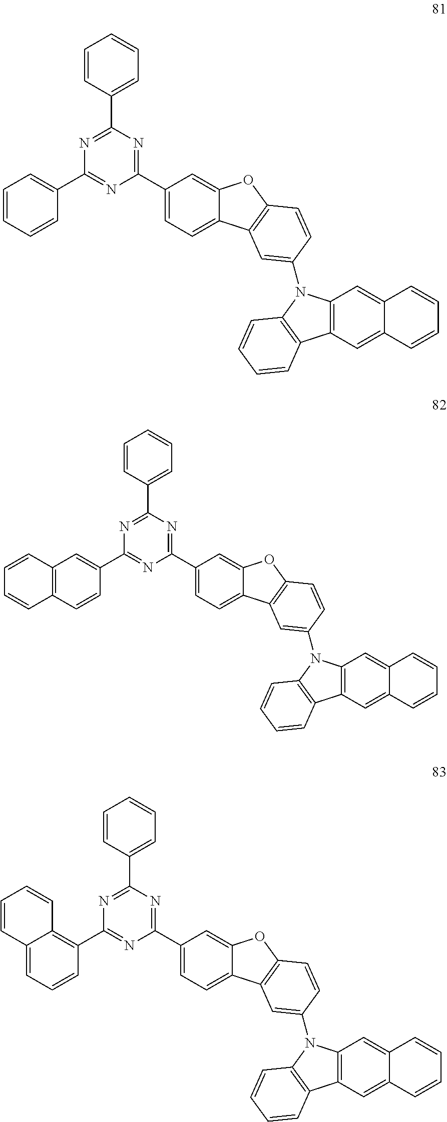 [SMILES: c1ccc(-c2nc(-c3ccccc3)nc(-c3ccc4c(c3)oc3ccc(-n5c6ccccc6c6cc7ccccc7cc65)cc34)n2)cc1 ; c1ccc(-c2nc(-c3ccc4ccccc4c3)nc(-c3ccc4c(c3)oc3ccc(-n5c6ccccc6c6cc7ccccc7cc65)cc34)n2)cc1 ; c1ccc(-c2nc(-c3ccc4c(c3)oc3ccc(-n5c6ccccc6c6cc7ccccc7cc65)cc34)nc(-c3cccc4ccccc34)n2)cc1]

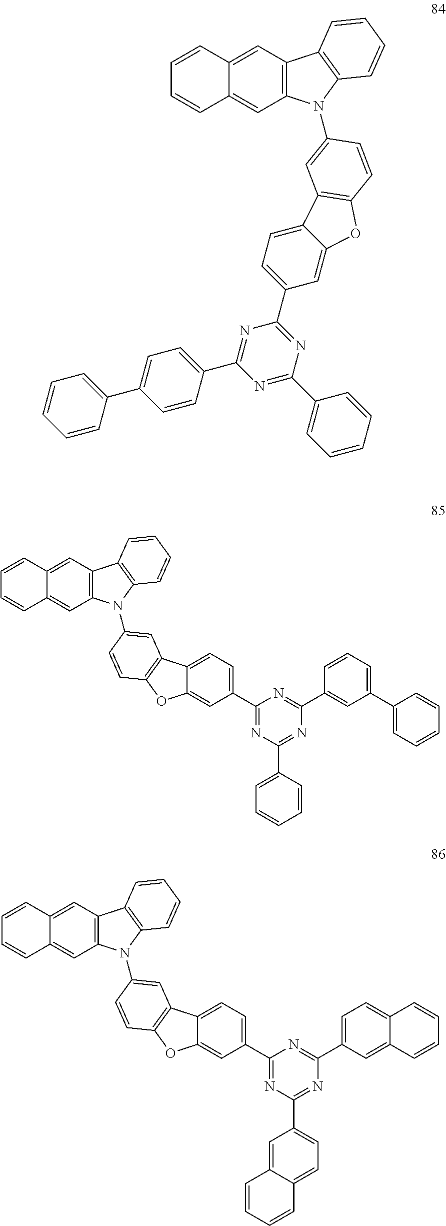 [SMILES: c1ccc(-c2ccc(-c3nc(-c4ccccc4)nc(-c4ccc5c(c4)oc4ccc(-n6c7ccccc7c7cc8ccccc8cc76)cc45)n3)cc2)cc1 ; c1ccc(-c2cccc(-c3nc(-c4ccccc4)nc(-c4ccc5c(c4)oc4ccc(-n6c7ccccc7c7cc8ccccc8cc76)cc45)n3)c2)cc1 ; c1ccc2cc(-c3nc(-c4ccc5ccccc5c4)nc(-c4ccc5c(c4)oc4ccc(-n6c7ccccc7c7cc8ccccc8cc76)cc45)n3)ccc2c1]

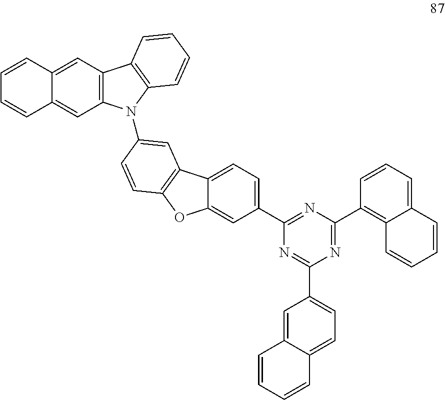 [SMILES: c1ccc2cc(-c3nc(-c4ccc5c(c4)oc4ccc(-n6c7ccccc7c7cc8ccccc8cc76)cc45)nc(-c4cccc5ccccc45)n3)ccc2c1]

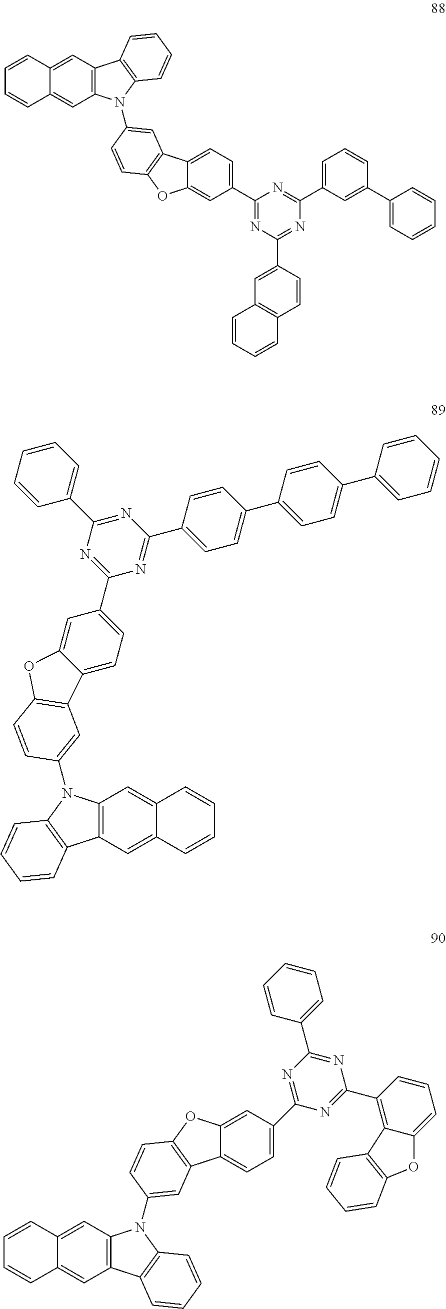 [SMILES: c1ccc(-c2cccc(-c3nc(-c4ccc5ccccc5c4)nc(-c4ccc5c(c4)oc4ccc(-n6c7ccccc7c7cc8ccccc8cc76)cc45)n3)c2)cc1 ; c1ccc(-c2ccc(-c3ccc(-c4nc(-c5ccccc5)nc(-c5ccc6c(c5)oc5ccc(-n7c8ccccc8c8cc9ccccc9cc87)cc56)n4)cc3)cc2)cc1 ; c1ccc(-c2nc(-c3ccc4c(c3)oc3ccc(-n5c6ccccc6c6cc7ccccc7cc65)cc34)nc(-c3cccc4oc5ccccc5c34)n2)cc1]

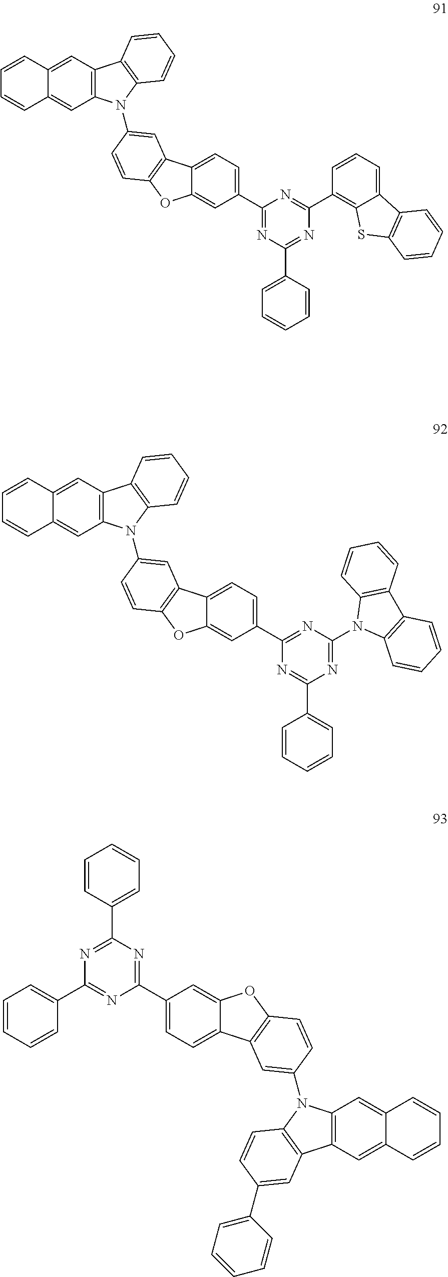 [SMILES: c1ccc(-c2nc(-c3ccc4c(c3)oc3ccc(-n5c6ccccc6c6cc7ccccc7cc65)cc34)nc(-c3cccc4c3sc3ccccc34)n2)cc1 ; c1ccc(-c2nc(-c3ccc4c(c3)oc3ccc(-n5c6ccccc6c6cc7ccccc7cc65)cc34)nc(-n3c4ccccc4c4ccccc43)n2)cc1 ; c1ccc(-c2ccc3c(c2)c2cc4ccccc4cc2n3-c2ccc3oc4cc(-c5nc(-c6ccccc6)nc(-c6ccccc6)n5)ccc4c3c2)cc1]

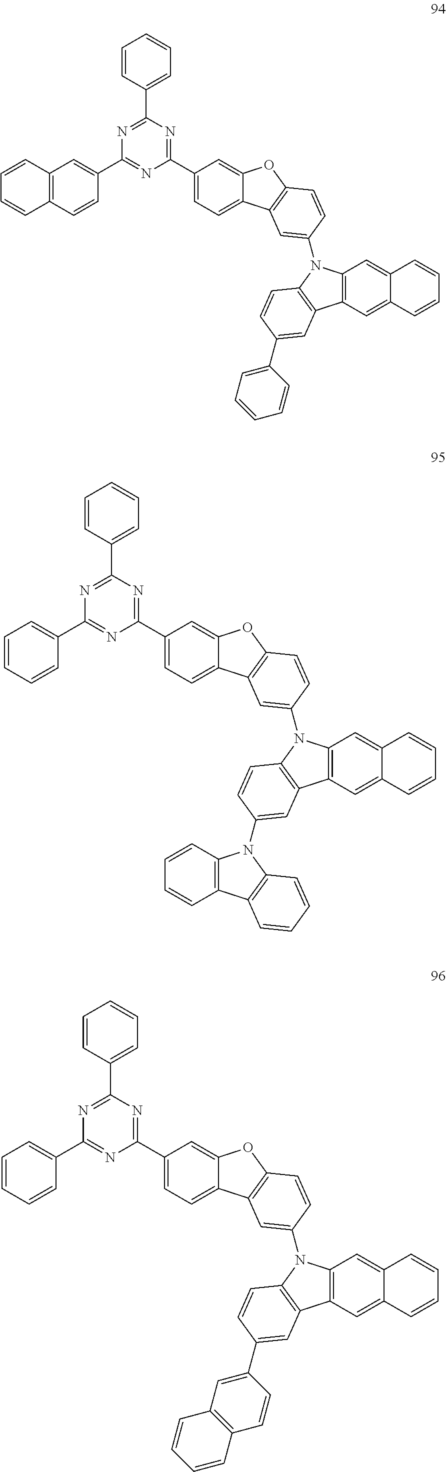 [SMILES: c1ccc(-c2ccc3c(c2)c2cc4ccccc4cc2n3-c2ccc3oc4cc(-c5nc(-c6ccccc6)nc(-c6ccc7ccccc7c6)n5)ccc4c3c2)cc1 ; c1ccc(-c2nc(-c3ccccc3)nc(-c3ccc4c(c3)oc3ccc(-n5c6ccc(-n7c8ccccc8c8ccccc87)cc6c6cc7ccccc7cc65)cc34)n2)cc1 ; c1ccc(-c2nc(-c3ccccc3)nc(-c3ccc4c(c3)oc3ccc(-n5c6ccc(-c7ccc8ccccc8c7)cc6c6cc7ccccc7cc65)cc34)n2)cc1]

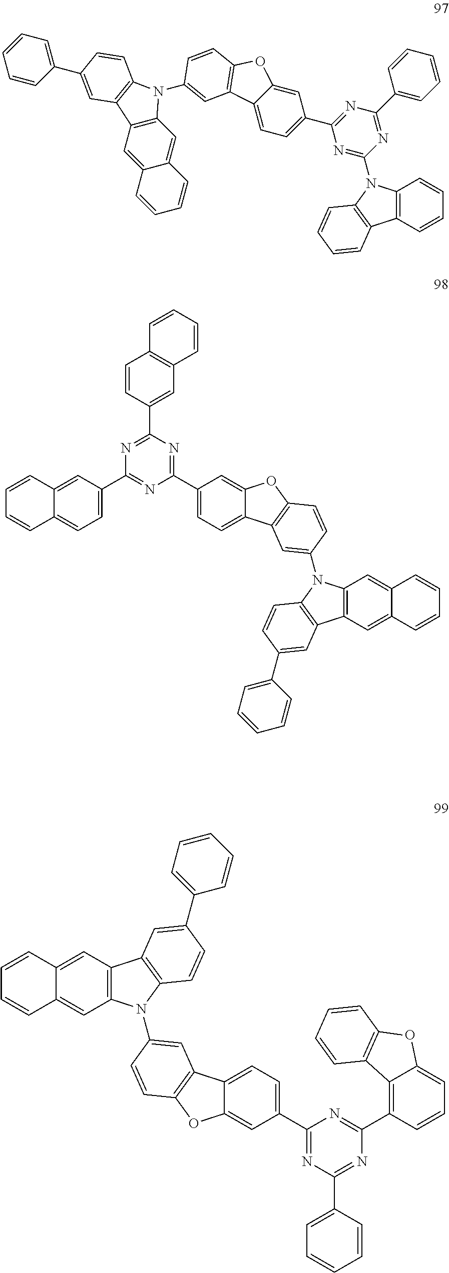 [SMILES: c1ccc(-c2ccc3c(c2)c2cc4ccccc4cc2n3-c2ccc3oc4cc(-c5nc(-c6ccccc6)nc(-n6c7ccccc7c7ccccc76)n5)ccc4c3c2)cc1 ; c1ccc(-c2ccc3c(c2)c2cc4ccccc4cc2n3-c2ccc3oc4cc(-c5nc(-c6ccc7ccccc7c6)nc(-c6ccc7ccccc7c6)n5)ccc4c3c2)cc1 ; c1ccc(-c2ccc3c(c2)c2cc4ccccc4cc2n3-c2ccc3oc4cc(-c5nc(-c6ccccc6)nc(-c6cccc7oc8ccccc8c67)n5)ccc4c3c2)cc1]

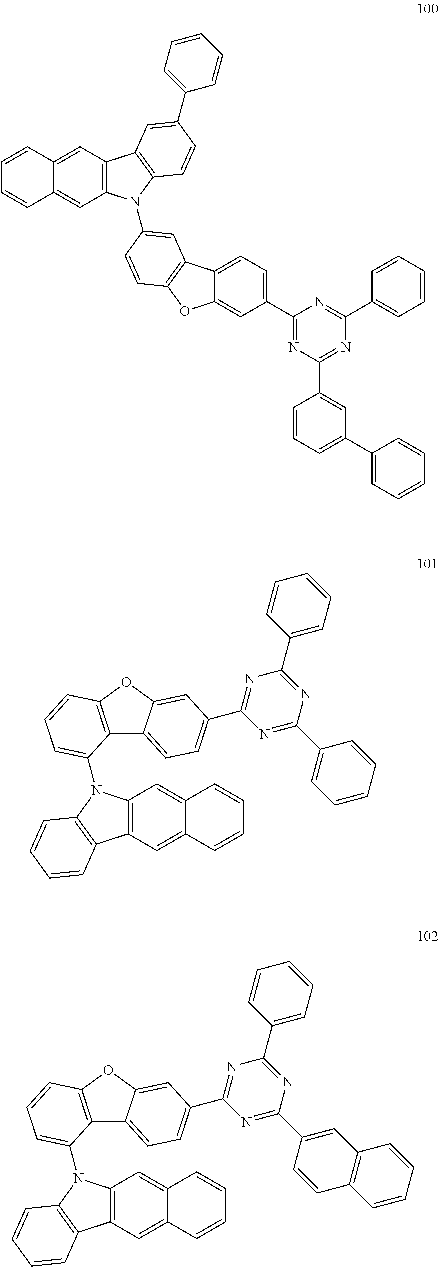 [SMILES: c1ccc(-c2cccc(-c3nc(-c4ccccc4)nc(-c4ccc5c(c4)oc4ccc(-n6c7ccc(-c8ccccc8)cc7c7cc8ccccc8cc76)cc45)n3)c2)cc1 ; c1ccc(-c2nc(-c3ccccc3)nc(-c3ccc4c(c3)oc3cccc(-n5c6ccccc6c6cc7ccccc7cc65)c34)n2)cc1 ; c1ccc(-c2nc(-c3ccc4ccccc4c3)nc(-c3ccc4c(c3)oc3cccc(-n5c6ccccc6c6cc7ccccc7cc65)c34)n2)cc1]

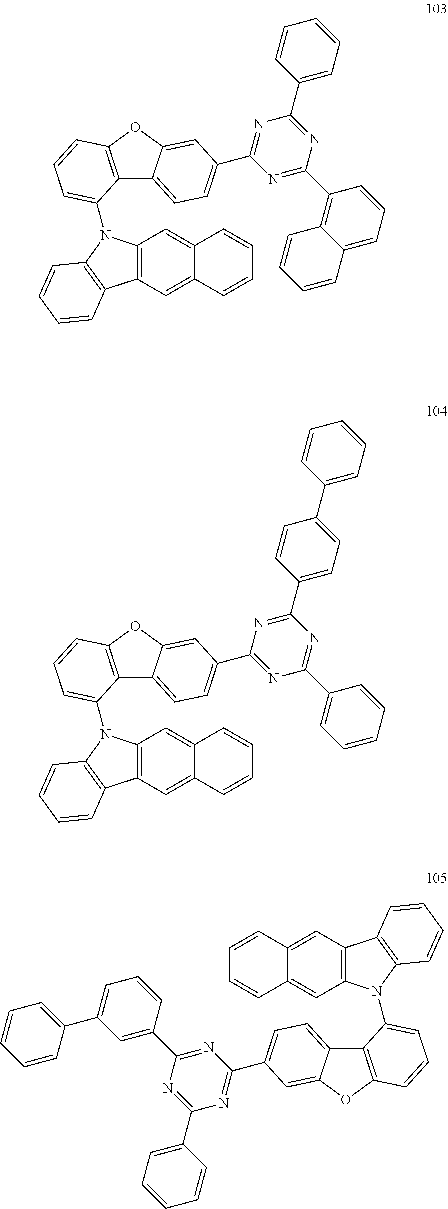 [SMILES: c1ccc(-c2nc(-c3ccc4c(c3)oc3cccc(-n5c6ccccc6c6cc7ccccc7cc65)c34)nc(-c3cccc4ccccc34)n2)cc1 ; c1ccc(-c2ccc(-c3nc(-c4ccccc4)nc(-c4ccc5c(c4)oc4cccc(-n6c7ccccc7c7cc8ccccc8cc76)c45)n3)cc2)cc1 ; c1ccc(-c2cccc(-c3nc(-c4ccccc4)nc(-c4ccc5c(c4)oc4cccc(-n6c7ccccc7c7cc8ccccc8cc76)c45)n3)c2)cc1]

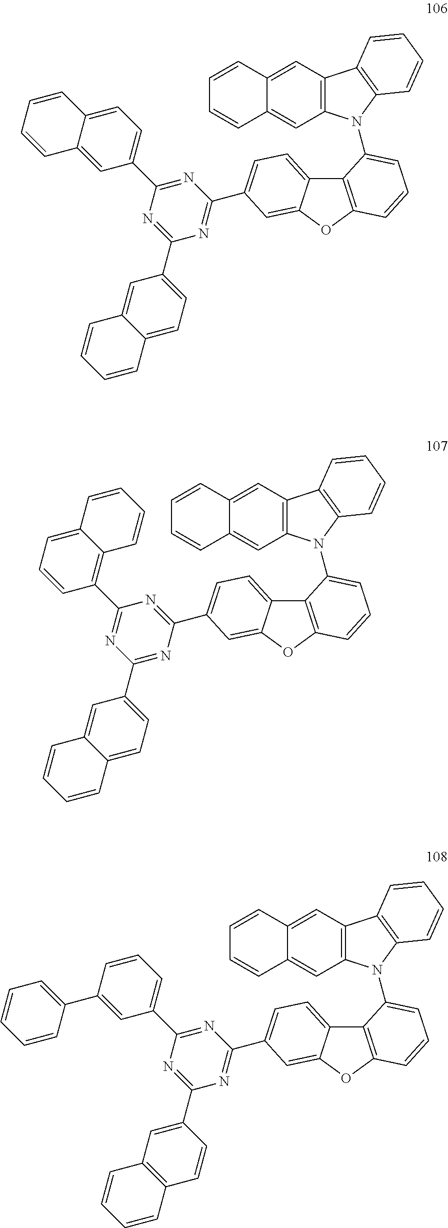 [SMILES: c1ccc2cc(-c3nc(-c4ccc5ccccc5c4)nc(-c4ccc5c(c4)oc4cccc(-n6c7ccccc7c7cc8ccccc8cc76)c45)n3)ccc2c1 ; c1ccc2cc(-c3nc(-c4ccc5c(c4)oc4cccc(-n6c7ccccc7c7cc8ccccc8cc76)c45)nc(-c4cccc5ccccc45)n3)ccc2c1 ; c1ccc(-c2cccc(-c3nc(-c4ccc5ccccc5c4)nc(-c4ccc5c(c4)oc4cccc(-n6c7ccccc7c7cc8ccccc8cc76)c45)n3)c2)cc1]

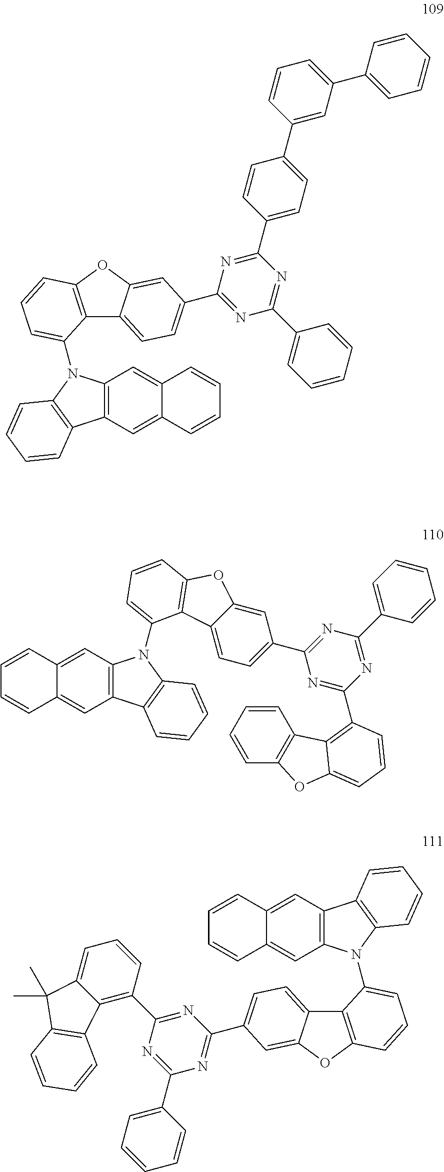 [SMILES: c1ccc(-c2cccc(-c3ccc(-c4nc(-c5ccccc5)nc(-c5ccc6c(c5)oc5cccc(-n7c8ccccc8c8cc9ccccc9cc87)c56)n4)cc3)c2)cc1 ; c1ccc(-c2nc(-c3ccc4c(c3)oc3cccc(-n5c6ccccc6c6cc7ccccc7cc65)c34)nc(-c3cccc4oc5ccccc5c34)n2)cc1 ; CC1(C)c2ccccc2-c2c(-c3nc(-c4ccccc4)nc(-c4ccc5c(c4)oc4cccc(-n6c7ccccc7c7cc8ccccc8cc76)c45)n3)cccc21]

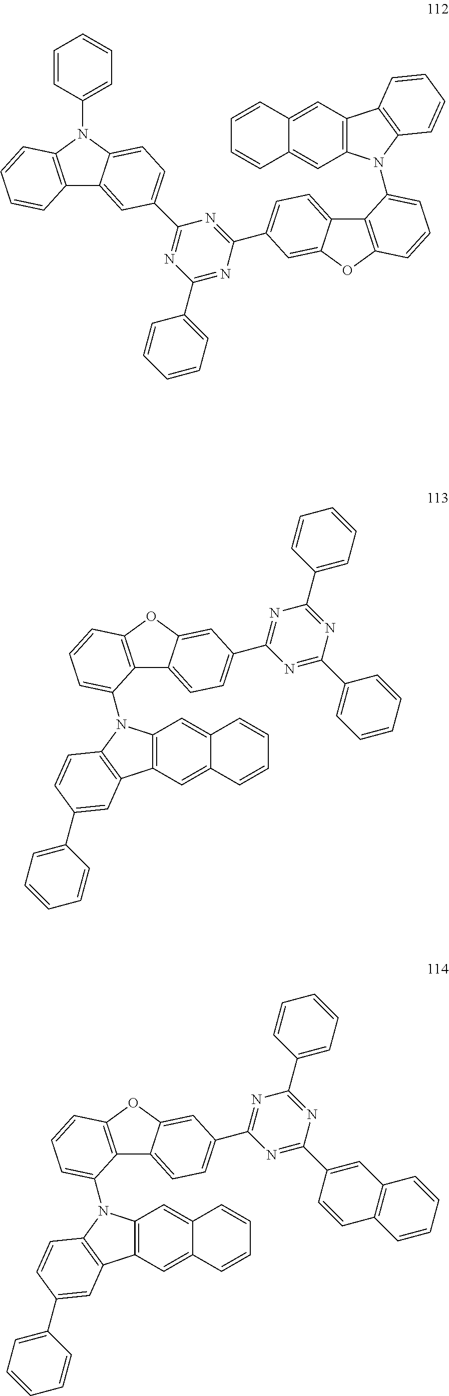 [SMILES: c1ccc(-c2nc(-c3ccc4c(c3)oc3cccc(-n5c6ccccc6c6cc7ccccc7cc65)c34)nc(-c3ccc4c(c3)c3ccccc3n4-c3ccccc3)n2)cc1 ; c1ccc(-c2ccc3c(c2)c2cc4ccccc4cc2n3-c2cccc3oc4cc(-c5nc(-c6ccccc6)nc(-c6ccccc6)n5)ccc4c23)cc1 ; c1ccc(-c2ccc3c(c2)c2cc4ccccc4cc2n3-c2cccc3oc4cc(-c5nc(-c6ccccc6)nc(-c6ccc7ccccc7c6)n5)ccc4c23)cc1]

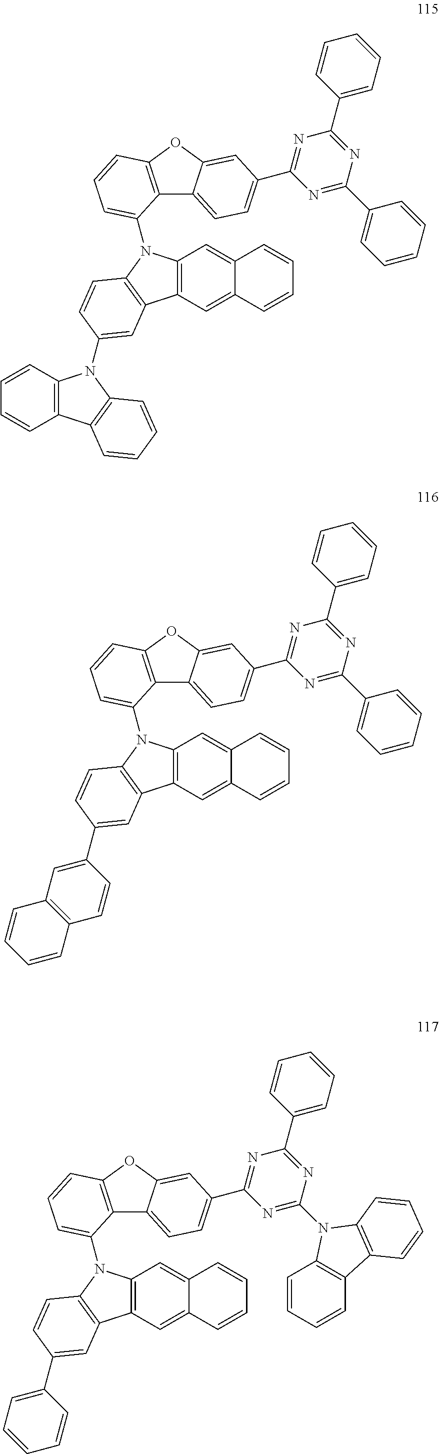 [SMILES: c1ccc(-c2nc(-c3ccccc3)nc(-c3ccc4c(c3)oc3cccc(-n5c6ccc(-n7c8ccccc8c8ccccc87)cc6c6cc7ccccc7cc65)c34)n2)cc1 ; c1ccc(-c2nc(-c3ccccc3)nc(-c3ccc4c(c3)oc3cccc(-n5c6ccc(-c7ccc8ccccc8c7)cc6c6cc7ccccc7cc65)c34)n2)cc1 ; c1ccc(-c2ccc3c(c2)c2cc4ccccc4cc2n3-c2cccc3oc4cc(-c5nc(-c6ccccc6)nc(-n6c7ccccc7c7ccccc76)n5)ccc4c23)cc1]

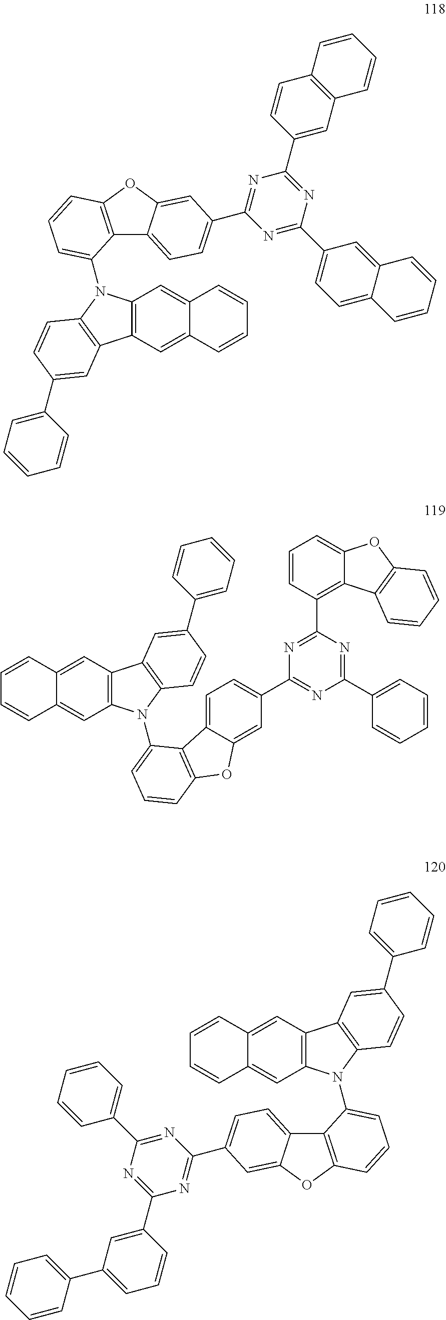 [SMILES: c1ccc(-c2ccc3c(c2)c2cc4ccccc4cc2n3-c2cccc3oc4cc(-c5nc(-c6ccc7ccccc7c6)nc(-c6ccc7ccccc7c6)n5)ccc4c23)cc1 ; c1ccc(-c2ccc3c(c2)c2cc4ccccc4cc2n3-c2cccc3oc4cc(-c5nc(-c6ccccc6)nc(-c6cccc7oc8ccccc8c67)n5)ccc4c23)cc1 ; c1ccc(-c2cccc(-c3nc(-c4ccccc4)nc(-c4ccc5c(c4)oc4cccc(-n6c7ccc(-c8ccccc8)cc7c7cc8ccccc8cc76)c45)n3)c2)cc1]

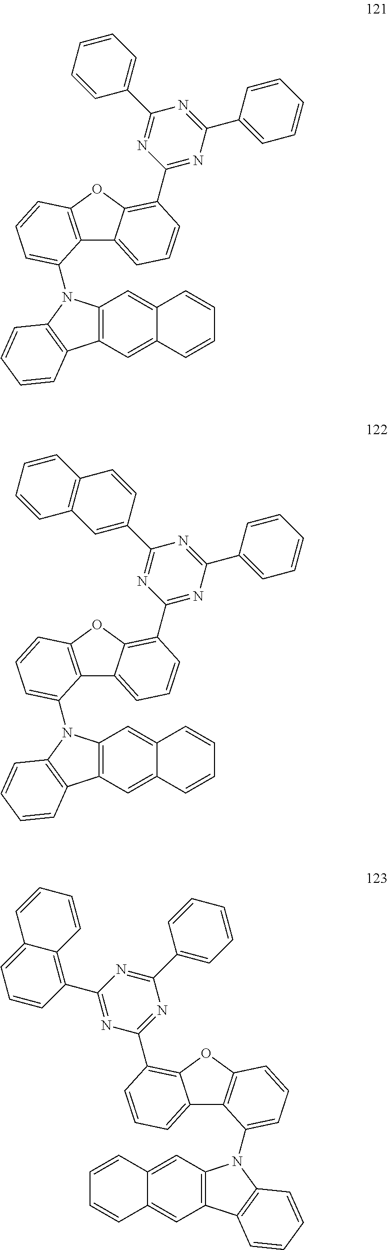 [SMILES: c1ccc(-c2nc(-c3ccccc3)nc(-c3cccc4c3oc3cccc(-n5c6ccccc6c6cc7ccccc7cc65)c34)n2)cc1 ; c1ccc(-c2nc(-c3ccc4ccccc4c3)nc(-c3cccc4c3oc3cccc(-n5c6ccccc6c6cc7ccccc7cc65)c34)n2)cc1 ; c1ccc(-c2nc(-c3cccc4ccccc34)nc(-c3cccc4c3oc3cccc(-n5c6ccccc6c6cc7ccccc7cc65)c34)n2)cc1]

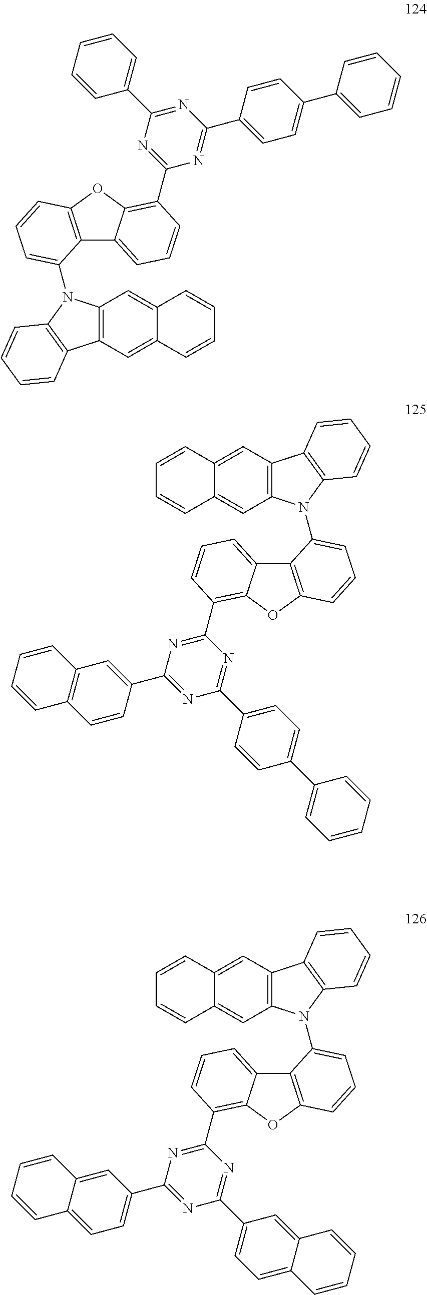 [SMILES: c1ccc(-c2ccc(-c3nc(-c4ccccc4)nc(-c4cccc5c4oc4cccc(-n6c7ccccc7c7cc8ccccc8cc76)c45)n3)cc2)cc1 ; c1ccc(-c2ccc(-c3nc(-c4ccc5ccccc5c4)nc(-c4cccc5c4oc4cccc(-n6c7ccccc7c7cc8ccccc8cc76)c45)n3)cc2)cc1 ; c1ccc2cc(-c3nc(-c4ccc5ccccc5c4)nc(-c4cccc5c4oc4cccc(-n6c7ccccc7c7cc8ccccc8cc76)c45)n3)ccc2c1]

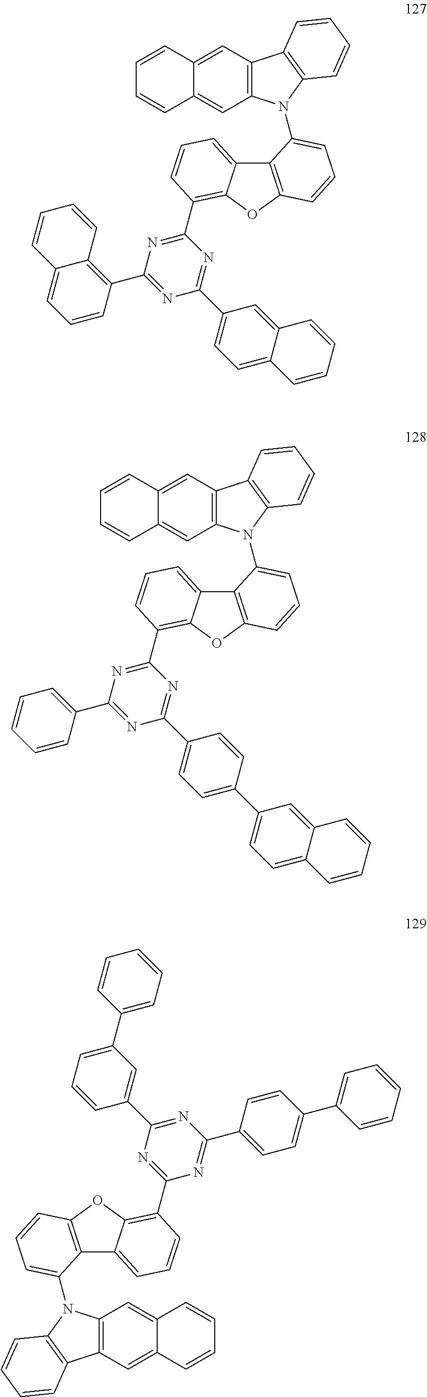 [SMILES: c1ccc2cc(-c3nc(-c4cccc5ccccc45)nc(-c4cccc5c4oc4cccc(-n6c7ccccc7c7cc8ccccc8cc76)c45)n3)ccc2c1 ; c1ccc(-c2nc(-c3ccc(-c4ccc5ccccc5c4)cc3)nc(-c3cccc4c3oc3cccc(-n5c6ccccc6c6cc7ccccc7cc65)c34)n2)cc1 ; c1ccc(-c2ccc(-c3nc(-c4cccc(-c5ccccc5)c4)nc(-c4cccc5c4oc4cccc(-n6c7ccccc7c7cc8ccccc8cc76)c45)n3)cc2)cc1]

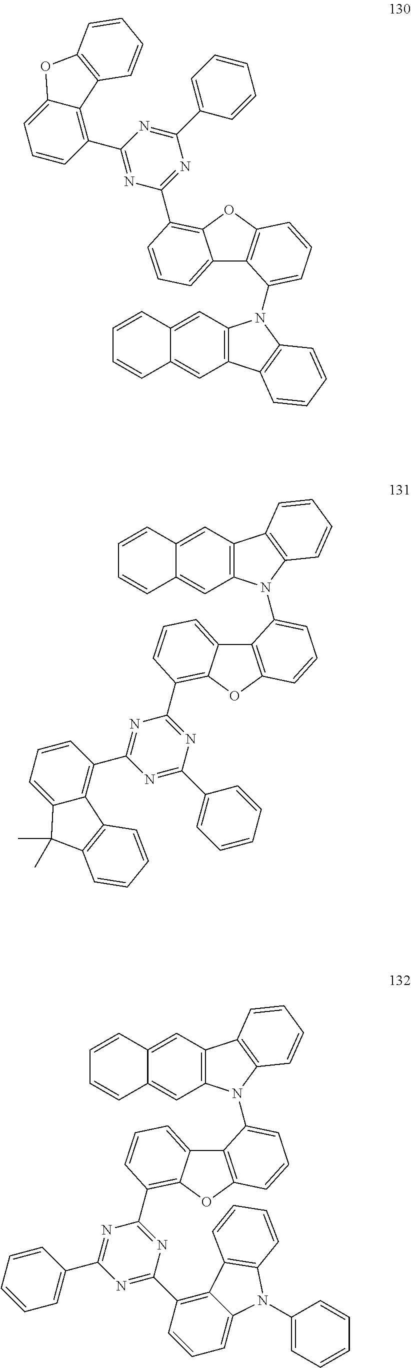 [SMILES: c1ccc(-c2nc(-c3cccc4c3oc3cccc(-n5c6ccccc6c6cc7ccccc7cc65)c34)nc(-c3cccc4oc5ccccc5c34)n2)cc1 ; CC1(C)c2ccccc2-c2c(-c3nc(-c4ccccc4)nc(-c4cccc5c4oc4cccc(-n6c7ccccc7c7cc8ccccc8cc76)c45)n3)cccc21 ; c1ccc(-c2nc(-c3cccc4c3oc3cccc(-n5c6ccccc6c6cc7ccccc7cc65)c34)nc(-c3cccc4c3c3ccccc3n4-c3ccccc3)n2)cc1]

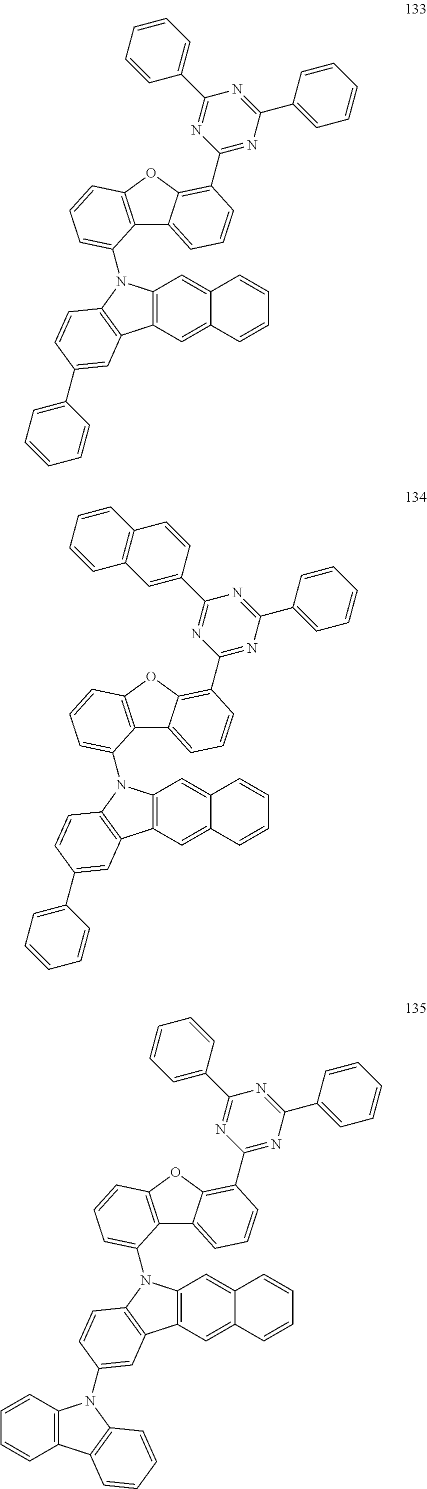 [SMILES: c1ccc(-c2ccc3c(c2)c2cc4ccccc4cc2n3-c2cccc3oc4c(-c5nc(-c6ccccc6)nc(-c6ccccc6)n5)cccc4c23)cc1 ; c1ccc(-c2ccc3c(c2)c2cc4ccccc4cc2n3-c2cccc3oc4c(-c5nc(-c6ccccc6)nc(-c6ccc7ccccc7c6)n5)cccc4c23)cc1 ; c1ccc(-c2nc(-c3ccccc3)nc(-c3cccc4c3oc3cccc(-n5c6ccc(-n7c8ccccc8c8ccccc87)cc6c6cc7ccccc7cc65)c34)n2)cc1]

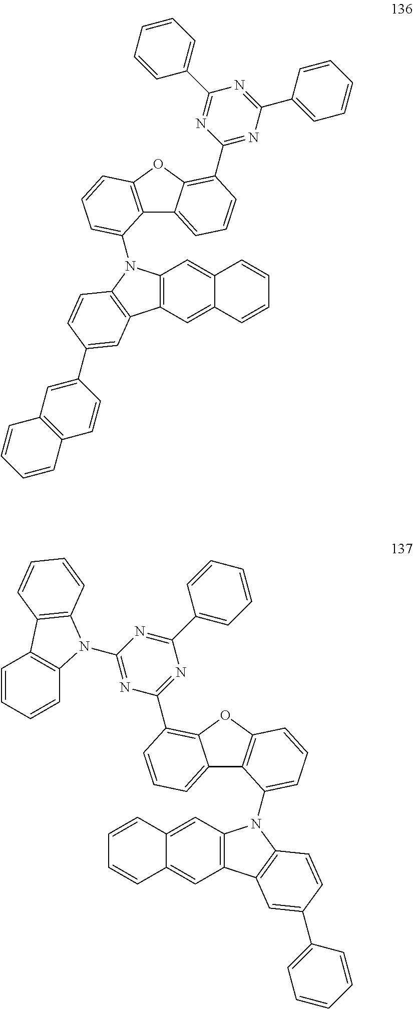 [SMILES: c1ccc(-c2nc(-c3ccccc3)nc(-c3cccc4c3oc3cccc(-n5c6ccc(-c7ccc8ccccc8c7)cc6c6cc7ccccc7cc65)c34)n2)cc1 ; c1ccc(-c2ccc3c(c2)c2cc4ccccc4cc2n3-c2cccc3oc4c(-c5nc(-c6ccccc6)nc(-n6c7ccccc7c7ccccc76)n5)cccc4c23)cc1]

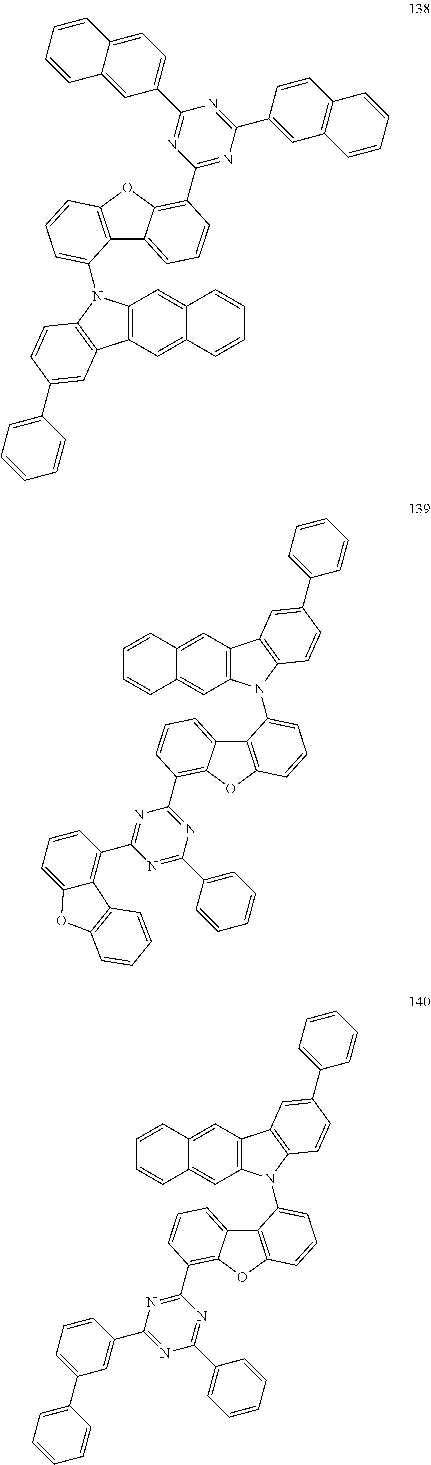 [SMILES: c1ccc(-c2ccc3c(c2)c2cc4ccccc4cc2n3-c2cccc3oc4c(-c5nc(-c6ccc7ccccc7c6)nc(-c6ccc7ccccc7c6)n5)cccc4c23)cc1 ; c1ccc(-c2ccc3c(c2)c2cc4ccccc4cc2n3-c2cccc3oc4c(-c5nc(-c6ccccc6)nc(-c6cccc7oc8ccccc8c67)n5)cccc4c23)cc1 ; c1ccc(-c2cccc(-c3nc(-c4ccccc4)nc(-c4cccc5c4oc4cccc(-n6c7ccc(-c8ccccc8)cc7c7cc8ccccc8cc76)c45)n3)c2)cc1]

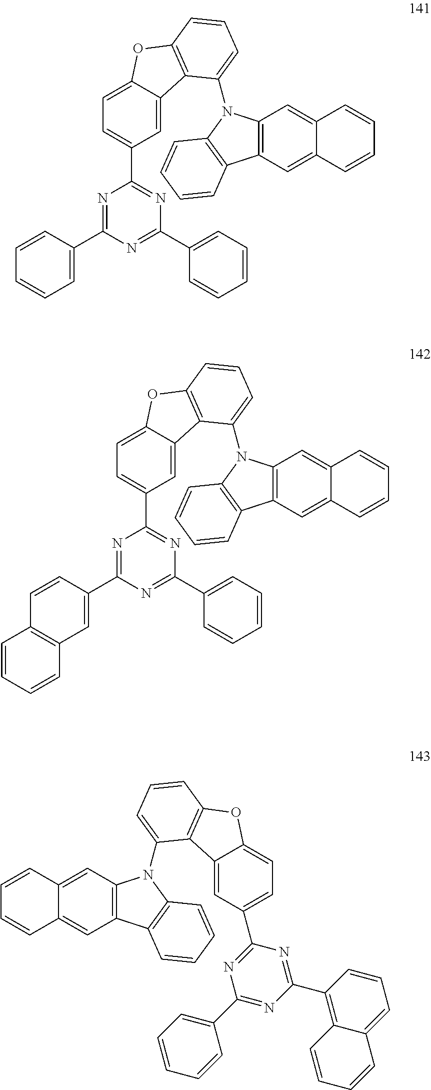 [SMILES: c1ccc(-c2nc(-c3ccccc3)nc(-c3ccc4oc5cccc(-n6c7ccccc7c7cc8ccccc8cc76)c5c4c3)n2)cc1 ; c1ccc(-c2nc(-c3ccc4ccccc4c3)nc(-c3ccc4oc5cccc(-n6c7ccccc7c7cc8ccccc8cc76)c5c4c3)n2)cc1 ; c1ccc(-c2nc(-c3ccc4oc5cccc(-n6c7ccccc7c7cc8ccccc8cc76)c5c4c3)nc(-c3cccc4ccccc34)n2)cc1]

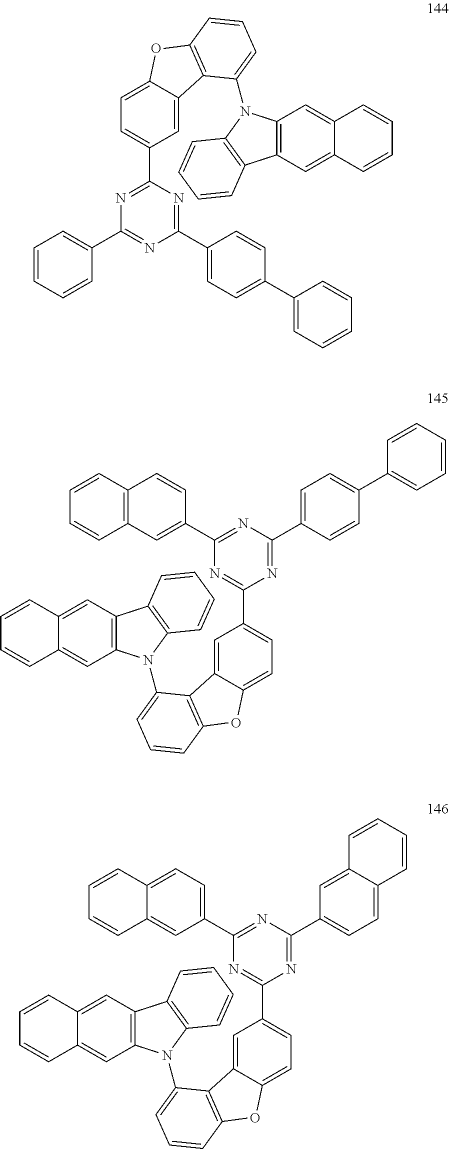 [SMILES: c1ccc(-c2ccc(-c3nc(-c4ccccc4)nc(-c4ccc5oc6cccc(-n7c8ccccc8c8cc9ccccc9cc87)c6c5c4)n3)cc2)cc1 ; c1ccc(-c2ccc(-c3nc(-c4ccc5ccccc5c4)nc(-c4ccc5oc6cccc(-n7c8ccccc8c8cc9ccccc9cc87)c6c5c4)n3)cc2)cc1 ; c1ccc2cc(-c3nc(-c4ccc5ccccc5c4)nc(-c4ccc5oc6cccc(-n7c8ccccc8c8cc9ccccc9cc87)c6c5c4)n3)ccc2c1]

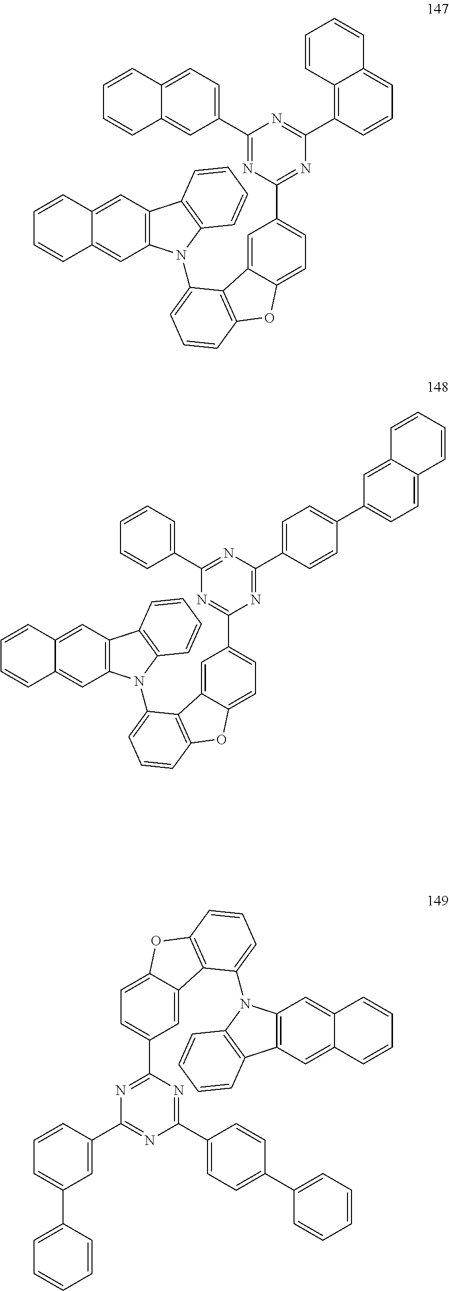 [SMILES: c1ccc2cc(-c3nc(-c4ccc5oc6cccc(-n7c8ccccc8c8cc9ccccc9cc87)c6c5c4)nc(-c4cccc5ccccc45)n3)ccc2c1 ; c1ccc(-c2nc(-c3ccc(-c4ccc5ccccc5c4)cc3)nc(-c3ccc4oc5cccc(-n6c7ccccc7c7cc8ccccc8cc76)c5c4c3)n2)cc1 ; c1ccc(-c2ccc(-c3nc(-c4cccc(-c5ccccc5)c4)nc(-c4ccc5oc6cccc(-n7c8ccccc8c8cc9ccccc9cc87)c6c5c4)n3)cc2)cc1]

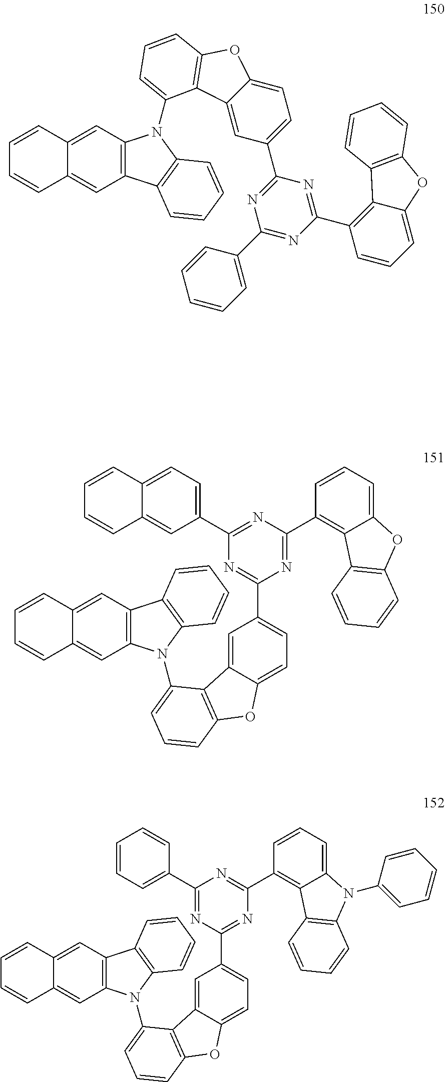 [SMILES: c1ccc(-c2nc(-c3ccc4oc5cccc(-n6c7ccccc7c7cc8ccccc8cc76)c5c4c3)nc(-c3cccc4oc5ccccc5c34)n2)cc1 ; c1ccc2cc(-c3nc(-c4ccc5oc6cccc(-n7c8ccccc8c8cc9ccccc9cc87)c6c5c4)nc(-c4cccc5oc6ccccc6c45)n3)ccc2c1 ; c1ccc(-c2nc(-c3ccc4oc5cccc(-n6c7ccccc7c7cc8ccccc8cc76)c5c4c3)nc(-c3cccc4c3c3ccccc3n4-c3ccccc3)n2)cc1]

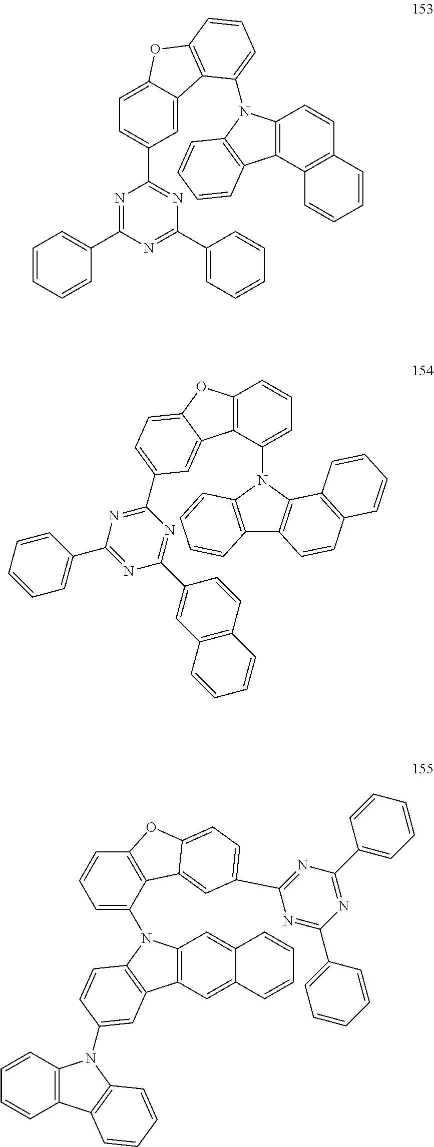 [SMILES: c1ccc(-c2nc(-c3ccccc3)nc(-c3ccc4oc5cccc(-n6c7ccccc7c7c8ccccc8ccc76)c5c4c3)n2)cc1 ; c1ccc(-c2nc(-c3ccc4ccccc4c3)nc(-c3ccc4oc5cccc(-n6c7ccccc7c7ccc8ccccc8c76)c5c4c3)n2)cc1 ; c1ccc(-c2nc(-c3ccccc3)nc(-c3ccc4oc5cccc(-n6c7ccc(-n8c9ccccc9c9ccccc98)cc7c7cc8ccccc8cc76)c5c4c3)n2)cc1]

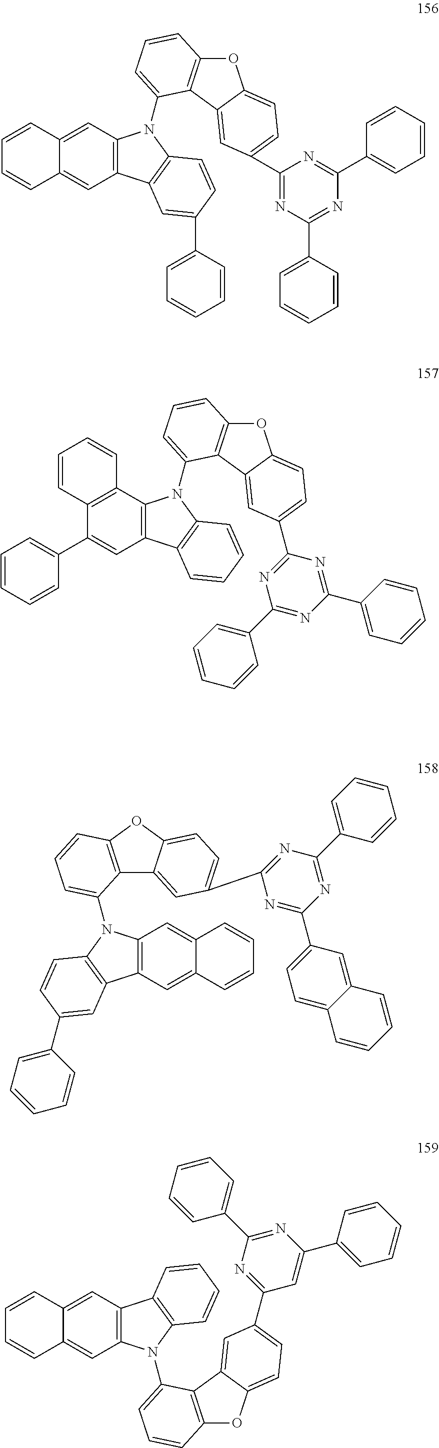 [SMILES: c1ccc(-c2ccc3c(c2)c2cc4ccccc4cc2n3-c2cccc3oc4ccc(-c5nc(-c6ccccc6)nc(-c6ccccc6)n5)cc4c23)cc1 ; c1ccc(-c2nc(-c3ccccc3)nc(-c3ccc4oc5cccc(-n6c7ccccc7c7cc(-c8ccccc8)c8ccccc8c76)c5c4c3)n2)cc1 ; c1ccc(-c2ccc3c(c2)c2cc4ccccc4cc2n3-c2cccc3oc4ccc(-c5nc(-c6ccccc6)nc(-c6ccc7ccccc7c6)n5)cc4c23)cc1 ; c1ccc(-c2cc(-c3ccc4oc5cccc(-n6c7ccccc7c7cc8ccccc8cc76)c5c4c3)nc(-c3ccccc3)n2)cc1]

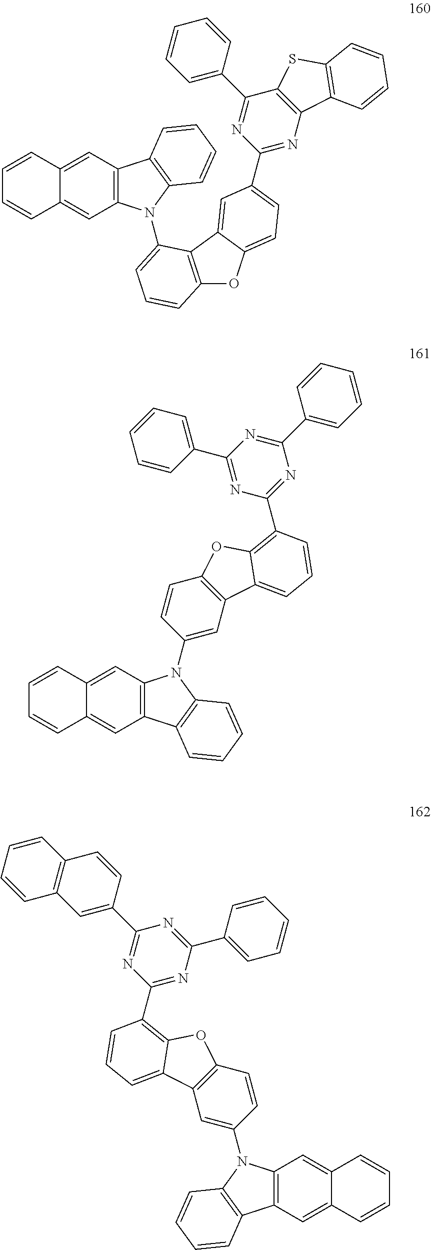 [SMILES: c1ccc(-c2nc(-c3ccc4oc5cccc(-n6c7ccccc7c7cc8ccccc8cc76)c5c4c3)nc3c2sc2ccccc23)cc1 ; c1ccc(-c2nc(-c3ccccc3)nc(-c3cccc4c3oc3ccc(-n5c6ccccc6c6cc7ccccc7cc65)cc34)n2)cc1 ; c1ccc(-c2nc(-c3ccc4ccccc4c3)nc(-c3cccc4c3oc3ccc(-n5c6ccccc6c6cc7ccccc7cc65)cc34)n2)cc1]

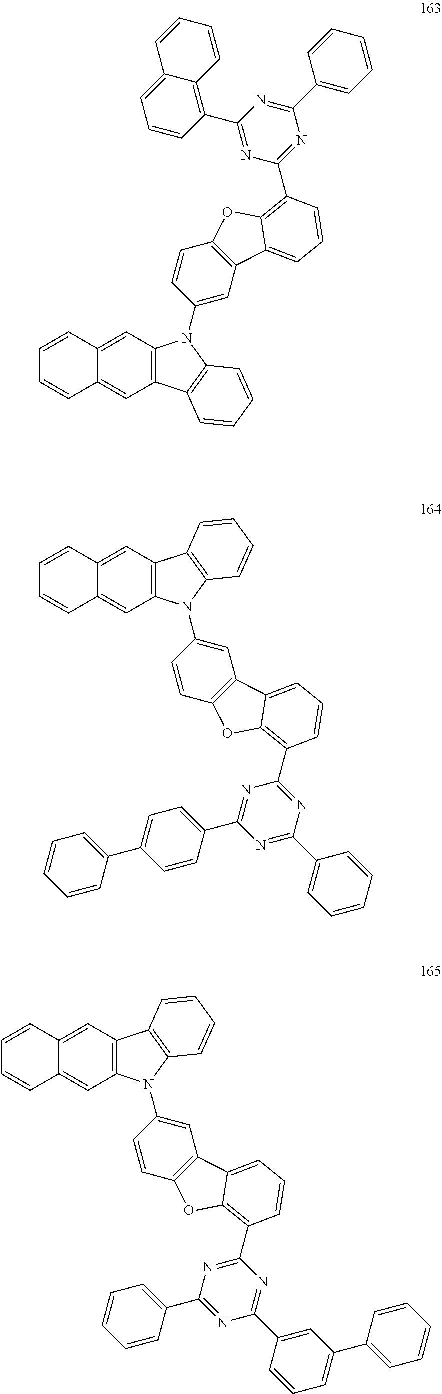 [SMILES: c1ccc(-c2nc(-c3cccc4ccccc34)nc(-c3cccc4c3oc3ccc(-n5c6ccccc6c6cc7ccccc7cc65)cc34)n2)cc1 ; c1ccc(-c2ccc(-c3nc(-c4ccccc4)nc(-c4cccc5c4oc4ccc(-n6c7ccccc7c7cc8ccccc8cc76)cc45)n3)cc2)cc1 ; c1ccc(-c2cccc(-c3nc(-c4ccccc4)nc(-c4cccc5c4oc4ccc(-n6c7ccccc7c7cc8ccccc8cc76)cc45)n3)c2)cc1]

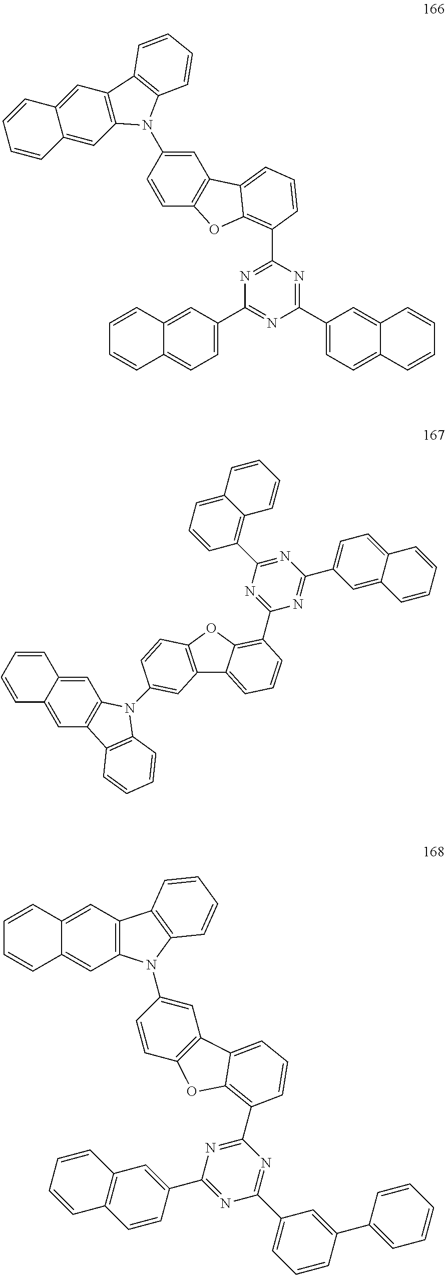 [SMILES: c1ccc2cc(-c3nc(-c4ccc5ccccc5c4)nc(-c4cccc5c4oc4ccc(-n6c7ccccc7c7cc8ccccc8cc76)cc45)n3)ccc2c1 ; c1ccc2cc(-c3nc(-c4cccc5ccccc45)nc(-c4cccc5c4oc4ccc(-n6c7ccccc7c7cc8ccccc8cc76)cc45)n3)ccc2c1 ; c1ccc(-c2cccc(-c3nc(-c4ccc5ccccc5c4)nc(-c4cccc5c4oc4ccc(-n6c7ccccc7c7cc8ccccc8cc76)cc45)n3)c2)cc1]

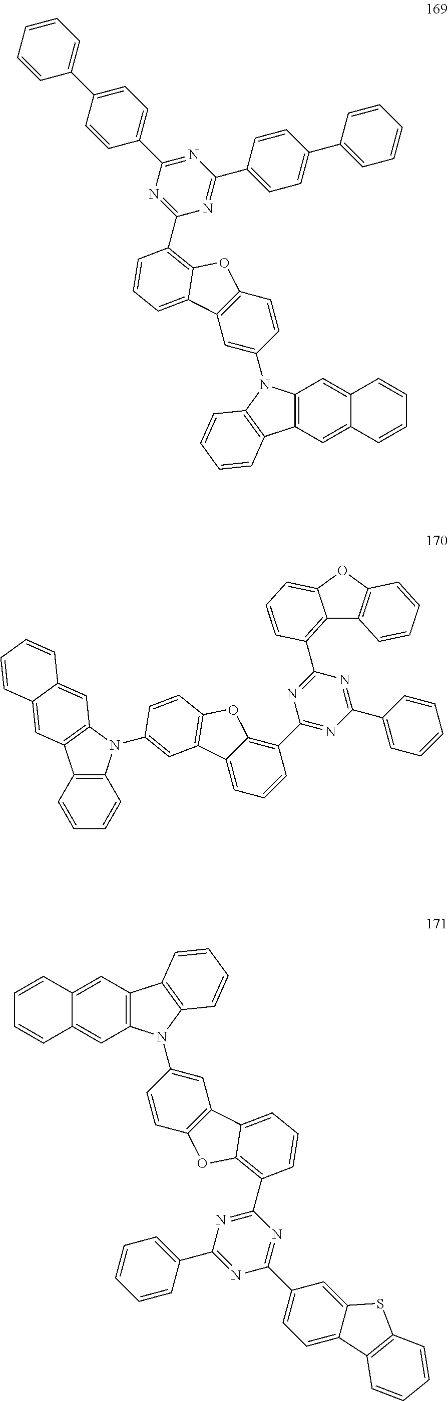 [SMILES: c1ccc(-c2ccc(-c3nc(-c4ccc(-c5ccccc5)cc4)nc(-c4cccc5c4oc4ccc(-n6c7ccccc7c7cc8ccccc8cc76)cc45)n3)cc2)cc1 ; c1ccc(-c2nc(-c3cccc4c3oc3ccc(-n5c6ccccc6c6cc7ccccc7cc65)cc34)nc(-c3cccc4oc5ccccc5c34)n2)cc1 ; c1ccc(-c2nc(-c3ccc4c(c3)sc3ccccc34)nc(-c3cccc4c3oc3ccc(-n5c6ccccc6c6cc7ccccc7cc65)cc34)n2)cc1]

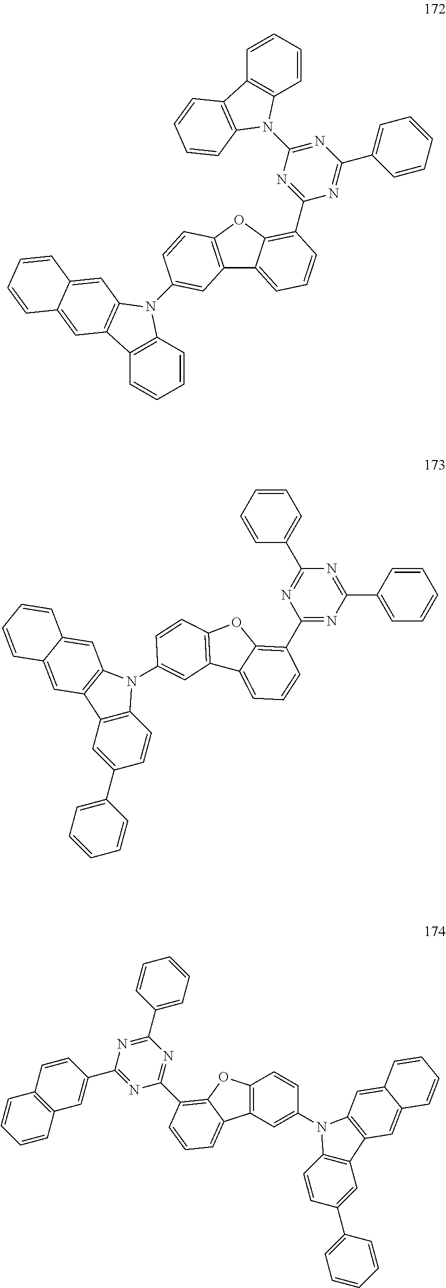 [SMILES: c1ccc(-c2nc(-c3cccc4c3oc3ccc(-n5c6ccccc6c6cc7ccccc7cc65)cc34)nc(-n3c4ccccc4c4ccccc43)n2)cc1 ; c1ccc(-c2ccc3c(c2)c2cc4ccccc4cc2n3-c2ccc3oc4c(-c5nc(-c6ccccc6)nc(-c6ccccc6)n5)cccc4c3c2)cc1 ; c1ccc(-c2ccc3c(c2)c2cc4ccccc4cc2n3-c2ccc3oc4c(-c5nc(-c6ccccc6)nc(-c6ccc7ccccc7c6)n5)cccc4c3c2)cc1]

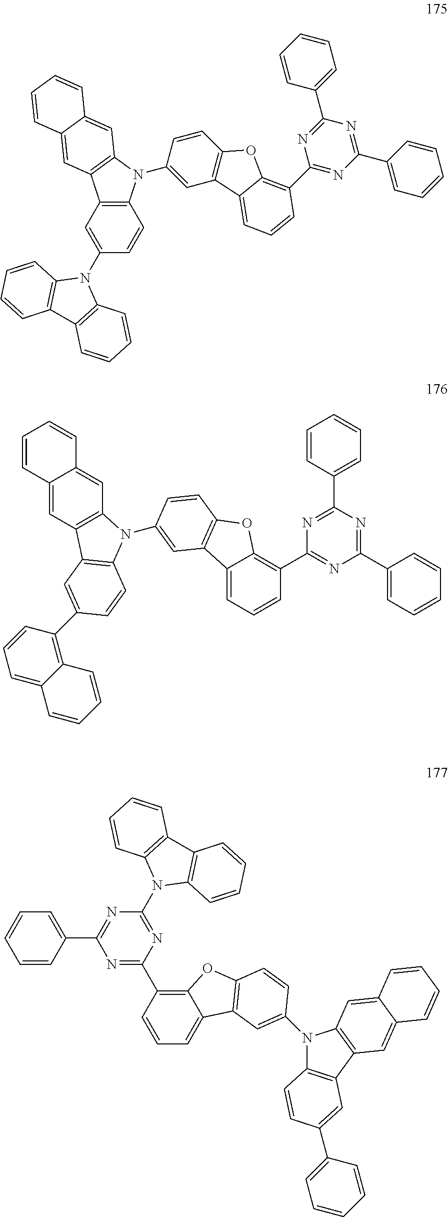 [SMILES: c1ccc(-c2nc(-c3ccccc3)nc(-c3cccc4c3oc3ccc(-n5c6ccc(-n7c8ccccc8c8ccccc87)cc6c6cc7ccccc7cc65)cc34)n2)cc1 ; c1ccc(-c2nc(-c3ccccc3)nc(-c3cccc4c3oc3ccc(-n5c6ccc(-c7cccc8ccccc78)cc6c6cc7ccccc7cc65)cc34)n2)cc1 ; c1ccc(-c2ccc3c(c2)c2cc4ccccc4cc2n3-c2ccc3oc4c(-c5nc(-c6ccccc6)nc(-n6c7ccccc7c7ccccc76)n5)cccc4c3c2)cc1]

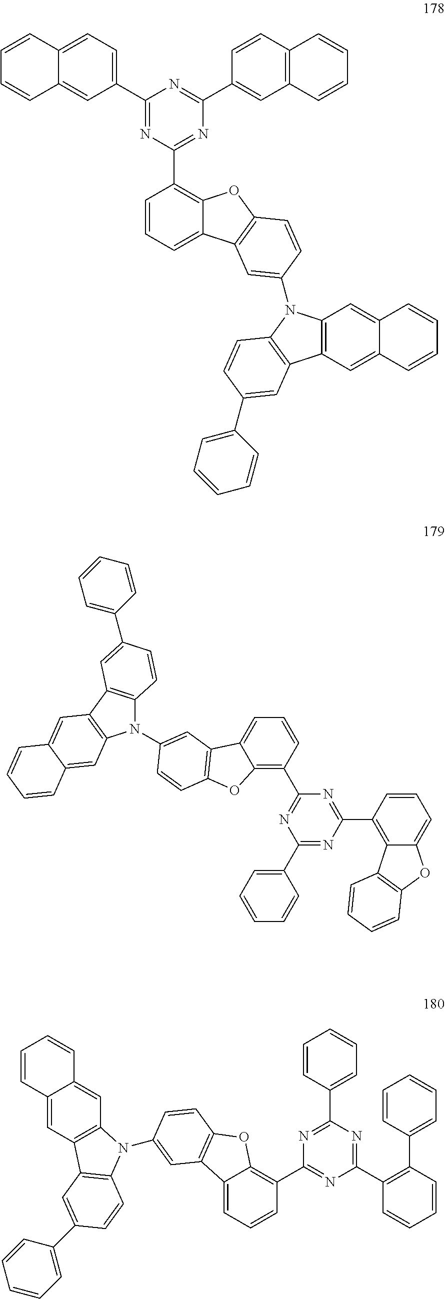 [SMILES: c1ccc(-c2ccc3c(c2)c2cc4ccccc4cc2n3-c2ccc3oc4c(-c5nc(-c6ccc7ccccc7c6)nc(-c6ccc7ccccc7c6)n5)cccc4c3c2)cc1 ; c1ccc(-c2ccc3c(c2)c2cc4ccccc4cc2n3-c2ccc3oc4c(-c5nc(-c6ccccc6)nc(-c6cccc7oc8ccccc8c67)n5)cccc4c3c2)cc1 ; c1ccc(-c2ccc3c(c2)c2cc4ccccc4cc2n3-c2ccc3oc4c(-c5nc(-c6ccccc6)nc(-c6ccccc6-c6ccccc6)n5)cccc4c3c2)cc1]

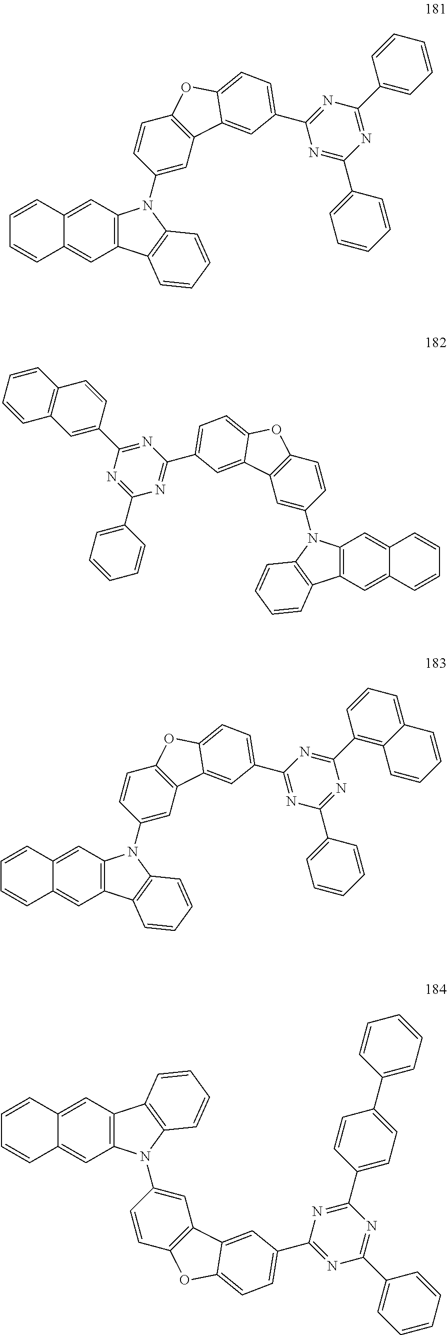 [SMILES: c1ccc(-c2nc(-c3ccccc3)nc(-c3ccc4oc5ccc(-n6c7ccccc7c7cc8ccccc8cc76)cc5c4c3)n2)cc1 ; c1ccc(-c2nc(-c3ccc4ccccc4c3)nc(-c3ccc4oc5ccc(-n6c7ccccc7c7cc8ccccc8cc76)cc5c4c3)n2)cc1 ; c1ccc(-c2nc(-c3ccc4oc5ccc(-n6c7ccccc7c7cc8ccccc8cc76)cc5c4c3)nc(-c3cccc4ccccc34)n2)cc1 ; c1ccc(-c2ccc(-c3nc(-c4ccccc4)nc(-c4ccc5oc6ccc(-n7c8ccccc8c8cc9ccccc9cc87)cc6c5c4)n3)cc2)cc1]

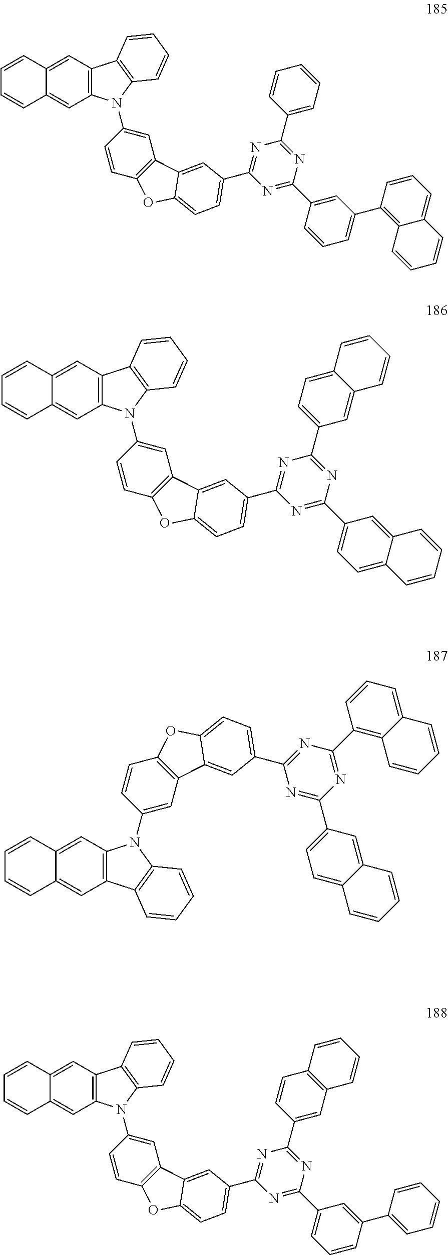 [SMILES: c1ccc(-c2nc(-c3cccc(-c4cccc5ccccc45)c3)nc(-c3ccc4oc5ccc(-n6c7ccccc7c7cc8ccccc8cc76)cc5c4c3)n2)cc1 ; c1ccc2cc(-c3nc(-c4ccc5ccccc5c4)nc(-c4ccc5oc6ccc(-n7c8ccccc8c8cc9ccccc9cc87)cc6c5c4)n3)ccc2c1 ; c1ccc2cc(-c3nc(-c4ccc5oc6ccc(-n7c8ccccc8c8cc9ccccc9cc87)cc6c5c4)nc(-c4cccc5ccccc45)n3)ccc2c1 ; c1ccc(-c2cccc(-c3nc(-c4ccc5ccccc5c4)nc(-c4ccc5oc6ccc(-n7c8ccccc8c8cc9ccccc9cc87)cc6c5c4)n3)c2)cc1]

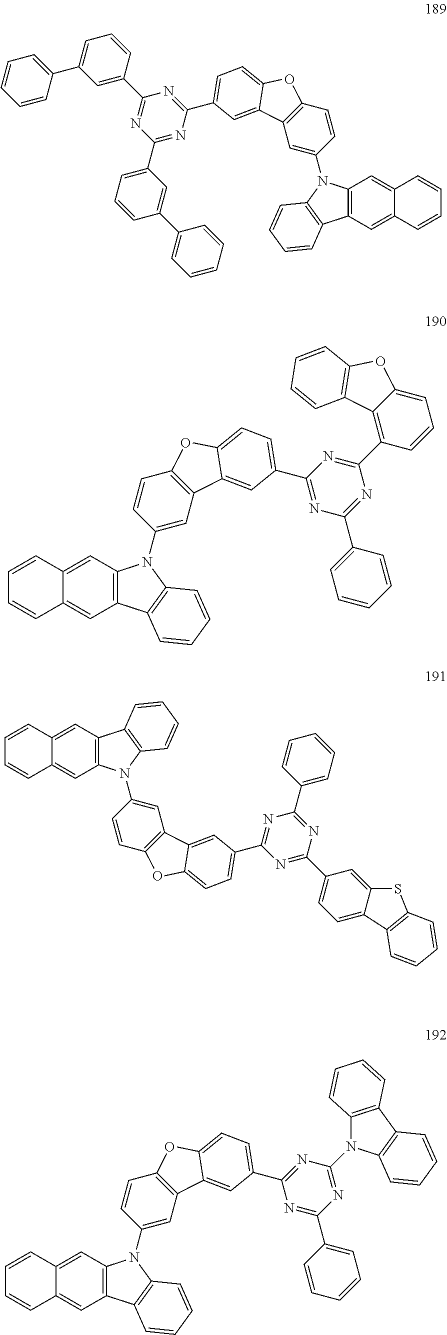 [SMILES: c1ccc(-c2cccc(-c3nc(-c4cccc(-c5ccccc5)c4)nc(-c4ccc5oc6ccc(-n7c8ccccc8c8cc9ccccc9cc87)cc6c5c4)n3)c2)cc1 ; c1ccc(-c2nc(-c3ccc4oc5ccc(-n6c7ccccc7c7cc8ccccc8cc76)cc5c4c3)nc(-c3cccc4oc5ccccc5c34)n2)cc1 ; c1ccc(-c2nc(-c3ccc4c(c3)sc3ccccc34)nc(-c3ccc4oc5ccc(-n6c7ccccc7c7cc8ccccc8cc76)cc5c4c3)n2)cc1 ; c1ccc(-c2nc(-c3ccc4oc5ccc(-n6c7ccccc7c7cc8ccccc8cc76)cc5c4c3)nc(-n3c4ccccc4c4ccccc43)n2)cc1]

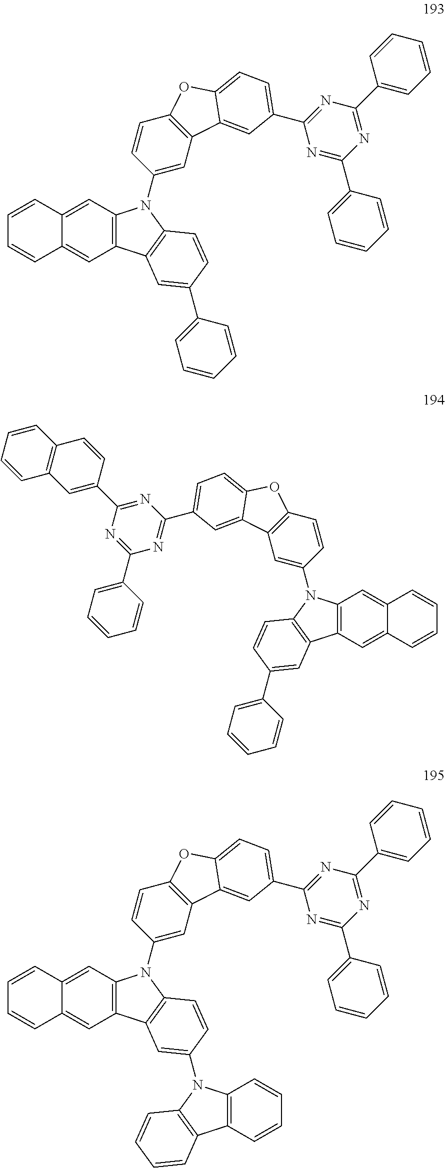 [SMILES: c1ccc(-c2ccc3c(c2)c2cc4ccccc4cc2n3-c2ccc3oc4ccc(-c5nc(-c6ccccc6)nc(-c6ccccc6)n5)cc4c3c2)cc1 ; c1ccc(-c2ccc3c(c2)c2cc4ccccc4cc2n3-c2ccc3oc4ccc(-c5nc(-c6ccccc6)nc(-c6ccc7ccccc7c6)n5)cc4c3c2)cc1 ; c1ccc(-c2nc(-c3ccccc3)nc(-c3ccc4oc5ccc(-n6c7ccc(-n8c9ccccc9c9ccccc98)cc7c7cc8ccccc8cc76)cc5c4c3)n2)cc1]

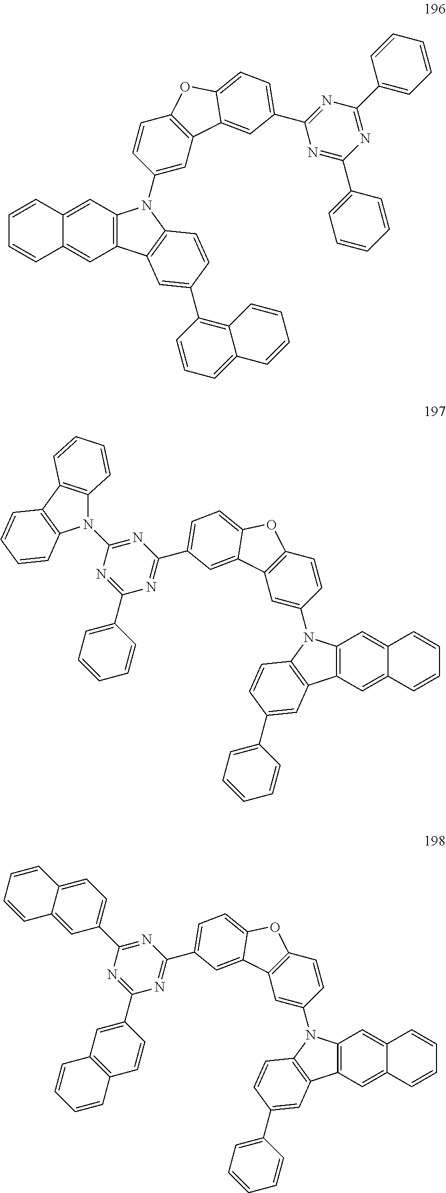 [SMILES: c1ccc(-c2nc(-c3ccccc3)nc(-c3ccc4oc5ccc(-n6c7ccc(-c8cccc9ccccc89)cc7c7cc8ccccc8cc76)cc5c4c3)n2)cc1 ; c1ccc(-c2ccc3c(c2)c2cc4ccccc4cc2n3-c2ccc3oc4ccc(-c5nc(-c6ccccc6)nc(-n6c7ccccc7c7ccccc76)n5)cc4c3c2)cc1 ; c1ccc(-c2ccc3c(c2)c2cc4ccccc4cc2n3-c2ccc3oc4ccc(-c5nc(-c6ccc7ccccc7c6)nc(-c6ccc7ccccc7c6)n5)cc4c3c2)cc1]

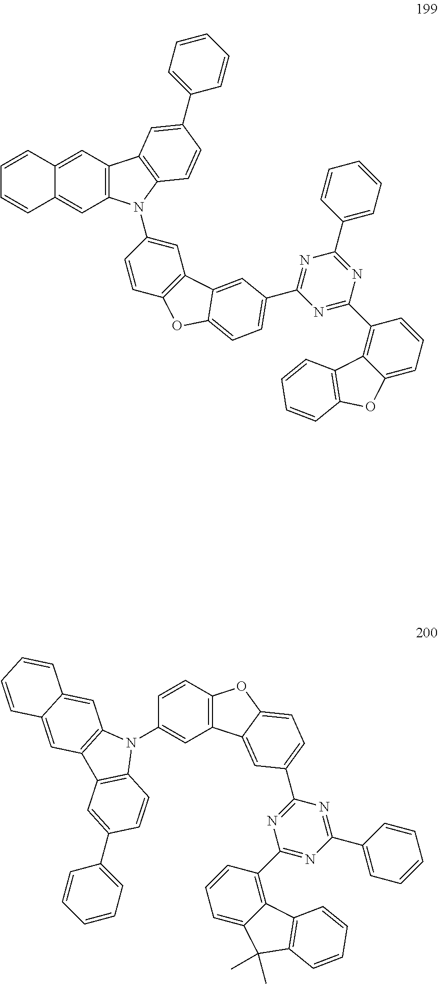 [SMILES: c1ccc(-c2ccc3c(c2)c2cc4ccccc4cc2n3-c2ccc3oc4ccc(-c5nc(-c6ccccc6)nc(-c6cccc7oc8ccccc8c67)n5)cc4c3c2)cc1 ; CC1(C)c2ccccc2-c2c(-c3nc(-c4ccccc4)nc(-c4ccc5oc6ccc(-n7c8ccc(-c9ccccc9)cc8c8cc9ccccc9cc87)cc6c5c4)n3)cccc21]

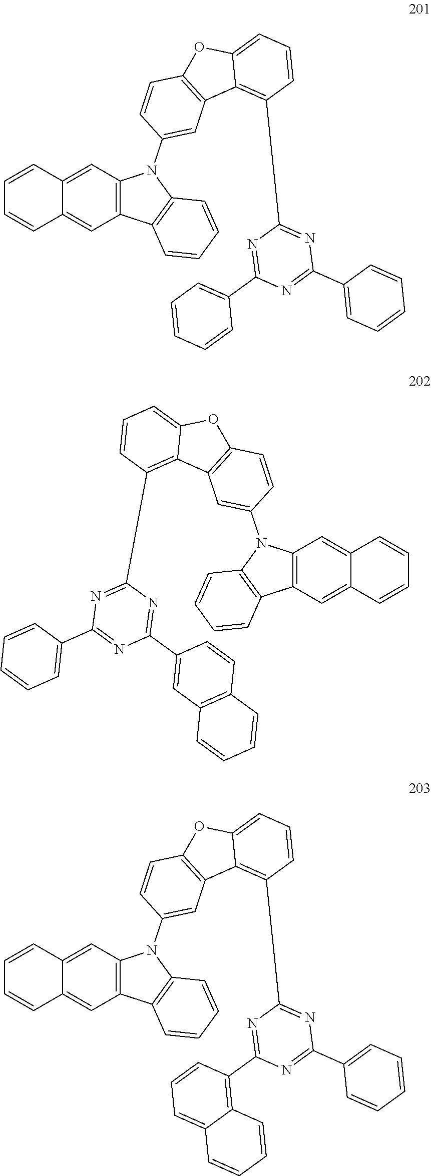 [SMILES: c1ccc(-c2nc(-c3ccccc3)nc(-c3cccc4oc5ccc(-n6c7ccccc7c7cc8ccccc8cc76)cc5c34)n2)cc1 ; c1ccc(-c2nc(-c3ccc4ccccc4c3)nc(-c3cccc4oc5ccc(-n6c7ccccc7c7cc8ccccc8cc76)cc5c34)n2)cc1 ; c1ccc(-c2nc(-c3cccc4ccccc34)nc(-c3cccc4oc5ccc(-n6c7ccccc7c7cc8ccccc8cc76)cc5c34)n2)cc1]

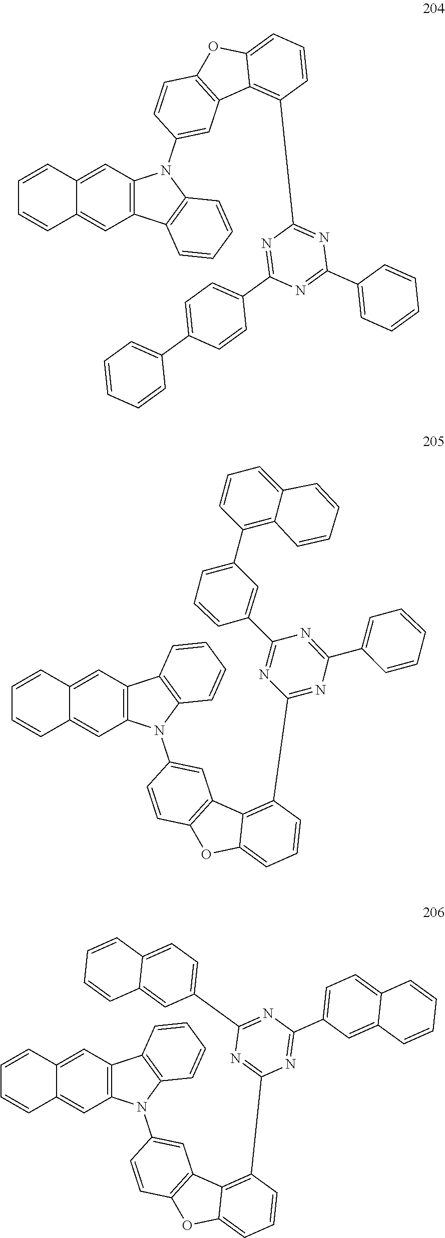 [SMILES: c1ccc(-c2ccc(-c3nc(-c4ccccc4)nc(-c4cccc5oc6ccc(-n7c8ccccc8c8cc9ccccc9cc87)cc6c45)n3)cc2)cc1 ; c1ccc(-c2nc(-c3cccc(-c4cccc5ccccc45)c3)nc(-c3cccc4oc5ccc(-n6c7ccccc7c7cc8ccccc8cc76)cc5c34)n2)cc1 ; c1ccc2cc(-c3nc(-c4ccc5ccccc5c4)nc(-c4cccc5oc6ccc(-n7c8ccccc8c8cc9ccccc9cc87)cc6c45)n3)ccc2c1]

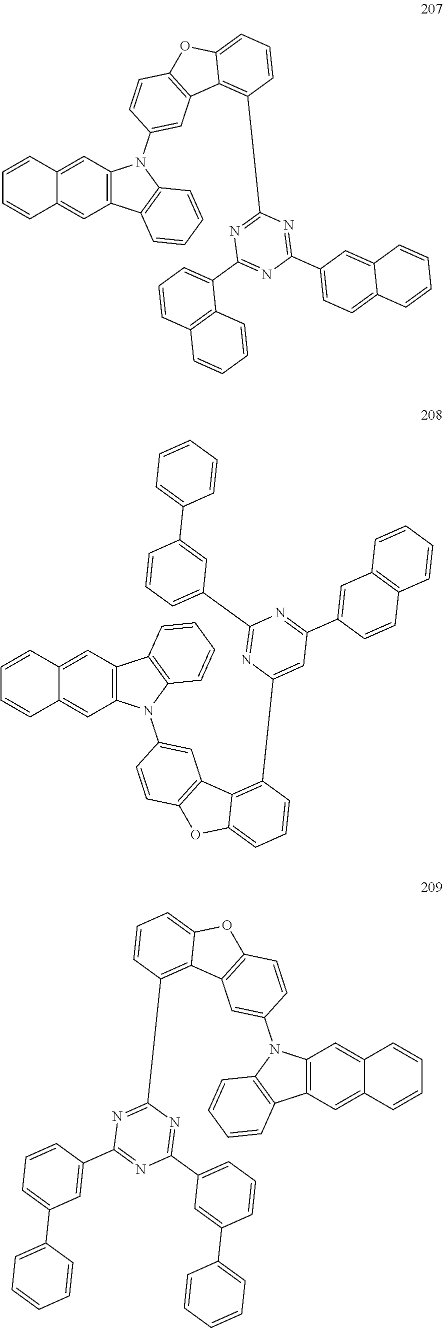 [SMILES: c1ccc2cc(-c3nc(-c4cccc5ccccc45)nc(-c4cccc5oc6ccc(-n7c8ccccc8c8cc9ccccc9cc87)cc6c45)n3)ccc2c1 ; c1ccc(-c2cccc(-c3nc(-c4ccc5ccccc5c4)cc(-c4cccc5oc6ccc(-n7c8ccccc8c8cc9ccccc9cc87)cc6c45)n3)c2)cc1 ; c1ccc(-c2cccc(-c3nc(-c4cccc(-c5ccccc5)c4)nc(-c4cccc5oc6ccc(-n7c8ccccc8c8cc9ccccc9cc87)cc6c45)n3)c2)cc1]

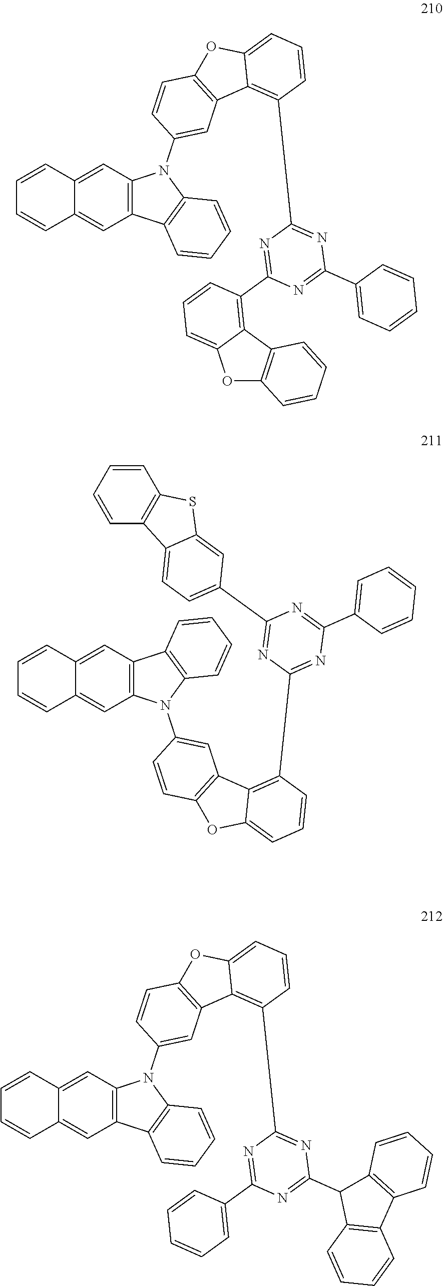 [SMILES: c1ccc(-c2nc(-c3cccc4oc5ccccc5c34)nc(-c3cccc4oc5ccc(-n6c7ccccc7c7cc8ccccc8cc76)cc5c34)n2)cc1 ; c1ccc(-c2nc(-c3ccc4c(c3)sc3ccccc34)nc(-c3cccc4oc5ccc(-n6c7ccccc7c7cc8ccccc8cc76)cc5c34)n2)cc1 ; c1ccc(-c2nc(-c3cccc4oc5ccc(-n6c7ccccc7c7cc8ccccc8cc76)cc5c34)nc(C3c4ccccc4-c4ccccc43)n2)cc1]

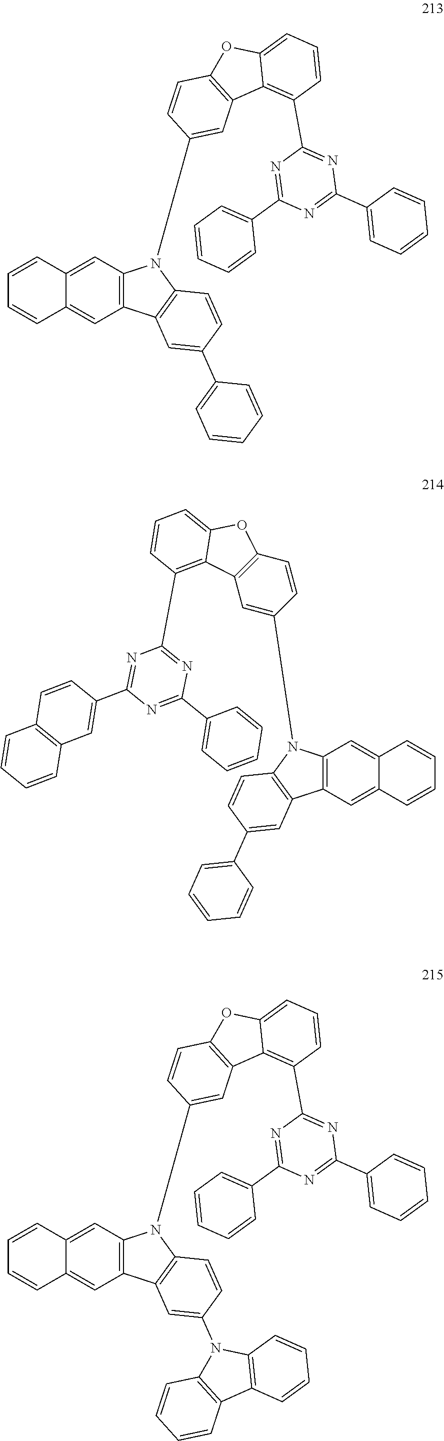 [SMILES: c1ccc(-c2ccc3c(c2)c2cc4ccccc4cc2n3-c2ccc3oc4cccc(-c5nc(-c6ccccc6)nc(-c6ccccc6)n5)c4c3c2)cc1 ; c1ccc(-c2ccc3c(c2)c2cc4ccccc4cc2n3-c2ccc3oc4cccc(-c5nc(-c6ccccc6)nc(-c6ccc7ccccc7c6)n5)c4c3c2)cc1 ; c1ccc(-c2nc(-c3ccccc3)nc(-c3cccc4oc5ccc(-n6c7ccc(-n8c9ccccc9c9ccccc98)cc7c7cc8ccccc8cc76)cc5c34)n2)cc1]

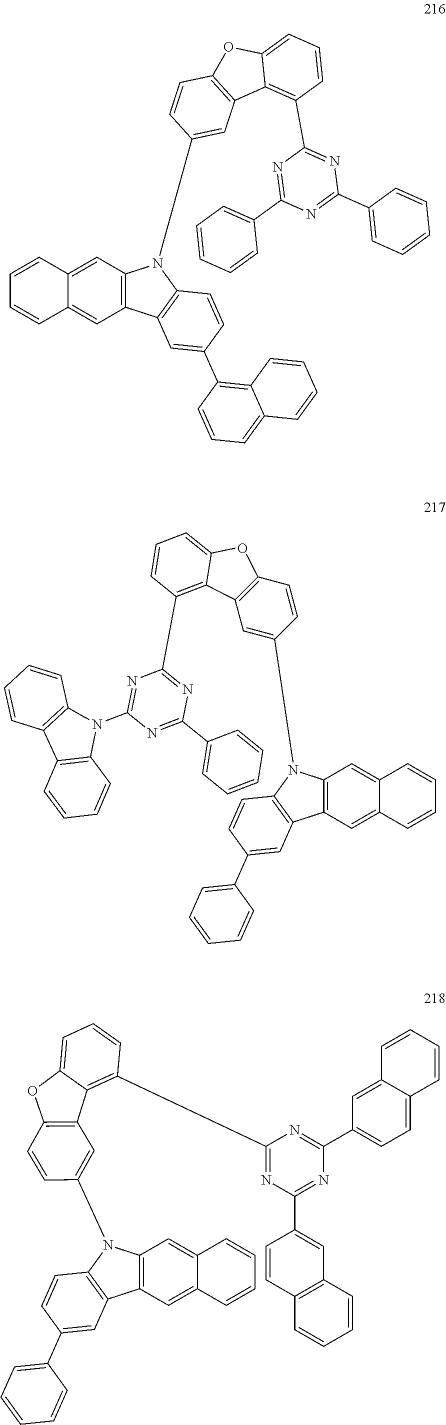 [SMILES: c1ccc(-c2nc(-c3ccccc3)nc(-c3cccc4oc5ccc(-n6c7ccc(-c8cccc9ccccc89)cc7c7cc8ccccc8cc76)cc5c34)n2)cc1 ; c1ccc(-c2ccc3c(c2)c2cc4ccccc4cc2n3-c2ccc3oc4cccc(-c5nc(-c6ccccc6)nc(-n6c7ccccc7c7ccccc76)n5)c4c3c2)cc1 ; c1ccc(-c2ccc3c(c2)c2cc4ccccc4cc2n3-c2ccc3oc4cccc(-c5nc(-c6ccc7ccccc7c6)nc(-c6ccc7ccccc7c6)n5)c4c3c2)cc1]

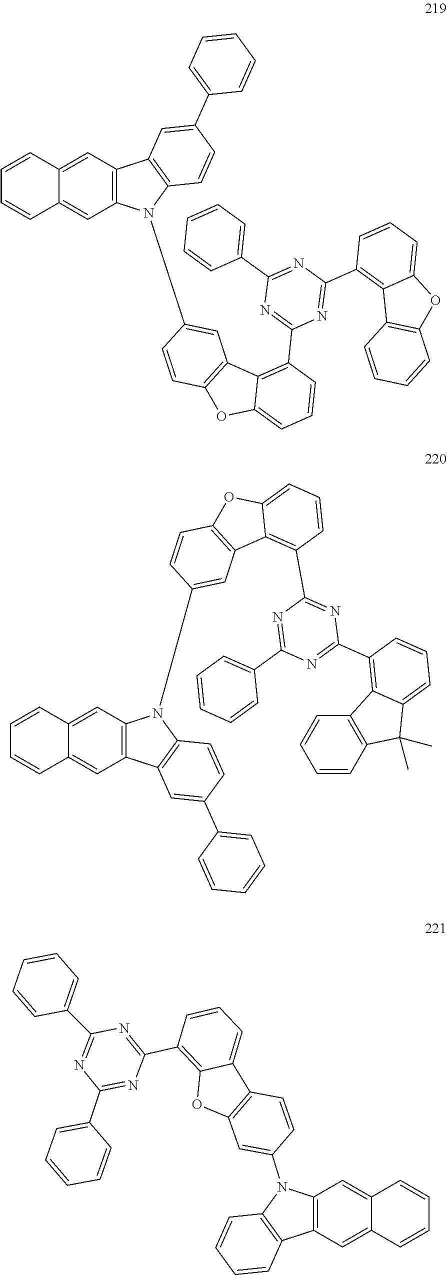 [SMILES: c1ccc(-c2ccc3c(c2)c2cc4ccccc4cc2n3-c2ccc3oc4cccc(-c5nc(-c6ccccc6)nc(-c6cccc7oc8ccccc8c67)n5)c4c3c2)cc1 ; CC1(C)c2ccccc2-c2c(-c3nc(-c4ccccc4)nc(-c4cccc5oc6ccc(-n7c8ccc(-c9ccccc9)cc8c8cc9ccccc9cc87)cc6c45)n3)cccc21 ; c1ccc(-c2nc(-c3ccccc3)nc(-c3cccc4c3oc3cc(-n5c6ccccc6c6cc7ccccc7cc65)ccc34)n2)cc1]

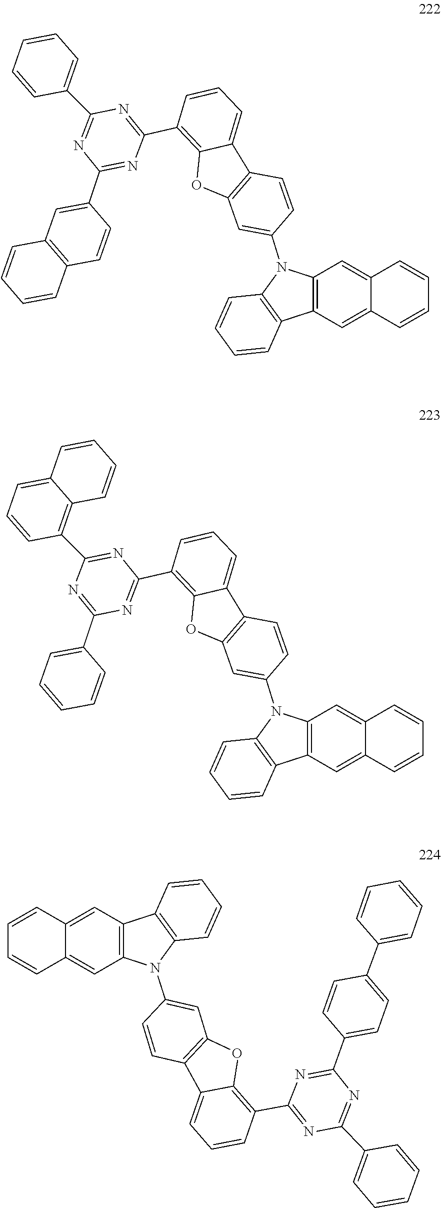 [SMILES: c1ccc(-c2nc(-c3ccc4ccccc4c3)nc(-c3cccc4c3oc3cc(-n5c6ccccc6c6cc7ccccc7cc65)ccc34)n2)cc1 ; c1ccc(-c2nc(-c3cccc4ccccc34)nc(-c3cccc4c3oc3cc(-n5c6ccccc6c6cc7ccccc7cc65)ccc34)n2)cc1 ; c1ccc(-c2ccc(-c3nc(-c4ccccc4)nc(-c4cccc5c4oc4cc(-n6c7ccccc7c7cc8ccccc8cc76)ccc45)n3)cc2)cc1]

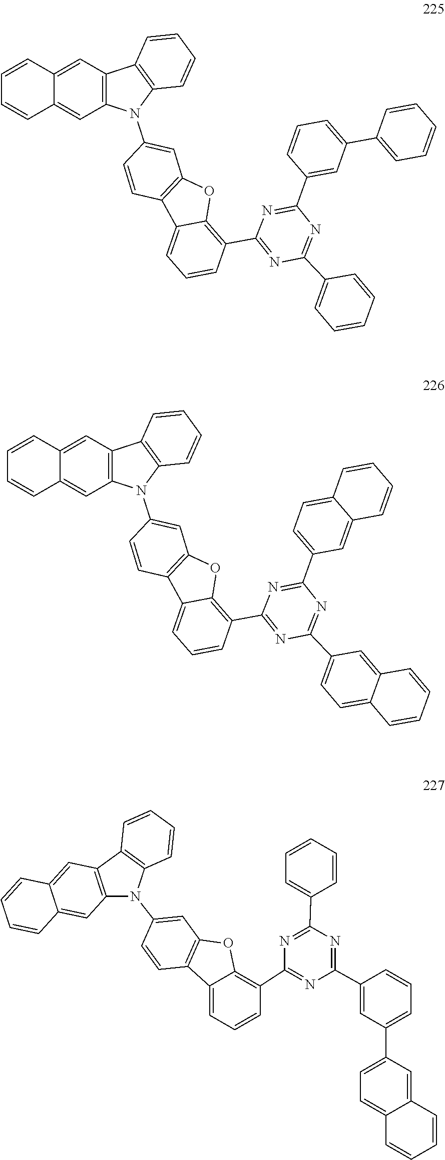 [SMILES: c1ccc(-c2cccc(-c3nc(-c4ccccc4)nc(-c4cccc5c4oc4cc(-n6c7ccccc7c7cc8ccccc8cc76)ccc45)n3)c2)cc1 ; c1ccc2cc(-c3nc(-c4ccc5ccccc5c4)nc(-c4cccc5c4oc4cc(-n6c7ccccc7c7cc8ccccc8cc76)ccc45)n3)ccc2c1 ; c1ccc(-c2nc(-c3cccc(-c4ccc5ccccc5c4)c3)nc(-c3cccc4c3oc3cc(-n5c6ccccc6c6cc7ccccc7cc65)ccc34)n2)cc1]

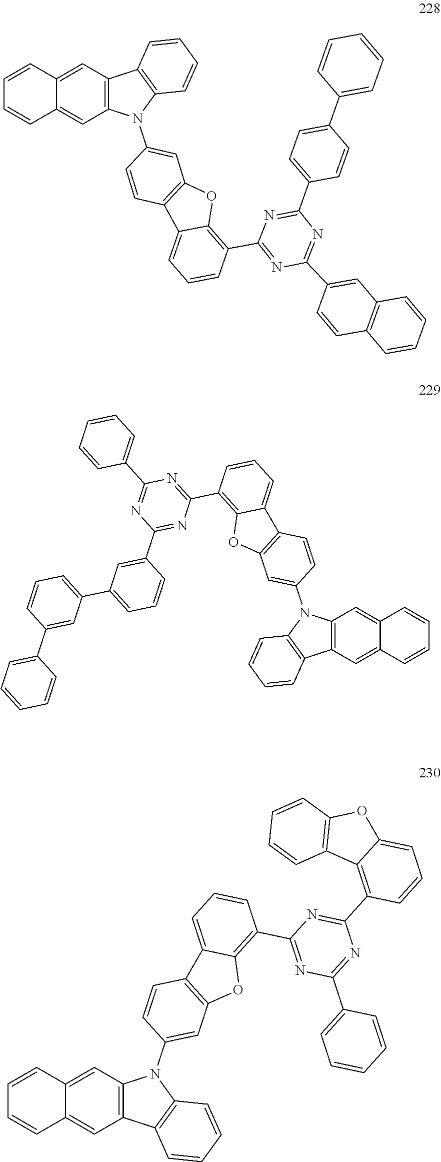 [SMILES: c1ccc(-c2ccc(-c3nc(-c4ccc5ccccc5c4)nc(-c4cccc5c4oc4cc(-n6c7ccccc7c7cc8ccccc8cc76)ccc45)n3)cc2)cc1 ; c1ccc(-c2cccc(-c3cccc(-c4nc(-c5ccccc5)nc(-c5cccc6c5oc5cc(-n7c8ccccc8c8cc9ccccc9cc87)ccc56)n4)c3)c2)cc1 ; c1ccc(-c2nc(-c3cccc4c3oc3cc(-n5c6ccccc6c6cc7ccccc7cc65)ccc34)nc(-c3cccc4oc5ccccc5c34)n2)cc1]

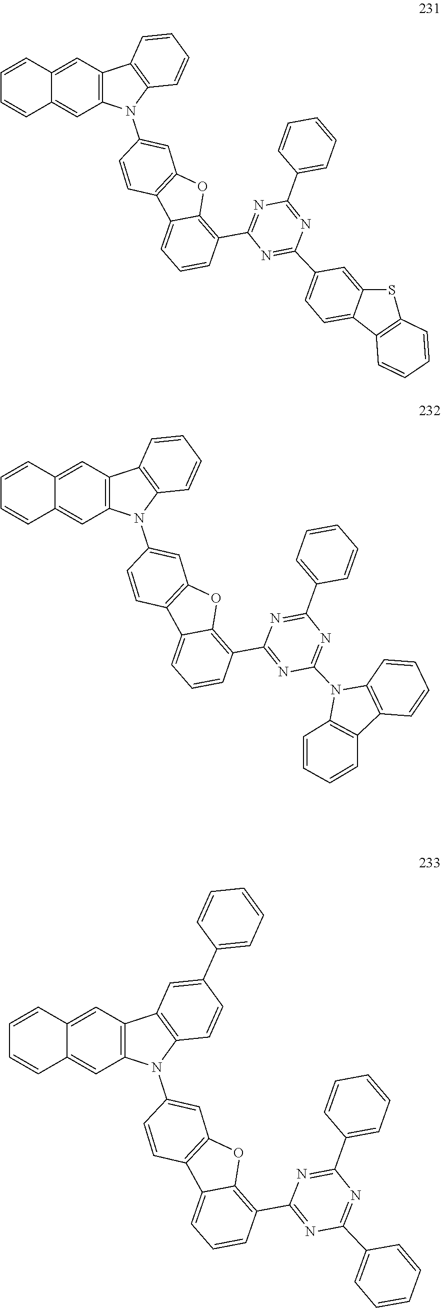 [SMILES: c1ccc(-c2nc(-c3ccc4c(c3)sc3ccccc34)nc(-c3cccc4c3oc3cc(-n5c6ccccc6c6cc7ccccc7cc65)ccc34)n2)cc1 ; c1ccc(-c2nc(-c3cccc4c3oc3cc(-n5c6ccccc6c6cc7ccccc7cc65)ccc34)nc(-n3c4ccccc4c4ccccc43)n2)cc1 ; c1ccc(-c2ccc3c(c2)c2cc4ccccc4cc2n3-c2ccc3c(c2)oc2c(-c4nc(-c5ccccc5)nc(-c5ccccc5)n4)cccc23)cc1]

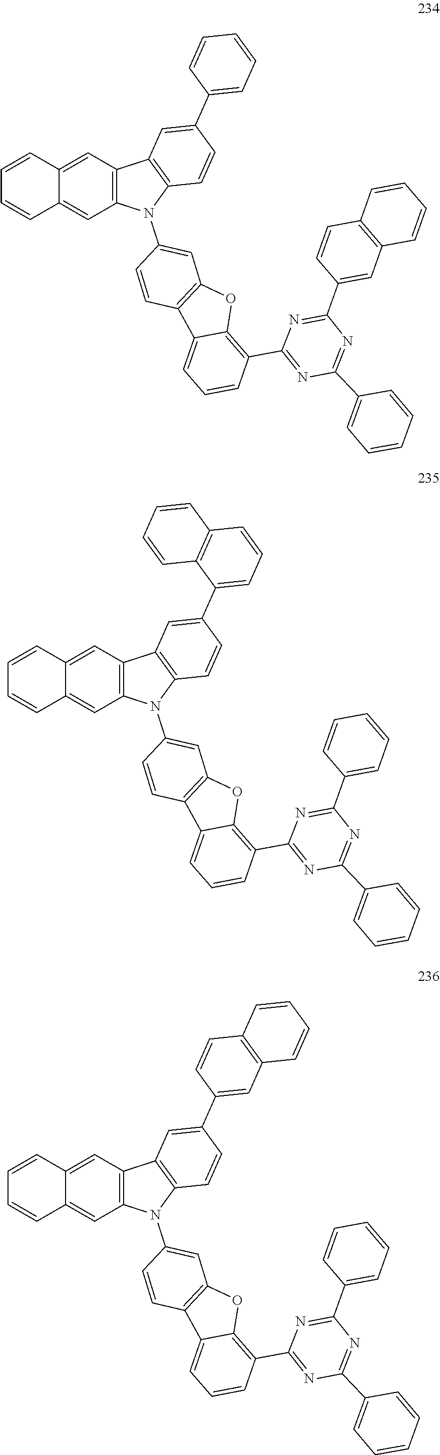 [SMILES: c1ccc(-c2ccc3c(c2)c2cc4ccccc4cc2n3-c2ccc3c(c2)oc2c(-c4nc(-c5ccccc5)nc(-c5ccc6ccccc6c5)n4)cccc23)cc1 ; c1ccc(-c2nc(-c3ccccc3)nc(-c3cccc4c3oc3cc(-n5c6ccc(-c7cccc8ccccc78)cc6c6cc7ccccc7cc65)ccc34)n2)cc1 ; c1ccc(-c2nc(-c3ccccc3)nc(-c3cccc4c3oc3cc(-n5c6ccc(-c7ccc8ccccc8c7)cc6c6cc7ccccc7cc65)ccc34)n2)cc1]

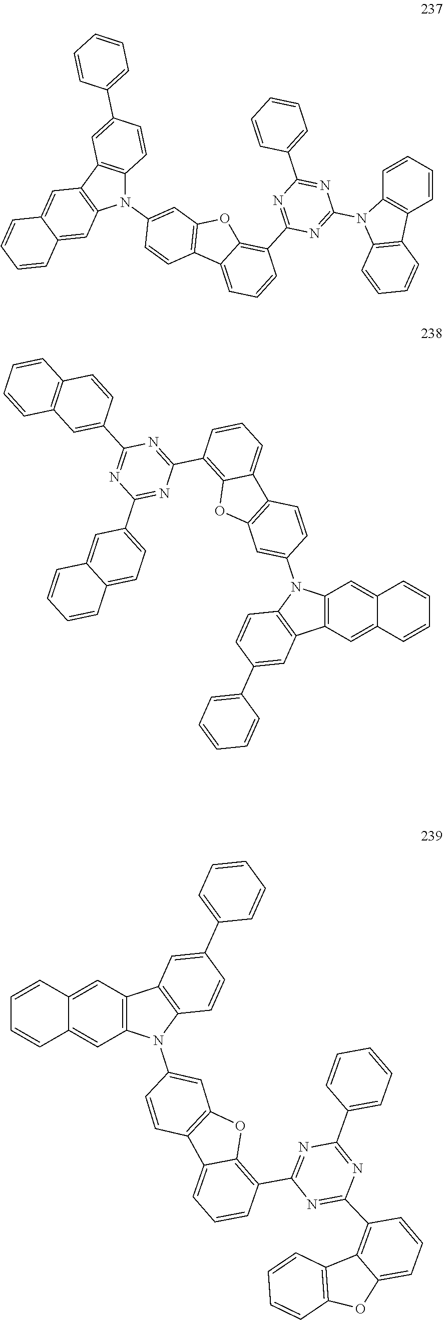 [SMILES: c1ccc(-c2ccc3c(c2)c2cc4ccccc4cc2n3-c2ccc3c(c2)oc2c(-c4nc(-c5ccccc5)nc(-n5c6ccccc6c6ccccc65)n4)cccc23)cc1 ; c1ccc(-c2ccc3c(c2)c2cc4ccccc4cc2n3-c2ccc3c(c2)oc2c(-c4nc(-c5ccc6ccccc6c5)nc(-c5ccc6ccccc6c5)n4)cccc23)cc1 ; c1ccc(-c2ccc3c(c2)c2cc4ccccc4cc2n3-c2ccc3c(c2)oc2c(-c4nc(-c5ccccc5)nc(-c5cccc6oc7ccccc7c56)n4)cccc23)cc1]

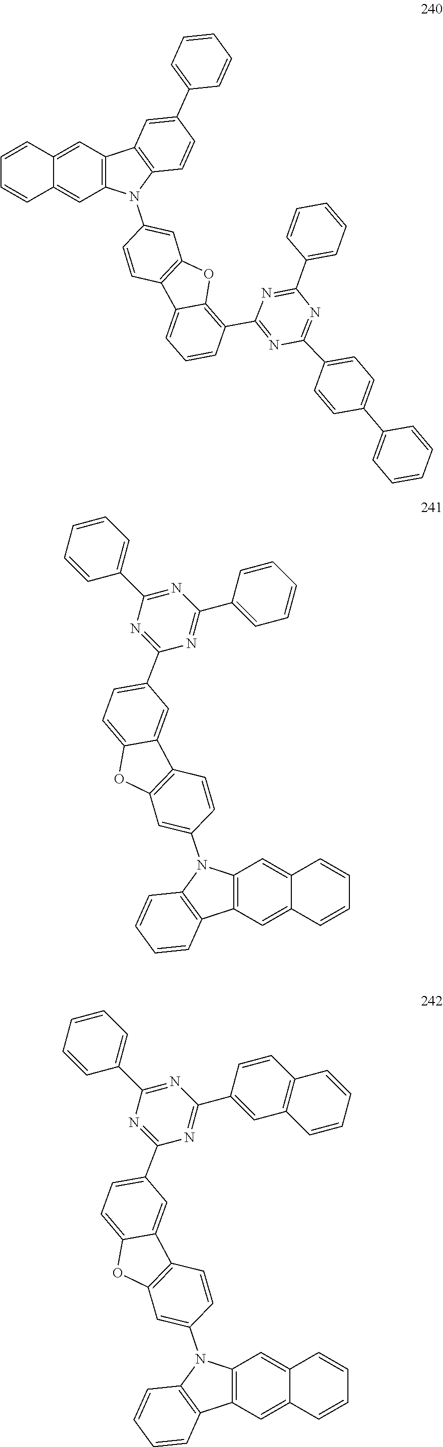 [SMILES: c1ccc(-c2ccc(-c3nc(-c4ccccc4)nc(-c4cccc5c4oc4cc(-n6c7ccc(-c8ccccc8)cc7c7cc8ccccc8cc76)ccc45)n3)cc2)cc1 ; c1ccc(-c2nc(-c3ccccc3)nc(-c3ccc4oc5cc(-n6c7ccccc7c7cc8ccccc8cc76)ccc5c4c3)n2)cc1 ; c1ccc(-c2nc(-c3ccc4ccccc4c3)nc(-c3ccc4oc5cc(-n6c7ccccc7c7cc8ccccc8cc76)ccc5c4c3)n2)cc1]

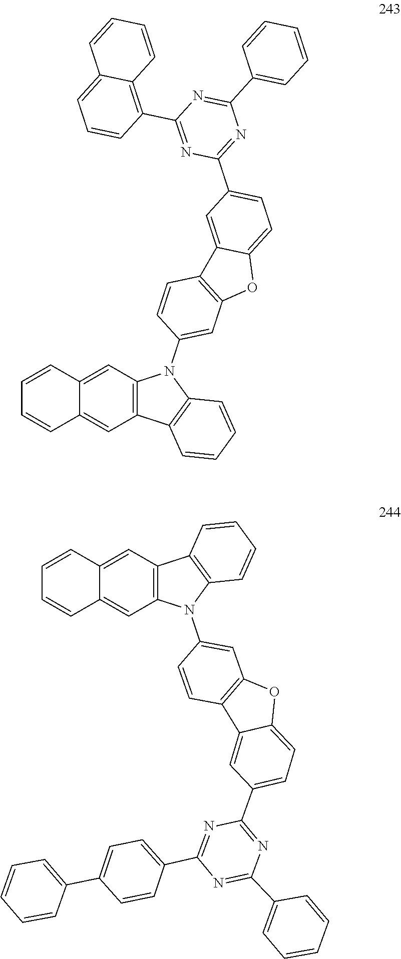 [SMILES: c1ccc(-c2nc(-c3ccc4oc5cc(-n6c7ccccc7c7cc8ccccc8cc76)ccc5c4c3)nc(-c3cccc4ccccc34)n2)cc1 ; c1ccc(-c2ccc(-c3nc(-c4ccccc4)nc(-c4ccc5oc6cc(-n7c8ccccc8c8cc9ccccc9cc87)ccc6c5c4)n3)cc2)cc1]

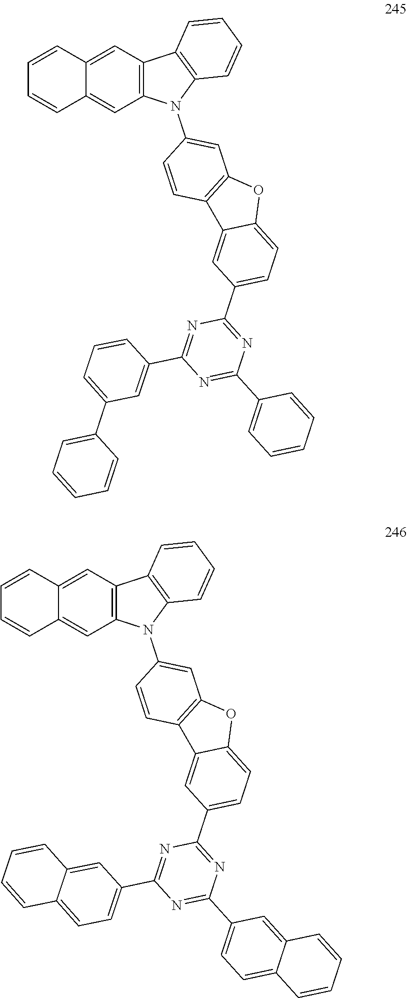 [SMILES: c1ccc(-c2cccc(-c3nc(-c4ccccc4)nc(-c4ccc5oc6cc(-n7c8ccccc8c8cc9ccccc9cc87)ccc6c5c4)n3)c2)cc1 ; c1ccc2cc(-c3nc(-c4ccc5ccccc5c4)nc(-c4ccc5oc6cc(-n7c8ccccc8c8cc9ccccc9cc87)ccc6c5c4)n3)ccc2c1]

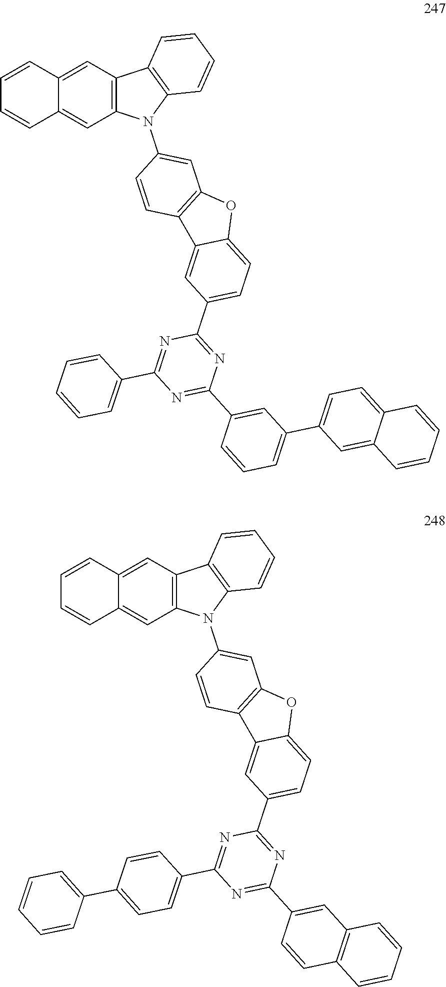 [SMILES: c1ccc(-c2nc(-c3cccc(-c4ccc5ccccc5c4)c3)nc(-c3ccc4oc5cc(-n6c7ccccc7c7cc8ccccc8cc76)ccc5c4c3)n2)cc1 ; c1ccc(-c2ccc(-c3nc(-c4ccc5ccccc5c4)nc(-c4ccc5oc6cc(-n7c8ccccc8c8cc9ccccc9cc87)ccc6c5c4)n3)cc2)cc1]

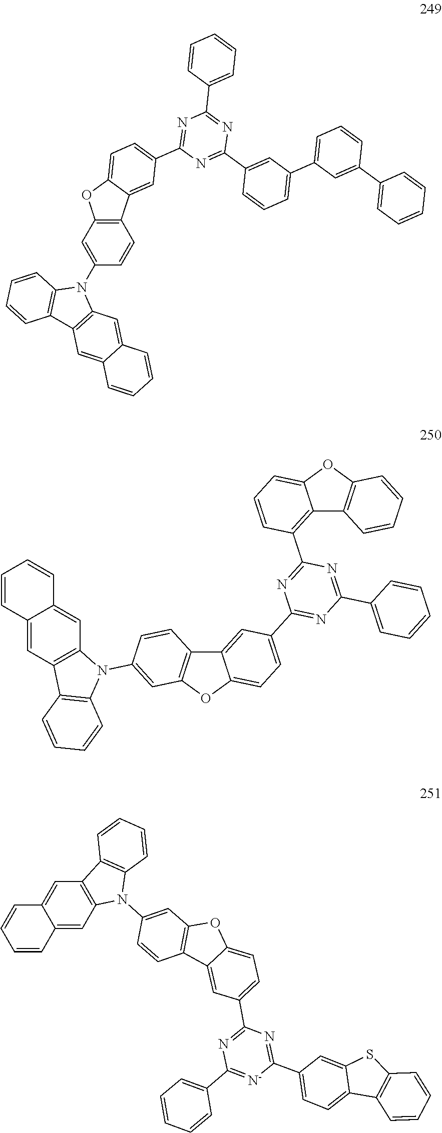

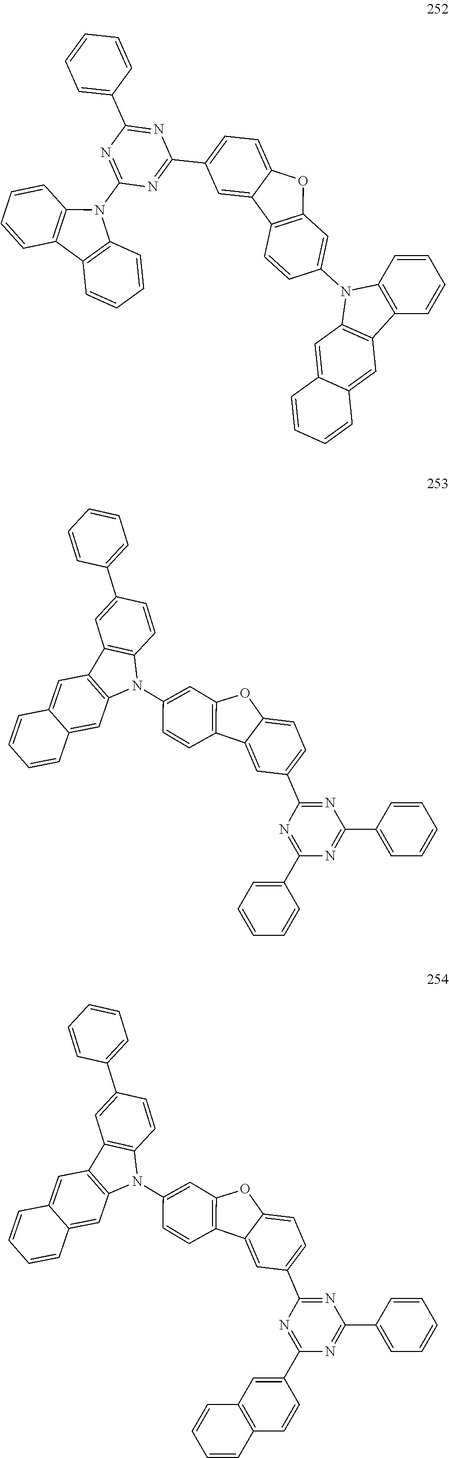

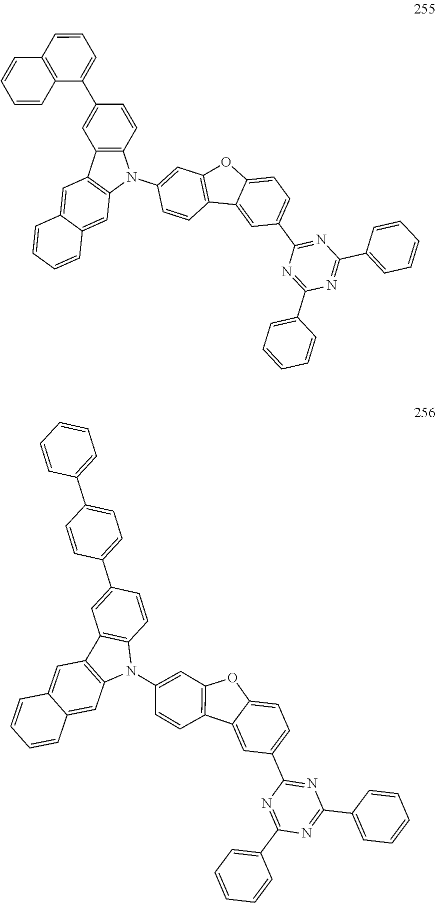

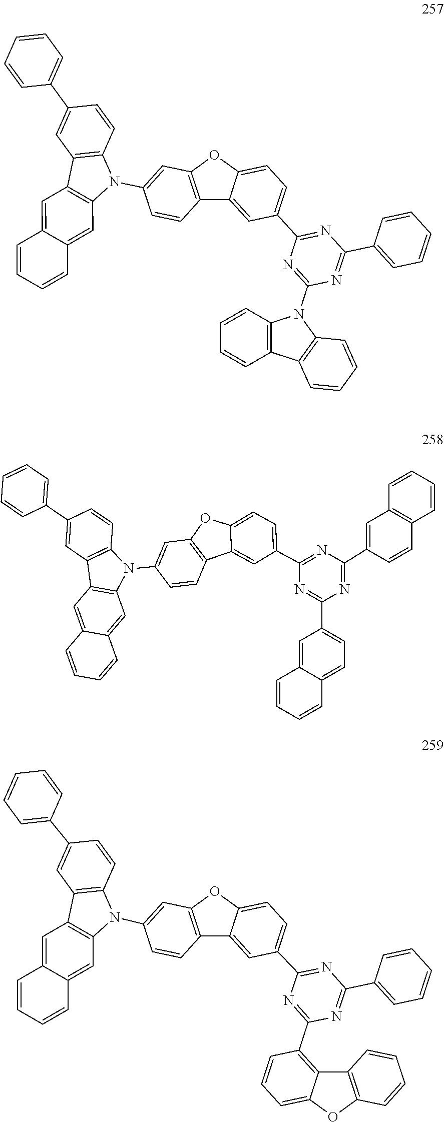 [SMILES: c1ccc(-c2ccc3c(c2)c2cc4ccccc4cc2n3-c2ccc3c(c2)oc2ccc(-c4nc(-c5ccccc5)nc(-n5c6ccccc6c6ccccc65)n4)cc23)cc1 ; c1ccc(-c2ccc3c(c2)c2cc4ccccc4cc2n3-c2ccc3c(c2)oc2ccc(-c4nc(-c5ccc6ccccc6c5)nc(-c5ccc6ccccc6c5)n4)cc23)cc1 ; c1ccc(-c2ccc3c(c2)c2cc4ccccc4cc2n3-c2ccc3c(c2)oc2ccc(-c4nc(-c5ccccc5)nc(-c5cccc6oc7ccccc7c56)n4)cc23)cc1]

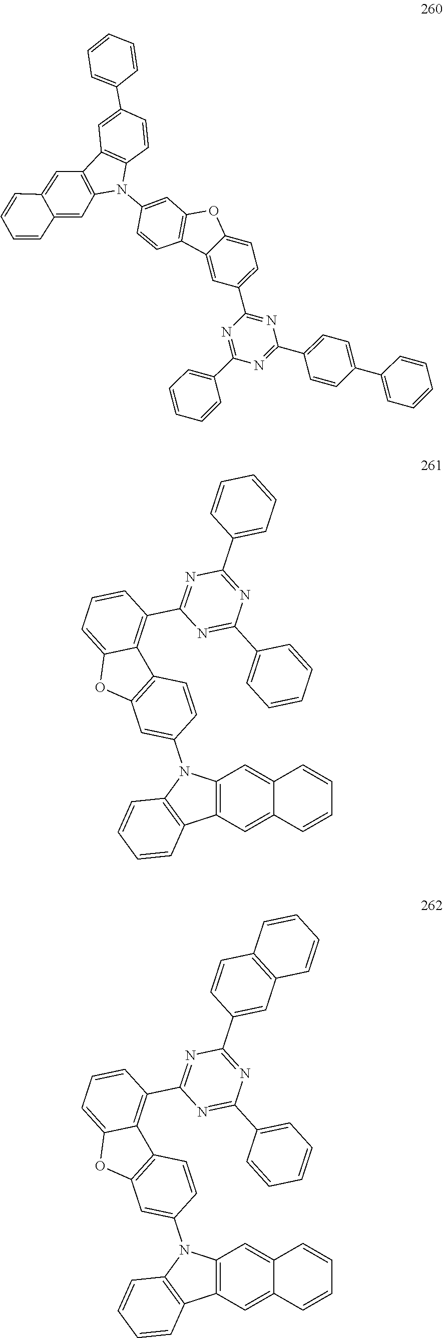

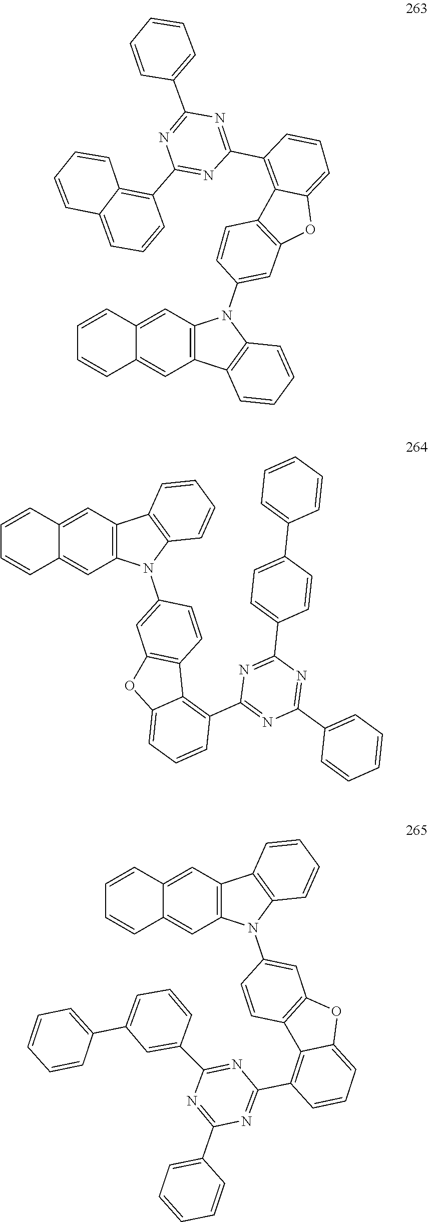

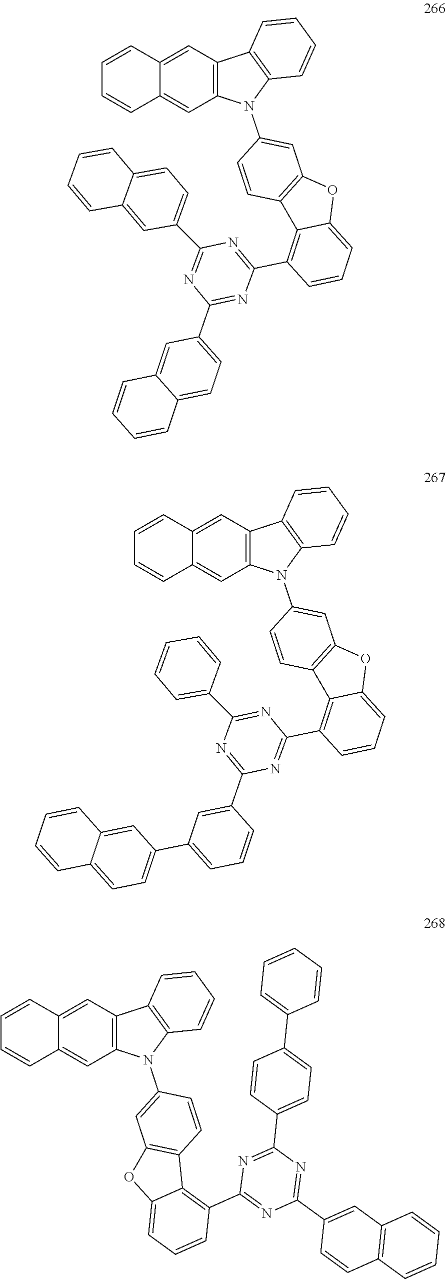 [SMILES: c1ccc2cc(-c3nc(-c4ccc5ccccc5c4)nc(-c4cccc5oc6cc(-n7c8ccccc8c8cc9ccccc9cc87)ccc6c45)n3)ccc2c1 ; c1ccc(-c2nc(-c3cccc(-c4ccc5ccccc5c4)c3)nc(-c3cccc4oc5cc(-n6c7ccccc7c7cc8ccccc8cc76)ccc5c34)n2)cc1 ; c1ccc(-c2ccc(-c3nc(-c4ccc5ccccc5c4)nc(-c4cccc5oc6cc(-n7c8ccccc8c8cc9ccccc9cc87)ccc6c45)n3)cc2)cc1]

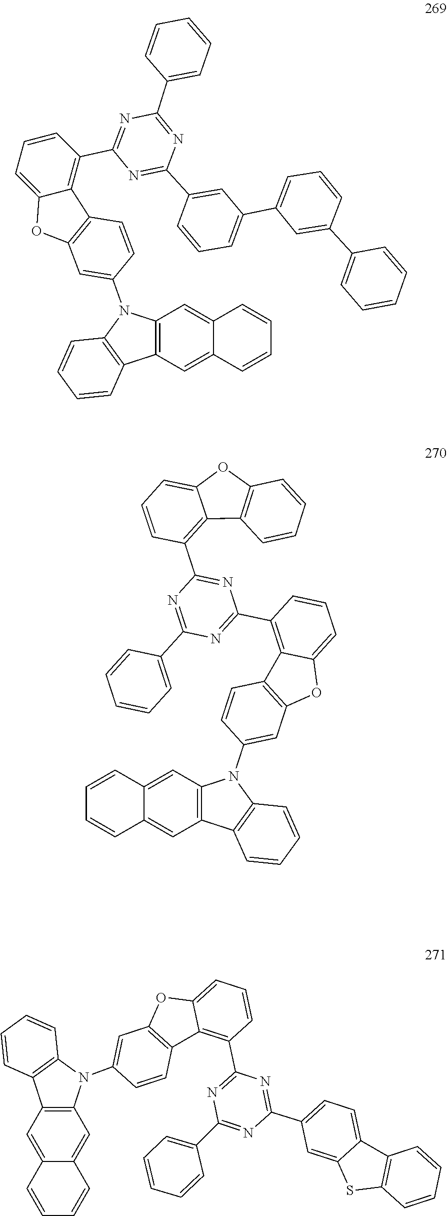 [SMILES: c1ccc(-c2cccc(-c3cccc(-c4nc(-c5ccccc5)nc(-c5cccc6oc7cc(-n8c9ccccc9c9cc%10ccccc%10cc98)ccc7c56)n4)c3)c2)cc1 ; c1ccc(-c2nc(-c3cccc4oc5ccccc5c34)nc(-c3cccc4oc5cc(-n6c7ccccc7c7cc8ccccc8cc76)ccc5c34)n2)cc1 ; c1ccc(-c2nc(-c3ccc4c(c3)sc3ccccc34)nc(-c3cccc4oc5cc(-n6c7ccccc7c7cc8ccccc8cc76)ccc5c34)n2)cc1]

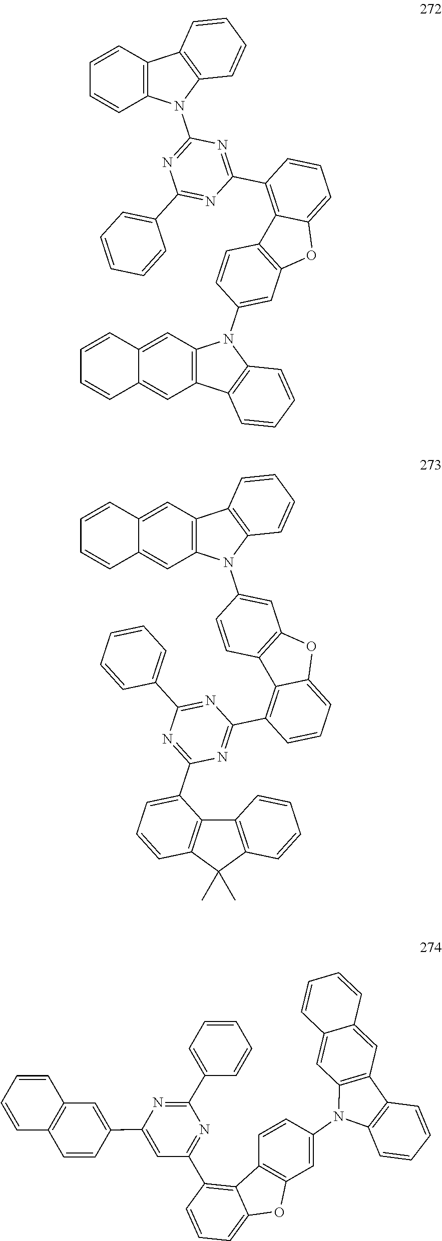 [SMILES: c1ccc(-c2nc(-c3cccc4oc5cc(-n6c7ccccc7c7cc8ccccc8cc76)ccc5c34)nc(-n3c4ccccc4c4ccccc43)n2)cc1 ; CC1(C)c2ccccc2-c2c(-c3nc(-c4ccccc4)nc(-c4cccc5oc6cc(-n7c8ccccc8c8cc9ccccc9cc87)ccc6c45)n3)cccc21 ; c1ccc(-c2nc(-c3ccc4ccccc4c3)cc(-c3cccc4oc5cc(-n6c7ccccc7c7cc8ccccc8cc76)ccc5c34)n2)cc1]

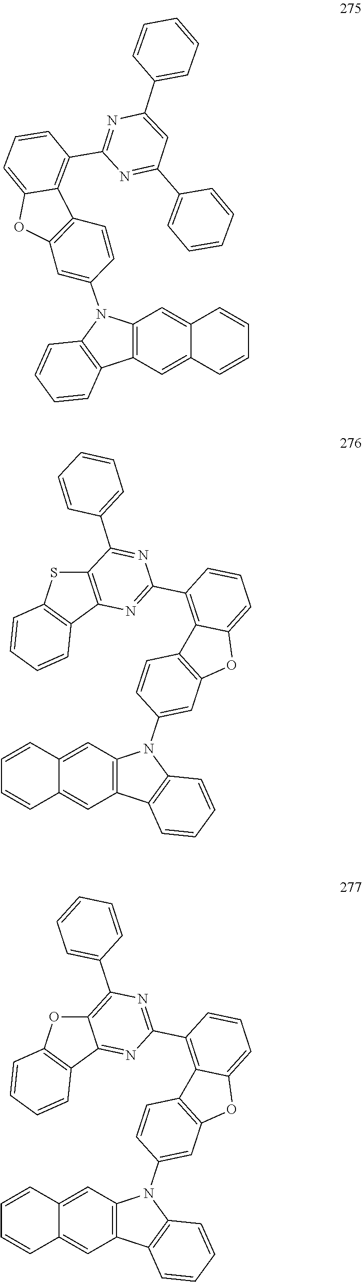

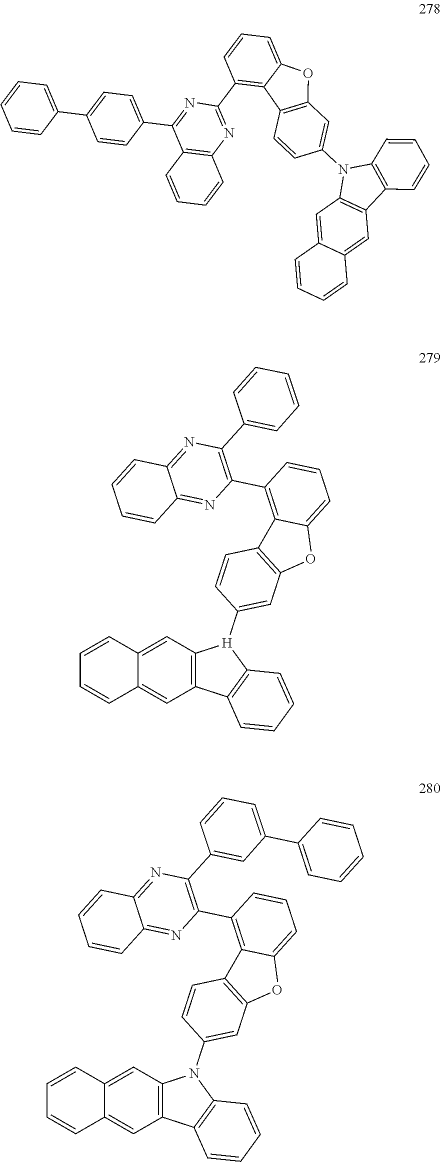

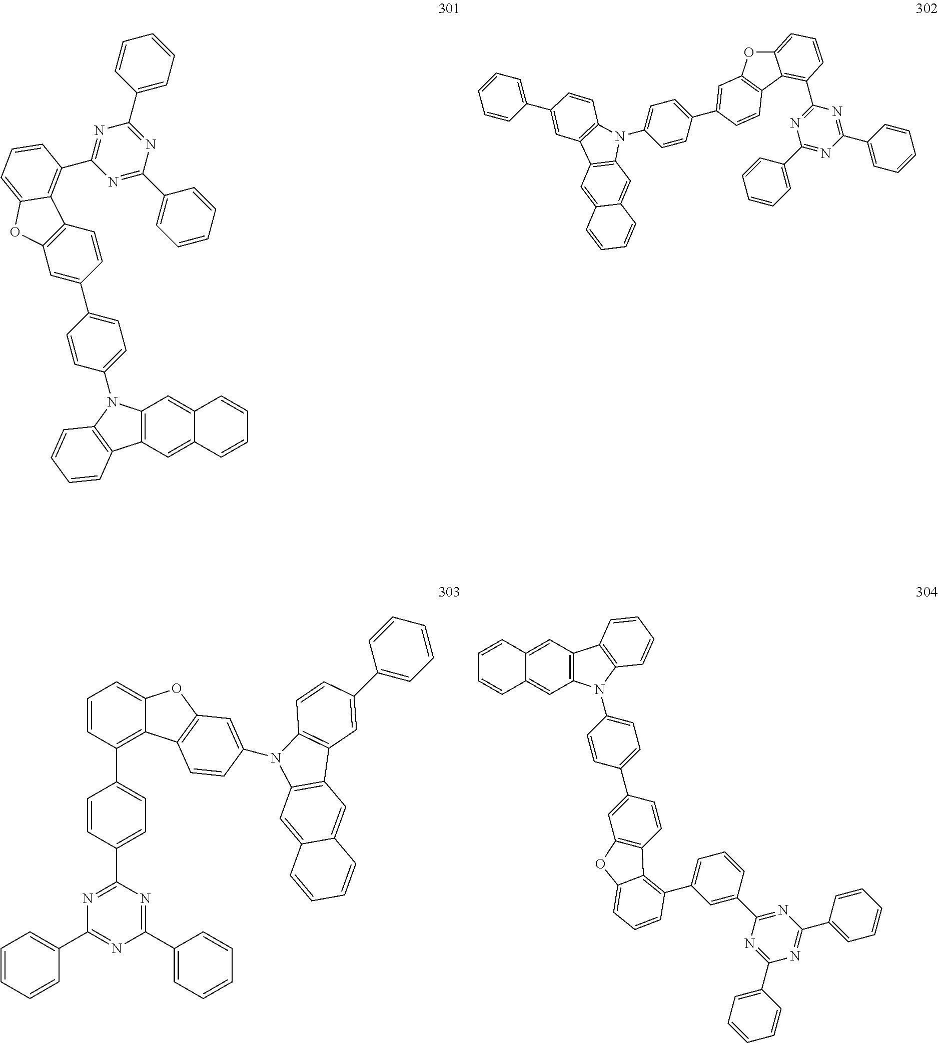 [SMILES: c1ccc(-c2nc(-c3ccccc3)nc(-c3cccc4oc5cc(-c6ccc(-n7c8ccccc8c8cc9ccccc9cc87)cc6)ccc5c34)n2)cc1 ; c1ccc(-c2ccc3c(c2)c2cc4ccccc4cc2n3-c2ccc(-c3ccc4c(c3)oc3cccc(-c5nc(-c6ccccc6)nc(-c6ccccc6)n5)c34)cc2)cc1 ; c1ccc(-c2ccc3c(c2)c2cc4ccccc4cc2n3-c2ccc3c(c2)oc2cccc(-c4ccc(-c5nc(-c6ccccc6)nc(-c6ccccc6)n5)cc4)c23)cc1 ; c1ccc(-c2nc(-c3ccccc3)nc(-c3cccc(-c4cccc5oc6cc(-c7ccc(-n8c9ccccc9c9cc%10ccccc%10cc98)cc7)ccc6c45)c3)n2)cc1]

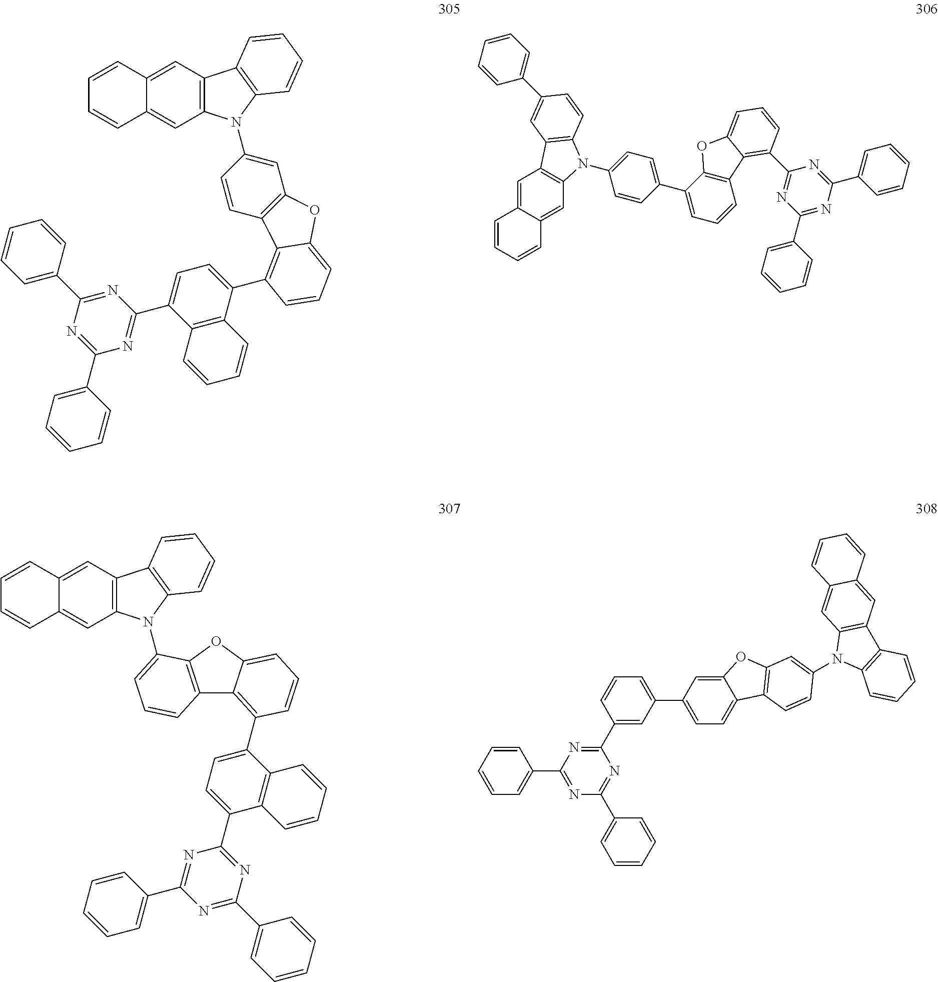 [SMILES: c1ccc(-c2nc(-c3ccccc3)nc(-c3ccc(-c4cccc5oc6cc(-n7c8ccccc8c8cc9ccccc9cc87)ccc6c45)c4ccccc34)n2)cc1 ; c1ccc(-c2ccc3c(c2)c2cc4ccccc4cc2n3-c2ccc(-c3cccc4c3oc3cccc(-c5nc(-c6ccccc6)nc(-c6ccccc6)n5)c34)cc2)cc1 ; c1ccc(-c2nc(-c3ccccc3)nc(-c3ccc(-c4cccc5oc6c(-n7c8ccccc8c8cc9ccccc9cc87)cccc6c45)c4ccccc34)n2)cc1 ; c1ccc(-c2nc(-c3ccccc3)nc(-c3cccc(-c4ccc5c(c4)oc4cc(-n6c7ccccc7c7cc8ccccc8cc76)ccc45)c3)n2)cc1]

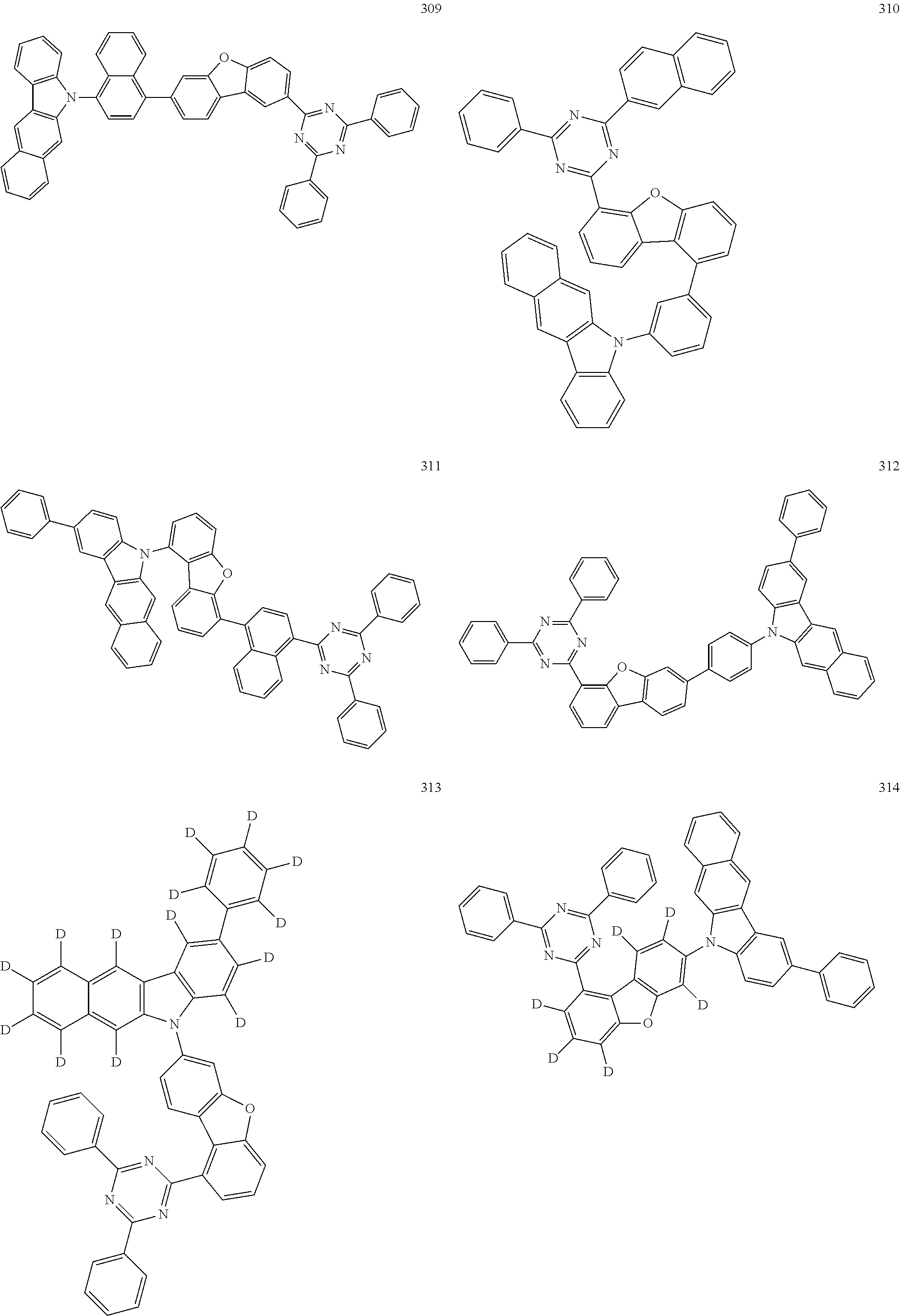

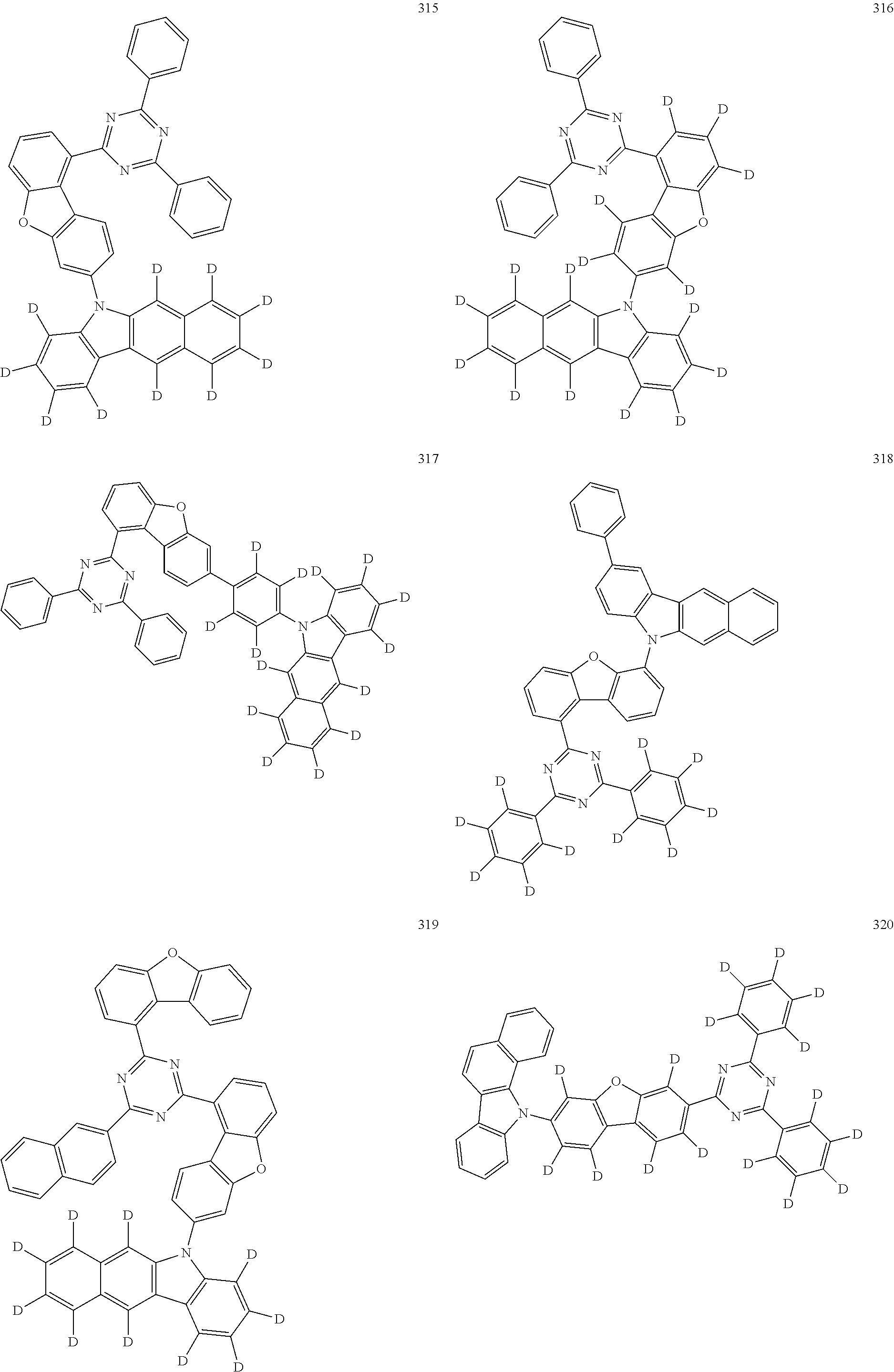

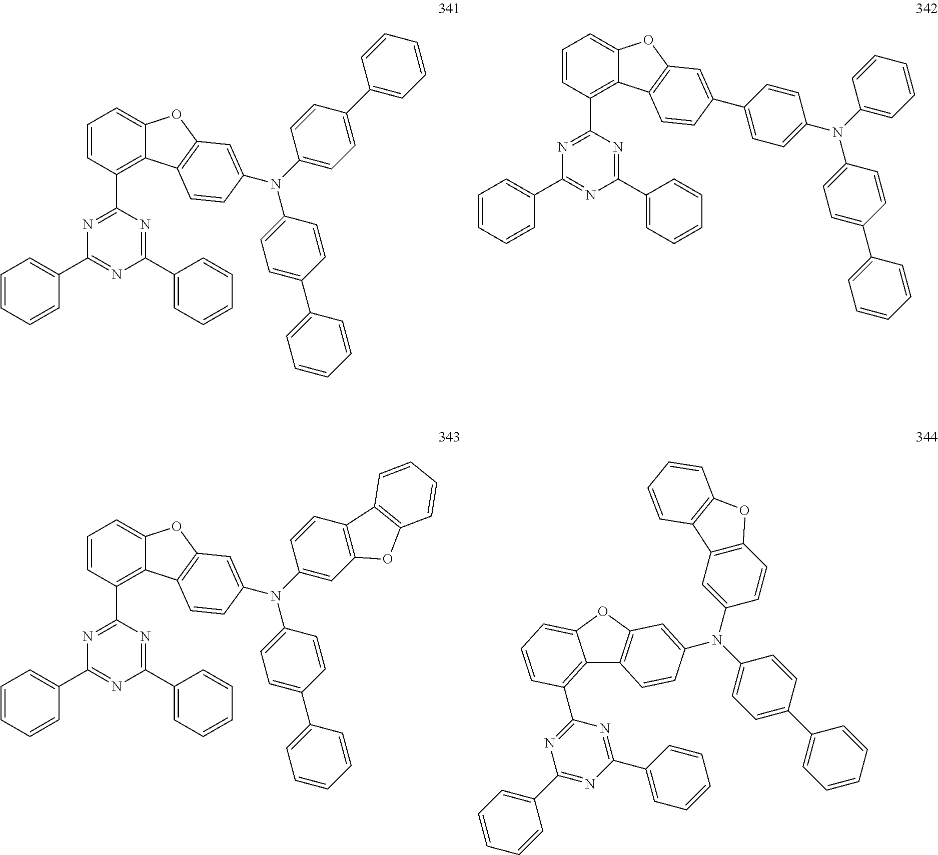 [SMILES: c1ccc(-c2ccc(N(c3ccc(-c4ccccc4)cc3)c3ccc4c(c3)oc3cccc(-c5nc(-c6ccccc6)nc(-c6ccccc6)n5)c34)cc2)cc1 ; c1ccc(-c2ccc(N(c3ccccc3)c3ccc(-c4ccc5c(c4)oc4cccc(-c6nc(-c7ccccc7)nc(-c7ccccc7)n6)c45)cc3)cc2)cc1 ; c1ccc(-c2ccc(N(c3ccc4c(c3)oc3ccccc34)c3ccc4c(c3)oc3cccc(-c5nc(-c6ccccc6)nc(-c6ccccc6)n5)c34)cc2)cc1 ; c1ccc(-c2ccc(N(c3ccc4c(c3)oc3cccc(-c5nc(-c6ccccc6)nc(-c6ccccc6)n5)c34)c3ccc4oc5ccccc5c4c3)cc2)cc1]

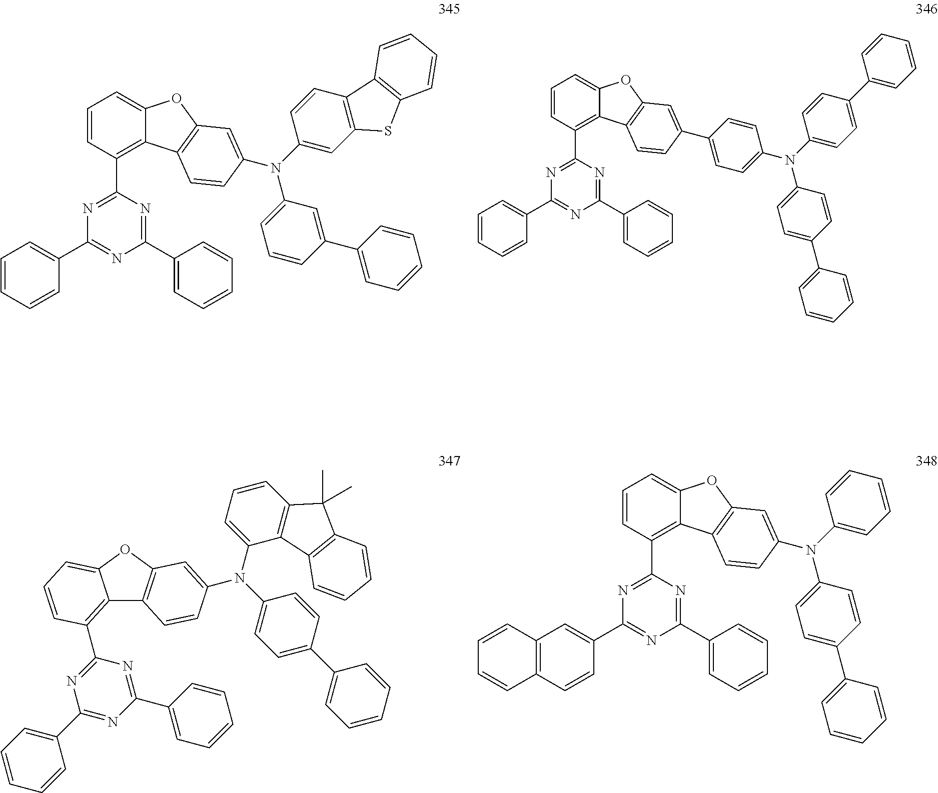 [SMILES: c1ccc(-c2cccc(N(c3ccc4c(c3)oc3cccc(-c5nc(-c6ccccc6)nc(-c6ccccc6)n5)c34)c3ccc4c(c3)sc3ccccc34)c2)cc1 ; c1ccc(-c2ccc(N(c3ccc(-c4ccccc4)cc3)c3ccc(-c4ccc5c(c4)oc4cccc(-c6nc(-c7ccccc7)nc(-c7ccccc7)n6)c45)cc3)cc2)cc1 ; CC1(C)c2ccccc2-c2c(N(c3ccc(-c4ccccc4)cc3)c3ccc4c(c3)oc3cccc(-c5nc(-c6ccccc6)nc(-c6ccccc6)n5)c34)cccc21 ; c1ccc(-c2ccc(N(c3ccccc3)c3ccc4c(c3)oc3cccc(-c5nc(-c6ccccc6)nc(-c6ccc7ccccc7c6)n5)c34)cc2)cc1]

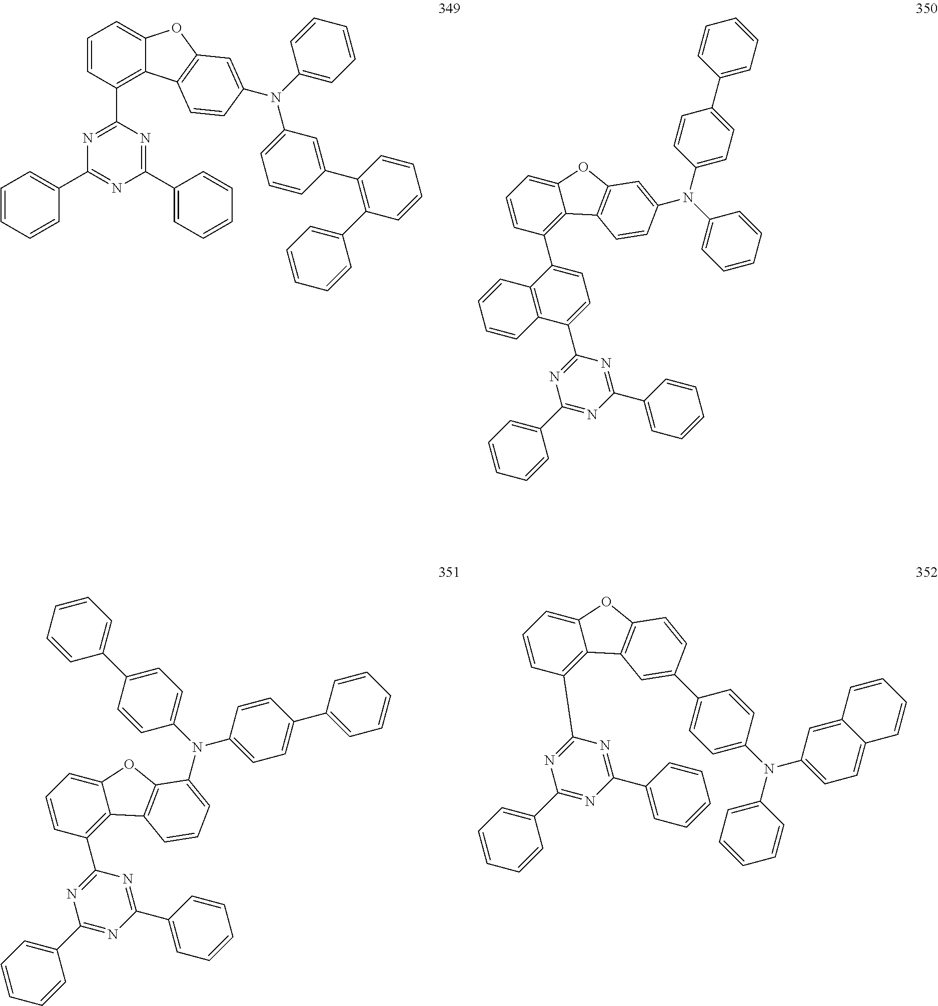 [SMILES: c1ccc(-c2nc(-c3ccccc3)nc(-c3cccc4oc5cc(N(c6ccccc6)c6cccc(-c7ccccc7-c7ccccc7)c6)ccc5c34)n2)cc1 ; c1ccc(-c2ccc(N(c3ccccc3)c3ccc4c(c3)oc3cccc(-c5ccc(-c6nc(-c7ccccc7)nc(-c7ccccc7)n6)c6ccccc56)c34)cc2)cc1 ; c1ccc(-c2ccc(N(c3ccc(-c4ccccc4)cc3)c3cccc4c3oc3cccc(-c5nc(-c6ccccc6)nc(-c6ccccc6)n5)c34)cc2)cc1 ; c1ccc(-c2nc(-c3ccccc3)nc(-c3cccc4oc5ccc(-c6ccc(N(c7ccccc7)c7ccc8ccccc8c7)cc6)cc5c34)n2)cc1]

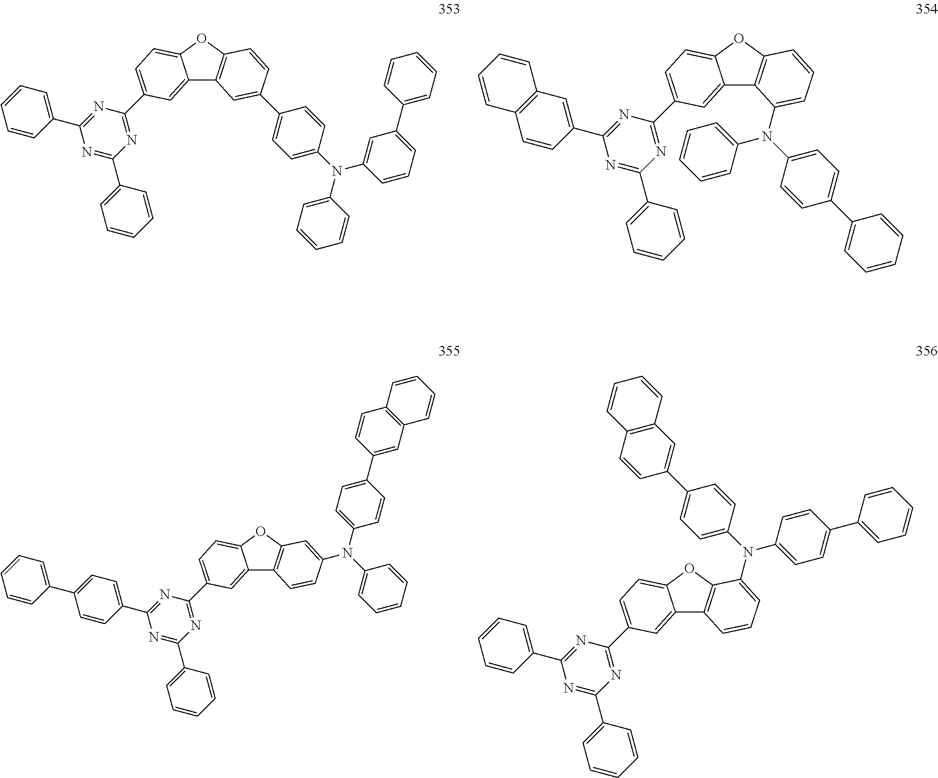 [SMILES: c1ccc(-c2cccc(N(c3ccccc3)c3ccc(-c4ccc5oc6ccc(-c7nc(-c8ccccc8)nc(-c8ccccc8)n7)cc6c5c4)cc3)c2)cc1 ; c1ccc(-c2ccc(N(c3ccccc3)c3cccc4oc5ccc(-c6nc(-c7ccccc7)nc(-c7ccc8ccccc8c7)n6)cc5c34)cc2)cc1 ; c1ccc(-c2ccc(-c3nc(-c4ccccc4)nc(-c4ccc5oc6cc(N(c7ccccc7)c7ccc(-c8ccc9ccccc9c8)cc7)ccc6c5c4)n3)cc2)cc1 ; c1ccc(-c2ccc(N(c3ccc(-c4ccc5ccccc5c4)cc3)c3cccc4c3oc3ccc(-c5nc(-c6ccccc6)nc(-c6ccccc6)n5)cc34)cc2)cc1]

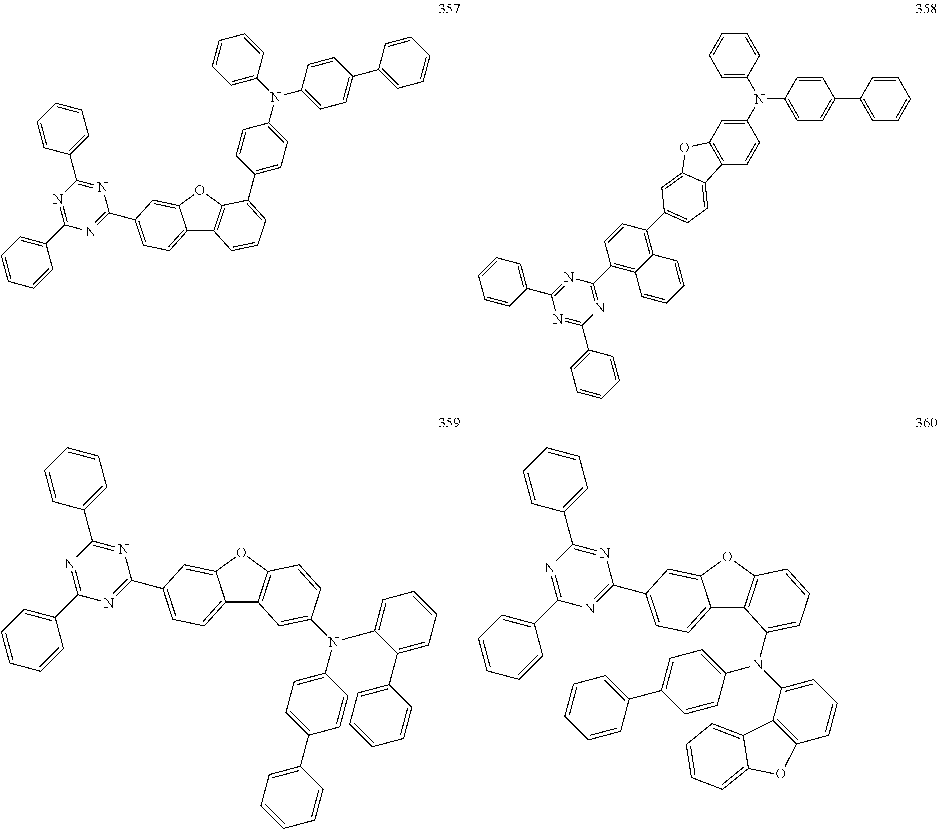 [SMILES: c1ccc(-c2ccc(N(c3ccccc3)c3ccc(-c4cccc5c4oc4cc(-c6nc(-c7ccccc7)nc(-c7ccccc7)n6)ccc45)cc3)cc2)cc1 ; c1ccc(-c2ccc(N(c3ccccc3)c3ccc4c(c3)oc3cc(-c5ccc(-c6nc(-c7ccccc7)nc(-c7ccccc7)n6)c6ccccc56)ccc34)cc2)cc1 ; c1ccc(-c2ccc(N(c3ccc4oc5cc(-c6nc(-c7ccccc7)nc(-c7ccccc7)n6)ccc5c4c3)c3ccccc3-c3ccccc3)cc2)cc1 ; c1ccc(-c2ccc(N(c3cccc4oc5ccccc5c34)c3cccc4oc5cc(-c6nc(-c7ccccc7)nc(-c7ccccc7)n6)ccc5c34)cc2)cc1]

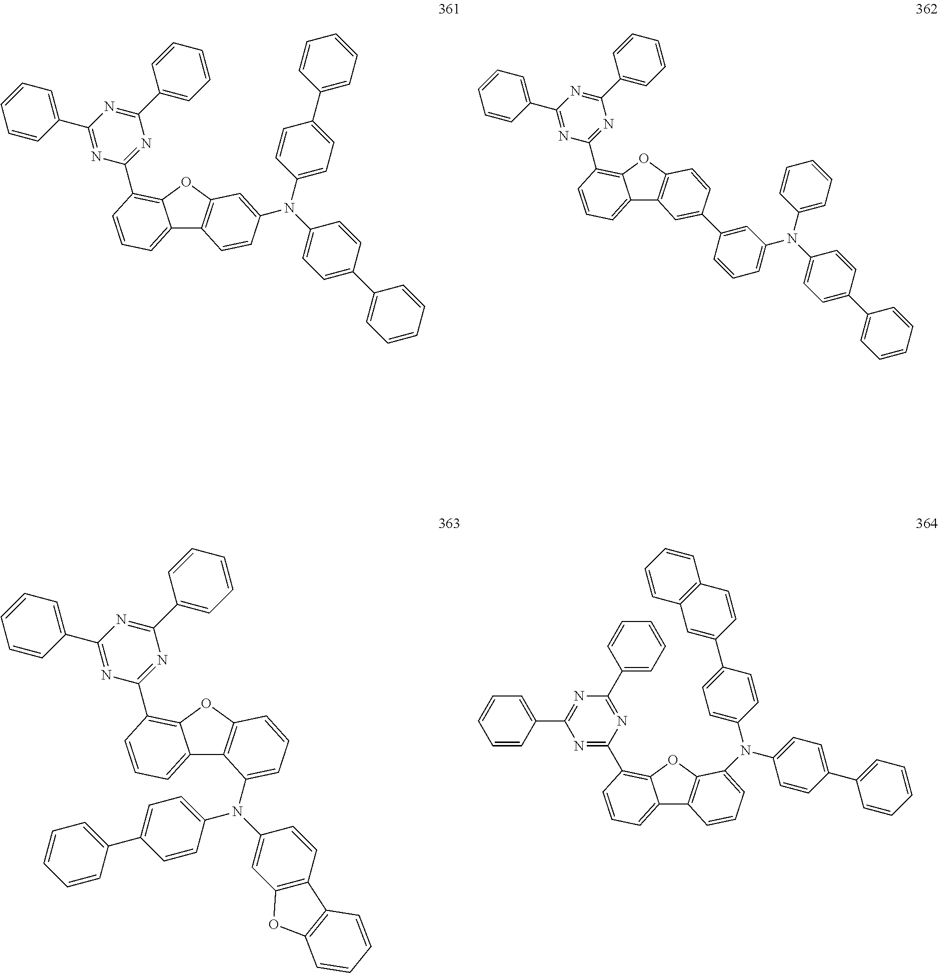 [SMILES: c1ccc(-c2ccc(N(c3ccc(-c4ccccc4)cc3)c3ccc4c(c3)oc3c(-c5nc(-c6ccccc6)nc(-c6ccccc6)n5)cccc34)cc2)cc1 ; c1ccc(-c2ccc(N(c3ccccc3)c3cccc(-c4ccc5oc6c(-c7nc(-c8ccccc8)nc(-c8ccccc8)n7)cccc6c5c4)c3)cc2)cc1 ; c1ccc(-c2ccc(N(c3ccc4c(c3)oc3ccccc34)c3cccc4oc5c(-c6nc(-c7ccccc7)nc(-c7ccccc7)n6)cccc5c34)cc2)cc1 ; c1ccc(-c2ccc(N(c3ccc(-c4ccc5ccccc5c4)cc3)c3cccc4c3oc3c(-c5nc(-c6ccccc6)nc(-c6ccccc6)n5)cccc34)cc2)cc1]

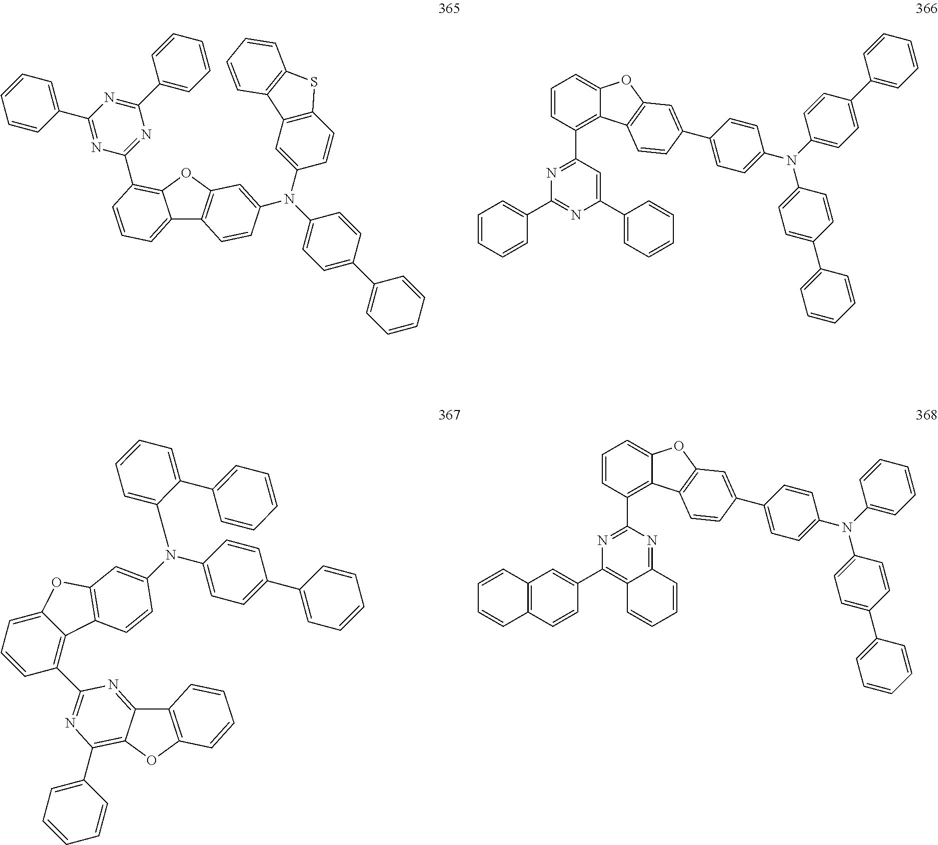 [SMILES: c1ccc(-c2ccc(N(c3ccc4c(c3)oc3c(-c5nc(-c6ccccc6)nc(-c6ccccc6)n5)cccc34)c3ccc4sc5ccccc5c4c3)cc2)cc1 ; c1ccc(-c2ccc(N(c3ccc(-c4ccccc4)cc3)c3ccc(-c4ccc5c(c4)oc4cccc(-c6cc(-c7ccccc7)nc(-c7ccccc7)n6)c45)cc3)cc2)cc1 ; c1ccc(-c2ccc(N(c3ccc4c(c3)oc3cccc(-c5nc(-c6ccccc6)c6oc7ccccc7c6n5)c34)c3ccccc3-c3ccccc3)cc2)cc1 ; c1ccc(-c2ccc(N(c3ccccc3)c3ccc(-c4ccc5c(c4)oc4cccc(-c6nc(-c7ccc8ccccc8c7)c7ccccc7n6)c45)cc3)cc2)cc1]

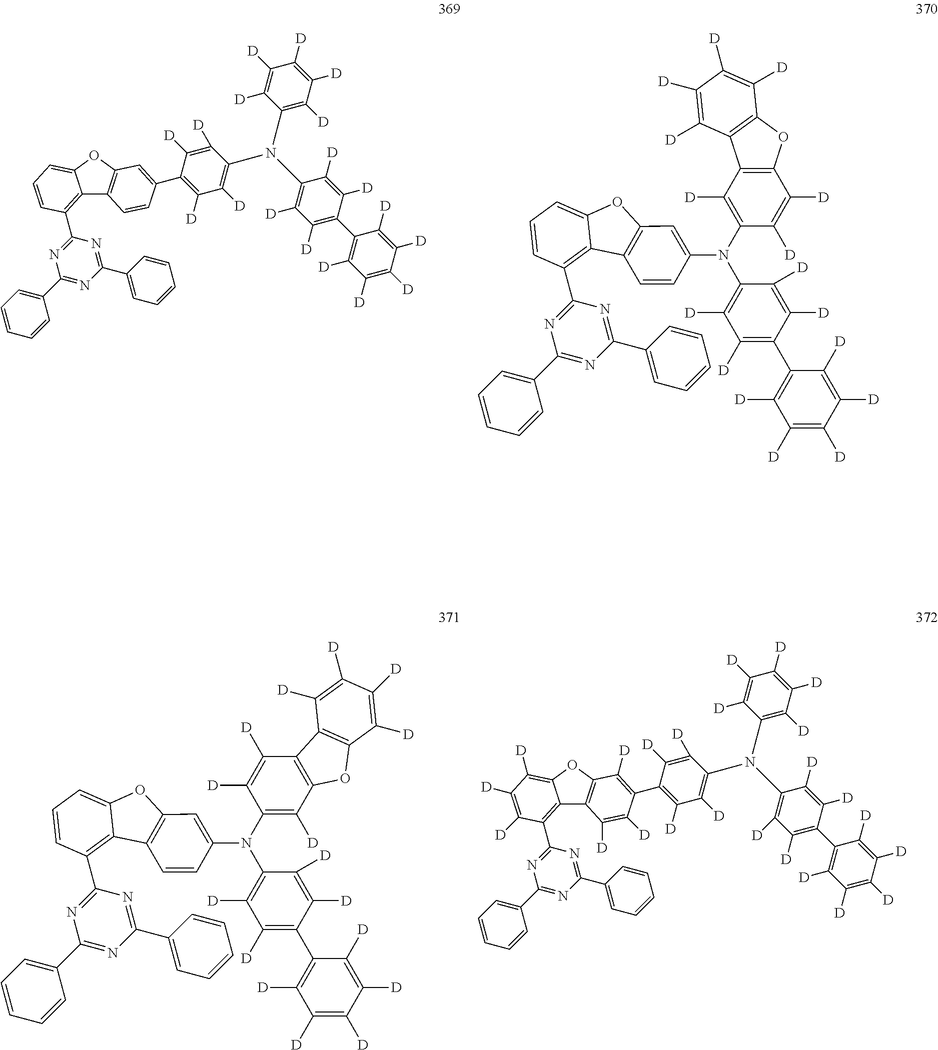

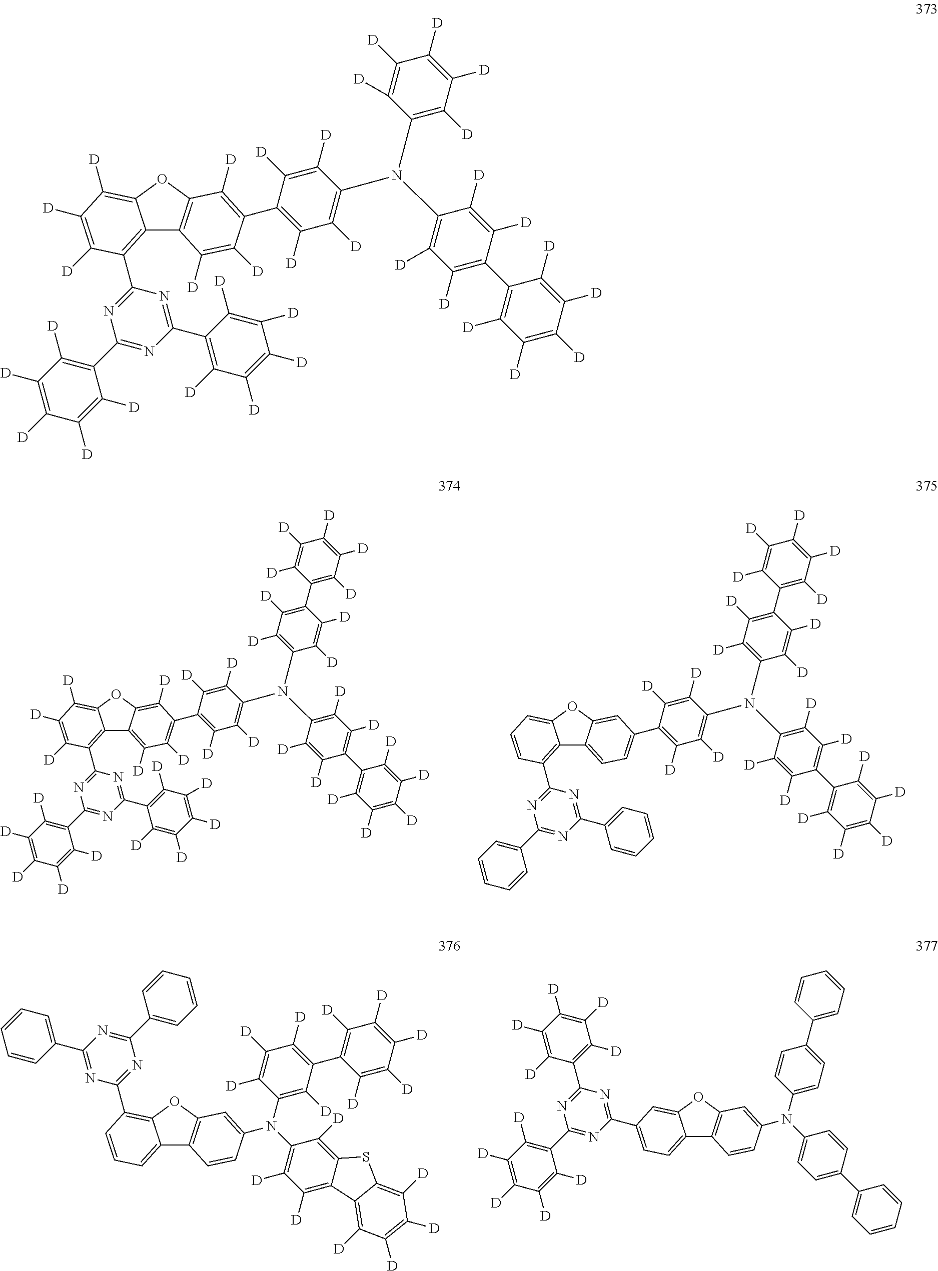

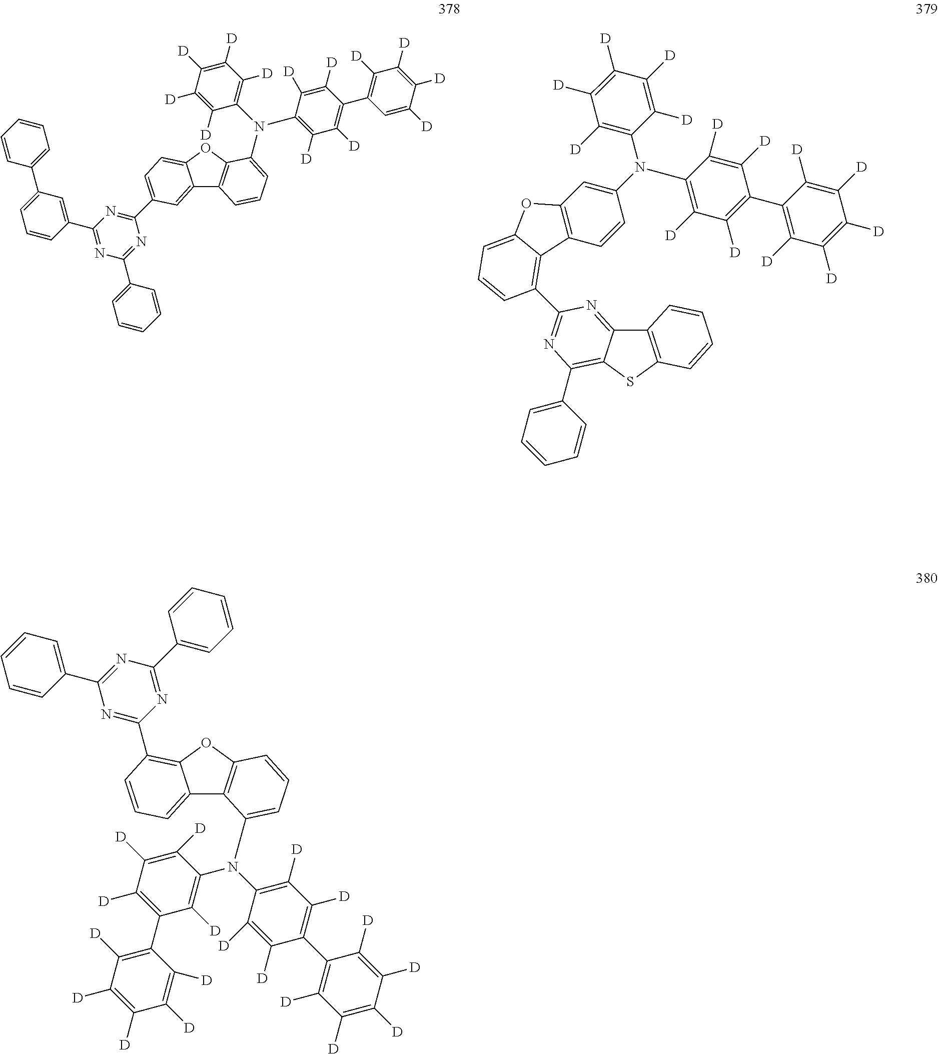

15. The organic light emitting device of claim 1, wherein Chemical Formula 2 is represented by any one of the following compounds:

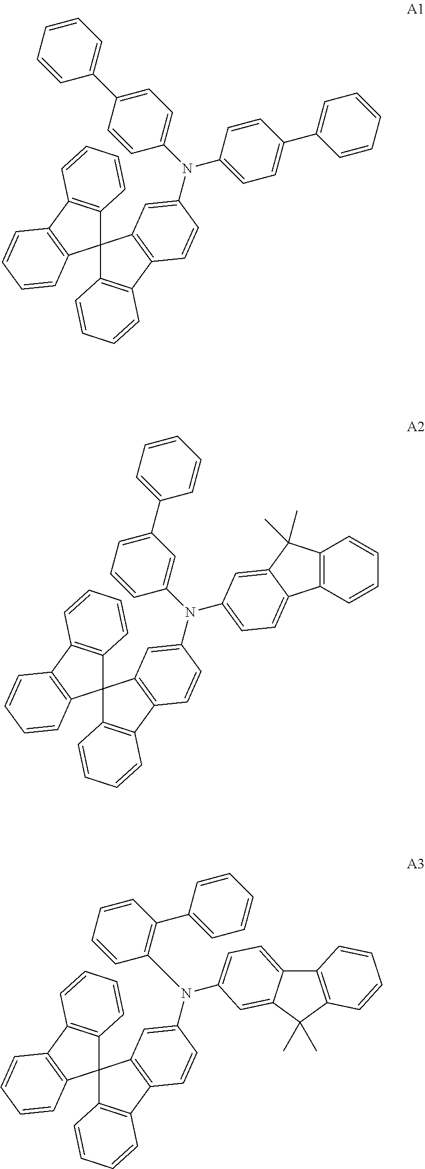 [SMILES: c1ccc(-c2ccc(N(c3ccc(-c4ccccc4)cc3)c3ccc4c(c3)C3(c5ccccc5-c5ccccc53)c3ccccc3-4)cc2)cc1 ; CC1(C)c2ccccc2-c2ccc(N(c3cccc(-c4ccccc4)c3)c3ccc4c(c3)C3(c5ccccc5-c5ccccc53)c3ccccc3-4)cc21 ; CC1(C)c2ccccc2-c2ccc(N(c3ccc4c(c3)C3(c5ccccc5-c5ccccc53)c3ccccc3-4)c3ccccc3-c3ccccc3)cc21]

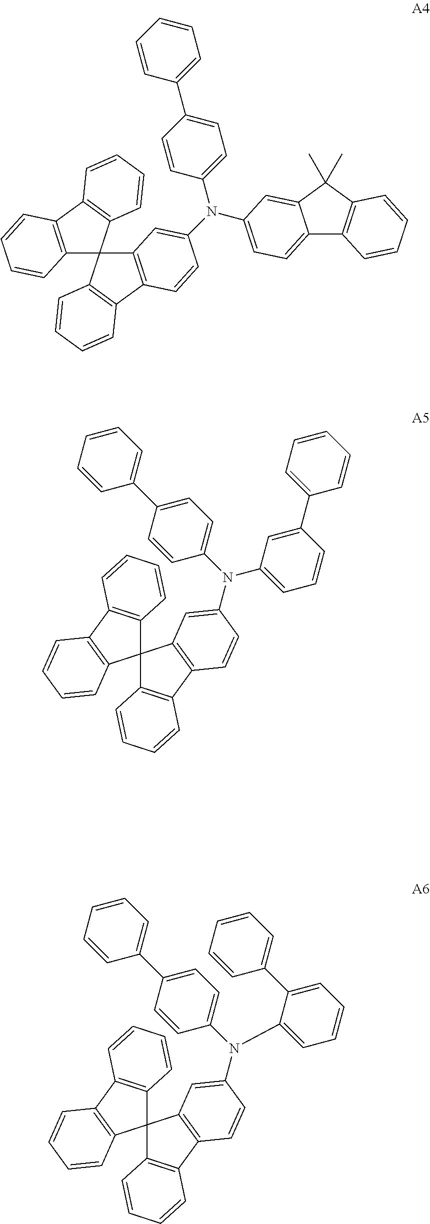 [SMILES: CC1(C)c2ccccc2-c2ccc(N(c3ccc(-c4ccccc4)cc3)c3ccc4c(c3)C3(c5ccccc5-c5ccccc53)c3ccccc3-4)cc21 ; c1ccc(-c2ccc(N(c3cccc(-c4ccccc4)c3)c3ccc4c(c3)C3(c5ccccc5-c5ccccc53)c3ccccc3-4)cc2)cc1 ; c1ccc(-c2ccc(N(c3ccc4c(c3)C3(c5ccccc5-c5ccccc53)c3ccccc3-4)c3ccccc3-c3ccccc3)cc2)cc1]

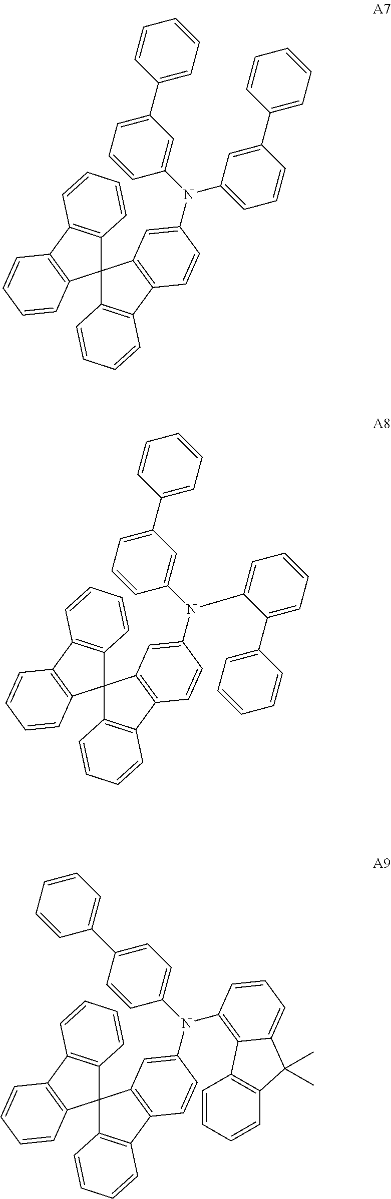 [SMILES: c1ccc(-c2cccc(N(c3cccc(-c4ccccc4)c3)c3ccc4c(c3)C3(c5ccccc5-c5ccccc53)c3ccccc3-4)c2)cc1 ; c1ccc(-c2cccc(N(c3ccc4c(c3)C3(c5ccccc5-c5ccccc53)c3ccccc3-4)c3ccccc3-c3ccccc3)c2)cc1 ; CC1(C)c2ccccc2-c2c(N(c3ccc(-c4ccccc4)cc3)c3ccc4c(c3)C3(c5ccccc5-c5ccccc53)c3ccccc3-4)cccc21]

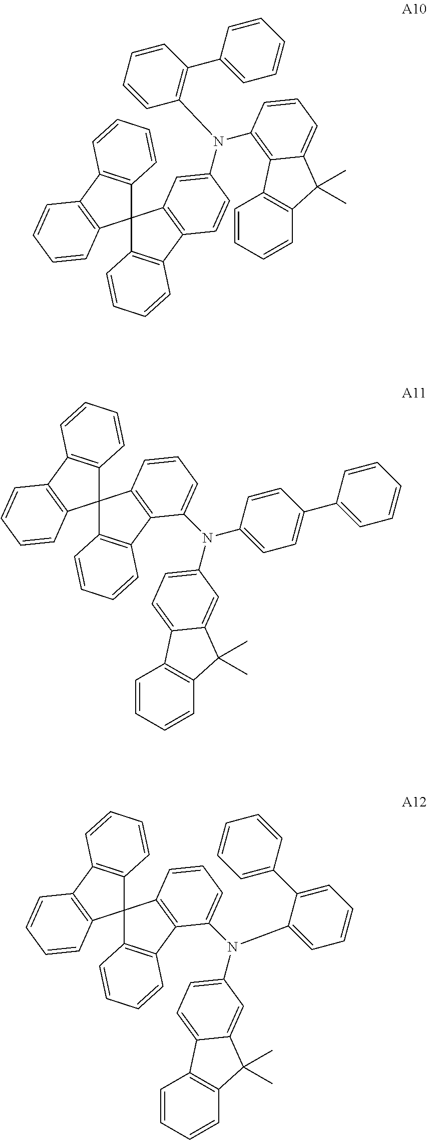 [SMILES: CC1(C)c2ccccc2-c2c(N(c3ccc4c(c3)C3(c5ccccc5-c5ccccc53)c3ccccc3-4)c3ccccc3-c3ccccc3)cccc21 ; CC1(C)c2ccccc2-c2ccc(N(c3ccc(-c4ccccc4)cc3)c3cccc4c3-c3ccccc3C43c4ccccc4-c4ccccc43)cc21 ; CC1(C)c2ccccc2-c2ccc(N(c3ccccc3-c3ccccc3)c3cccc4c3-c3ccccc3C43c4ccccc4-c4ccccc43)cc21]

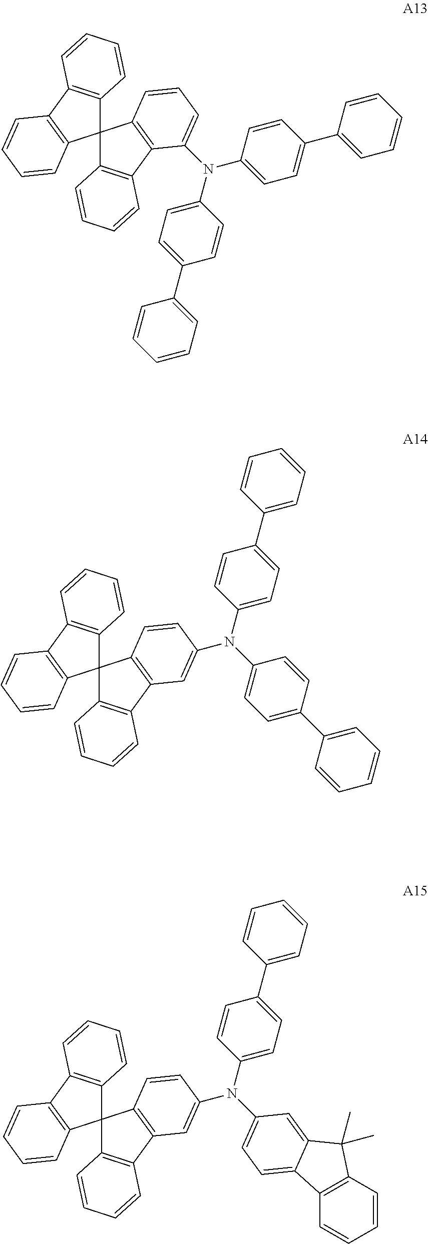 [SMILES: c1ccc(-c2ccc(N(c3ccc(-c4ccccc4)cc3)c3cccc4c3-c3ccccc3C43c4ccccc4-c4ccccc43)cc2)cc1 ; c1ccc(-c2ccc(N(c3ccc(-c4ccccc4)cc3)c3ccc4c(c3)-c3ccccc3C43c4ccccc4-c4ccccc43)cc2)cc1 ; CC1(C)c2ccccc2-c2ccc(N(c3ccc(-c4ccccc4)cc3)c3ccc4c(c3)-c3ccccc3C43c4ccccc4-c4ccccc43)cc21]

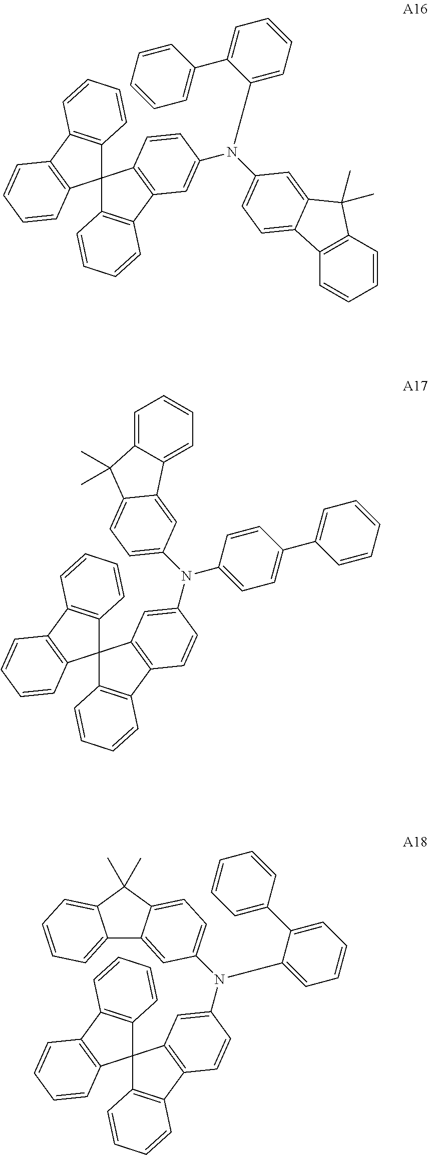 [SMILES: CC1(C)c2ccccc2-c2ccc(N(c3ccc4c(c3)-c3ccccc3C43c4ccccc4-c4ccccc43)c3ccccc3-c3ccccc3)cc21 ; CC1(C)c2ccccc2-c2cc(N(c3ccc(-c4ccccc4)cc3)c3ccc4c(c3)C3(c5ccccc5-c5ccccc53)c3ccccc3-4)ccc21 ; CC1(C)c2ccccc2-c2cc(N(c3ccc4c(c3)C3(c5ccccc5-c5ccccc53)c3ccccc3-4)c3ccccc3-c3ccccc3)ccc21]

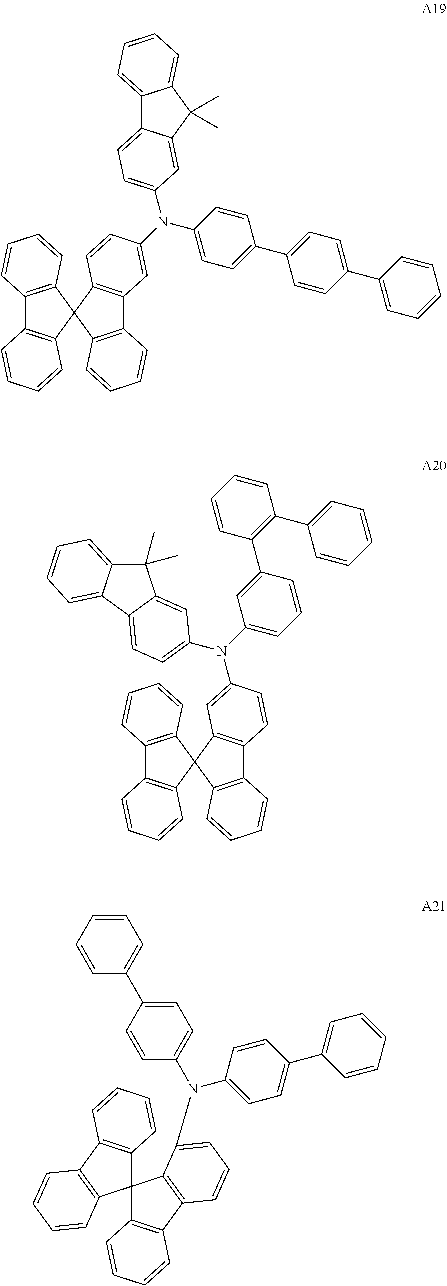 [SMILES: CC1(C)c2ccccc2-c2ccc(N(c3ccc(-c4ccc(-c5ccccc5)cc4)cc3)c3ccc4c(c3)-c3ccccc3C43c4ccccc4-c4ccccc43)cc21 ; CC1(C)c2ccccc2-c2ccc(N(c3cccc(-c4ccccc4-c4ccccc4)c3)c3ccc4c(c3)C3(c5ccccc5-c5ccccc53)c3ccccc3-4)cc21 ; c1ccc(-c2ccc(N(c3ccc(-c4ccccc4)cc3)c3cccc4c3C3(c5ccccc5-c5ccccc53)c3ccccc3-4)cc2)cc1]

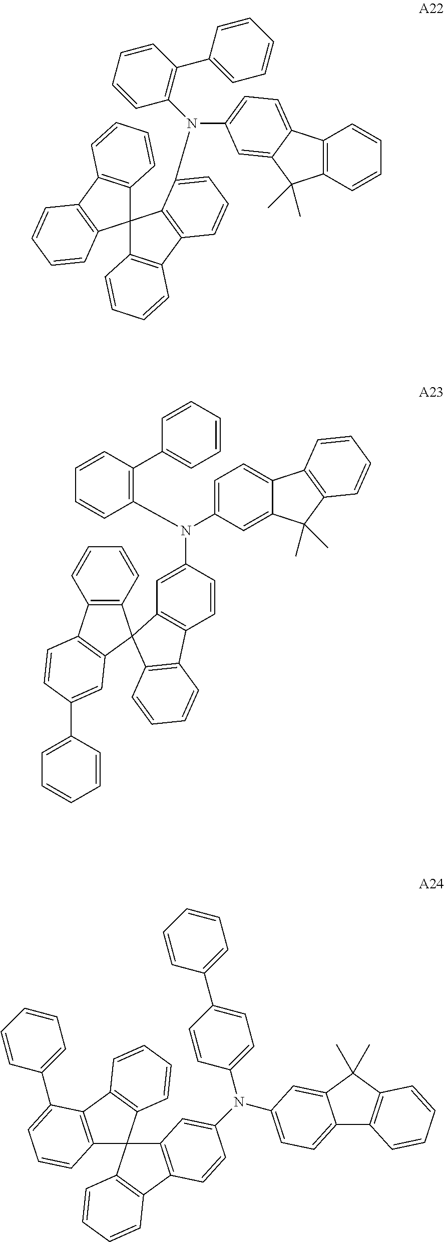 [SMILES: CC1(C)c2ccccc2-c2ccc(N(c3ccccc3-c3ccccc3)c3cccc4c3C3(c5ccccc5-c5ccccc53)c3ccccc3-4)cc21 ; CC1(C)c2ccccc2-c2ccc(N(c3ccc4c(c3)C3(c5ccccc5-c5ccc(-c6ccccc6)cc53)c3ccccc3-4)c3ccccc3-c3ccccc3)cc21 ; CC1(C)c2ccccc2-c2ccc(N(c3ccc(-c4ccccc4)cc3)c3ccc4c(c3)C3(c5ccccc5-4)c4ccccc4-c4c(-c5ccccc5)cccc43)cc21]

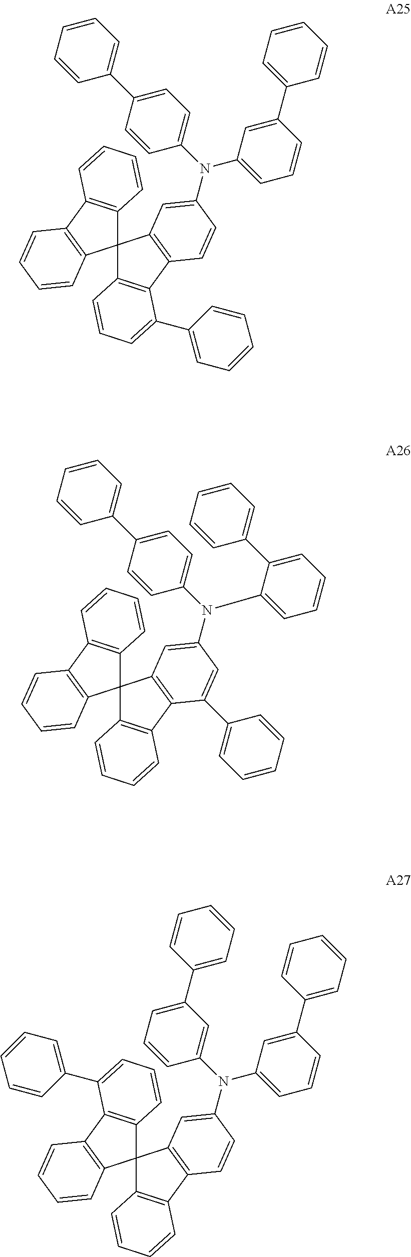 [SMILES: c1ccc(-c2ccc(N(c3cccc(-c4ccccc4)c3)c3ccc4c(c3)C3(c5ccccc5-c5ccccc53)c3cccc(-c5ccccc5)c3-4)cc2)cc1 ; c1ccc(-c2ccc(N(c3cc(-c4ccccc4)c4c(c3)C3(c5ccccc5-c5ccccc53)c3ccccc3-4)c3ccccc3-c3ccccc3)cc2)cc1 ; c1ccc(-c2cccc(N(c3cccc(-c4ccccc4)c3)c3ccc4c(c3)C3(c5ccccc5-4)c4ccccc4-c4c(-c5ccccc5)cccc43)c2)cc1]

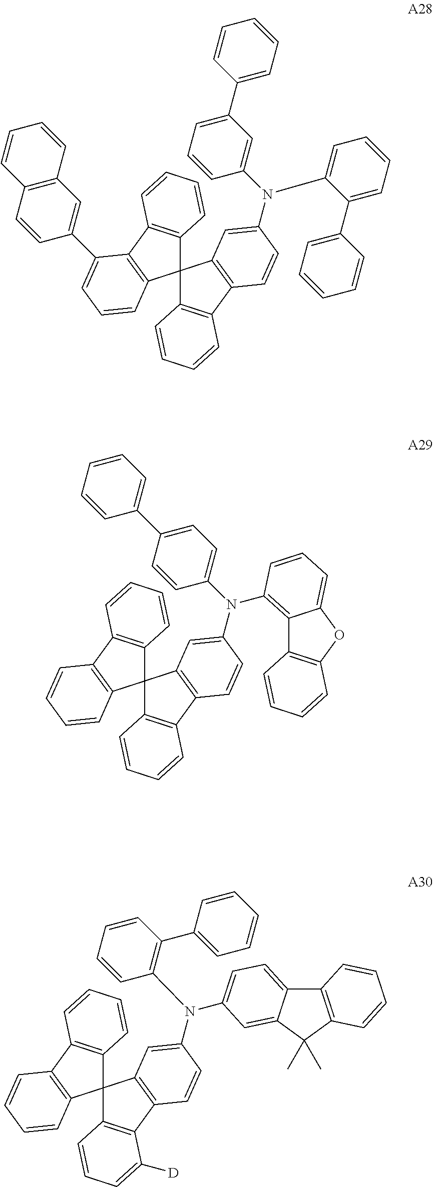 [SMILES: c1ccc(-c2cccc(N(c3ccc4c(c3)C3(c5ccccc5-4)c4ccccc4-c4c(-c5ccc6ccccc6c5)cccc43)c3ccccc3-c3ccccc3)c2)cc1 ; c1ccc(-c2ccc(N(c3ccc4c(c3)C3(c5ccccc5-c5ccccc53)c3ccccc3-4)c3cccc4oc5ccccc5c34)cc2)cc1 ; [2H]c1cccc2c1-c1ccc(N(c3ccc4c(c3)C(C)(C)c3ccccc3-4)c3ccccc3-c3ccccc3)cc1C21c2ccccc2-c2ccccc21]

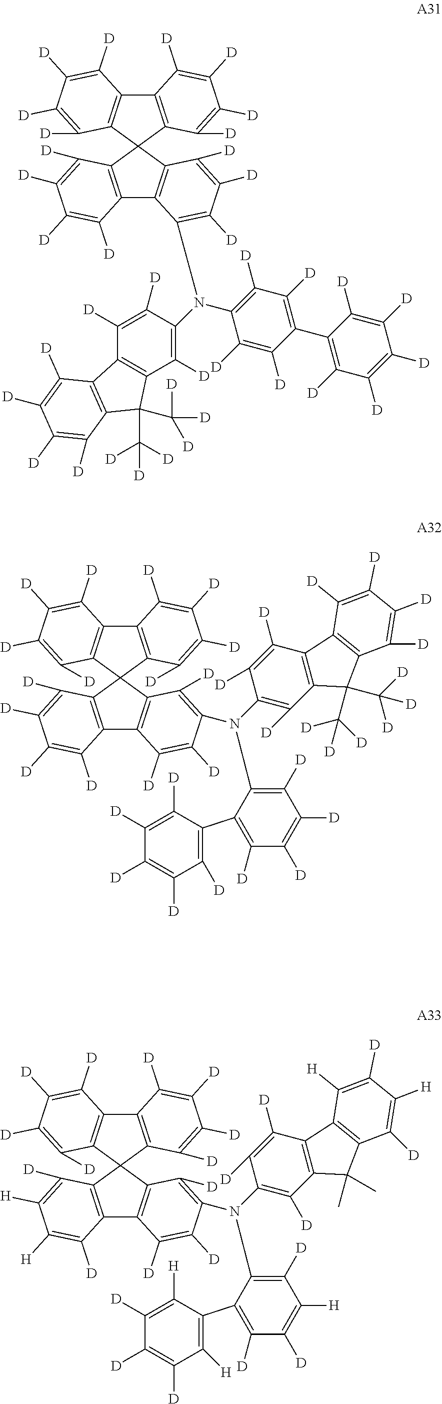

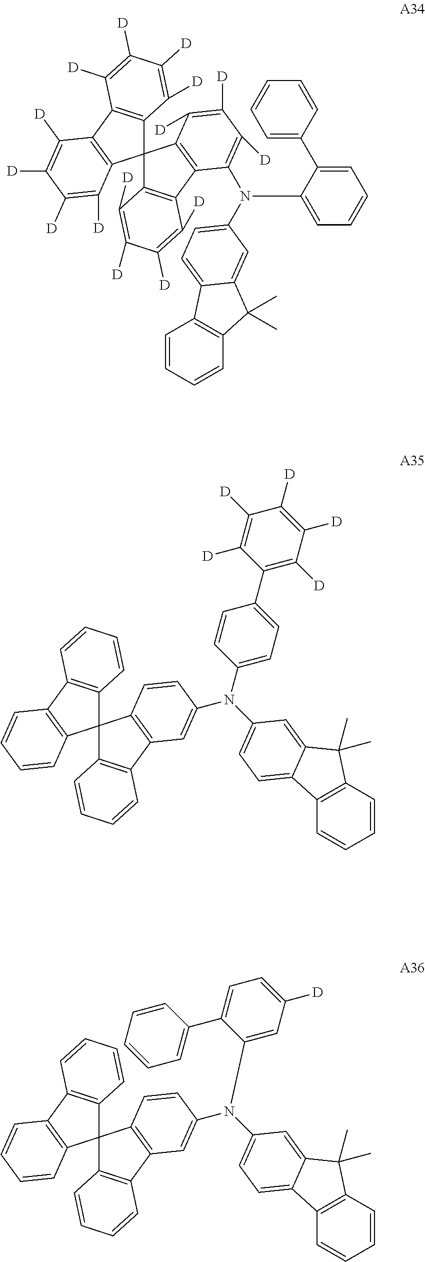 [SMILES: [2H]c1c([2H])c([2H])c2c(c1[2H])-c1c([2H])c([2H])c([2H])c([2H])c1C21c2c([2H])c([2H])c([2H])c([2H])c2-c2c(N(c3ccc4c(c3)C(C)(C)c3ccccc3-4)c3ccccc3-c3ccccc3)c([2H])c([2H])c([2H])c21 ; [2H]c1c([2H])c([2H])c(-c2ccc(N(c3ccc4c(c3)-c3ccccc3C43c4ccccc4-c4ccccc43)c3ccc4c(c3)C(C)(C)c3ccccc3-4)cc2)c([2H])c1[2H] ; [2H]c1ccc(-c2ccccc2)c(N(c2ccc3c(c2)-c2ccccc2C32c3ccccc3-c3ccccc32)c2ccc3c(c2)C(C)(C)c2ccccc2-3)c1]

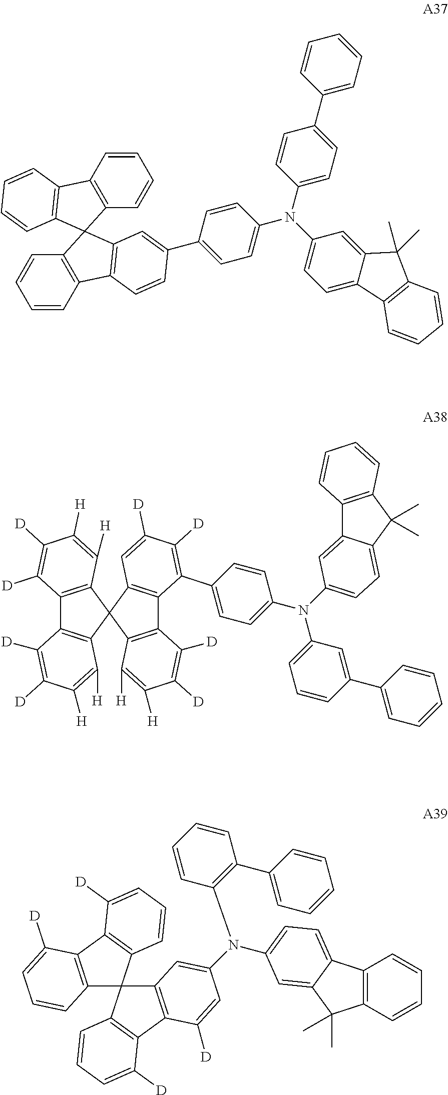 [SMILES: CC1(C)c2ccccc2-c2ccc(N(c3ccc(-c4ccccc4)cc3)c3ccc(-c4ccc5c(c4)C4(c6ccccc6-c6ccccc64)c4ccccc4-5)cc3)cc21 ; [2H]c1ccc2c(c1[2H])-c1c(ccc([2H])c1[2H])C21c2ccc([2H])c([2H])c2-c2c1cc([2H])c([2H])c2-c1ccc(N(c2cccc(-c3ccccc3)c2)c2ccc3c(c2)-c2ccccc2C3(C)C)cc1 ; [2H]c1cccc2c1-c1c([2H])cccc1C21c2cccc([2H])c2-c2c([2H])cc(N(c3ccc4c(c3)C(C)(C)c3ccccc3-4)c3ccccc3-c3ccccc3)cc21]

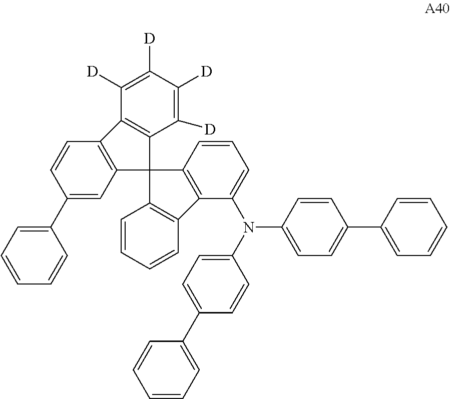 [SMILES: [2H]c1c([2H])c([2H])c2c(c1[2H])-c1ccc(-c3ccccc3)cc1C21c2ccccc2-c2c(N(c3ccc(-c4ccccc4)cc3)c3ccc(-c4ccccc4)cc3)cccc21]

16. The organic light emitting device of claim 1,
wherein the organic material layer further comprises one or more of an electron blocking layer, a hole injection layer, a hole blocking layer and an electron transport layer.

17. The organic light emitting device of claim 1, wherein the light emitting layer comprises the heterocyclic compound represented by Chemical Formula 1 as a host.

18. The organic light emitting device of claim 1, wherein the light emitting layer comprises the heterocyclic compound represented by Chemical Formula 1 as a red host.
